(19) United States
(12) Patent Application Publication
(10) Pub. No.: US 2024/0239825 A1
(43) Pub. Date: Jul. 18, 2024

(54) 1,8-SUBSTITUTED CARBAZOLE-BASED PLATINUM COMPLEXES WITH HIGH RADIATION RATE AND APPLICATION THEREOF

(71) Applicants: ZHEJIANG UNIVERSITY OF TECHNOLOGY, Hangzhou, Zhejiang (CN); ZHEJIANG HUAXIAN PHOTOELECTRICITY TECHNOLOGY CO., LTD, Jiaxing, Zhejiang (CN)

(72) Inventors: Guijie LI, Hangzhou, Zhejiang (CN); Yuanbin SHE, Hangzhou, Zhejiang (CN); Jianbin ZHENG, Hangzhou, Zhejiang (CN); Kewei XU, Hangzhou, Zhejiang (CN)

(21) Appl. No.: 18/555,428

(22) PCT Filed: Apr. 22, 2022
(86) PCT No.: PCT/CN2022/088329

§ 371 Date: Oct. 13, 2023

(30) Foreign Application Priority Data
Apr. 22, 2021 (CN) 202110436077.3

(51) Int. Cl. C07F 15/00; C09K 11/06; H10K 50/11; H10K 50/15; H10K 50/16; H10K 50/18; H10K 85/30

(52) U.S. Cl. CPC C07F 15/0086; C09K 11/06; H10K 50/11; H10K 50/15; H10K 50/16; H10K 50/181; H10K 85/346; C09K 2211/185

(57) ABSTRACT

The present invention provides a high radiation rate platinum complex based on 1,8-substituted carbazole and an application thereof. The luminescent material of the present invention can efficiently control the excited state properties of material molecules by introducing substituents at 1-, 8-position of carbazole, which increases components of metal-to-ligand charge transfer state (MLCT), and improves the intersystem crossing rate of molecules; at the same time, the introduction of substituents at the 1-, 8-position of carbazole can increase the dihedral angle thereof with a pyridine ring, which can improve the rigidity of molecules, effectively reduce the energy consumed by the vibration and rotation of the carbazole ring in the molecules, and reduce non-radiative attenuation. The described factors can jointly increase the radiation rate of material molecules and shorten the lifetime of the excited state.

### TECHNICAL FIELD

The present invention belongs to the field of luminescent materials, and particularly relates to a high radiation rate platinum complex based on 1,8-substituted carbazole and an application thereof.

### BACKGROUND

Since Dr. C. W. Tang and VanSlyke from Kodak in the United States successfully prepared the first high-efficiency organic light emitting device (OLED) in 1987, after more than thirty years of research, OLEDs have developed into a new generation of full color display and solid-state lighting technology. An OLED is a self-luminescent system with the advantages such as low manufacturing cost and energy consumption, high luminous efficiency, wide viewing angle, and fast response, and has broad application prospects in the field of full color display and lighting.

Luminescent materials are core materials of OLED devices, but stable and efficient luminescent materials that can meet commercial applications are still extremely scarce, especially phosphorescent and delayed fluorescent materials with high quantum efficiency. Therefore, the design and development of novel high-performance luminescent materials remain an important direction for promoting the development of the OLED field. In addition, the stability of the OLED devices remains a bottleneck issue that restricts their development, while a radiation rate (kᵣ^{obs}) of the luminescent materials is an important factor affecting the stability of the OLED devices. Increasing the radiation rate of luminescent material molecules may enable them to efficiently emit light in a radiation mode; at the same time, the time the molecules are in an excited state is shortened, the lifetime τ^{obs} of the excited state of the molecules is reduced, and singlet excitons which produce high energy due to triplet-triplet exciton annihilation are reduced or avoided; and in addition, thermal energy produced by non-radiative relaxation of excited-state molecules is reduced, and the stability of the material molecules and the OLED devices is improved. Therefore, designing and developing luminescent materials with a high radiation rate kᵣ^{obs} and a short excited-state lifetime τ^{obs} is of great significance for improving the stability of the material molecules and the OLED devices.

### SUMMARY OF THE INVENTION

The object of the present invention is to, aiming at the shortcomings in the prior art, provide a high radiation rate platinum complex based on 1,8-substituted carbazole and an application thereof. The luminescent material of the present invention is a tetradentate cyclometalated platinum (II) complex based on phenyl carbazole molecule parent nuclei and containing 1,8-substituted carbazole, and has a high radiation rate kᵣ^{obs} and a short excited-state lifetime τ^{obs}.

The object of the present invention is implemented through the following technical solution: a high radiation rate platinum complex luminescent material based on 1,8-substituted carbazole is a tetradentate cyclometalated platinum (II) complex containing 1,8-di(substituted) carbazole having a chemical formula as shown in General Formula (1):

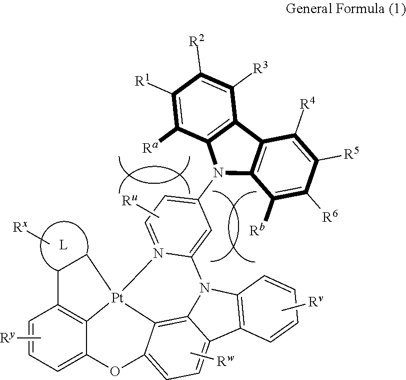

wherein L is a five-membered or six-membered heteroaromatic ring.
   R^{a} and R^{b} are not hydrogen atoms, and each independently represent alkyl, alkoxy, cycloalkyl, heterocyclyl, alkenyl, substituted or unsubstituted aryl, substituted or unsubstituted aryloxy, substituted or unsubstituted heteroaryl, halogen, hydroxyl, sulfhydryl, nitryl, cyano, amino, carboxyl, sulfo, hydrazino, carbamido, alkynyloxy, ester group, acylamino, sulfonyl, sulfinyl, sulfonylamino, phosphorylamino, alkoxycarbonylamino, aryloxycarbonylamino, silyl, alkylamino, dialkylamino, monoarylamino, biarylamino, ureylene, imino, or a combination thereof.
   R¹, R², R³, R⁴, R⁵ and R⁶ each independently represent hydrogen, deuterium, alkyl, alkoxy, cycloalkyl, heterocyclyl, alkenyl, substituted or unsubstituted aryl, substituted or unsubstituted aryloxy, substituted or unsubstituted heteroaryl, halogen, hydroxyl, sulfhydryl, nitryl, cyano, amino, carboxyl, sulfo, hydrazino, carbamido, alkynyloxy, ester group, acylamino, sulfonyl, sulfinyl, sulfonylamino, phosphorylamino, alkoxycarbonylamino, aryloxycarbonylamino, silyl, alkylamino, dialkylamino, monoarylamino, biarylamino, ureylene, imino, or a combination thereof.
   Two or more of R¹, R², R³, R⁴, R⁵ and R⁶ are able to be connected to form a fused ring, and the fused ring is further able to be fused with other rings.
   R^{u}, R^{v}, R^{w}, R^{x} and R^{y} each independently represent mono-substituted, bis-substituted, tri-substituted, tetra-substituted or unsubstituted, and R^{u}, R^{v}, R^{w}, R^{x} and R^{y} each independently are hydrogen, deuterium, alkyl, alkoxy, cycloalkyl, heterocyclyl, alkenyl, substituted or unsubstituted aryl, substituted or unsubstituted aryloxy, substituted or unsubstituted heteroaryl, halogen, hydroxyl, sulfhydryl, nitryl, cyano, amino, carboxyl, sulfo, hydrazino, carbamido, alkynyloxy, ester group, acylamino, sulfonyl, sulfinyl, sulfonylamino, phosphorylamino, alkoxycarbonylamino, aryloxycarbonylamino, silyl, alkylamino, dialkylamino, monoarylamino, biarylamino, ureylene, imino, or a combination thereof; and two or more adjacent ones of R^{u}, R^{v}, R^{w}, R^{x} and R^{y} are each independently or selectively connected to form a fused ring.

Further, the luminescent material has one of the following chemical structures:

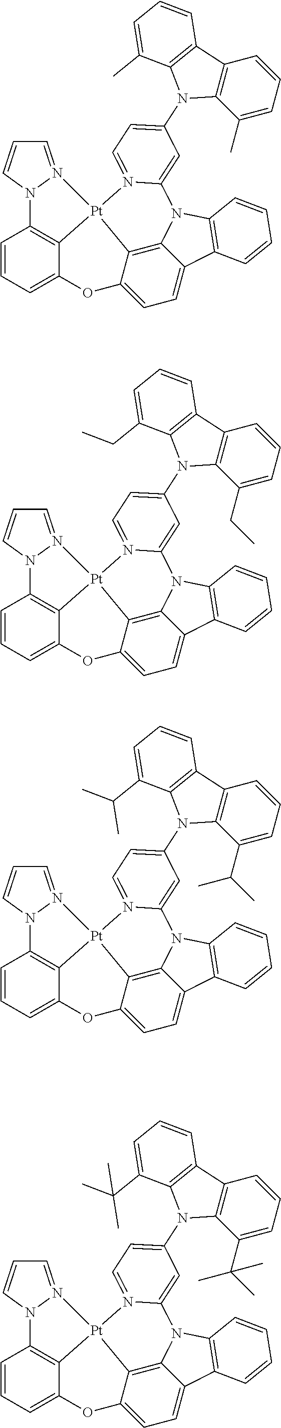

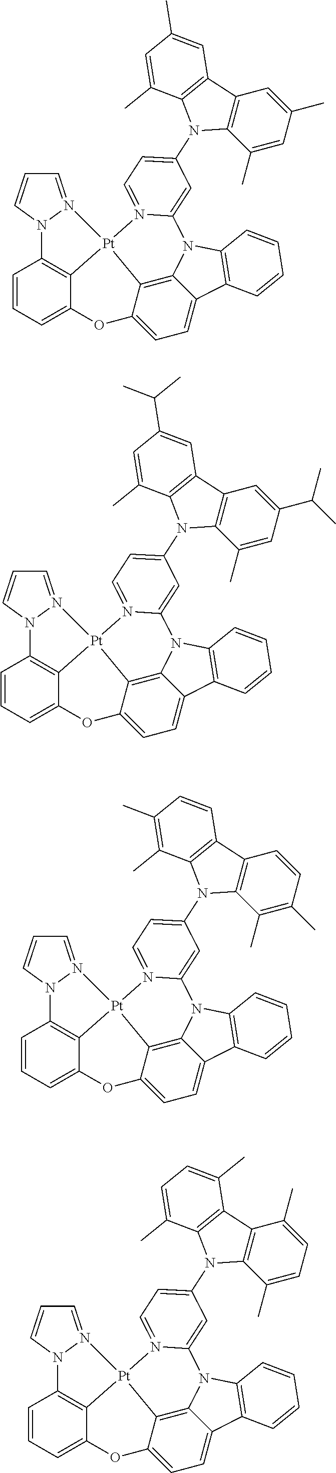

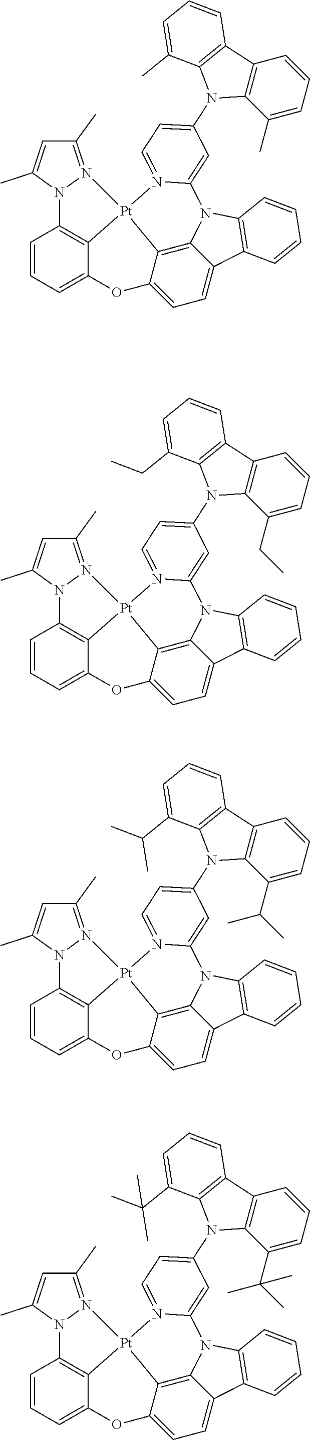

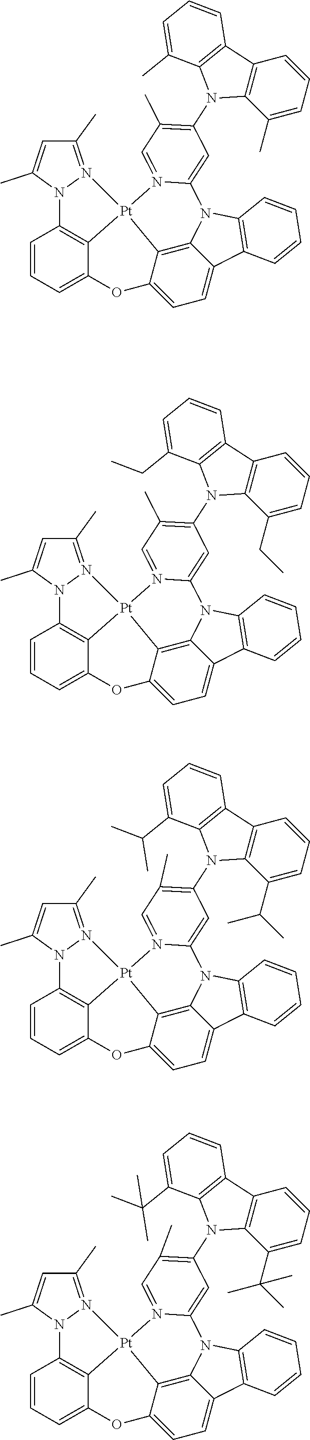

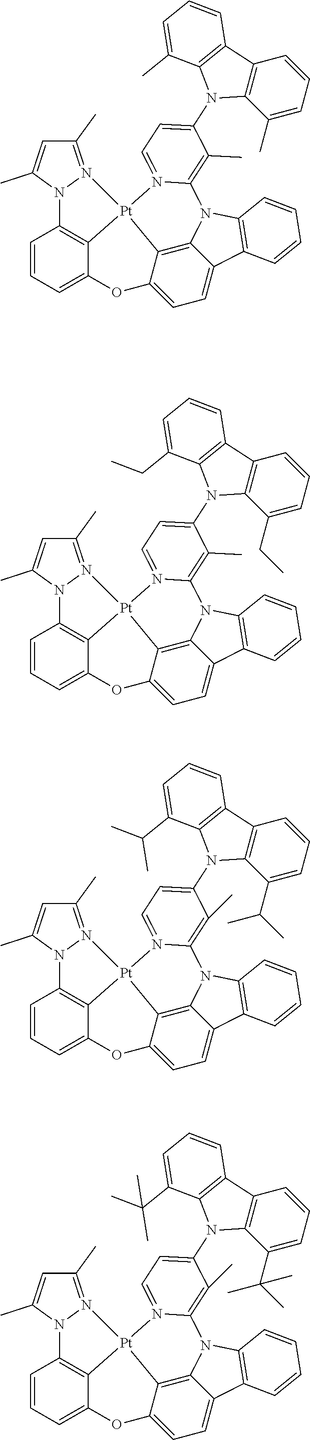

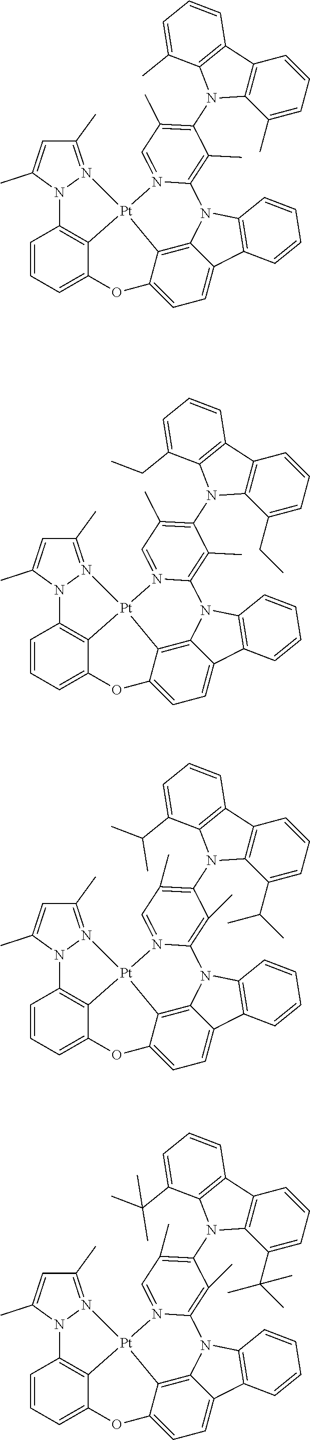

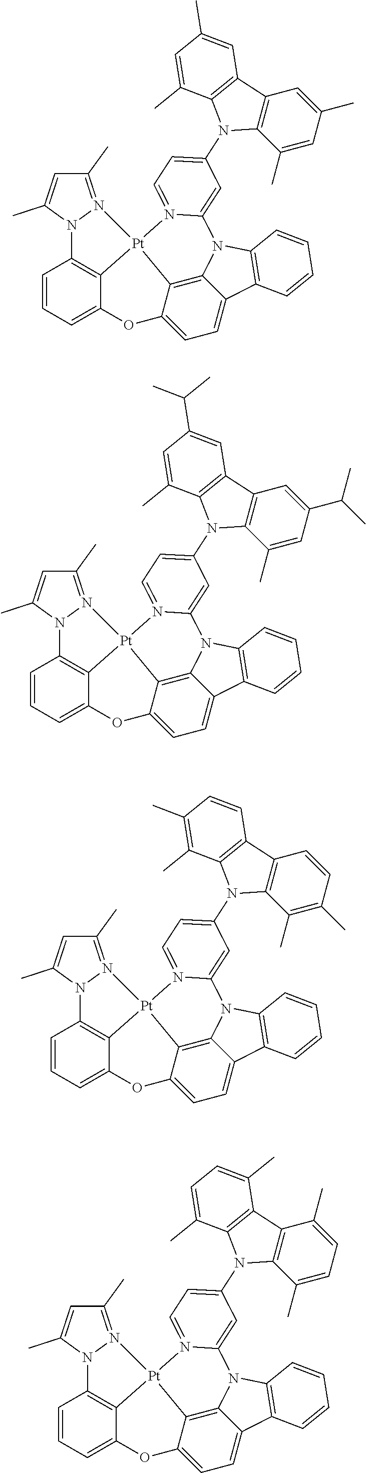

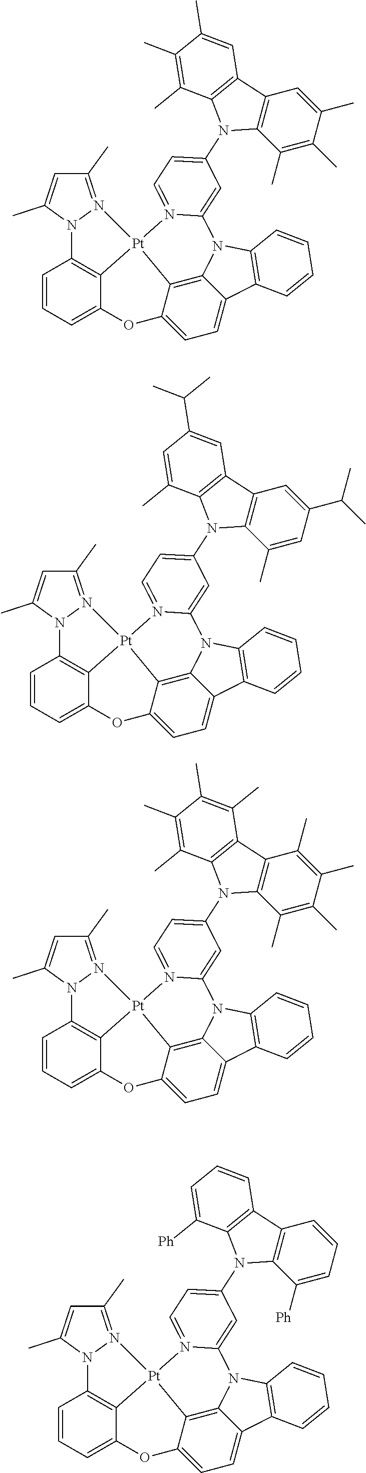

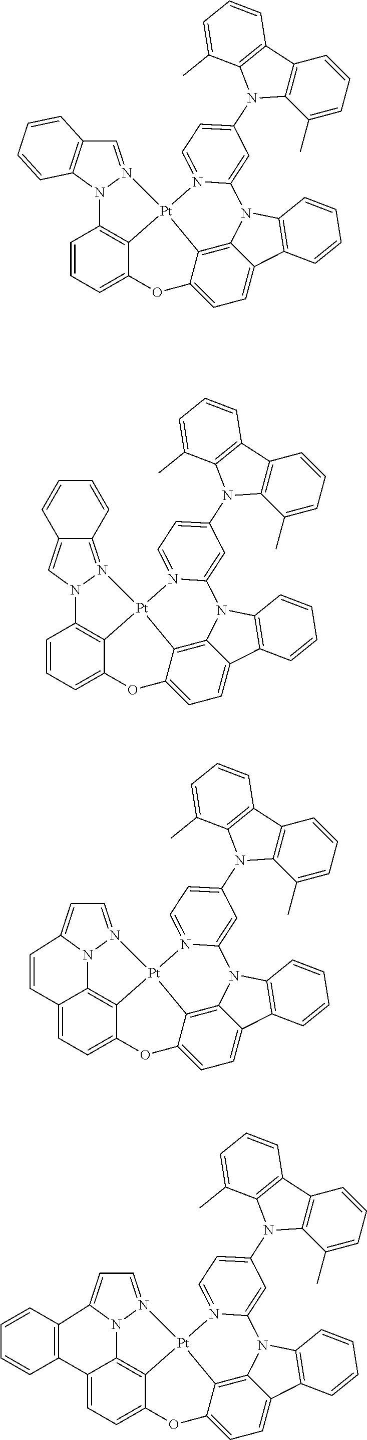

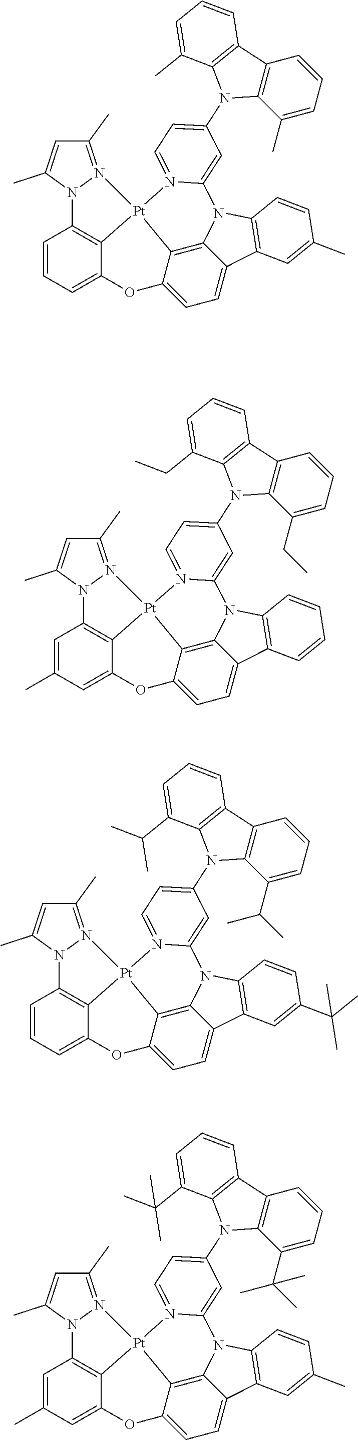

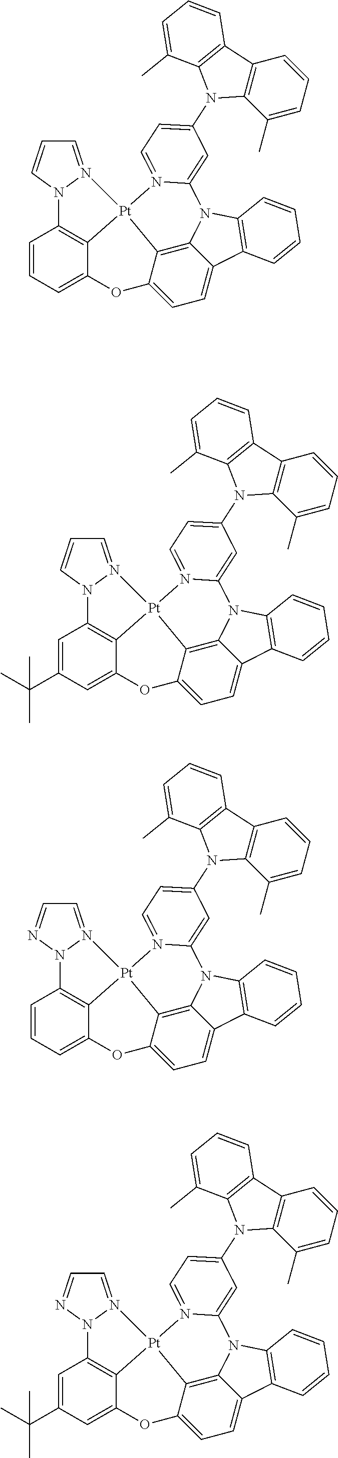

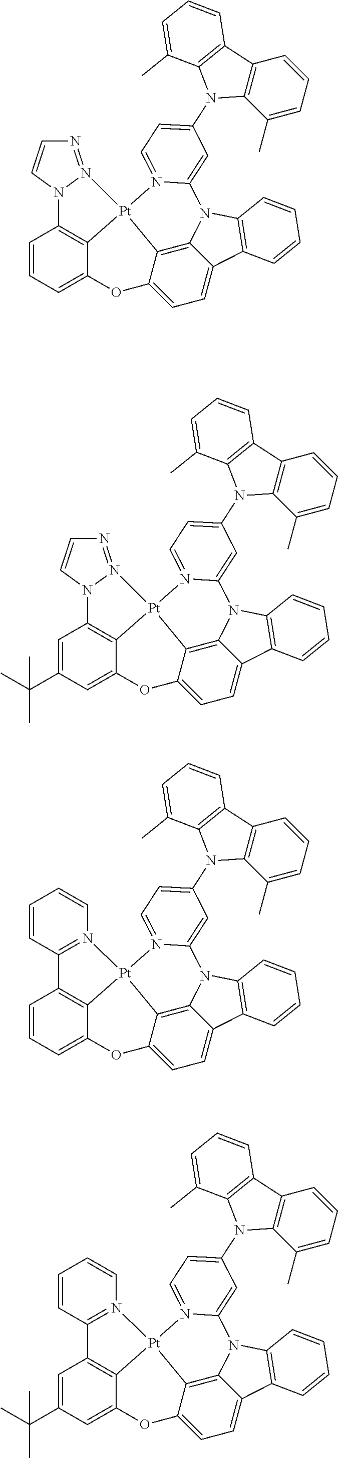

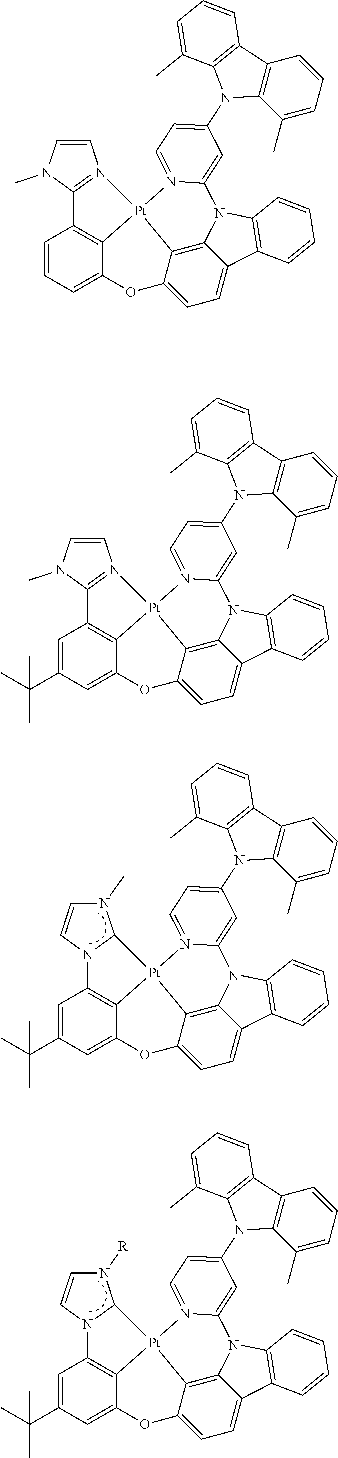

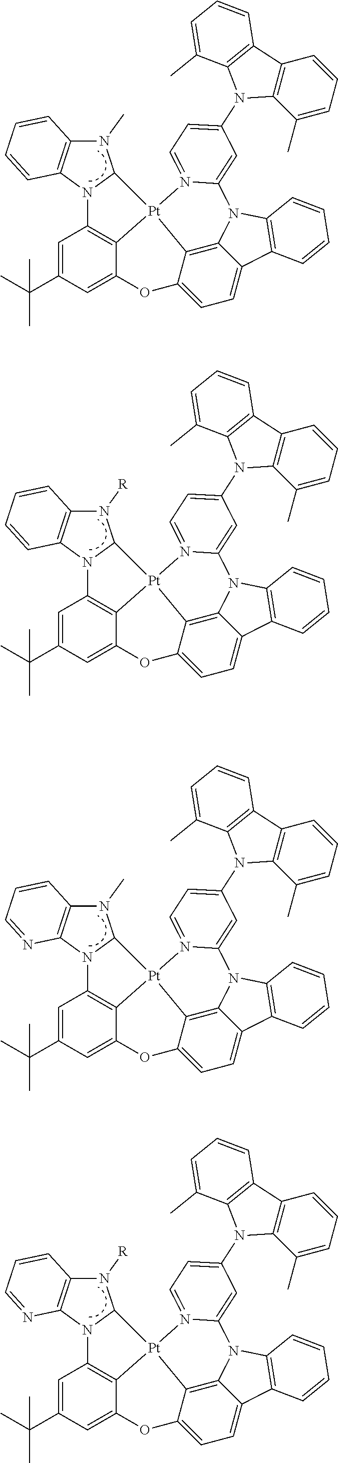

wherein R is not alkyl except for methyl, alkoxy, cycloalkyl, heterocyclyl, alkenyl, substituted or unsubstituted aryl, substituted or unsubstituted aryloxy, substituted or unsubstituted heteroaryl, or deuterated substituents thereof.

An application of the above high radiation rate platinum complex luminescent material based on 1,8-substituted carbazole in an organic light emitting element is provided.

Further, the organic light emitting element is an organic light emitting diode, a light emitting diode, or a light emitting electrochemical cell.

An application of the above high radiation rate platinum complex luminescent material based on 1,8-substituted carbazole is provided, and the luminescent material serves as a phosphorescent luminescent material or a delayed fluorescent material in an organic light emitting device.

A light emitting device includes a first electrode, a second electrode and an organic layer; at least one of the organic layer is disposed between the first electrode and the second electrode; and the organic layer includes the above luminescent material.

Further, the organic layer is at least one of a hole injection layer, a hole transport layer, a light emitting layer or active layer, an electron blocking layer or an electron transport layer.

A display apparatus includes the above light emitting device.

The present invention has the beneficial effects:
(1) by introducing substituents at 1-, 8-position of carbazole in a ligand, a dihedral angle between a substituted carbazole ring and a pyridine ring may be increased, conjugation between the two rings is reduced, the excited state properties of material molecules are regulated, components of a metal-to-ligand charge transfer state (MLCT) are increased, and the intersystem crossing rate of the molecules is increased, thereby increasing the radiation rate kᵣ^{obs} and shortening the excited-state lifetime τ^{obs}; at the same time, the phosphorescent quantum efficiency of the material molecules is improved; and
(2) the dihedral angle between the substituted carbazole ring and the pyridine ring is increased, which may improve the rigidity of the molecules, effectively reduce the energy consumed by the vibration and rotation of the carbazole ring in the molecules, reduce non-radiative attenuation and improve the phosphorescent quantum efficiency.

### BRIEF DESCRIPTION OF THE DRAWINGS

FIG. 1 is a schematic diagram of optimized molecular structures of PtPN1-Cz and PtDMCz calculated through a density functional theory (DFT) and a corresponding dihedral angle between carbazole/pyridine and 1,8-dimethyl/pyridine.

FIG. 2 is a schematic comparison diagram of an emission spectrogram of PtON1-Cz under various environments, wherein 2-MeTHF is 2-methyltetrahydrofuran, DCM is dichloromethane, and RT represents a room temperature.

FIG. 3 is a schematic comparison diagram of an emission spectrogram of PtDMCz under various environments, wherein 2-MeTHF is 2-methyltetrahydrofuran, DCM is dichloromethane, PMMA is polymethyl methacrylate, and RT represents a room temperature.

FIG. 4 is a schematic diagram of an attenuation curve of a light emitting intensity of PtDMCz in a dichloromethane solution under a room temperature, wherein DCM is dichloromethane, and RT represents the room temperature.

FIG. 5 is an emission spectrogram of PtDMCz, PtDMCz-ppz, PtDMCz-2-ptz, PtDMCz-1-ptz, PtDMCz-piz, PtDMCz-ppy, PtDMCz-NHC and PtDMCz-Ph-NHC in a dichloromethane solution under a room temperature.

FIG. 6 is comparison of light stability tests for PtDMCz and PdDMCz.

FIG. 7 is a schematic structural diagram of an organic light emitting element, wherein a substrate, an anode, a hole injection layer, a hole transport layer, a light emitting layer, an electron transport layer and a cathode are represented in sequence from bottom to top.

### DETAILED DESCRIPTION

The content of the present invention is described in detail below. The description of the constituent elements recorded below is sometimes based on representative implementations or specific examples of the present invention, but the present invention is not limited to such implementations or specific examples.

A high radiation rate platinum complex luminescent material based on 1,8-substituted carbazole of the present invention is a tetradentate cyclometalated platinum (II) complex containing 1,8-di(substituted) carbazole having a chemical formula as shown in General Formula (1):

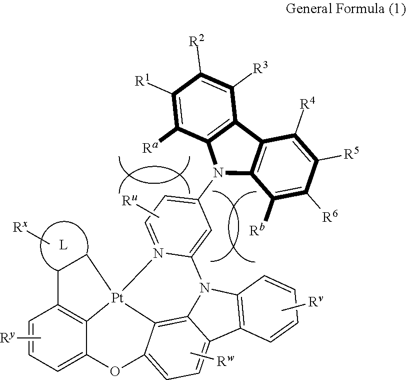

wherein L is a five-membered or six-membered heteroaromatic ring.
   R^{a} and R^{b} are not hydrogen atoms, and each independently represent alkyl, alkoxy, cycloalkyl, heterocyclyl, alkenyl, substituted or unsubstituted aryl, substituted or unsubstituted aryloxy, substituted or unsubstituted heteroaryl, halogen, hydroxyl, sulfhydryl, nitryl, cyano, amino, carboxyl, sulfo, hydrazino, carbamido, alkynyloxy, ester group, acylamino, sulfonyl, sulfinyl, sulfonylamino, phosphorylamino, alkoxycarbonylamino, aryloxycarbonylamino, silyl, alkylamino, dialkylamino, monoarylamino, biarylamino, ureylene, imino, or a combination thereof.
   R¹, R², R³, R⁴, R⁵ and R⁶ each independently represent hydrogen, deuterium, alkyl, alkoxy, cycloalkyl, heterocyclyl, alkenyl, substituted or unsubstituted aryl, substituted or unsubstituted aryloxy, substituted or unsubstituted heteroaryl, halogen, hydroxyl, sulfhydryl, nitryl, cyano, amino, carboxyl, sulfo, hydrazino, carbamido, alkynyloxy, ester group, acylamino, sulfonyl, sulfinyl, sulfonylamino, phosphorylamino, alkoxycarbonylamino, aryloxycarbonylamino, silyl, alkylamino, dialkylamino, monoarylamino, biarylamino, ureylene, imino, or a combination thereof. Two or more of R¹, R², R³, R⁴, R⁵ and R⁶ may be connected to form a fused ring, and the fused ring may further be fused with other rings.
   R^{u}, R^{v}, R^{w}, R^{x} and R^{y} each independently represent mono-substituted, bis-substituted, tri-substituted, tetra-substituted or unsubstituted, and R^{u}, R^{v}, R^{v}, R^{x} and R^{y} each independently are hydrogen, deuterium, alkyl, alkoxy, cycloalkyl, heterocyclyl, alkenyl, substituted or unsubstituted aryl, substituted or unsubstituted aryloxy, substituted or unsubstituted heteroaryl, halogen, hydroxyl, sulfhydryl, nitryl, cyano, amino, carboxyl, sulfo, hydrazino, carbamido, alkynyloxy, ester group, acylamino, sulfonyl, sulfinyl, sulfonylamino, phosphorylamino, alkoxycarbonylamino, aryloxycarbonylamino, silyl, alkylamino, dialkylamino, monoarylamino, biarylamino, ureylene, imino, or a combination thereof, and two or more adjacent ones of R^{u}, R^{v}, R^{w}, R^{x} and R^{y} are each independently or selectively connected to form a fused ring.

The present invention specifically may be one of, but not limited to, the following chemical structures:

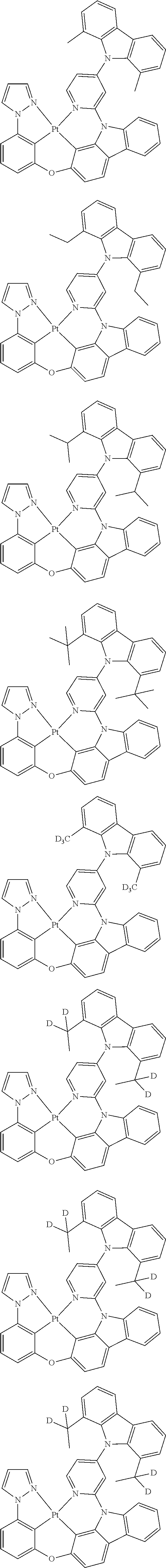

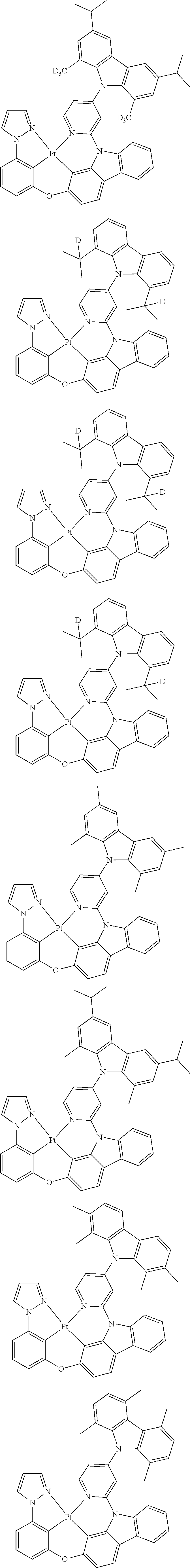

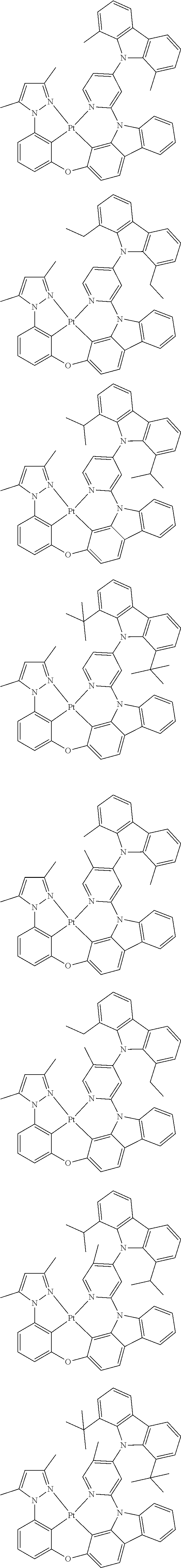

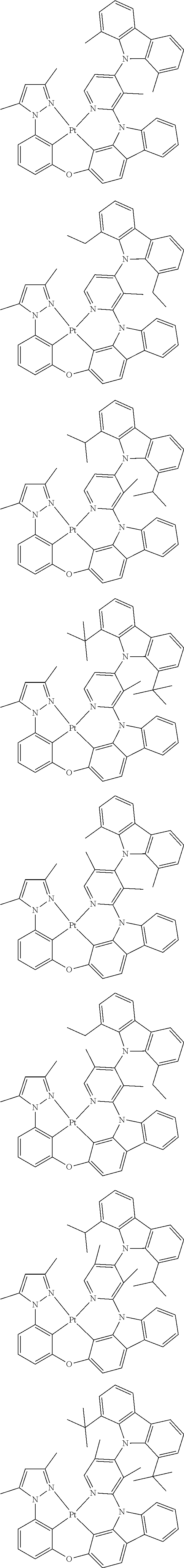

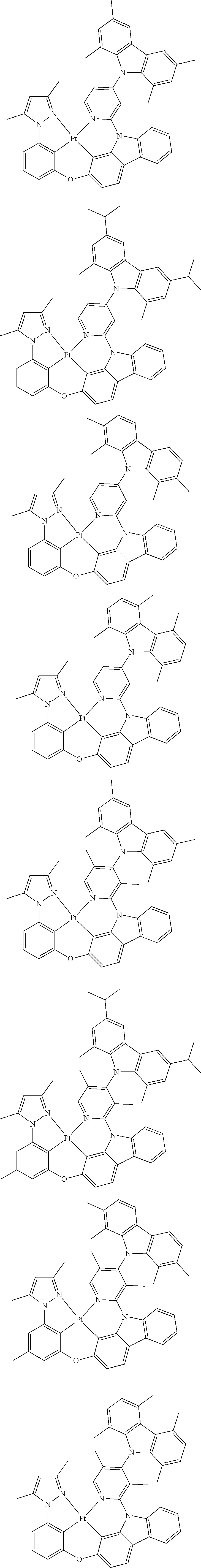

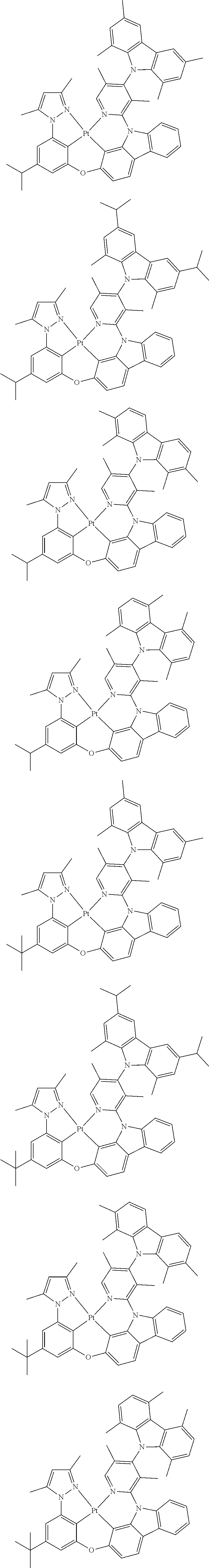

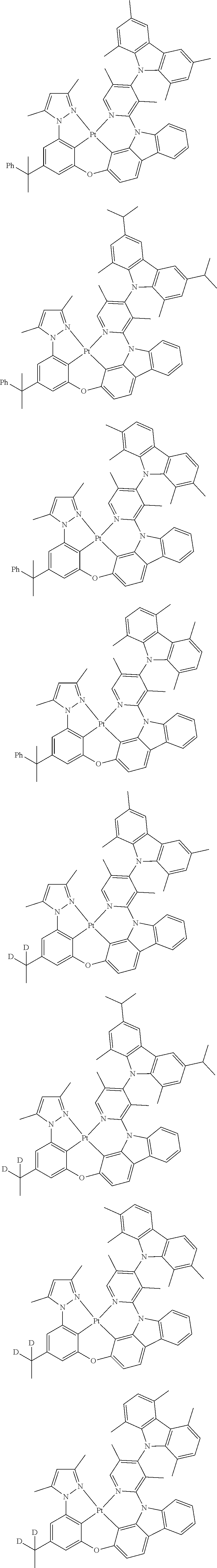

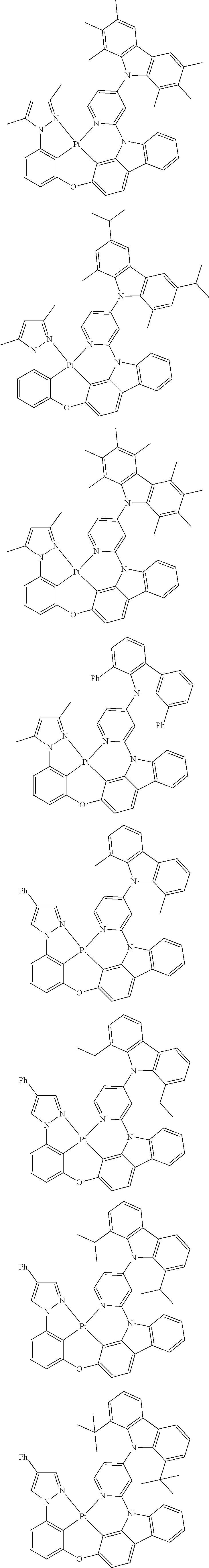

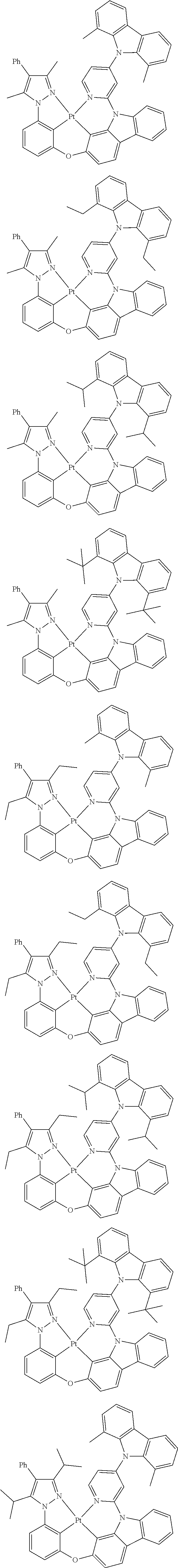

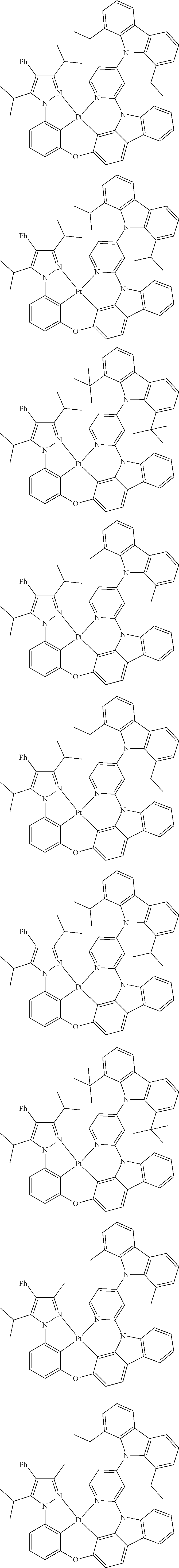

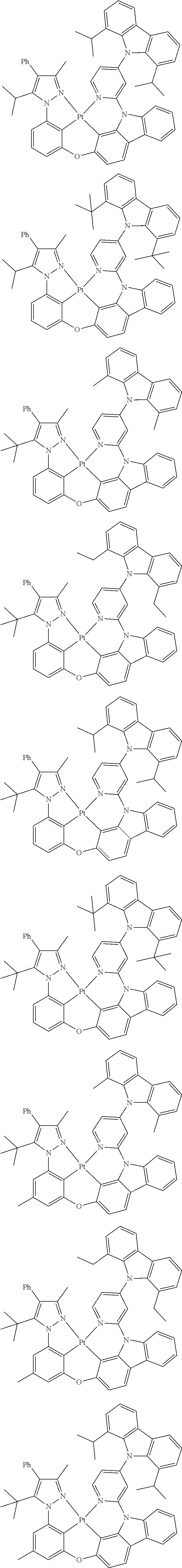

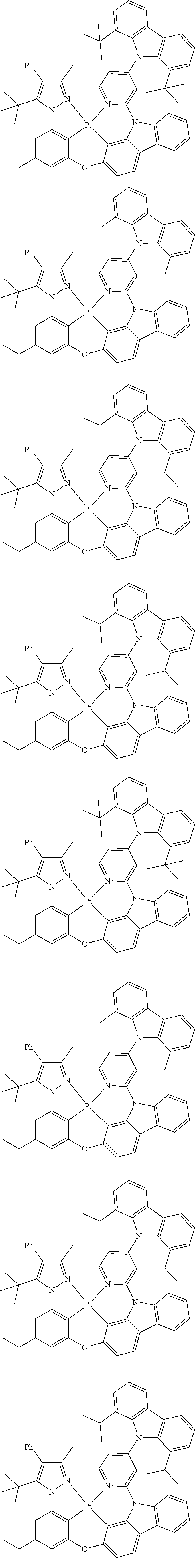

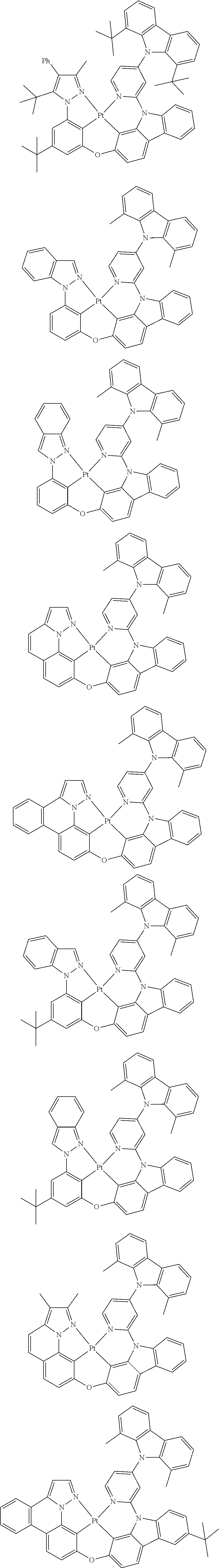

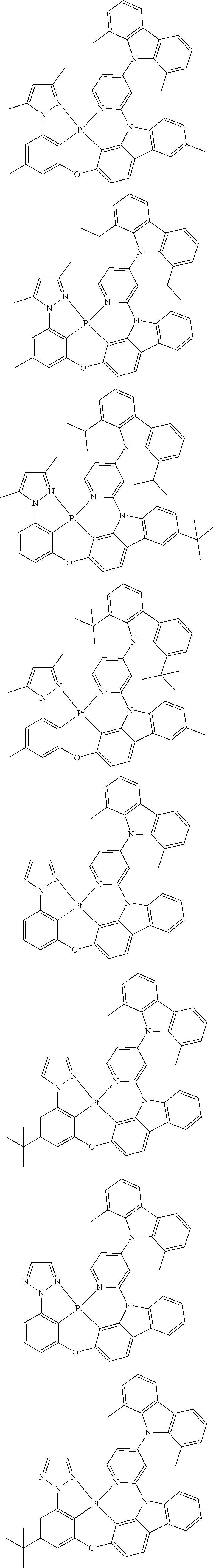

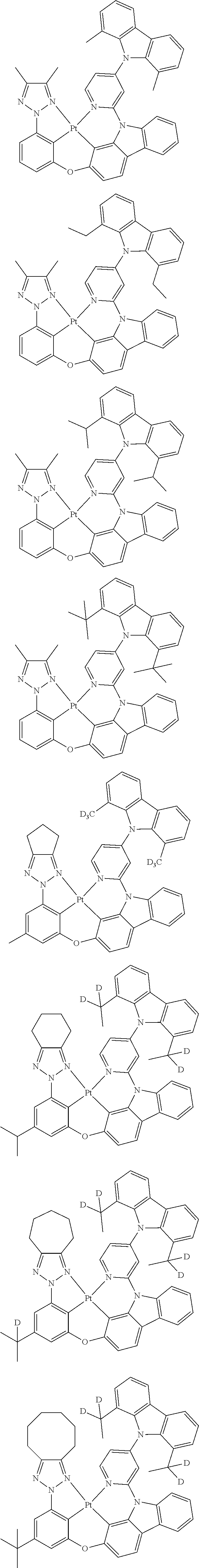

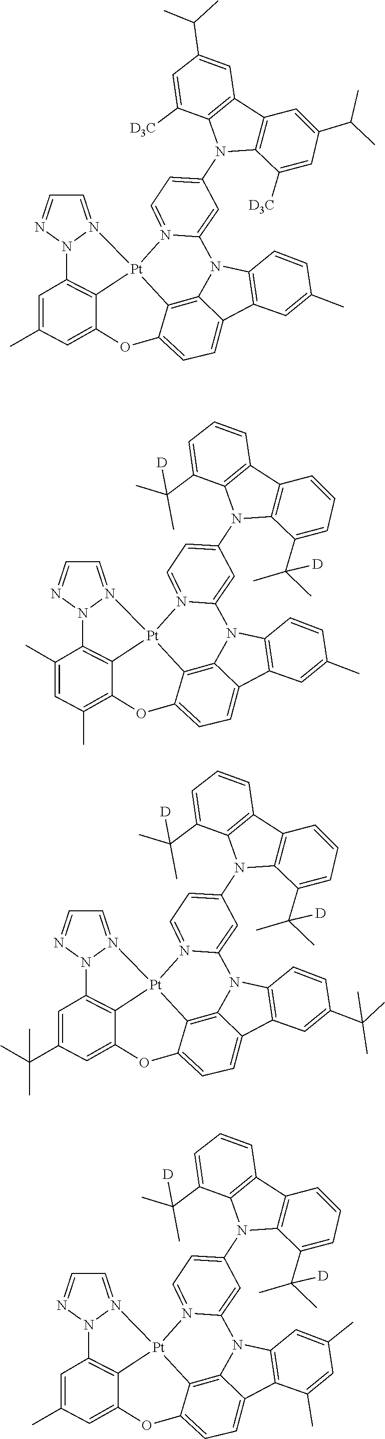

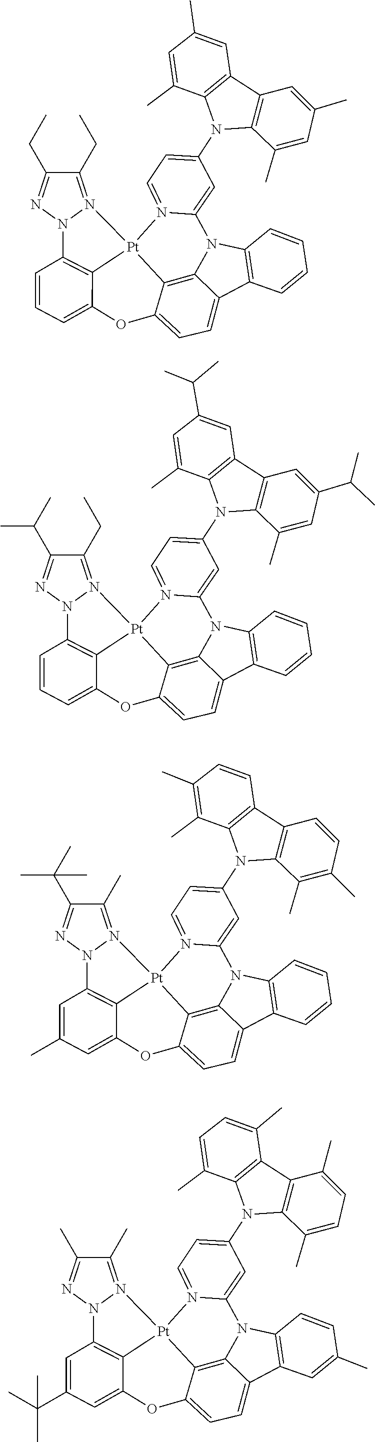

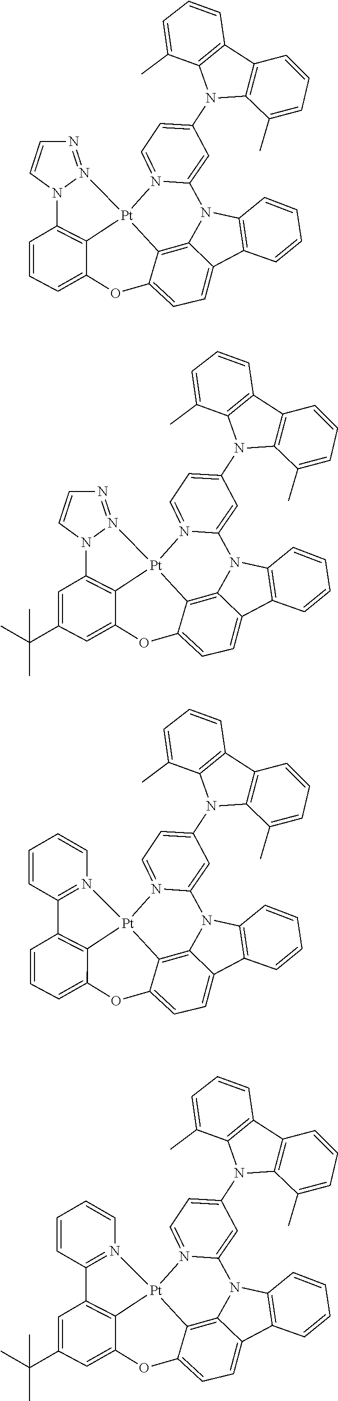

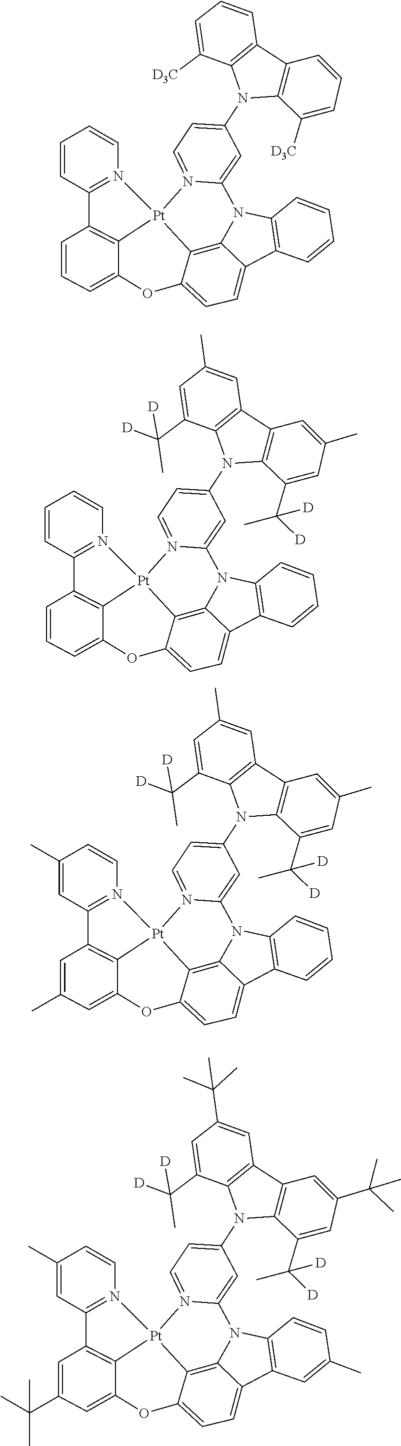

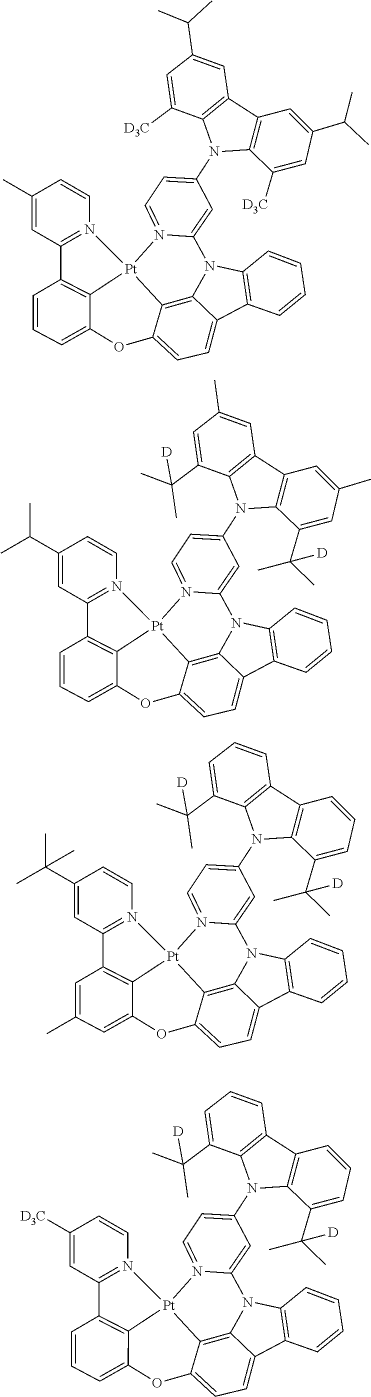

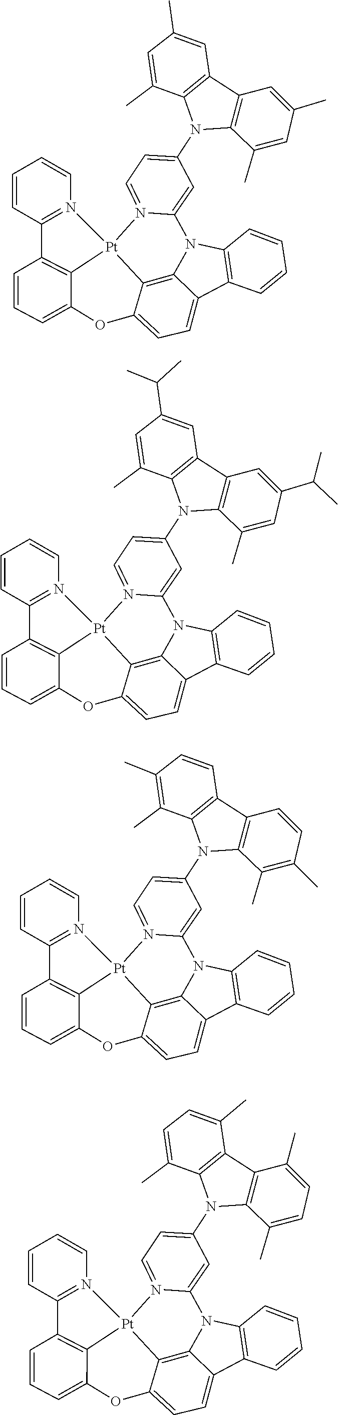

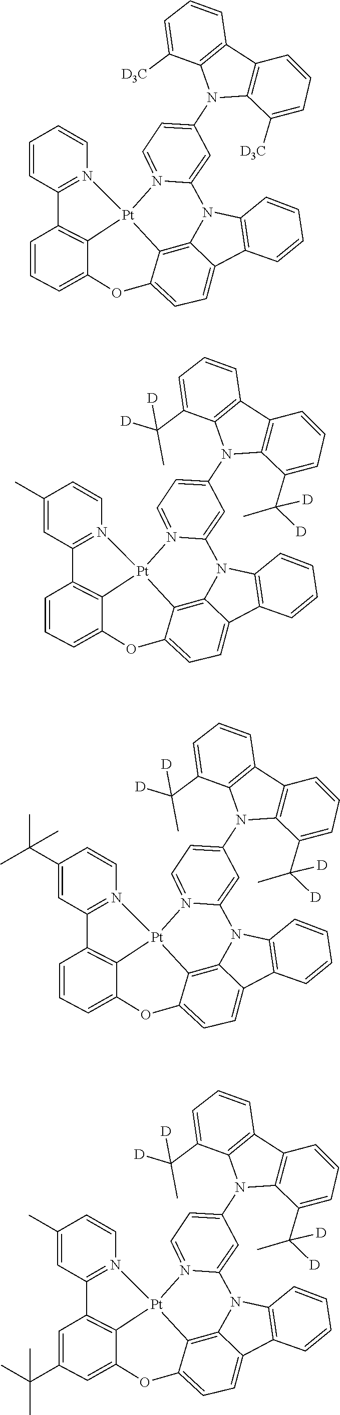

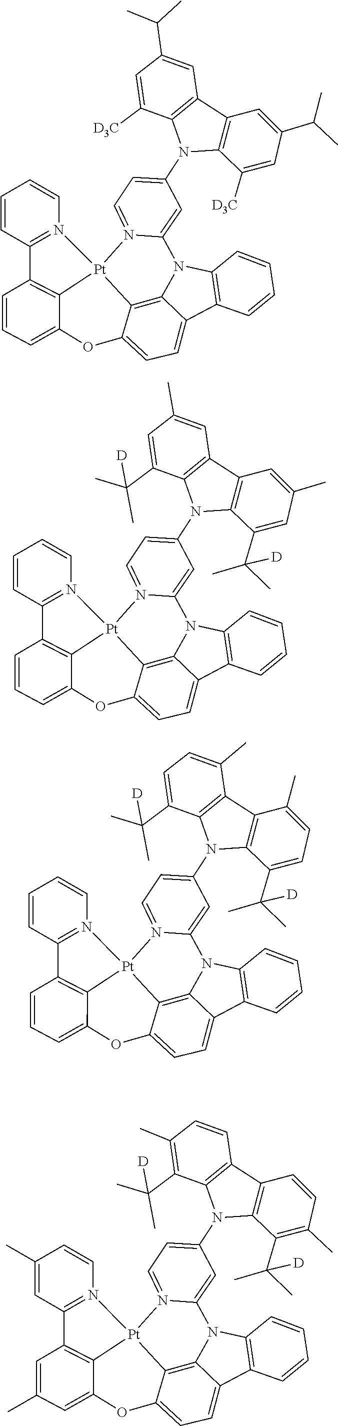

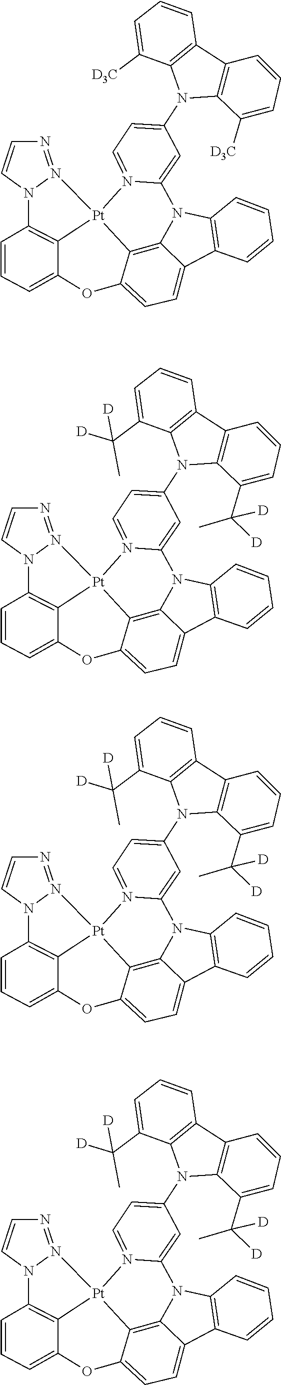

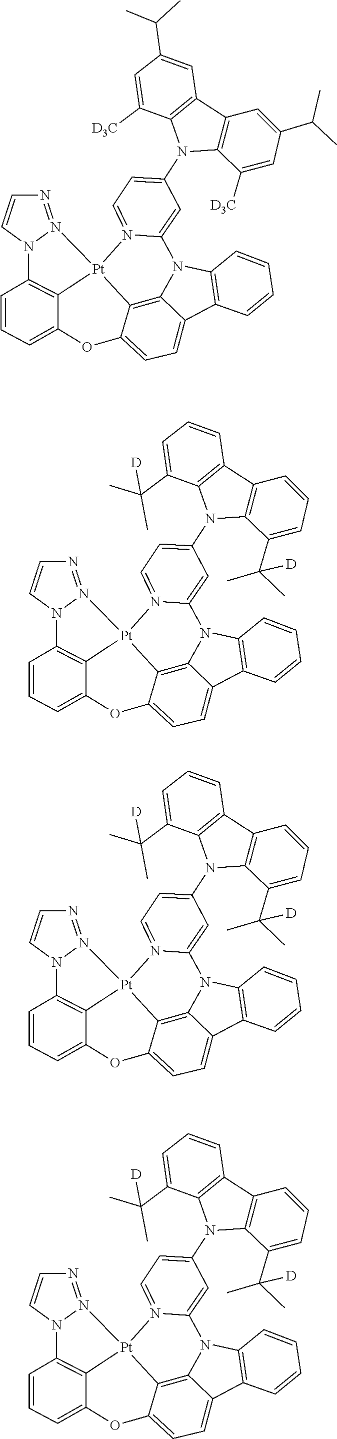

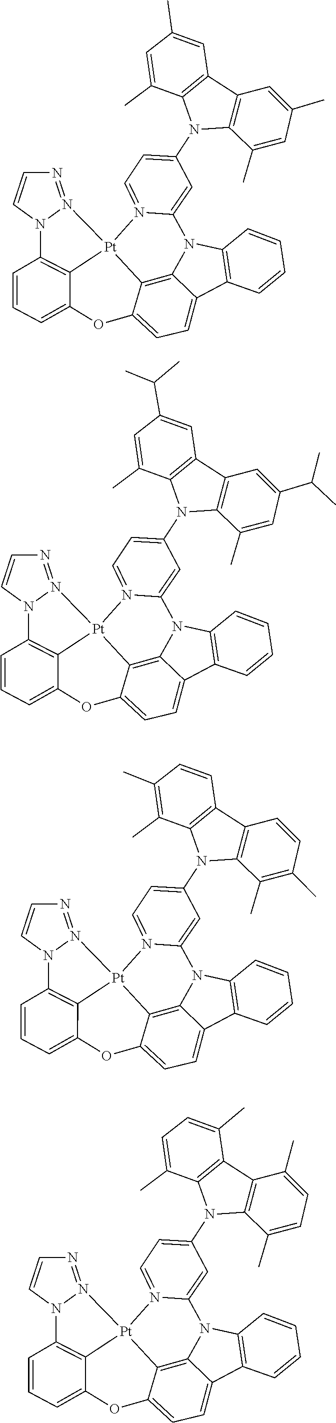

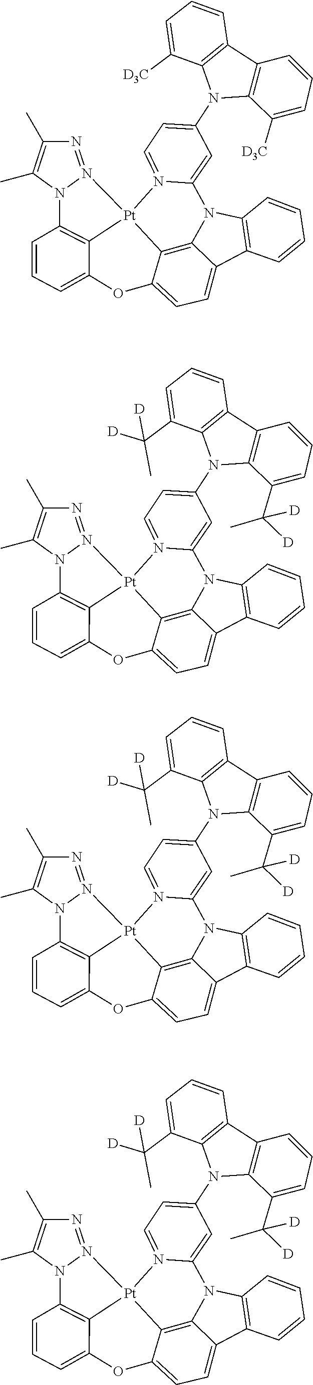

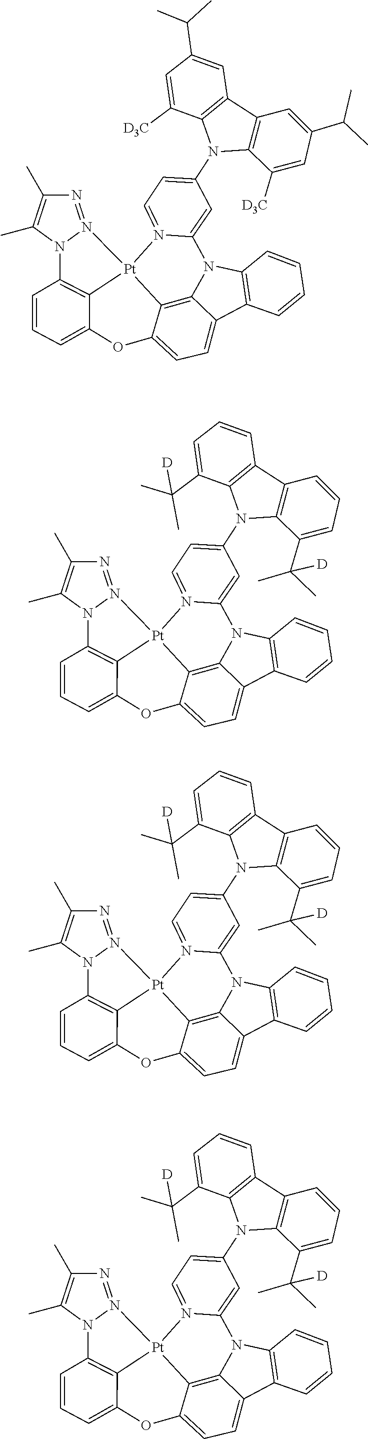

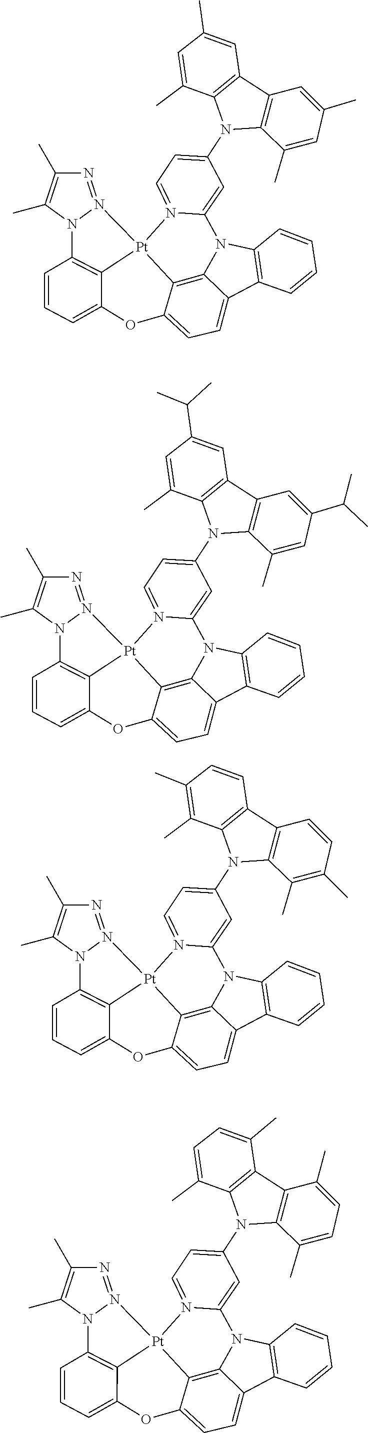

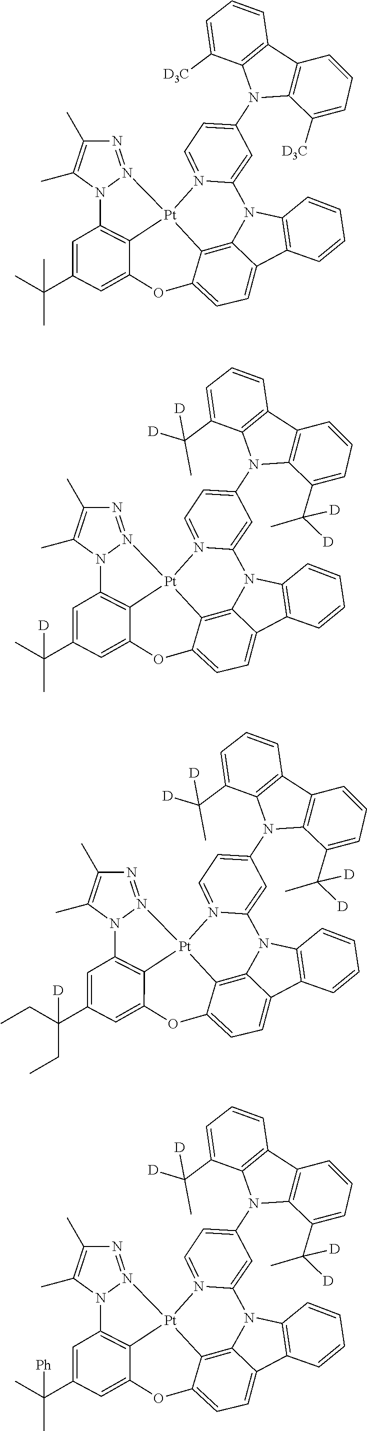

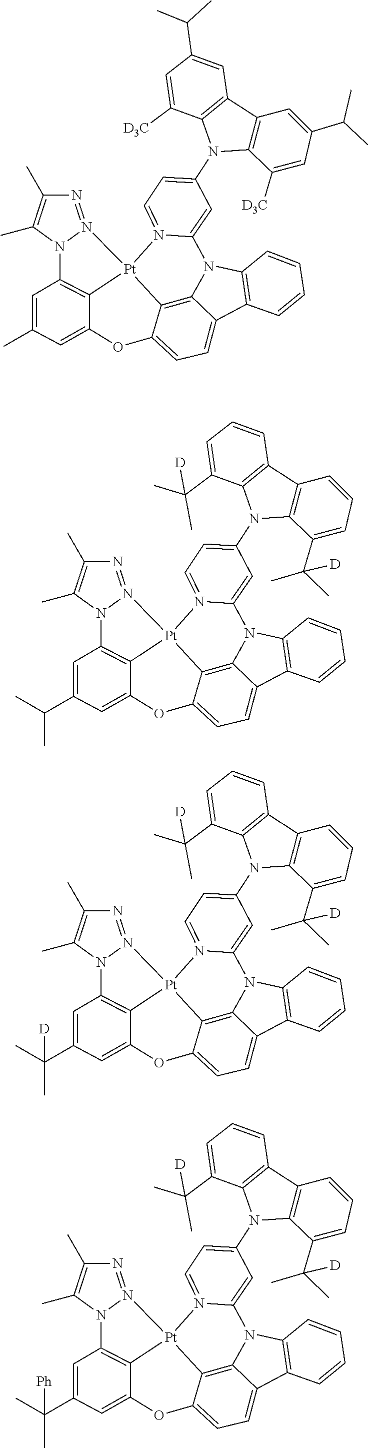

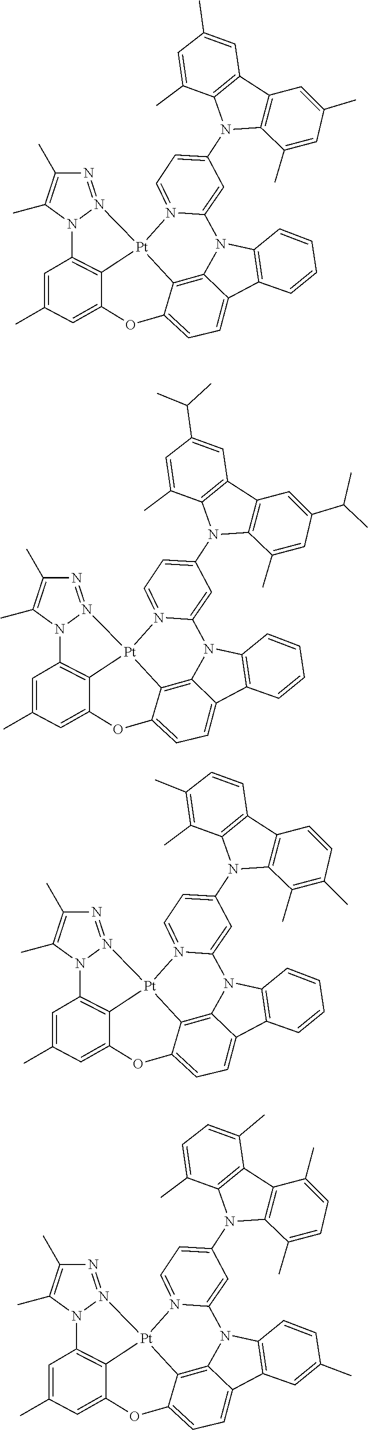

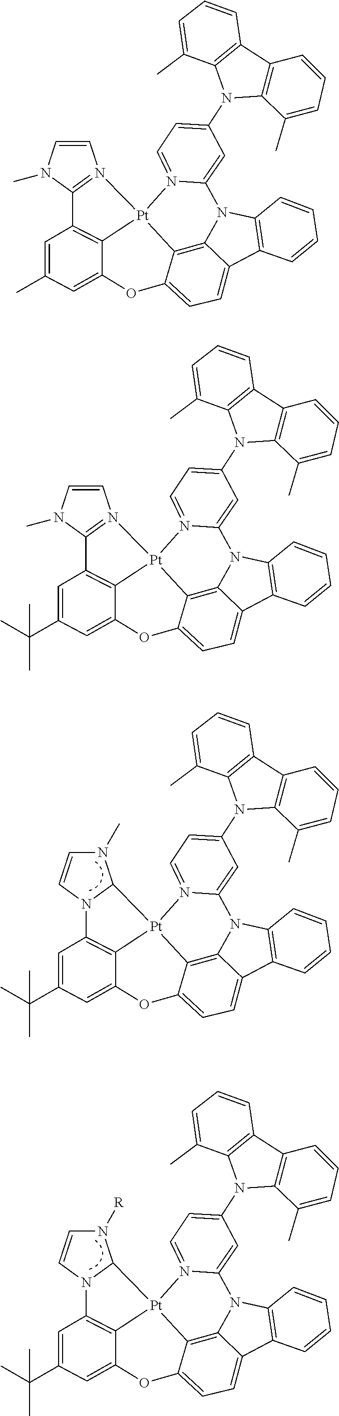

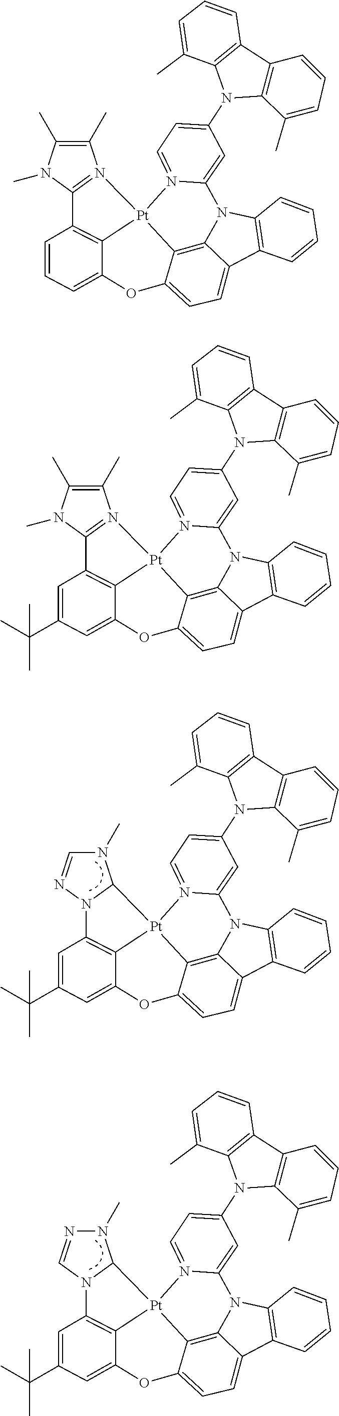

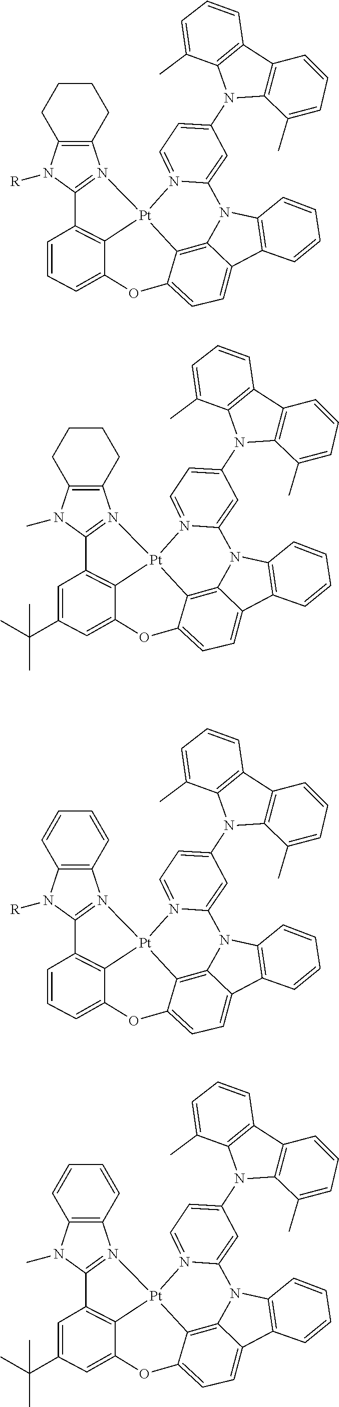

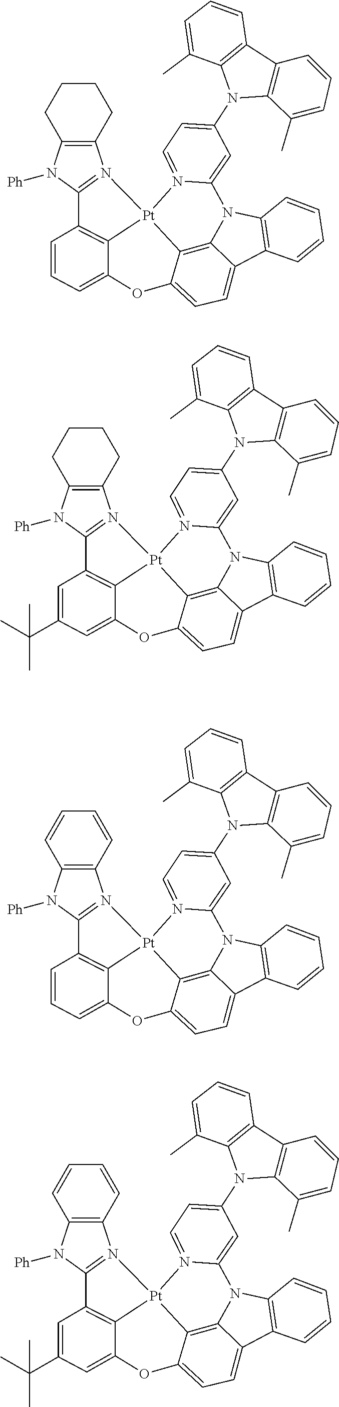

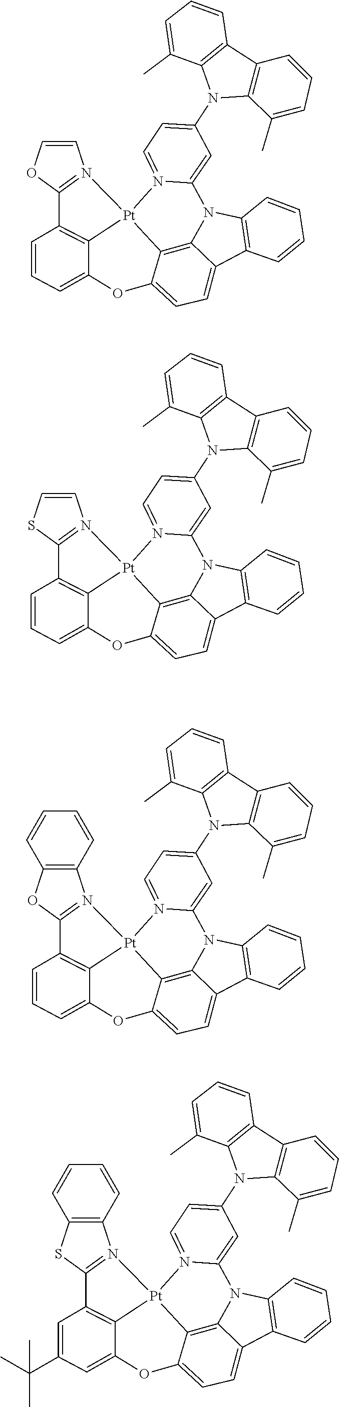

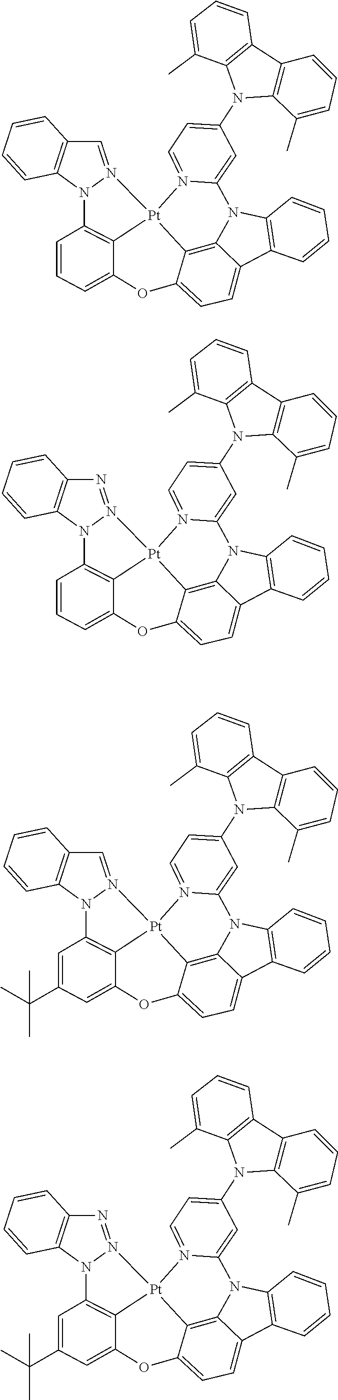

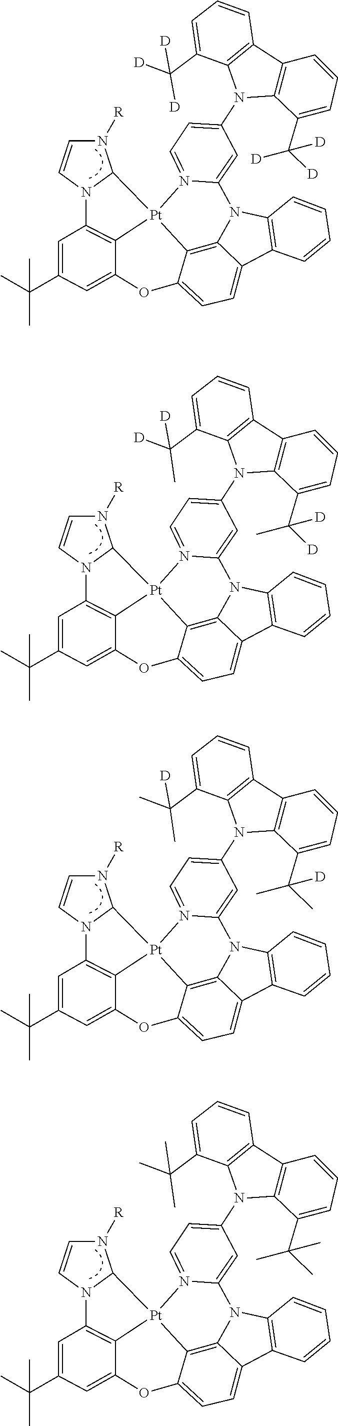

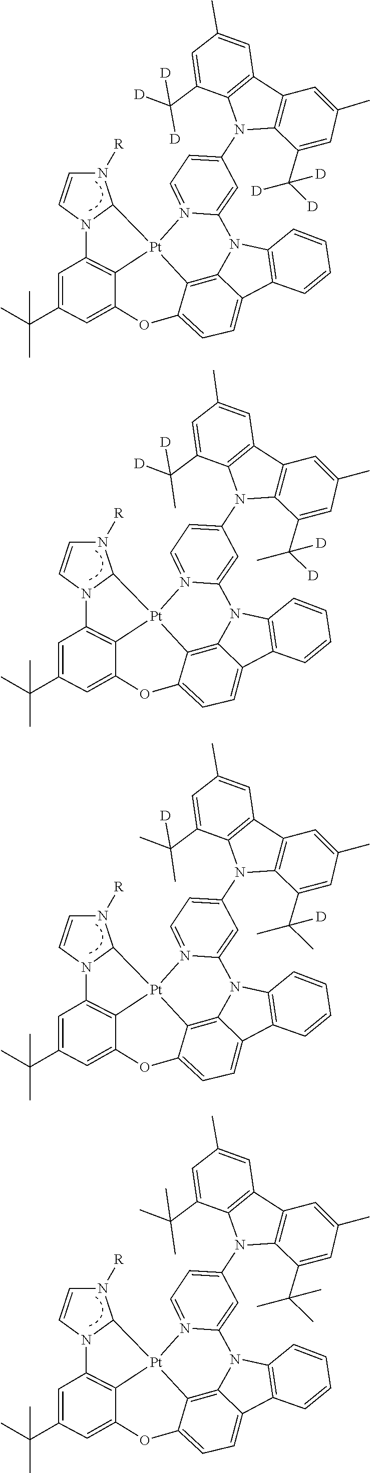

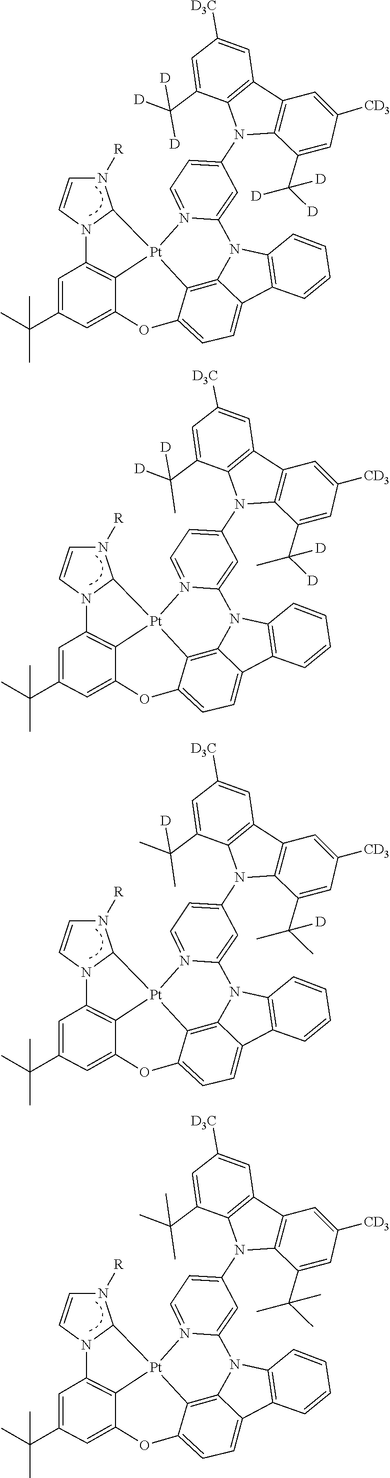

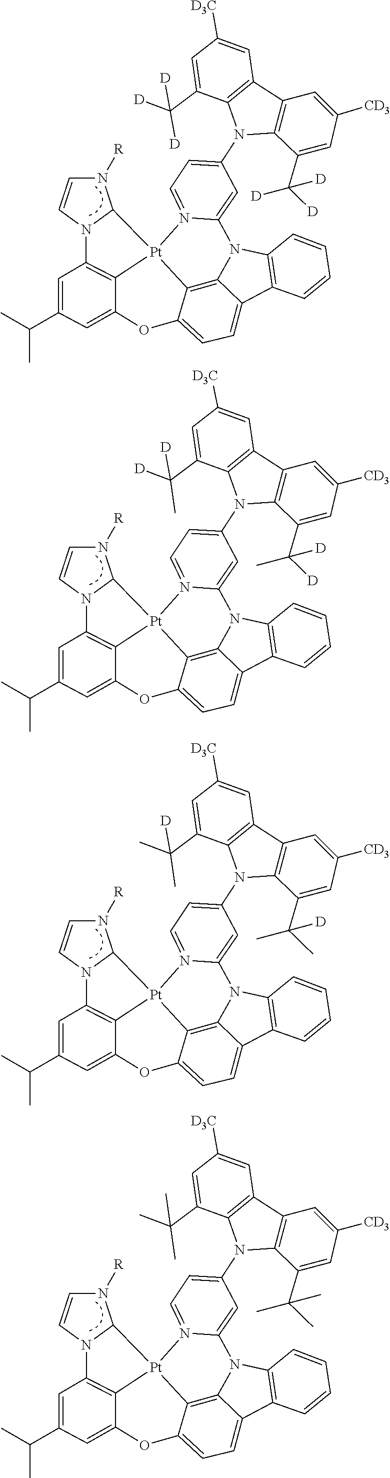

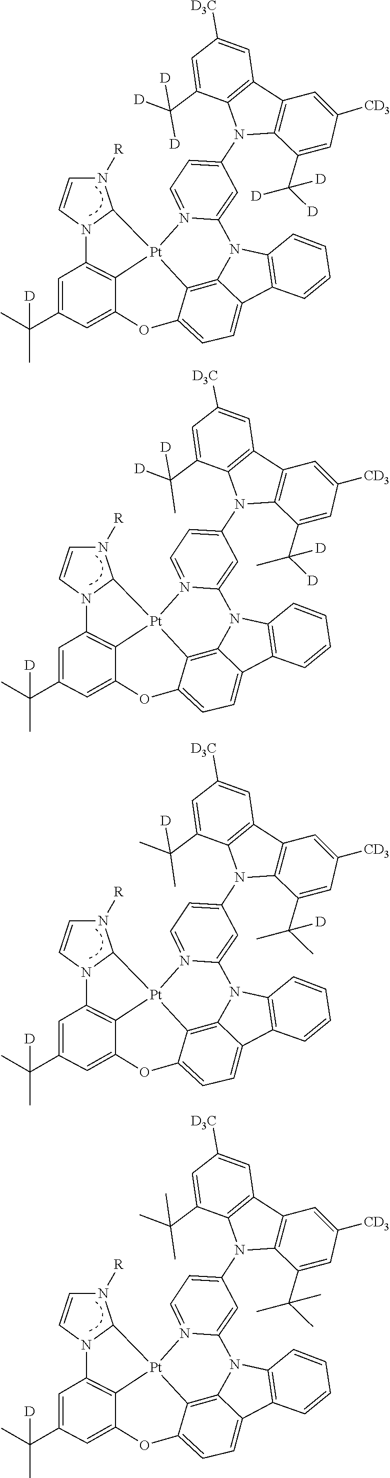

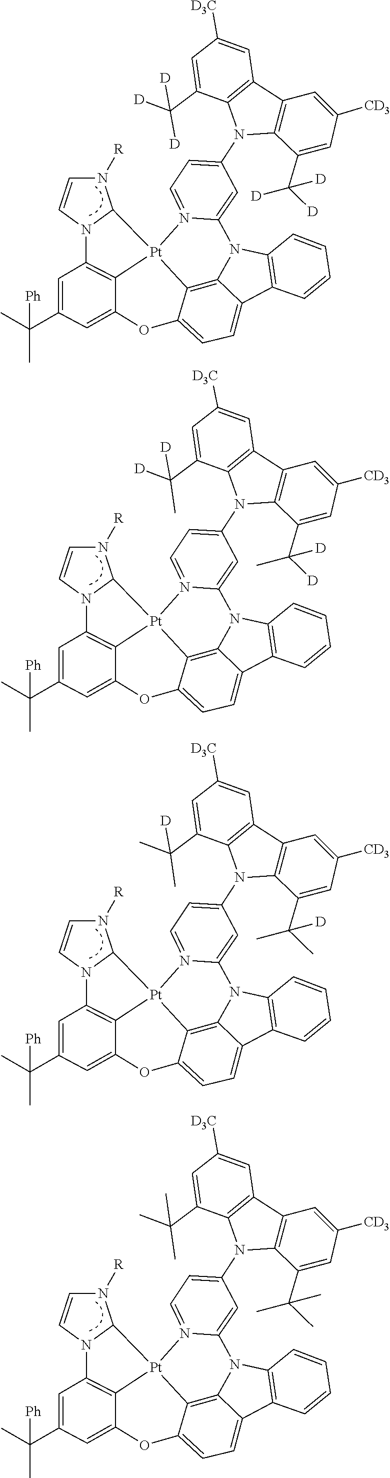

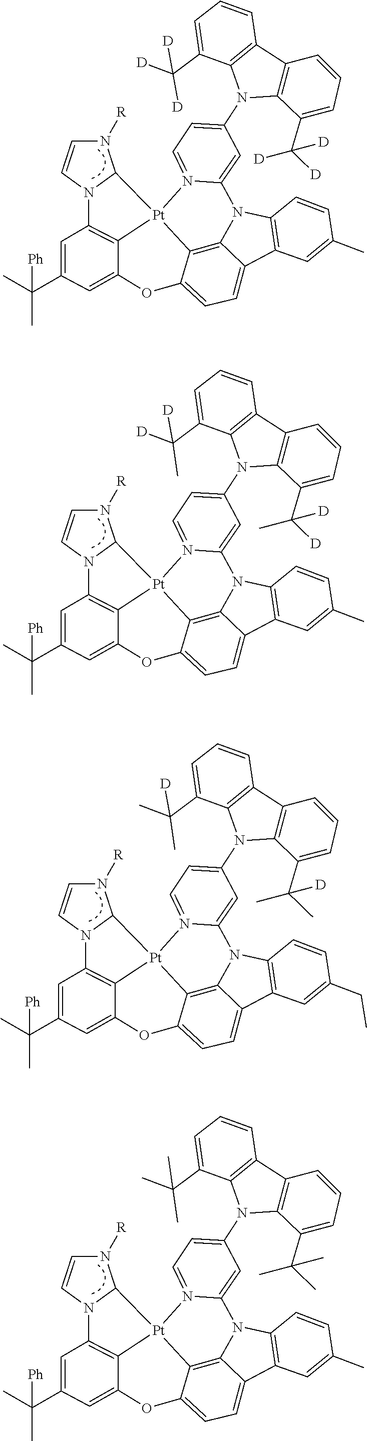

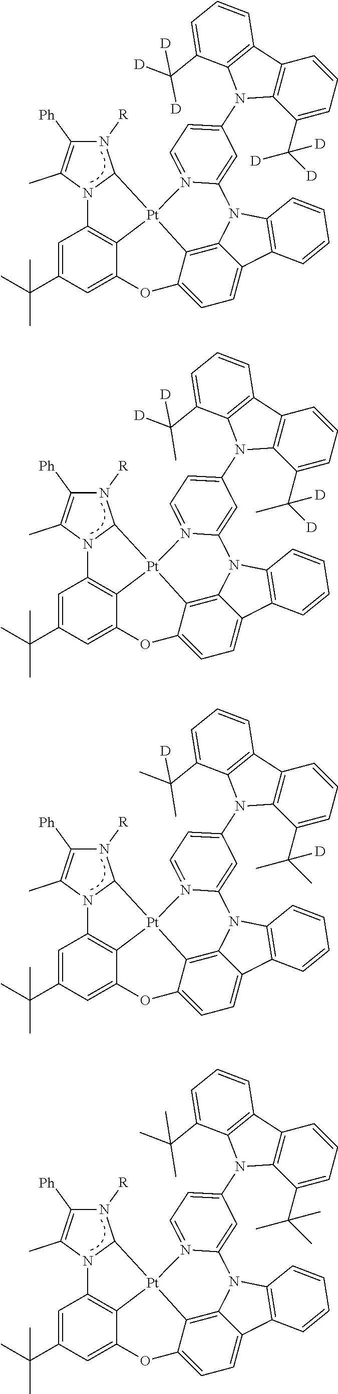

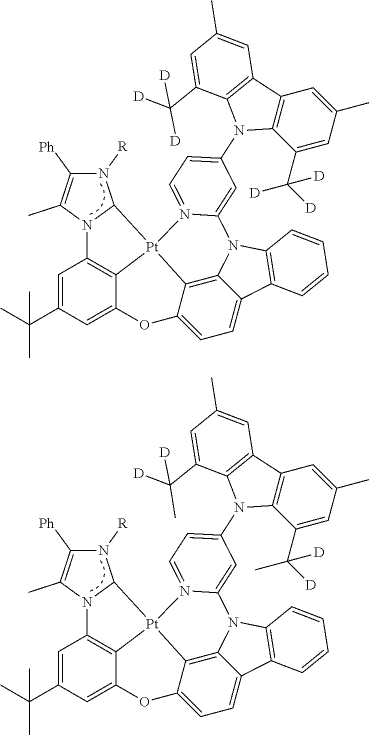

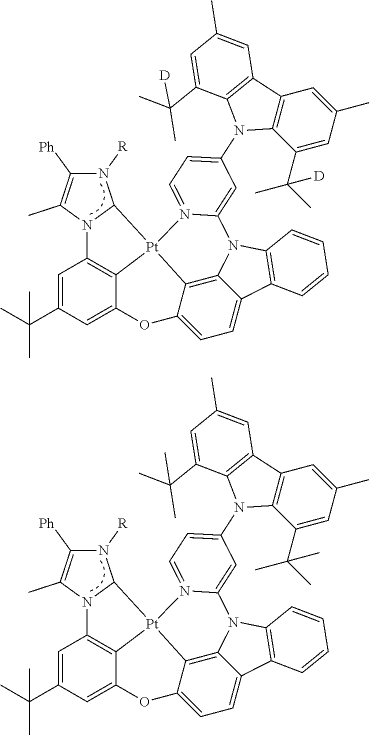

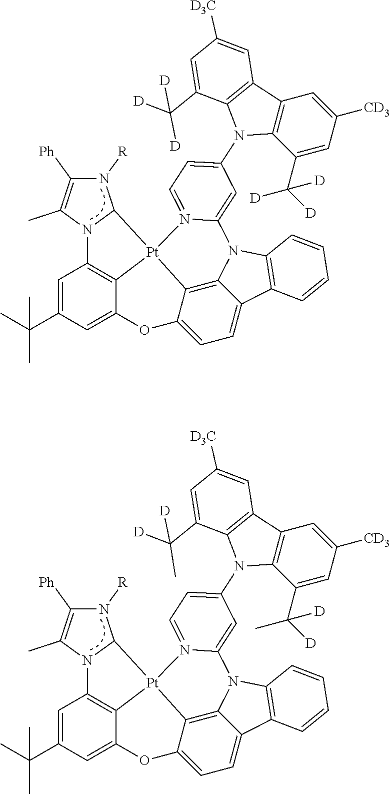

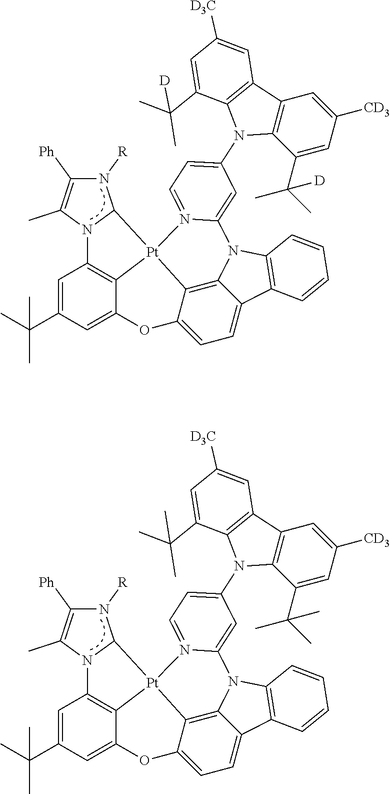

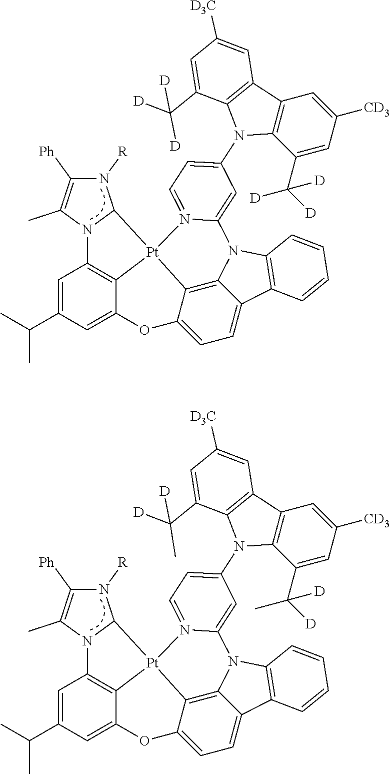

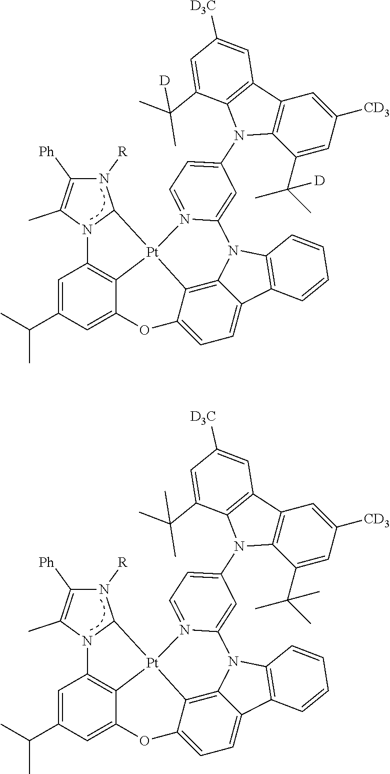

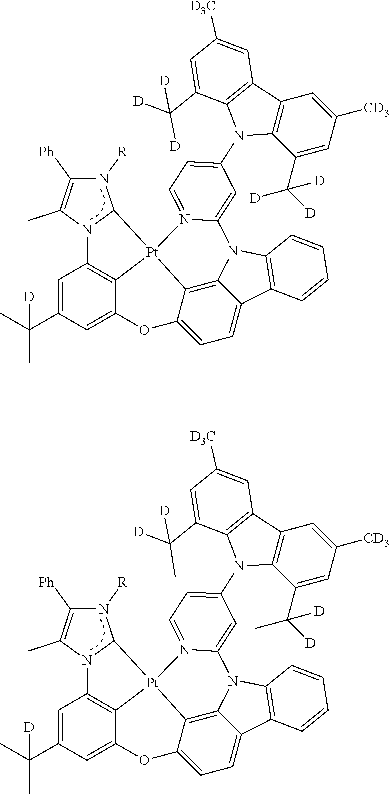

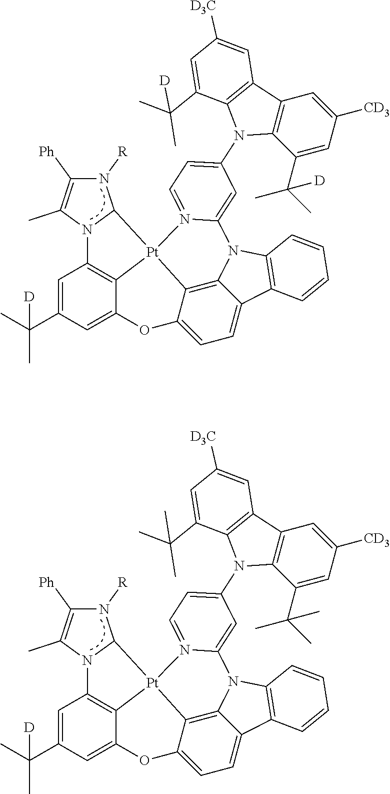

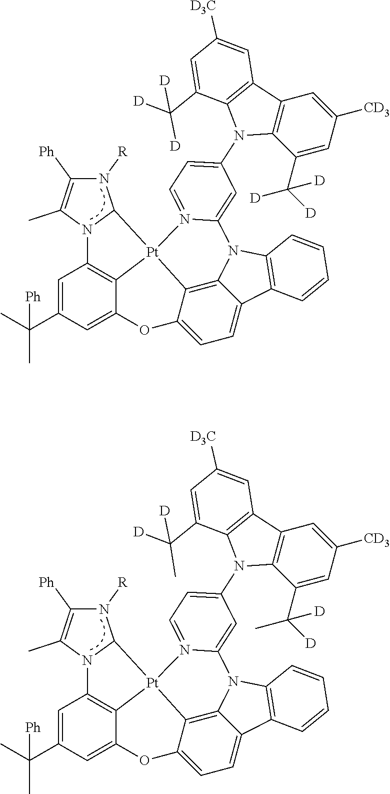

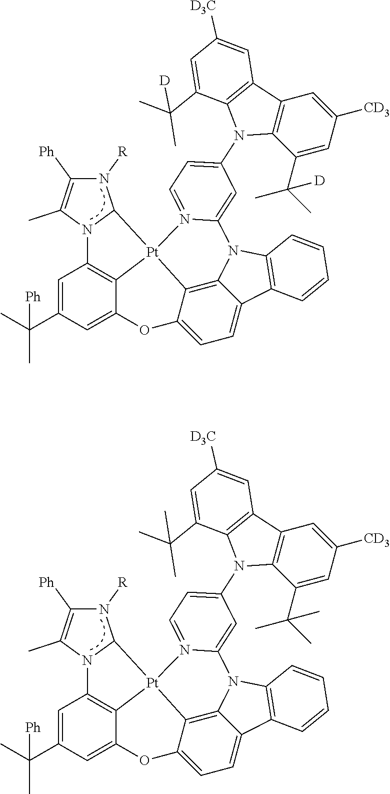

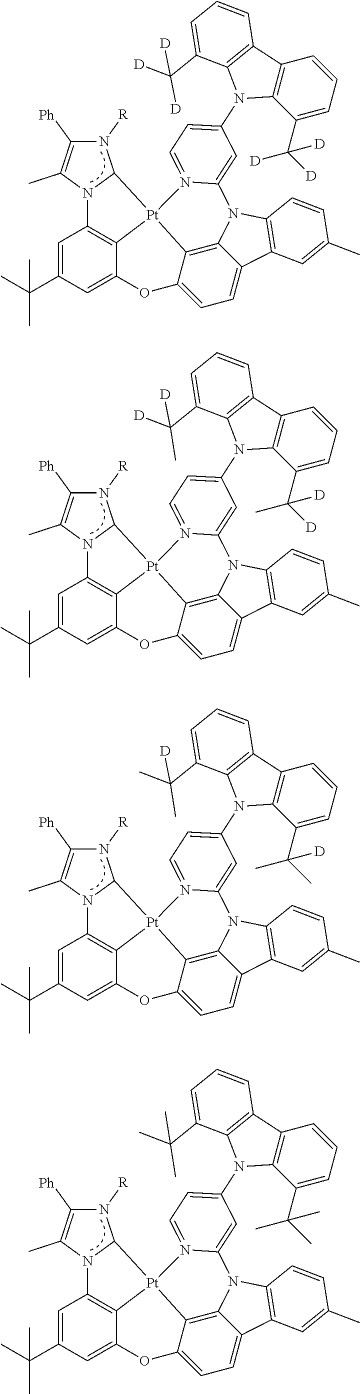

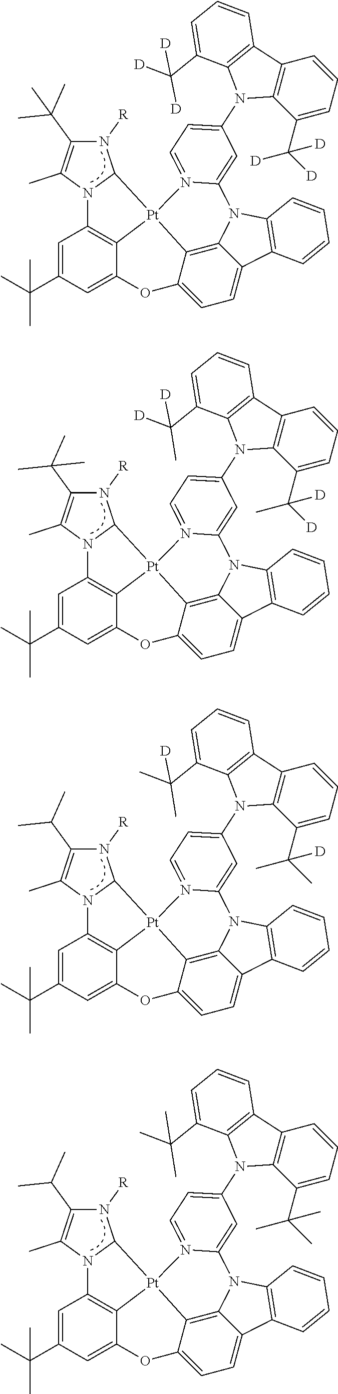

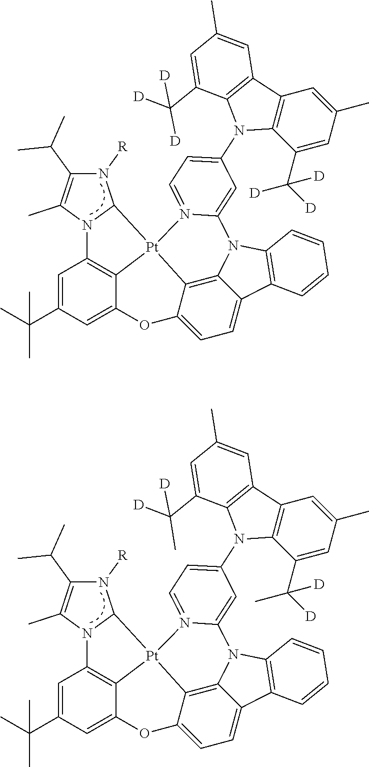

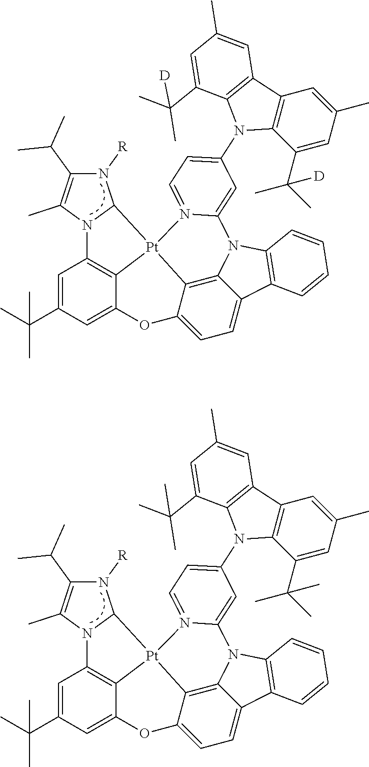

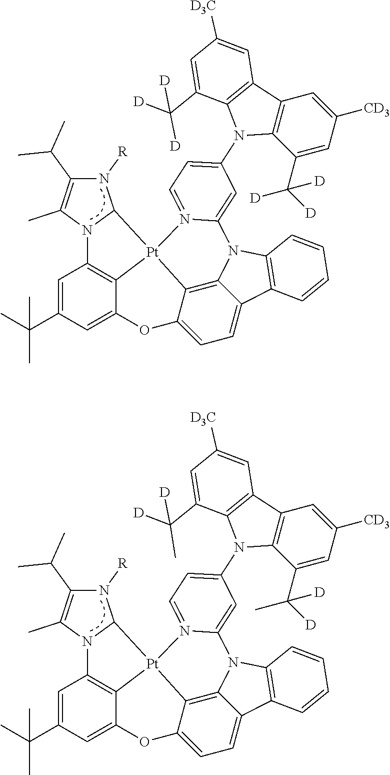

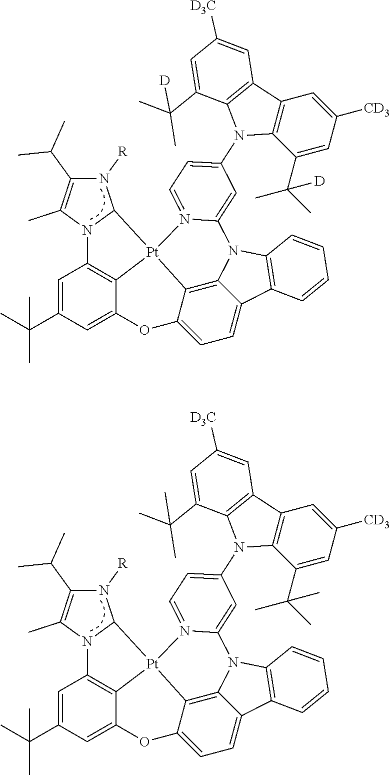

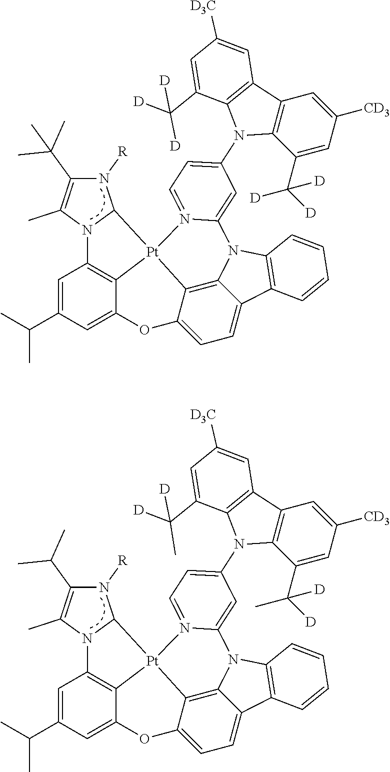

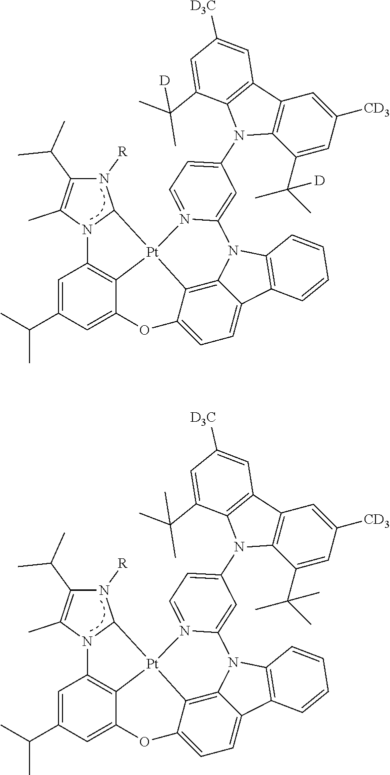

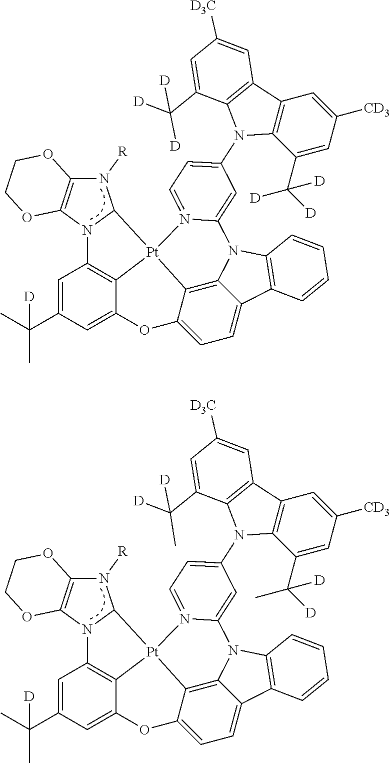

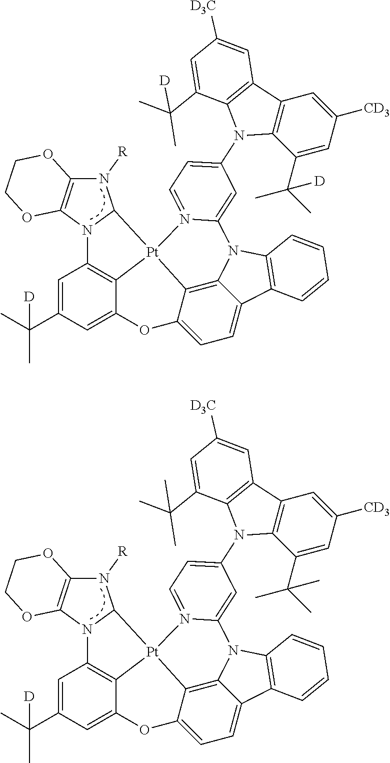

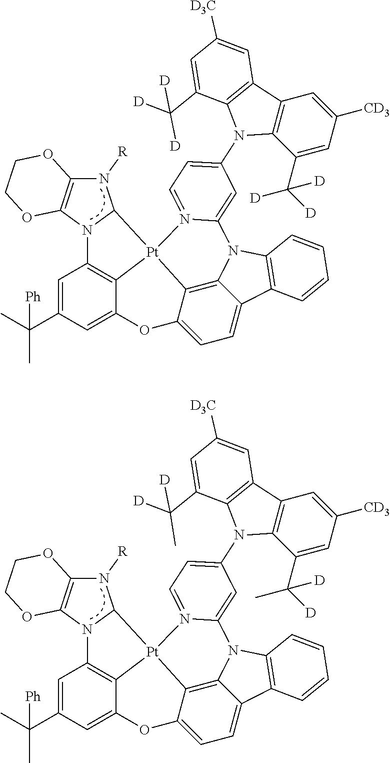

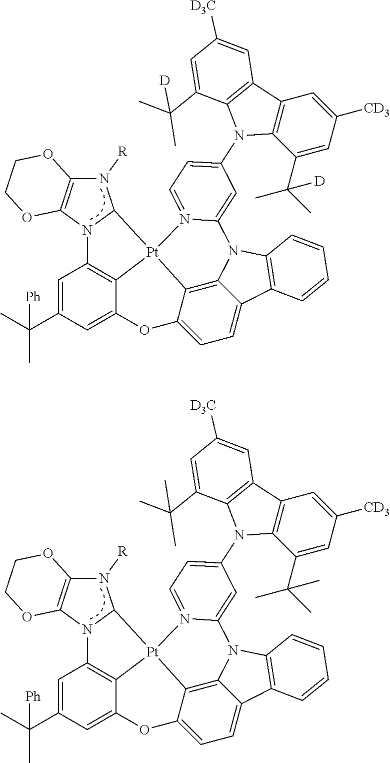

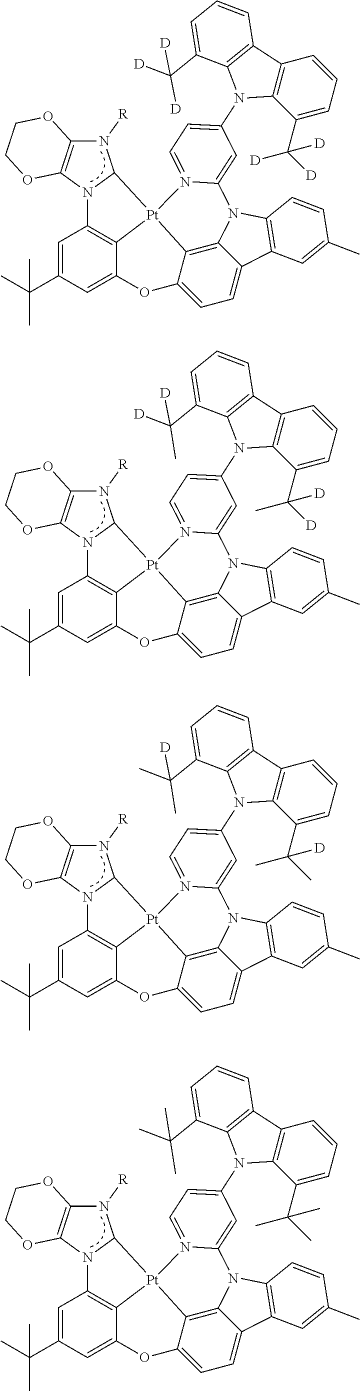

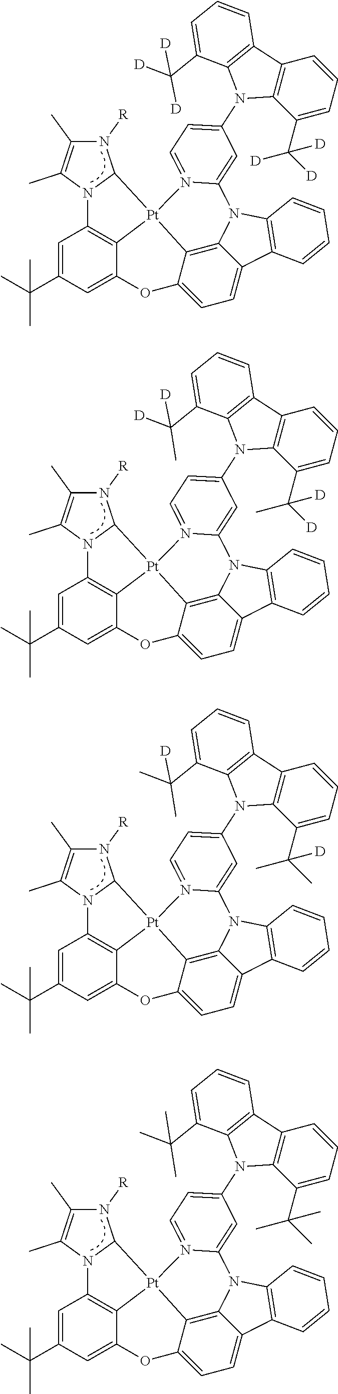

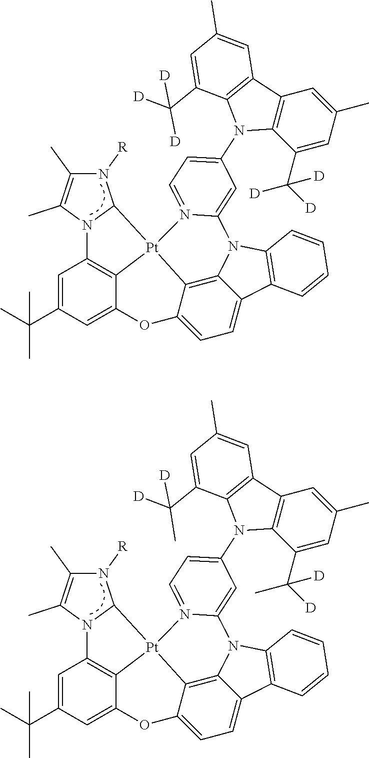

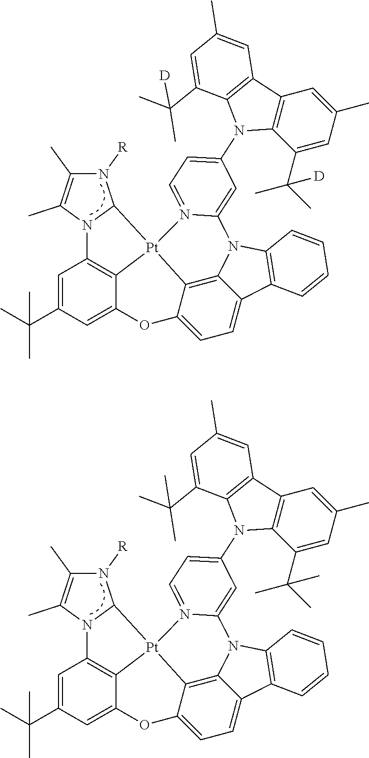

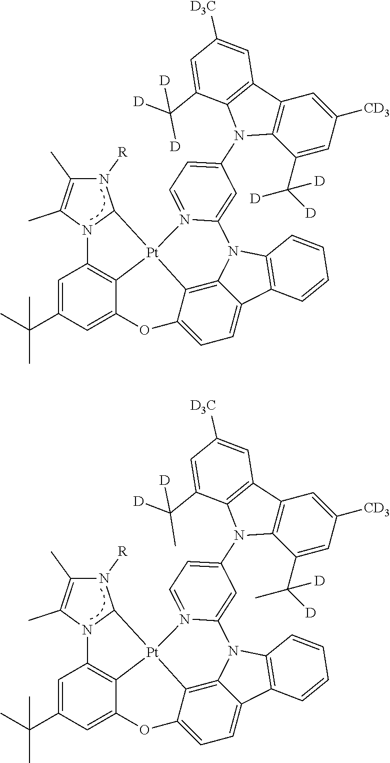

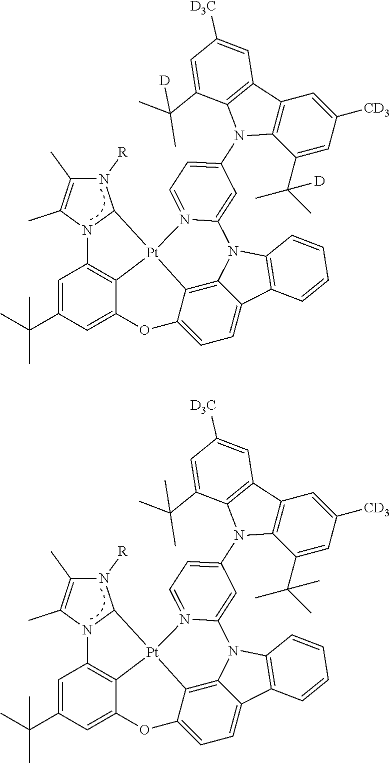

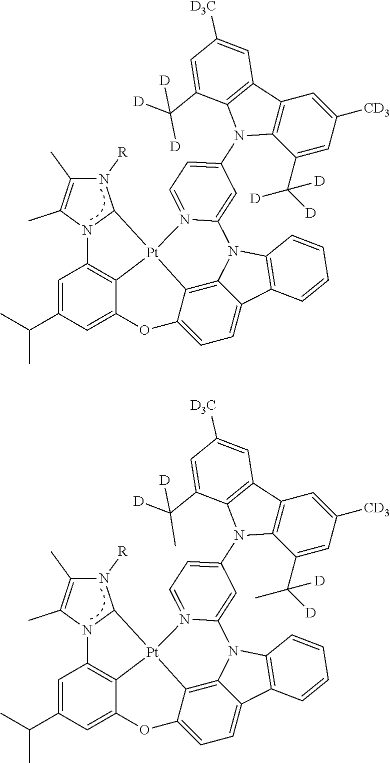

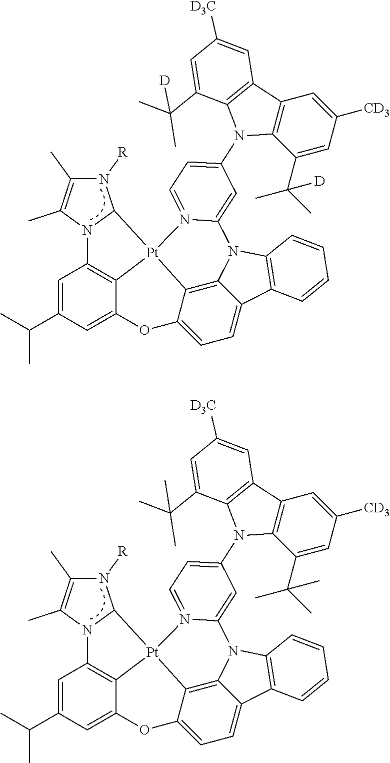

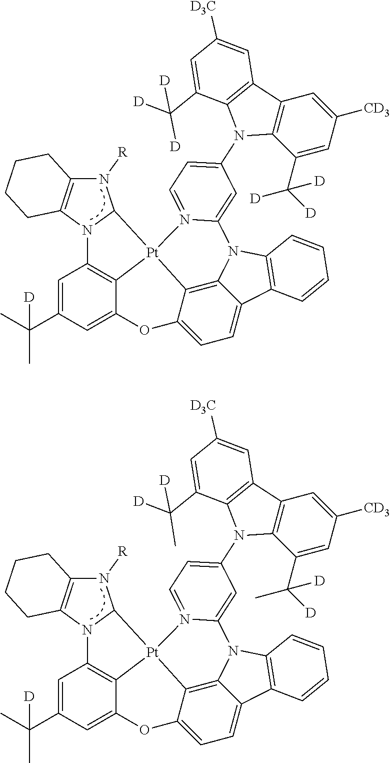

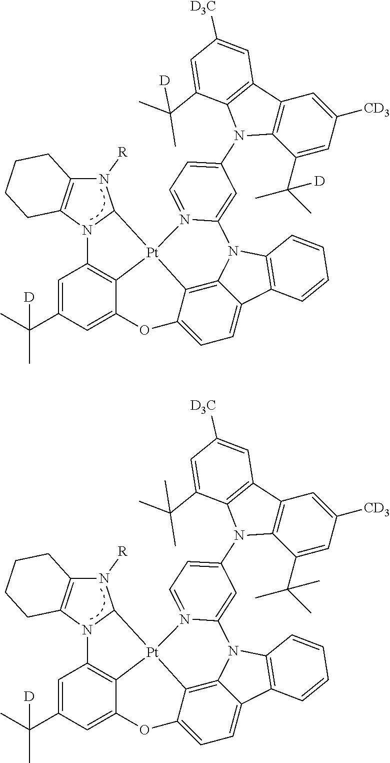

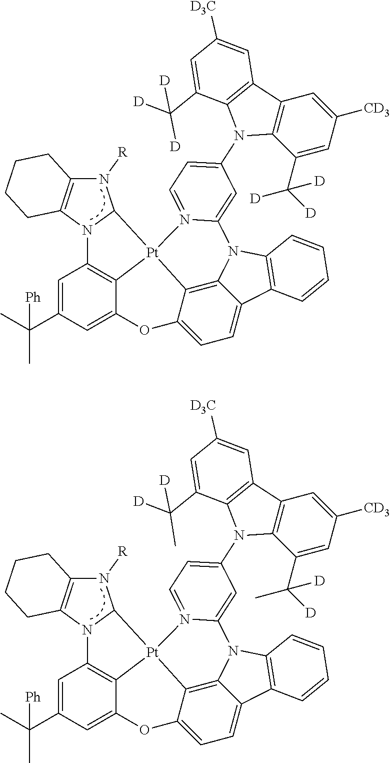

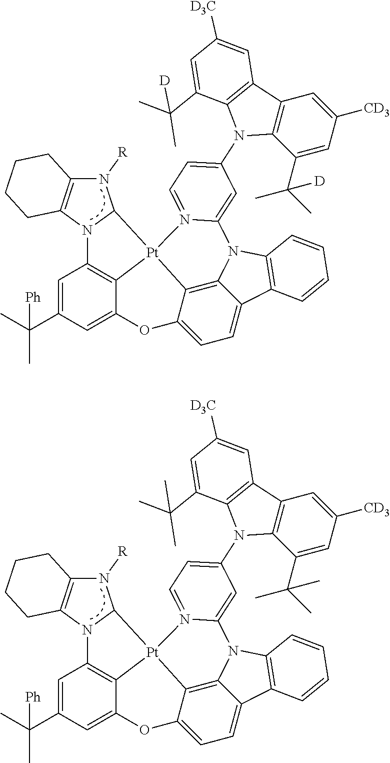

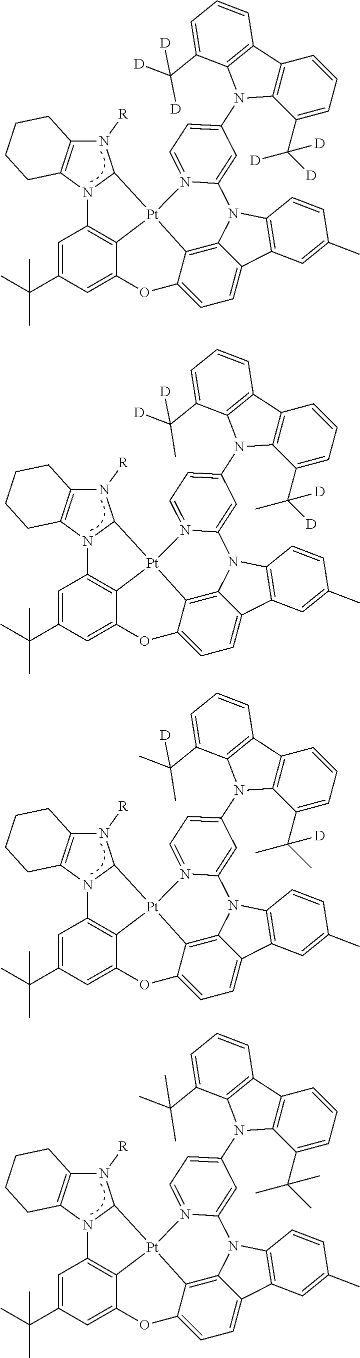

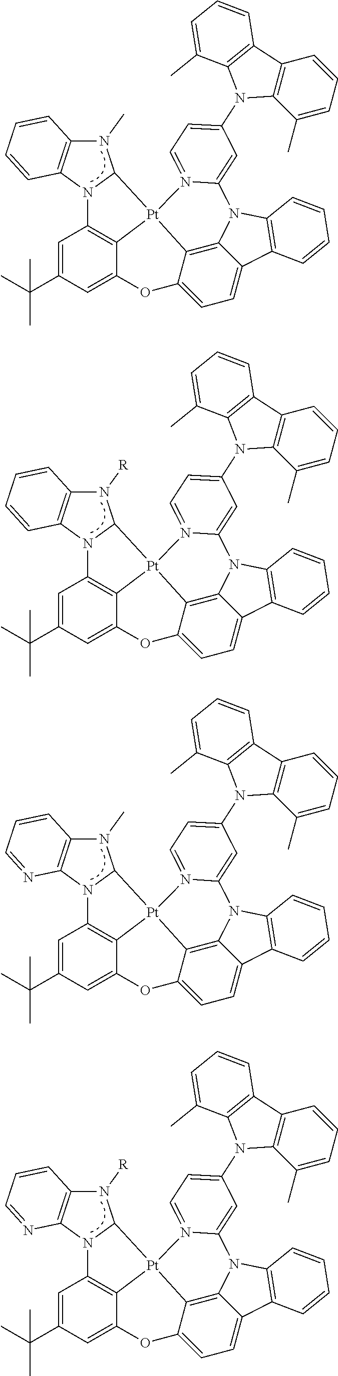

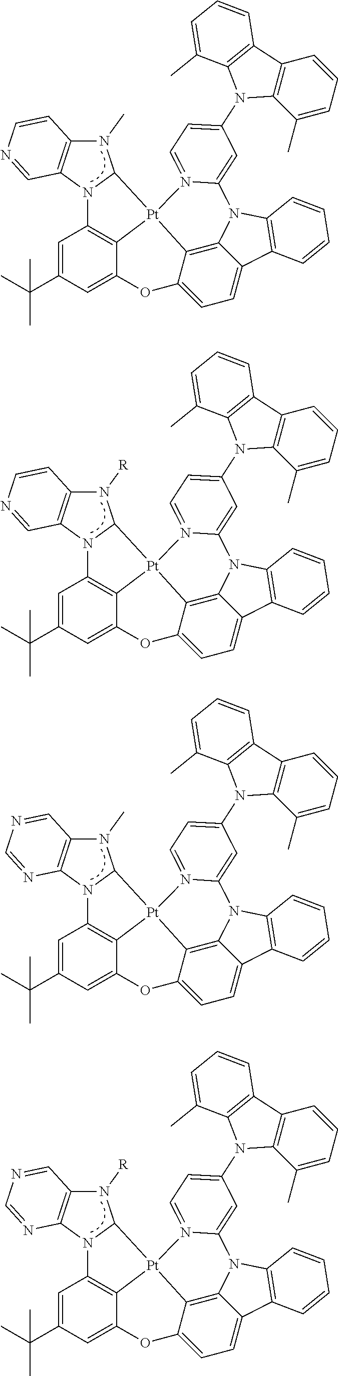

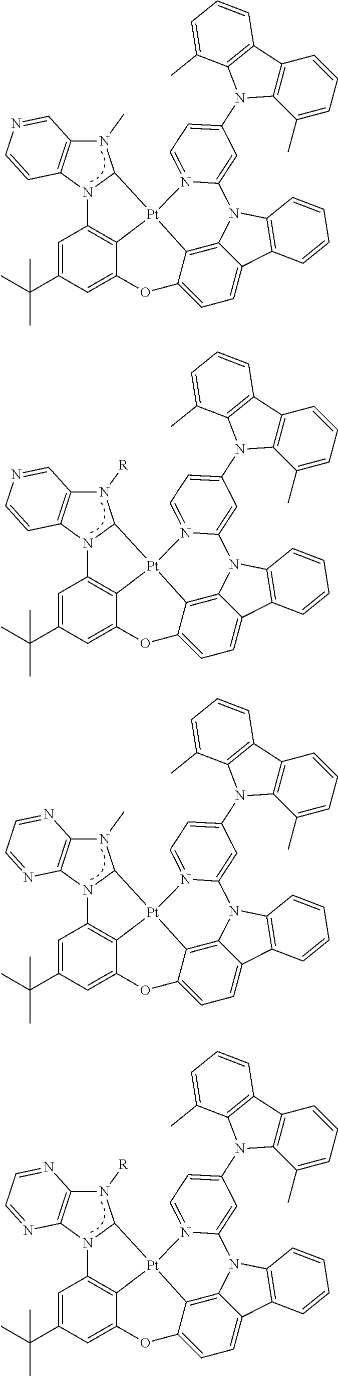

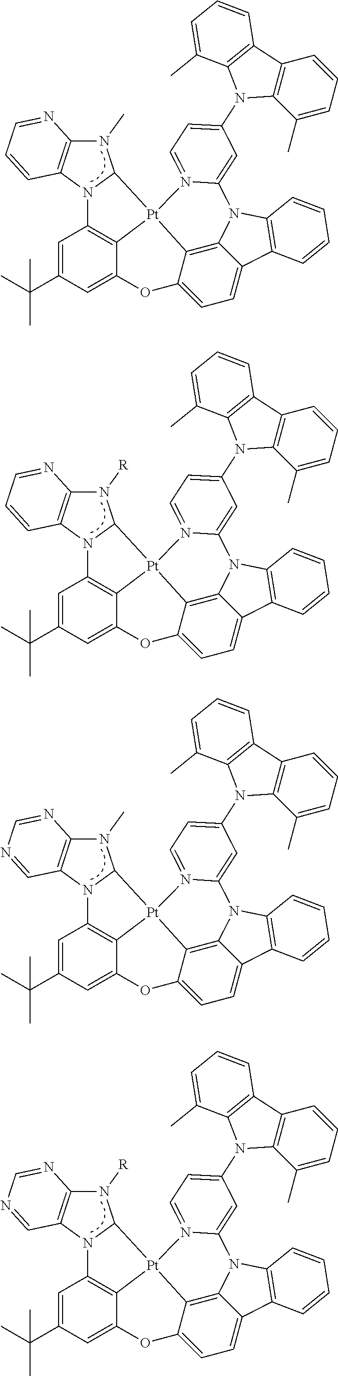

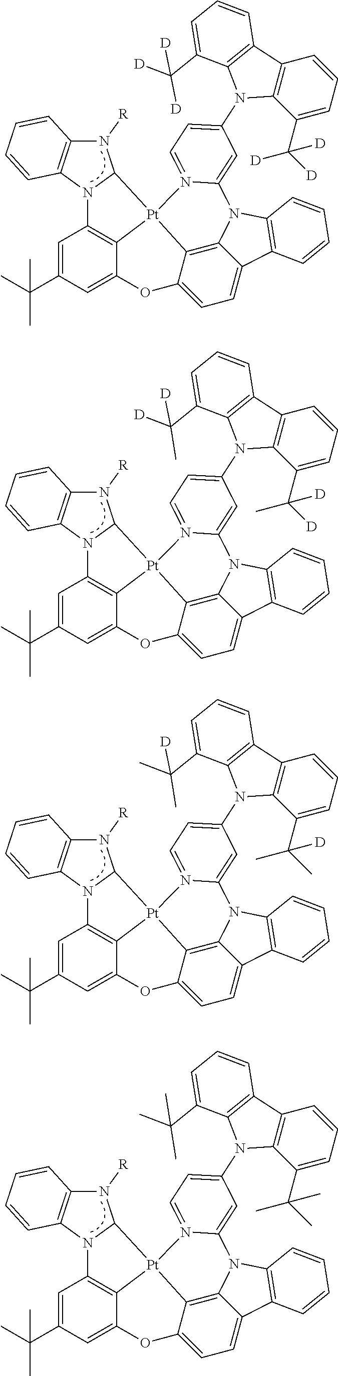

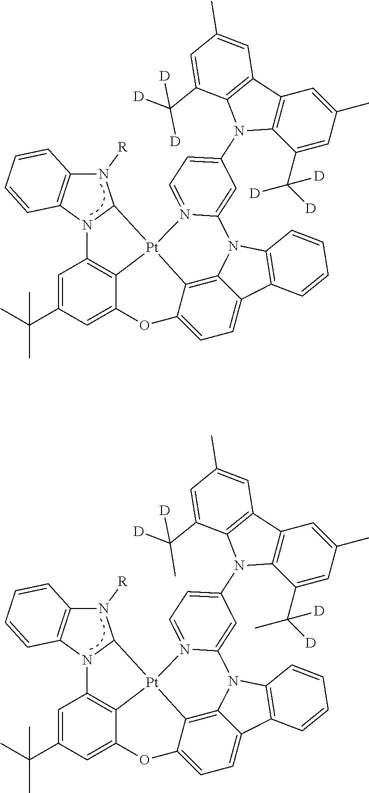

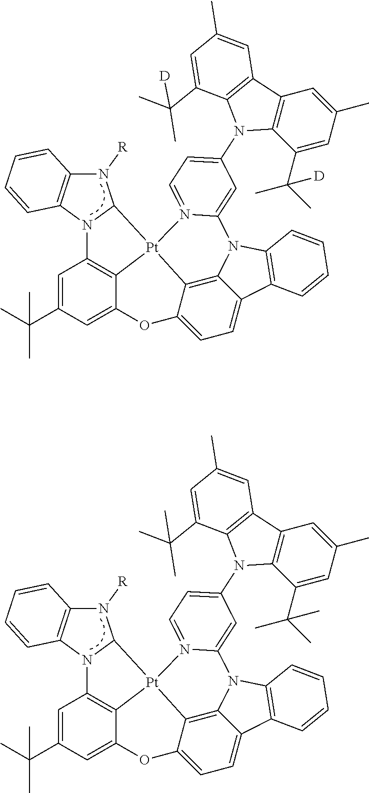

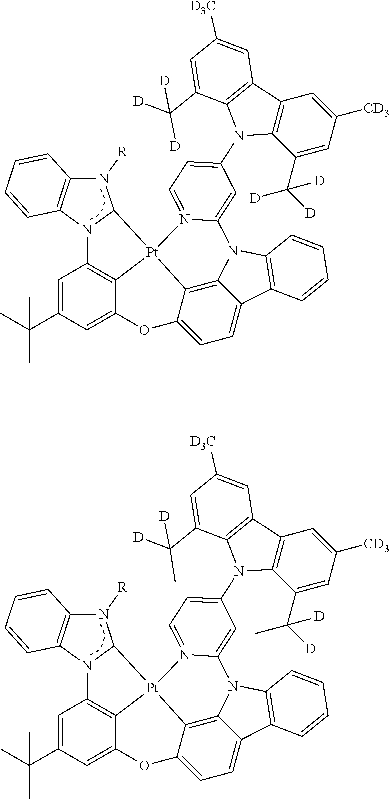

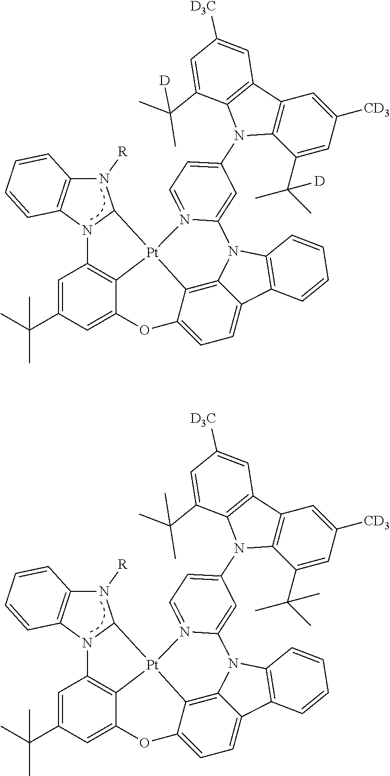

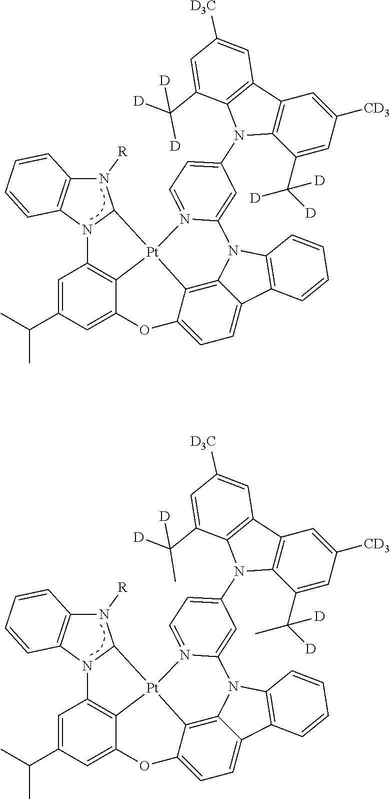

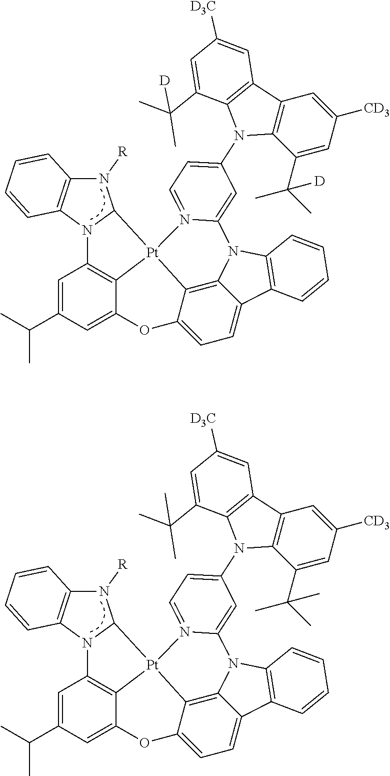

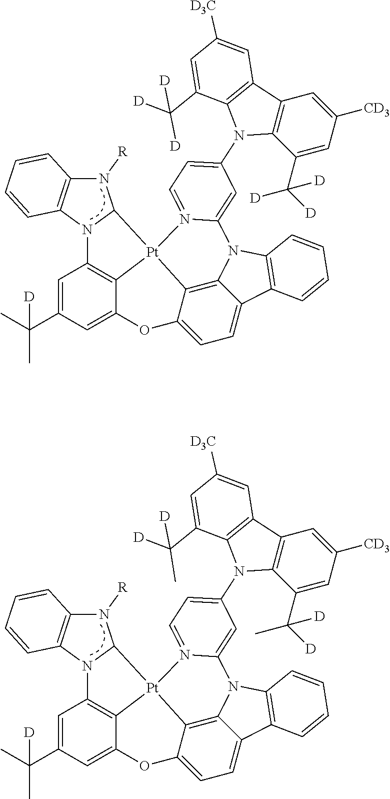

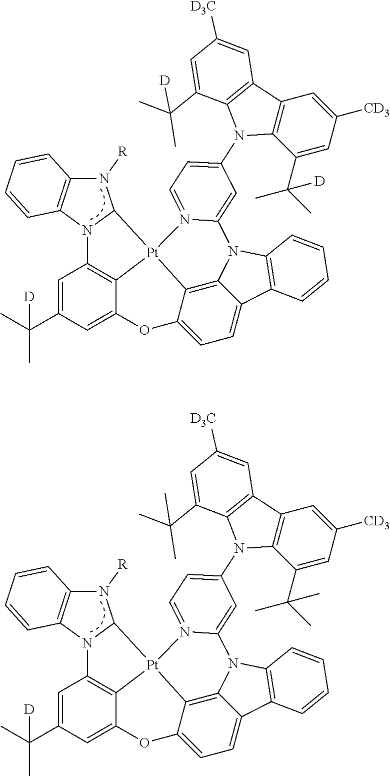

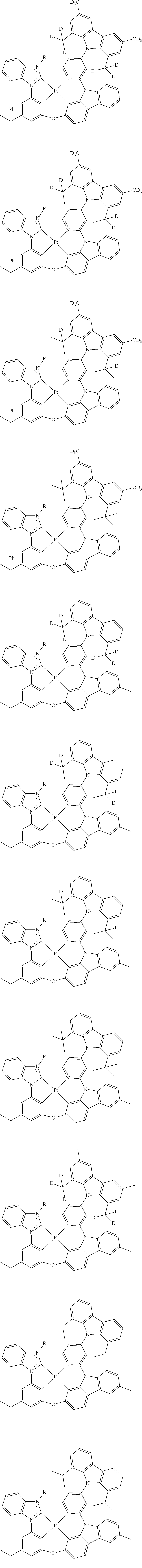

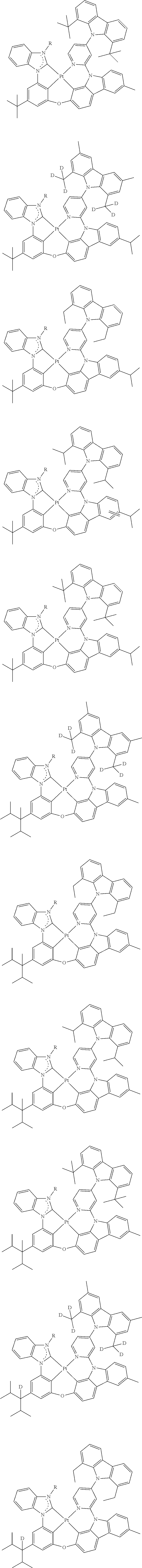

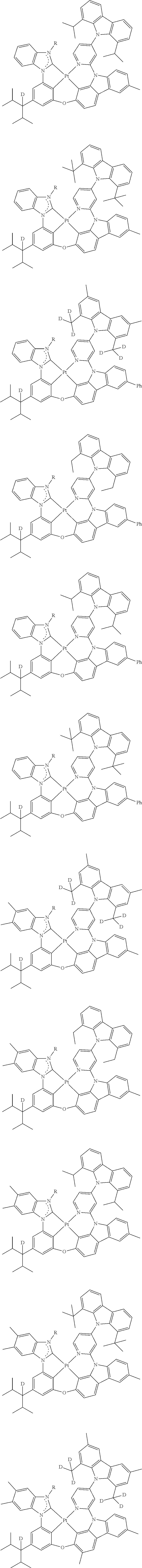

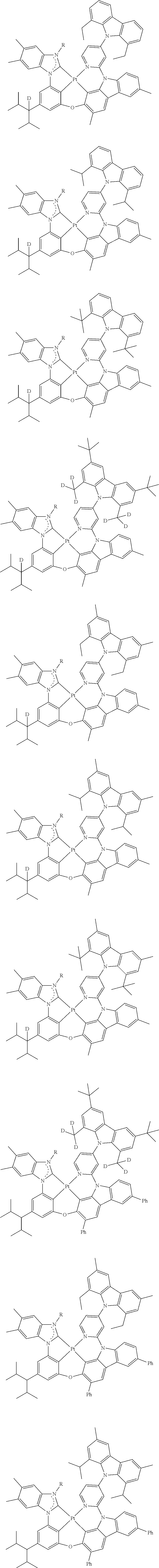

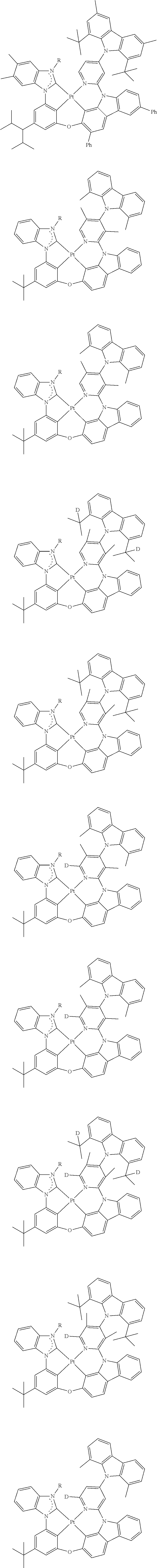

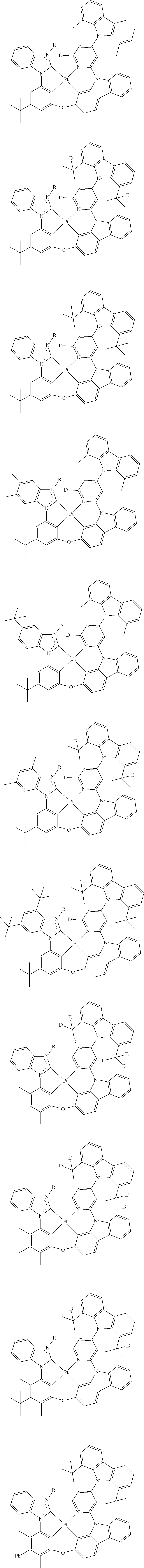

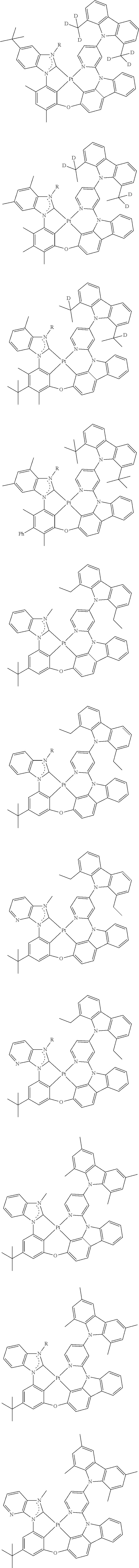

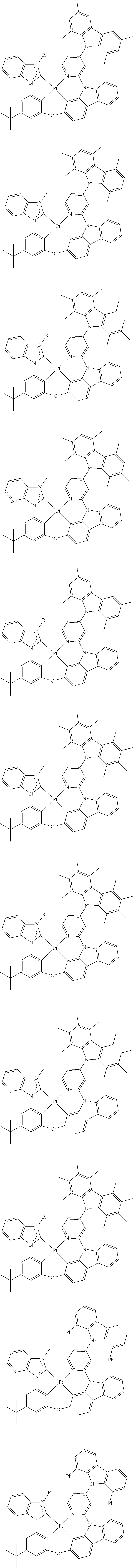

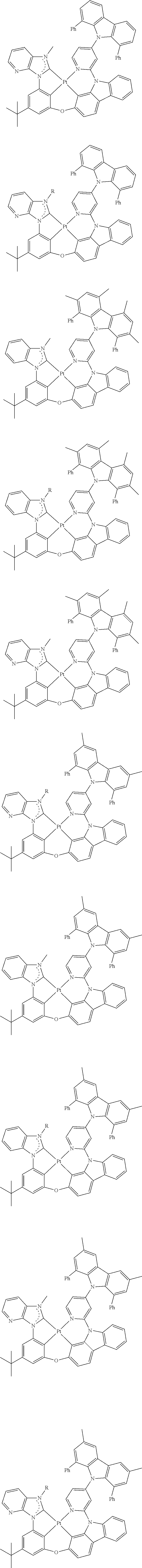

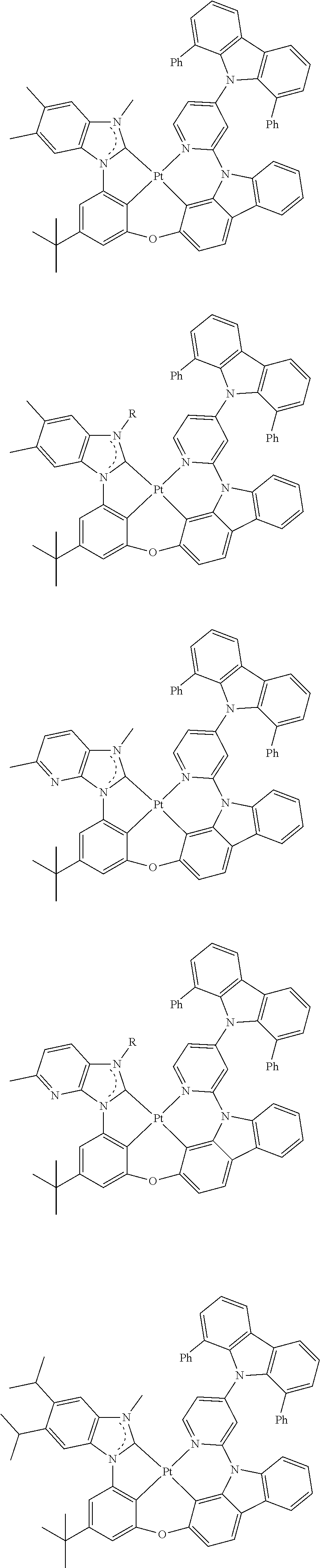

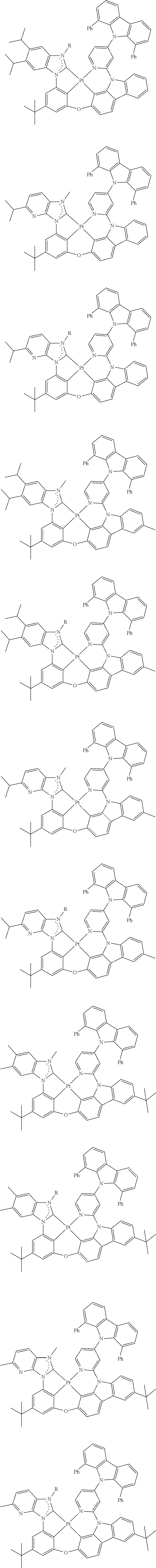

wherein R is not alkyl except for methyl, alkoxy, cycloalkyl, heterocyclyl, alkenyl, substituted or unsubstituted aryl, substituted or unsubstituted aryloxy, substituted or unsubstituted heteroaryl, or deuterated substituents thereof.

The above high radiation rate platinum complex luminescent material based on 1,8-substituted carbazole of the present invention may serve as a phosphorescent luminescent material or a delayed fluorescent material in an organic light emitting element.

The organic light emitting element is an organic light emitting diode, a light emitting diode, or a light emitting electrochemical cell.

The present invention further provides a light emitting device which includes a first electrode, a second electrode and an organic layer. The luminescent material of the present invention is used as an organic layer in the light emitting device, and at least one of the organic layer is disposed between the first electrode and the second electrode.

Specific instances of the phosphorescent luminescent material of the present invention represented by the following General Formula (1) are described by way of examples below, however, they are not interpreted as limiting the present invention.

The content of the present invention is described in detail below. The description of the constituent elements recorded below is sometimes based on representative implementations or specific examples of the present invention, but the present invention is not limited to such implementations or specific examples.

The present disclosure may be understood more easily with reference to the following specific implementations and embodiments contained therein. Before disclosing and describing the compounds, devices, and/or methods of the present invention, it should be understood that unless otherwise stated, they are not limited to specific synthesis methods or specific reagents, as they can vary. It should also be understood that the terms used in the present invention are only for describing specific aspects and are not intended to limit. Although any methods and materials similar or equivalent to those described in the present invention can be used in this practice or experiment, exemplary methods and materials are now described.

The singular forms “a”, “one”, and “the” used in the specification and attached claims include plural references, otherwise the context may expressly indicate. Therefore, for example, when referring to “component”, it includes a mixture of two or more components.

The terms “optional” or “optionally” used in the present invention mean that the subsequently described event or situation may or may not occur, and the description includes instances where the event or situation occurred and instances where it did not occur.

Disclosed are components that can be used to prepare a composition described in the present invention, as well as the composition itself to be used in methods disclosed in the present invention. The present invention discloses these and other materials, and it should be understood that the combinations, subsets, interactions, groups, etc. of these substances are disclosed. Although it is not possible to specifically disclose each different individual and total combination of these compounds, as well as specific references to their arrangement, each has its own specific ideas and descriptions. For example, if a specific compound is disclosed and discussed, and many modifications that can be made to many molecules containing the compound are discussed, then each combination and arrangement of the compound, as well as possible modifications, are specifically considered, unless opposite possible modifications are specifically indicated. Therefore, if a class of molecules A, B, and C, as well as a class of molecules D, E, and F, and instances of combined molecules A-D are disclosed, then even if each is not separately recorded, each individual and total combination of meanings, A-E, A-F, B-D, B-E, B-F, C-D, C-E, and C-F, is also considered to be disclosed. Similarly, any subset or combination of these is also disclosed. For example, subgroups of A-E, B-F, and C-E are also disclosed. This concept applies to all aspects of the present invention, including but not limited to the steps in methods for preparing and using the composition. Therefore, if there are various additional steps that can be carried out, it should be understood that each of these additional steps can be carried out in a specific implementation or combination of implementations of the methods.

Connecting atoms used in the present invention can connect two groups, such as connecting N and C. The connecting atoms can optionally (if valence bonds allow) attach to other chemical groups. For example, oxygen atoms do not have any other chemical group attachments because once two atoms (such as N or C) are bonded, the valence bond is already satisfied. On the contrary, when carbon is a connecting atom, two other chemical groups can attach to the carbon atom. Suitable chemical groups include but are not limited to hydrogen, hydroxyl, alkyl, alkoxy, ═O, halogen, nitryl, amine, amide, sulfhydryl, aryl, heteroaryl, cycloalkyl and heterocyclyl.

The term “cyclic structure” or similar terms used in the present invention refer to any cyclic chemical structure, including but not limited to aryl, heteroaryl, cycloalkyl, cycloalkenyl, heterocyclyl, carbene, and N-heterocyclic carbene.

The term “substituted” or similar terms used in the present invention includes all permitted substituents of organic compounds. Broadly speaking, the permitted substituents include cyclic and non-cyclic, branched and non-branched, carbocyclic and heterocyclic, aromatic and non-aromatic substituents of the organic compounds. For example, exemplary substituents include the following. For suitable organic compounds, the permitted substituents may be one or more, the same or different. For the purpose of the present invention, a heteroatom (such as nitrogen) can have a hydrogen substituent and/or any permitted substituent of an organic compound that satisfies the valence bond of the heteroatom as described in the present invention. The present invention is not intended to limit in any way with any substituents permitted by the organic compounds. Similarly, the term “substituted” or “substituted with” includes implicit conditions that the substitution conforms to the permitted valence bond of the substituted atom and the substituent, and that the substitution leads to stable compounds (such as compounds that do not undergo spontaneous transformation (such as through rearrangement, cyclization, elimination, etc.). In certain aspects, unless explicitly stated to the contrary, individual substituents can be further optionally substituted (i.e., further substituted or unsubstituted).

When defining various terms, “R¹”, “R²”, “R³”, and “R⁴” are used as general symbols in the present invention to represent various specific substituents. These symbols can be any substituent, not limited to those disclosed in the present invention. When they are defined as certain substituents in one instance, they can also be defined as some other substituents in another instance.

The term “alkyl” used in the present invention refers to a saturated hydrocarbon group with 1 to 30 carbon atoms, either branched or unbranched, such as methyl, ethyl, n-propyl, isopropyl, n-butyl, isobutyl, sec-butyl, tert-butyl, n-pentyl, isopentyl, sec-pentyl, neopentyl, hexyl, heptyl, octyl, nonyl, decyl, dodecyl, tetradecyl, hexadecyl, eicosyl, tetracosyl, etc. The alkyl may be cyclic or non-cyclic. The alkyl may be branched or unbranched. The alkyl may also be substituted or unsubstituted. For example, the alkyl may substitute one or more groups, including but not limited to optionally substituted alkyl, cycloalkyl, alkoxy, amino, ether, halogen, hydroxyl, nitryl, silyl, thio-oxo group, and sulfhydryl described in the present invention. A “lower alkyl” group is alkyl containing 1 to 6 (e.g. 1 to 4) carbon atoms.

Throughout the specification, “alkyl” usually refers to both unsubstituted and substituted alkyl; however, the substituted alkyl is also specifically mentioned in the present invention by determining specific substituents on the alkyl. For example, the term “halogenated alkyl” or “haloalkyl” specifically refers to alkyl substituted with one or more halogens (such as fluorine, chlorine, bromine, or iodine). The term “alkoxy alkyl” specifically refers to alkyl substituted with one or more alkoxy groups, as described below. The term “alkyl amino” specifically refers to alkyl substituted with one or more amino groups, as described below. When using “alkyl” in one situation and specific terms such as “alkyl alcohol” in another situation, it does not imply that the term “alkyl” does not refer to specific terms such as “alkyl alcohol” at the same time.

This approach is also applicable to other groups described in the present invention. That is to say, when the term “cycloalkyl” refers to both unsubstituted and substituted cycloalkyl moieties, the substituted moieties may be specifically determined in the present invention additionally. For example, the specific substituted cycloalkyl may be referred to as, for example, “alkyl cycloalkyl”. Similarly, substituted alkoxy may be specifically referred to as for example “halogenated alkoxy”, and specific substituted alkenyl may be for example “enol”. Similarly, the use of general terms such as “cycloalkyl” and specific terms such as “alkyl cycloalkyl” does not mean that the general term does not also include the specific term at the same time.

The term “cycloalkyl” used in the present invention is a non-aromatic carbon ring, consisting of at least three carbon atoms, of 3 to 30 carbon atoms. Examples of the cycloalkyl include but are not limited to cyclopropyl, cyclobutyl, cyclopentyl, cyclohexyl, cyclononyl, etc. The term “heterocyclic alkyl” is a type of cycloalkyl as defined above and is included in the meaning of the term “cycloalkyl”, wherein at least one cyclic carbon atom is substituted with a heteroatom such as but not limited to nitrogen, oxygen, sulfur, or phosphorus. The cycloalkyl and the heterocyclic alkyl may be substituted or unsubstituted. The cycloalkyl and the heterocyclic alkyl may be substituted with one or more groups, including but not limited to alkyl, cycloalkyl, alkoxy, amino, ether, halogen, hydroxyl, nitryl, silyl, thio-oxo group, and sulfhydryl as described in the present invention.

The terms “alkoxy” and “alkoxy group” used in the present invention refer to alkyl or cycloalkyl of 1 to 30 carbon atoms bonded through ether bonds; that is, the term “alkoxy” may be defined as —OR, wherein R¹ is alkyl or cycloalkyl as defined above. “Alkoxy” also contains an alkoxy polymer just described; that is, the alkoxy may be polyether, such as —OR¹—OR² or —OR¹—(OR²)ₐ—OR³, wherein “a” is an integer from 1 to 500, and R¹, R² and R³ are independently alkyl, cycloalkyl or a combination thereof.

The term “alkenyl” used in the present invention refers to a hydrocarbon group of 2 to 30 carbon atoms, with a structural formula containing at least one carbon-carbon double bond. An asymmetric structure such as (R¹R²)C═C(R³R⁴) contains E and Z isomers. This may be inferred that there is asymmetric olefin in the structural formula of the present invention, or it may be clearly represented by a bond symbol C═C. The alkenyl may be substituted with one or more groups, including but not limited to alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxyl, ketone, azido, nitryl, silyl, a thio-oxo group, or sulfhydryl described in the present invention.

The term “cycloalkenyl” used in the present invention is a non-aromatic carbon ring of 3 to 30 carbon atoms, which consists of at least 3 carbon atoms and contains at least one carbon carbon double bond, i.e. C═C. Instances of the cycloalkenyl include but are not limited to cyclopropenyl, cyclobutenyl, cyclopentenyl, cyclopentadienyl, cyclohexenyl, cyclohexadienyl, cycloheptenyl, etc. The term “heterocyclic alkenyl” is a type of cycloalkenyl as defined above and is included in the meaning of the term “cycloalkenyl”, wherein at least one carbon atom of the ring is substituted with a heteroatom such as but not limited to nitrogen, oxygen, sulfur, or phosphorus. The cycloalkenyl and the heterocyclic alkenyl may be substituted or unsubstituted. The cycloalkenyl and the heterocyclic alkenyl may be substituted with one or more groups, including but not limited to alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxyl, ketone, azido, nitryl, silyl, a thio-oxo group, or sulfhydryl described in the present invention.

The term “alkynyl” used in the present invention refers to a hydrocarbon group with 2 to 30 carbon atoms, with a structural formula containing at least one carbon-carbon triple bond. The alkynyl may be unsubstituted or substituted with one or more groups, including but not limited to alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxyl, ketone, azido, nitryl, silyl, a thio-oxo group, or sulfhydryl described in the present invention.

The term “cycloalkynyl” used in the present invention is a non-aromatic carbon ring, which contains at least 7 carbon atoms and contains at least one carbon-carbon triple bond. Instances of the cycloalkynyl include but are not limited to cycloheptynyl, cyclo-octynyl, cyclononynoyl, etc. The term “heterocyclic alkynyl” is a kind of cycloalkynyl as defined above and is included in the meaning of the term “cycloalkynyl”, wherein at least one carbon atom of the ring is substituted with a heteroatom such as but not limited to nitrogen, oxygen, sulfur, or phosphorus. The cycloalkynyl and the heterocyclic alkynyl may be substituted or unsubstituted. The cycloalkynyl and the heterocyclic alkynyl may be substituted with one or more groups, including but not limited to alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxyl, ketone, azido, nitryl, silyl, a thio-oxo group, or sulfhydryl described in the present invention.

The term “aryl” used in the present invention refers to groups containing 60 carbon atoms or less of any carbon-based aromatic group, including but not limited to benzene, naphthalene, phenyl, biphenyl, phenoxybenzene, etc. The term “aryl” also includes “heteroaryl”, which is defined as a group containing an aromatic group, wherein an aromatic group ring contains at least one heteroatom. Instances of the heteroatom include but are not limited to nitrogen, oxygen, sulfur, or phosphorus. Similarly, the term “non-heteroaryl” (also included in the term “aryl”) defines groups containing an aromatic group that does not contain heteroatoms. The aryl may also be substituted or unsubstituted. The aryl may be substituted with one or more groups, including but not limited to alkyl, cycloalkyl, alkoxy, alkenyl, cycloalkenyl, alkynyl, cycloalkynyl, aryl, heteroaryl, aldehyde, amino, carboxylic acid, ester, ether, halogen, hydroxyl, ketone, azido, nitryl, silyl, a thio-oxo group, or sulfhydryl described in the present invention. The term “diaryl” is a specific type of aryl and is included in the definition of “aryl”. The diaryl refers to two aryl groups that are bonded together by a fused ring structure, as in naphthalene, or two aryl groups that are connected by one or more carbon-carbon bonds, as in biphenyl.

The term “aldehyde” used in the present invention is represented by a formula —C(O)H. Throughout the specification, “C(O)” is the abbreviated form of carbonyl (i.e., C═O).

The term “amine” or “amino” used in the present invention is represented by a formula —NR¹R², wherein R¹ and R² may be independently selected from hydrogen, alkyl, cycloalkyl, alkenyl, cycloalkenyl, alkynyl, cycloalkynyl, aryl or heteroaryl.

The term “alkylamino” used in the present invention is represented by a formula —NH(-alkyl), wherein alkyl is as described in the present invention. Representative instances include but are not limited to methylamino, ethylamino, propylamino, isopropylamino, butylamino, isobutylamino, sec-butylamino, tert-butylamino, pentylamino, isopentylamino, tert-pentylamino, hexylamino, etc.

The term “dialkylamino” used in the present invention is represented by a formula —N(-alkyl)₂, wherein alkyl is as described in the present invention. Representative instances include but are not limited to dimethylamino, diethylamino, dipropylamino, diisopropylamino, dibutylamino, diisobutylamino, di-sec-butylamino, di-tert-butylamino, dipentylamino, diisopentylamino, di-tert-pentylamino, dihexylamino, N-ethyl-N-methylamino, N-methyl-N-propylamino, N-ethyl-N-propylamino, etc.

The term “carboxylic acid” used in the present invention is represented by a formula —C(O)OH.

The term “ester” used in the present invention is represented by a formula —OC(O)R¹ or —C(O)OR¹, wherein R¹ may be alkyl, cycloalkyl, alkenyl, cycloalkenyl, alkynyl, cycloalkynyl, aryl or heteroaryl as described in the present invention. The term “polyester” used in the present invention is represented by a formula —(R¹O(O)C—R²—C(O)O)ₐ— or —(R¹O(O)C—R²—OC(O))ₐ—, wherein R¹ and R² may independently be alkyl, cycloalkyl, alkenyl, cycloalkenyl, alkynyl, cycloalkynyl, aryl or heteroaryl as described in the present invention, and “a” is an integer from 1 to 500. The term “polyester” is used to describe groups generated by reaction between a compound with at least two carboxyl groups and a compound with at least two hydroxyl groups.

The term “ether” used in the present invention is represented by a formula R¹OR², wherein R¹ and R² may independently be alkyl, cycloalkyl, alkenyl, cycloalkenyl, alkynyl, cycloalkynyl, aryl or heteroaryl as described in the present invention. The term “polyether” used in the present invention is represented by a formula —(R¹O—R²O)ₐ—, wherein R¹ and R² may independently be alkyl, cycloalkyl, alkenyl, cycloalkenyl, alkynyl, cycloalkynyl, aryl or heteroaryl as described in the present invention, and “a” is an integer from 1 to 500. Instances of polyether groups include polyethylene oxide, polypropylene oxide, and polybutylene oxide.

The term “halogen” used in the present invention refers to halogen fluorine, chlorine, bromine, and iodine.

The term “heterocyclyl” used in the present invention refers to non-aromatic ring systems of single and multi rings, and the term “heteroaryl” used in the present invention refers to aromatic ring systems of single and multi rings with no more than 60 carbon atoms: at least one of ring members is not carbon. This term includes azetidinyl, dioxanyl, furanyl, imidazolyl, isothiazolyl, isoxazolyl, morpholinyl, oxazolyl (including oxazolyl of 1,2,3-oxadiazolyl, 1,2,5-oxadiazolyl, and 1,3,4-oxadiazolyl), piperazinyl, piperidinyl, pyrazinyl, pyrazolyl, pyridazinyl, pyridyl, pyrimidinyl, pyrryl, pyrrolidinyl, tetrahydrofuranyl, tetrahydropyranyl, tetrazinyl including 1,2,4,5-tetrazinyl, tetrazolyl including 1,2,3,4-tetrazolyl and 1,2,4,5-tetrazolyl, thiadiazolyl including 1,2,3-thiadiazolyl, 1,2,5-thiadiazolyl and 1,3,4-thiadiazolyl, thiazolyl, thienyl, triazinyl including 1,3,5-triazinyl and 1,2,4-triazinyl, triazolyl including 1,2,3-triazolyl and 1,3,4-triazolyl, etc.

The term “hydroxyl” used in the present invention is represented by a formula —OH.

The term “ketone” used in the present invention is represented by a formula R¹C(O)R², wherein R¹ and R² may independently be alkyl, cycloalkyl, alkenyl, cycloalkenyl, alkynyl, cycloalkynyl, aryl or heteroaryl as described in the present invention.

The term “nitryl” used in the present invention is represented by a formula —NO₂.

The term “nitrile” used in the present invention is represented by a formula —CN.

The term “silyl” used in the present invention is represented by a formula —SiR¹R²R³, wherein R¹, R² and R³ may independently be hydrogen or alkyl, cycloalkyl, alkoxy, alkenyl, cycloalkenyl, alkynyl, cycloalkynyl, aryl or heteroaryl as described in the present invention.

The term “sulfhydryl” used in the present invention is represented by a formula —SH.

“R¹”, “R²”, “R³”, and “Rⁿ” (wherein n is an integer) used in the present invention may independently have one or more of the groups listed above. For example, if R¹ is linear chain alkyl, then one hydrogen atom of the alkyl may be optionally substituted with hydroxyl, alkoxy, alkyl, halogen, etc. Depending on the selected group, a first group may be bound within a second group, or a first group may be laterally connected (i.e., connected) to a second group. For example, for the phrase “alkyl containing amino”, the amino may be bound within a main chain of the alkyl. Optionally, the amino may be connected to the main chain of the alkyl. The nature of the selected group will determine whether the first group is embedded or connected to the second group.

The compound described in the present invention may contain “optionally substituted” parts. Usually, the term “substituted” (whether or not the term “optionally” exists before) means that one or more hydrogen in a specified portion is substituted with a suitable substituent. Unless otherwise specified, “optionally substituted” groups may have suitable substituents at each substitutable position of the group, and when more than one position in any given structure may be substituted with more than one substituent selected from a specified group, the substituent may be the same or different at each position. A substituent combination envisioned in the present invention is preferably a combination forming stable or chemically feasible compounds. It can also be imagined that in certain aspects, unless explicitly stated to the contrary, each substituent may be further optionally substituted (i.e., further substituted or unsubstituted).

The structure of a compound may be represented by a formula below:

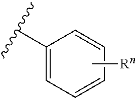

it is understood to be equivalent to a formula below:

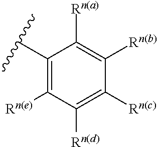

wherein n is usually an integer. That is to say, Rⁿ is understood to represent five separate substituents R^{n(a)}, R^{n(b)}, R^{n(c)}, R^{n(d)} and R^{n(e)}. The “separate substituent” means that each R substituent may be independently defined. For example, if R^{n(a}) is halogen in one situation, then R^{n(b)} is not necessarily halogen in this situation.

R¹, R², R³, R⁴, R⁵, R⁶, etc. are mentioned many times in chemical structures and units disclosed and described in the present invention. In the specification, any description of R¹, R², R³, R⁴, R⁵, R⁶, etc. is respectively suitable for any structure or unit that cites R¹, R², R³, R⁴, R⁵, R⁶, etc., unless otherwise stated.

The term “fused ring” used in the present invention means that two adjacent substituents may be fused into a six-membered aromatic ring and a heteroaromatic ring, such as a benzene ring, a pyridine ring, a pyrazine ring, a pyridazine ring, an m-diazo heterocyclic ring, as well as a saturated six-membered or seven-membered carbon ring or carbon heterocyclic ring.

Due to various reasons, the use of organic materials in optoelectronic devices has become increasingly urgent. Many materials used to manufacture such apparatuses are relatively cheap, so organic optoelectronic apparatuses have the potential for cost advantages in inorganic apparatuses. In addition, the inherent characteristics of organic materials, such as their flexibility, may make them very suitable for special applications such as manufacturing on flexible substrates. Instances of organic optoelectronic devices include organic light emitting devices (OLEDs), organic phototransistors, organic photovoltaic cells, and organic photodetectors. For the OLEDs, organic materials may have performance advantages over conventional materials. For example, the wavelength of light emitted from an organic light emitting layer may usually be easily tuned with appropriate doping agents.

Excitons decay from a singlet excited state to a ground state to produce instant luminescence, which is fluorescence. If the excitons decay from a triplet excited state to the ground state to produce luminescence, it is phosphorescence. Due to the strong spin orbit coupling between a singlet excited state and a triplet excited state of heavy metal atoms, which effectively enhances inter-system crossing (ISC), a phosphorescent metal complex (such as a platinum complex) has shown the potential to utilize both singlet and triplet excitons simultaneously, achieving 100% internal quantum efficiency. Therefore, the phosphorescent metal complex is a good candidate for a doping agent in an emission layer of an organic light emitting device (OLED) and has received great attention in academic and industrial fields. Over the past decade, many achievements have been made, leading to the profitable commercialization of this technology. For example, OLEDs have been used in advanced displays for smart phones, televisions, and digital cameras.

However, to date, blue electroluminescent devices remain the most challenging field in this technology, with the stability of blue devices being a major issue. It has been proven that the selection of a host material is crucial for the stability of the blue devices. However, the lowest energy of a triplet excited state (T₁) of a blue luminescent material is very high, which means that the lowest energy of the triplet excited state (T₁) of the host material of the blue devices should be higher. This has increased the difficulty in developing host materials for blue equipment.

The metal complex of the present invention may be customized or tuned for specific applications with specific emission or absorption characteristics. The optical properties of the metal complex in the present disclosure may be adjusted by changing the structure of a ligand surrounding the metal center or changing the structure of a fluorescent luminescent body on the ligand. For example, in emission and absorption spectra, metal complexes with electron donating substituent ligands or electron withdrawing substituents typically may exhibit different optical properties. The color of the metal complex may be adjusted by modifying conjugated groups on fluorescent luminescent bodies and ligands.

The emission of this complex of the present invention may be adjusted, for example, by changing the structure of ligands or fluorescent luminescent bodies, such as from ultraviolet to near-infrared. Fluorescent luminescent bodies are a group of atoms in organic molecules, and may absorb energy to produce a singlet excited state, and singlet excitons rapidly decay to produce instant luminescence. On the one hand, the complex of the present invention may provide emission of most visible spectra. In specific instances, the complex of the present invention may emit light in the range of about 400 nm to about 700 nm. On the other hand, the complex of the present invention has improved stability and efficiency compared to traditional emission complexes. In addition, the complex of the present invention may be used as luminescent labels for emitters in, for example, biological applications, anticancer agents, and organic light emitting diodes (OLEDs) or combinations thereof. On the other hand, the complex of the present invention may be used for light emitting devices, such as compact fluorescent lamps (CFLs), light emitting diodes (LEDs), incandescent lamps, and combinations thereof.

A compound or compound complex containing platinum is disclosed herein. The term compound or complex is interchangeable in the present invention. In addition, the compound disclosed herein has neutral charges.

The compound disclosed herein may exhibit expected properties and has emission and/or absorption spectra that may be adjusted by selecting appropriate ligands. On the other hand, the present invention may exclude any one or more compounds, structures, or parts thereof specifically described herein.

The compound disclosed herein is applicable to various optical and electro-optical apparatuses, including but not limited to light absorption apparatuses, such as solar and photosensitive apparatuses, organic light emitting diodes (OLEDs), light emitting devices or devices that are compatible with light absorption and emission, as well as biomarkers for biological applications.

As described above, the disclosed compound is a platinum complex. Meanwhile, the compound disclosed herein may be used as a host material for OLED applications, such as a full-color display.

The compound disclosed herein may be used for various applications. As a luminescent material, this compound may be used in organic light emitting diodes (OLEDs), light emitting apparatuses, displays, and other light emitting devices.

The compound of the present invention may be prepared using various methods, including but not limited to those described in the embodiments provided herein.

The compound disclosed herein may be a delayed fluorescent and/or phosphorescent emitter. On the one hand, the compound disclosed herein may be a delayed fluorescent emitter. On the one hand, the compound disclosed herein may be a phosphorescent emitter.

On the other hand, the compound disclosed herein may be a delayed fluorescent emitter and a phosphorescent emitter.

The present disclosure relates to a cyclometalated platinum complex, which may be used as a luminescent material and a host material in an OLED device.

Unless otherwise specified, all commercial reagents involved in the following experiments are directly used after purchase without further purification. Both hydrogen and carbon nuclear magnetic resonance are measured in a deuterated chloroform (CDCl₃) or deuterated dimethyl sulfoxide (DMSO-d₆) solution. A 400 or 500 MHz nuclear magnetic spectrometer is used for the hydrogen nuclear magnetic resonance, while a 100 or 126 MHz nuclear magnetic resonance spectrometer is used for the carbon nuclear magnetic resonance. The chemical shift is based on tetramethylsilane (TMS) or a residual solvent. If CDCl₃ is used as the solvent, the hydrogen nuclear magnetic resonance and the carbon nuclear magnetic resonance use TMS (δ=0.00 ppm) and CDCl₃ (δ=77.00 ppm) as internal standards respectively. If DMSO-d₆ is used as the solvent, the hydrogen nuclear magnetic resonance and the carbon nuclear magnetic resonance use TMS (δ=0.00 ppm) and DMSO-d₆ (δ=39.52 ppm) as internal standards respectively. The following abbreviations (or combinations) are used to explain hydrogen nuclear magnetic resonance peaks: s=single peak, d=double peak, t-triple peak, q=quadruple peak, p=quintuple peak, m=multiple peak, and br=broad peak. A high resolution mass spectrum is measured on the ESI-QTOF mass spectrometer of Applied Biosystems, and a sample ionization mode is electrospray ionization.

Embodiment 1: A synthetic route of a tetradentate cyclometalated platinum (II) complex phosphorescent luminescent material PtDMCz is as follows:

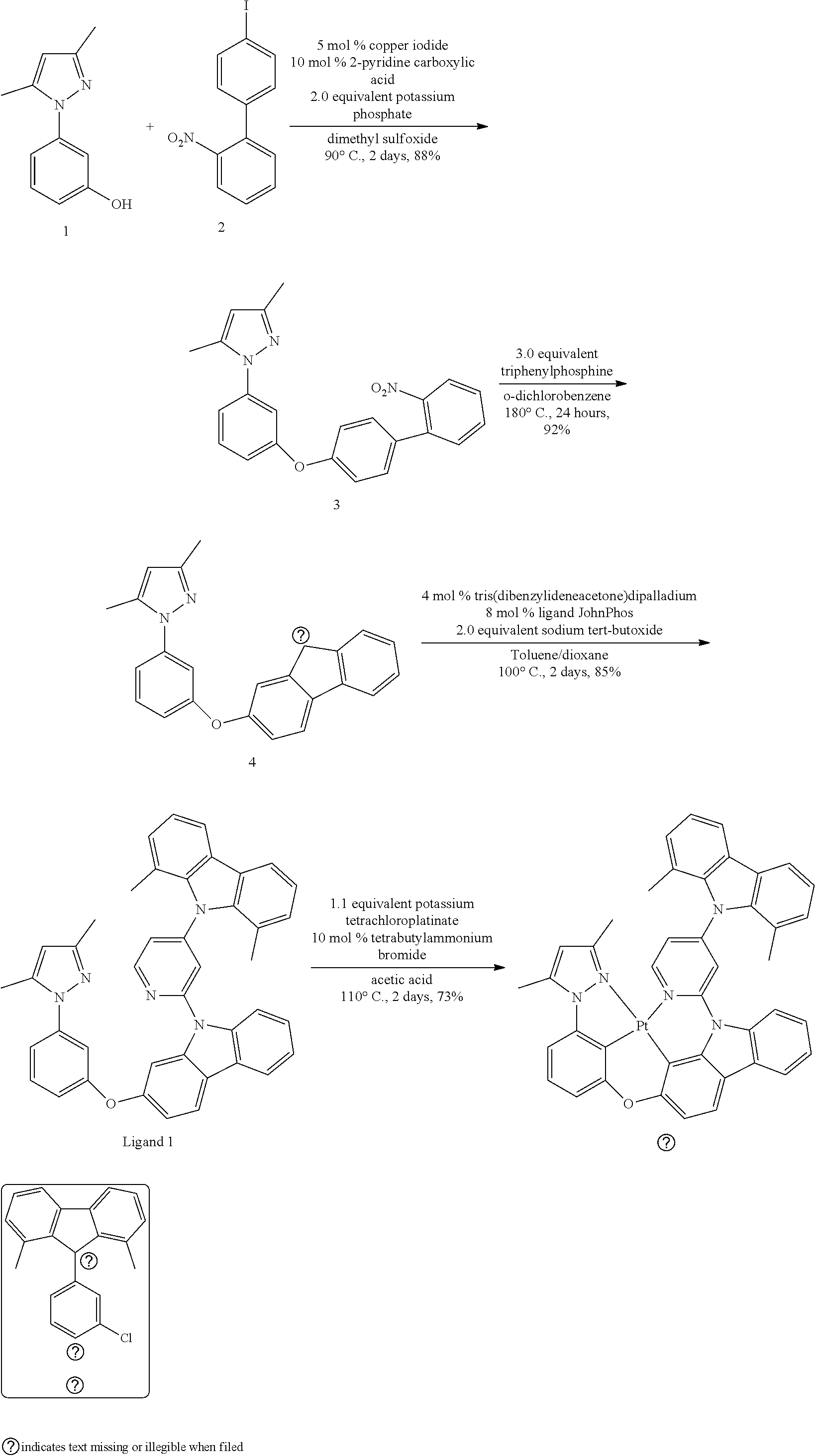

Synthesis of an intermediate 3: a compound 1 (1.00 g, 5.31 mmol, 1.0 equivalent), a compound 2 (2.07 g, 6.38 mmol, 1.2 equivalent), copper iodide (51 mg, 0.27 mmol, 5 mol %), 2-pyridine carboxylic acid (65 mg, 0.53 mmol, 10 mol %), and potassium phosphate (2.26 g, 10.62 mmol, 2.0 equivalent) were sequentially added into a dry three-necked flask with a magnetic stirring rotor and a condenser tube, then vacuumizing nitrogen-replacement was carried out three times, and dimethyl sulfoxide (20 mL) was added under the protection of nitrogen. A mixture was stirred in a 90° C. oil bath to react for 2 days, and was cooled to the room temperature when the completion of the raw material reaction was monitored through thin-layer chromatography. A small amount of saline was added, and ethyl acetate was used for extraction. An organic layer was washed twice with water, and a water layer was extracted twice with ethyl acetate. An organic phase was combined, drying was carried out with anhydrous sodium sulfate, and filtering was carried out. A solvent was removed through reduced pressure distillation, an obtained crude product was subjected to separation and purification through a silica gel chromatographic column, an eluent: petroleum ether/ethyl acetate=10:1-3:1-2:1, the intermediate 3 was obtained, viscous liquid was 1.80 g, and a yield was 88%. ¹H NMR (DMSO-d₆, 400 MHz): δ 2.15 (s, 3H), 2.30 (s, 3H), 6.06 (s, 1H), 7.07 (dd, J=8.0, 2.4 Hz, 1H), 7.13-7.16 (m, 3H), 7.30-7.32 (m, 1H), 7.36-7.40 (m, 2H), 7.52 (t, J=8.0, 1H), 7.57 (dd, J=7.6, 1.2 Hz, 1H), 7.59-7.64 (m, 1H), 7.75 (td, J=7.6, 1.2 Hz, 1H), 7.97 (dd, J=8.0, 1.2 Hz, 1H).

Synthesis of an intermediate 4: a compound 3 (1.71 g, 4.41 mmol, 1.0 equivalent), and triphenylphosphine (3.47 g, 13.23 mmol, 3.0 equivalent) were sequentially added into a dry three-necked flask with a magnetic stirring rotor and a condenser tube, then vacuumizing nitrogen-replacement was carried out three times, and o-dichlorobenzene (25 mL) was added under the protection of nitrogen. A mixture was stirred in a 180° C. oil bath to react for 24 hours, and was cooled to the room temperature when the completion of the raw material reaction was monitored through thin-layer chromatography. A solvent was removed through reduced pressure distillation, an obtained crude product was subjected to separation and purification through a silica gel chromatographic column, an eluent: petroleum ether/dichloromethane=10:1-5:1, the intermediate 4 was obtained, white solid was 1.43 g, and a yield was 92%. ¹H NMR (500 MHz, CDCl₃): δ 2.26 (s, 3H), 2.27 (s, 3H), 5.96 (s, 1H), 6.81 (d, J=2.0 Hz, 1H), 6.92 (dd, J=8.5, 2.0 Hz, 1H), 6.97-7.00 (m, 1H), 7.07 (t, J=2.0 Hz, 1H), 7.14-7.16 (m, 1H), 7.21-7.25 (m, 1H), 7.31-7.37 (m, 3H), 7.96 (d, J=8.5 Hz, 1H), 8.01 (d, J=7.5 Hz, 1H), 8.53 (s, 1H).

Synthesis of a ligand 1: a compound 4 (1.00 g, 2.83 mmol, 1.0 equivalent), a compound 5 (955 mg, 3.11 mmol, 1.1 equivalent), tris(dibenzylideneacetone)dipalladium (104 mg, 0.11 mmol, 4 mol %), a ligand JohnPhos (68 mg, 0.23 mmol, 8 mol %), and sodium tert-butoxide (544 mg, 5.66 mmol, 2.0 equivalent) were sequentially added into a dry three-necked flask with a magnetic stirring rotor and a condenser tube, then vacuumizing nitrogen-replacement was carried out three times, and toluene (30 mL) and dioxane (30 mL) were added under the protection of nitrogen. A mixture was stirred in a 100° C. oil bath to react for 2 days, and was cooled to the room temperature when the completion of the raw material reaction was monitored through thin-layer chromatography. Filtering was carried out, elution was carried out with ethyl acetate, a filtrate was washed twice with water, and a water layer was extracted twice with ethyl acetate. An organic phase was combined, and drying was carried out with anhydrous sodium sulfate. A solvent was removed through reduced pressure distillation, an obtained crude product was subjected to separation and purification through a silica gel chromatographic column, an eluent: petroleum ether/dichloromethane=10:1-1:1, the ligand 1 was obtained, foamy solid was 1.50 g, and a yield was 85%. A calculated value of HRMS (ESI): C₄₂H₃₄N₅O [M+H]⁺ was 624.2758, and a measured value was 624.2761. ¹H NMR (500 MHz, CDCl₃): δ 2.05 (s, 6H), 2.23 (s, 3H), 2.24 (s, 3H), 5.93 (s, 1H), 6.99-7.01 (m, 1H), 7.06 (dd, J=8.5, 2.0 Hz, 1H), 7.10-7.15 (m, 4H), 7.19 (t, J=7.5 Hz, 2H), 7.29-7.35 (m, 2H), 7.38 (td, J=7.5, 1.5 Hz, 1H), 7.43 (dd, J=5.0, 1.5 Hz, 1H), 7.67 (d, J=2.5 Hz, 1H), 7.75 (d, J=8.0 Hz, 1H), 7.81 (d, J=2.0 Hz, 1H), 7.98 (d, J=7.5 Hz, 2H), 8.04 (d, J=8.5 Hz, 2H), 8.78 (d, J=5.0 Hz, 1H). ¹³C NMR (125 MHz, CDCl₃): δ 12.40, 13.39, 19.65, 102.73, 107.16, 110.77, 113.65, 114.58, 116.80, 118.17, 118.95, 119.93, 120.75, 120.77, 120.99, 121.11, 121.14, 121.63, 123.95, 124.31, 124.61, 125.91, 129.34, 129.87, 139.21, 139.61, 140.38, 140.41, 141.16, 148.99, 149.74, 152.28, 153.08, 155.66, 158.2.

Synthesis of PtDMCz: a ligand 1 (624 mg, 1.00 mmol, 1.0 equivalent), potassium tetrachloroplatinate (457 mg, 1.10 mmol, 1.1 equivalent), and tetrabutylammonium bromide (32 mg, 0.10 mmol, 10 mol %) were sequentially added into a dry three-necked flask with a magnetic stirring rotor and a condenser tube, then vacuumizing nitrogen-replacement was carried out three times, acetic acid (60 mL) was added under the protection of nitrogen, and nitrogen bubbling was carried out for 25 minutes. A mixture was stirred under the room temperature for 8 hours, and then was stirred in a 110° C. oil bath pan to react for 2 days, and a product was cooled to the room temperature. Afterwards, a solvent was removed through reduced pressure distillation, an obtained crude product was subjected to separation and purification through a silica gel chromatographic column, an eluent: petroleum ether/dichloromethane=10:1-5:1, Pt1 was obtained, yellow solid was 595 mg, and a yield was 73%. A calculated value of HRMS (ESI): C₄₂H₃₂N₅O¹⁹⁵Pt [M+H]⁺ was 817.2249, and a measured value was 817.2236. ¹H NMR (500 MHz, DMSO-d₆): δ 2.06 (s, 6H), 2.47 (s, 3H), 2.75 (s, 3H), 6.45 (s, 1H), 6.99 (dd, J=8.0, 1.0 Hz, 1H), 7.15-7.26 (m, 6H), 7.30-7.36 (m, 3H), 7.53 (dd, J=8.5, 2.0 Hz, 1H), 7.87 (d, J=8.0 Hz, 1H), 7.90-7.93 (m, 1H), 8.09-8.14 (m, 3H), 8.43 (d, J=2.0 Hz, 1H), 9.40 (d, J=6.5 Hz, 1H). ¹³C NMR (125 MHz, CDCl₃): δ 14.44, 15.84, 19.90, 99.56, 106.99, 110.05, 110.32, 113.28, 113.40, 114.32, 115.51, 116.40, 117.59, 118.33, 120.11, 120.53, 120.94, 120.96, 123.37, 124.26, 124.67, 124.84, 129.48, 137.94, 139.85, 141.39, 142.01, 147.76, 148.98, 149.24, 152.63, 152.68, 152.90, 153.91.

Embodiment 2: a synthetic route of a tetradentate cyclometalated platinum (II) complex phosphorescent luminescent material PtDMCz-2-ptz is as follows:

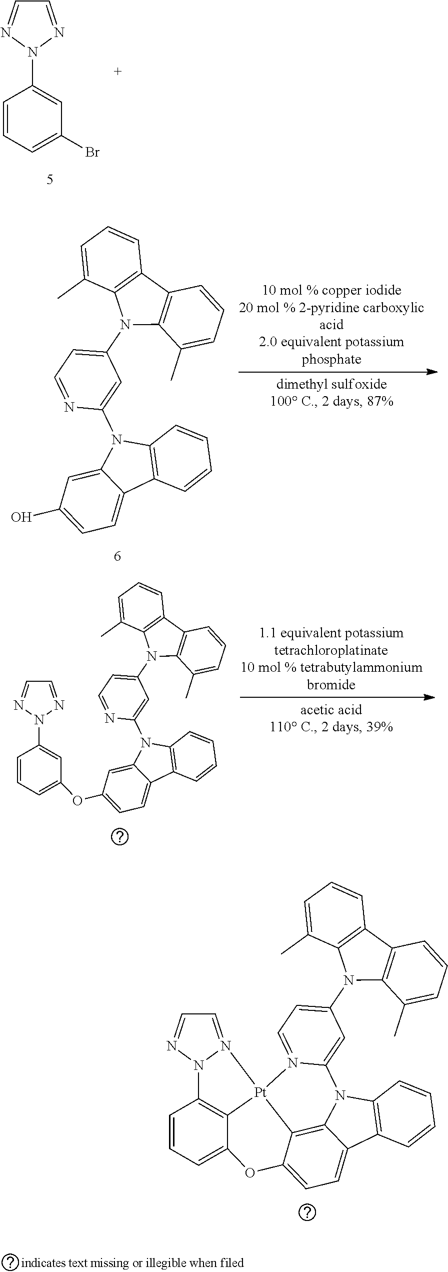

Synthesis of a ligand DMCz-2-ptz: a compound 6 (454 mg, 1.00 mmol, 1.0 equivalent), a compound 5 (246 mg, 1.10 mmol, 1.1 equivalent), copper iodide (19 mg, 0.10 mmol, 10 mol %), 2-pyridine carboxylic acid (25 mg, 0.20 mmol, 20 mol), and potassium phosphate (425 mg, 2.00 mmol, 2.0 equivalent) were sequentially added into a dry three-necked flask with a magnetic stirring rotor and a condenser tube, then vacuumizing nitrogen-replacement was carried out three times, and dimethyl sulfoxide (20 mL) was added under the protection of nitrogen. A mixture was stirred in a 100° C. oil bath to react for 2 days, and was cooled to the room temperature when the completion of the raw material reaction was monitored through thin-layer chromatography. Ethyl acetate was added, washing with water was carried out twice, a water layer was extracted twice with ethyl acetate, an organic phase was combined, and drying was carried out with anhydrous sodium sulfate. A solvent was removed through reduced pressure distillation, an obtained crude product was subjected to separation and purification through a silica gel chromatographic column, an eluent: petroleum ether/dichloromethane=10:1-3:1, the ligand DMCz-2-ptz was obtained, foamy solid was 518 mg, and a yield was 87%. ¹H NMR (500 MHz, CDCl₃): δ 2.01 (s, 6H), 7.02 (ddd, J=8.0, 3.0, 1.0 Hz, 1H), 7.07 (d, J=7.5 Hz, 2H), 7.10 (dd, J=8.5, 2.0 Hz, 1H), 7.18 (t, J=7.5 Hz, 2H), 7.32-7.38 (m, 2H), 7.39-7.43 (m, 2H), 7.63 (d, J=2.5 Hz, 1H), 7.66 (s, 2H), 7.71 (ddd, J=7.5, 2.5, 1.0 Hz, 1H), 7.78 (t, J=2.0 Hz, 1H), 7.82-7.84 (m, 2H), 7.96 (d, J=7.5 Hz, 2H), 8.06-8.08 (m, 2H), 8.78 (d, J=5.5 Hz, 1H). ¹³C NMR (125 MHz, CDCl₃): δ 19.61, 102.27, 109.23, 111.04, 113.47, 113.67, 114.74, 115.21, 117.41, 118.17, 119.93, 120.73, 121.08, 121.33, 121.70, 123.97, 124.59, 125.98, 129.32, 130.35, 135.46, 139.74, 140.36, 140.90, 149.76, 149.93, 152.12, 152.34, 153.15, 155.71, 158.51, 164.75.

Synthesis of PtDMCz-2-ptz: a ligand DMCz-2-ptz (200 mg, 0.34 mmol, 1.0 equivalent), potassium tetrachloroplatinate (153 mg, 0.37 mmol, 1.1 equivalent), and tetrabutylammonium bromide (10 mg, 0.03 mmol, 10 mol %) were sequentially added into a dry three-necked flask with a magnetic stirring rotor and a condenser tube, then vacuumizing nitrogen-replacement was carried out three times, acetic acid (20 mL) was added under the protection of nitrogen, and nitrogen bubbling was carried out for 25 minutes. A mixture was stirred in a 110° C. oil bath pan to react for 2 days, and was cooled to the room temperature. Afterwards, a solvent was removed through reduced pressure distillation, an obtained crude product was subjected to separation and purification through a silica gel chromatographic column, an eluent: petroleum ether/dichloromethane=10:1-3:1, PtDMCz-2-ptz was obtained, yellow solid was 102 mg, and a yield was 39%. ¹H NMR (500 MHz, DMSO-d₆): δ 2.15 (s, 6H), 7.16-7.23 (m, 5H), 7.30-7.37 (m, 4H), 7.57 (dd, J=8.0, 1.5 Hz, 1H), 7.60 (dd, J=6.0, 2.0 Hz, 1H), 7.90-7.91 (m, 1H), 7.97 (d, J=8.5 Hz, 1H), 8.11 (dd, J=8.5, 1.0 Hz, 2H), 8.15-8.17 (m, 1H), 8.50 (d, J=0.5 Hz, 1H), 8.54 (d, J=2.0 Hz, 1H), 8.79 (d, J=0.5 Hz, 1H), 9.44 (d, J=6.0 Hz, 1H).

Embodiment 3: a synthetic route of a tetradentate cyclometalated platinum (II) complex phosphorescent luminescent material PtDMCz-1-ptz is as follows:

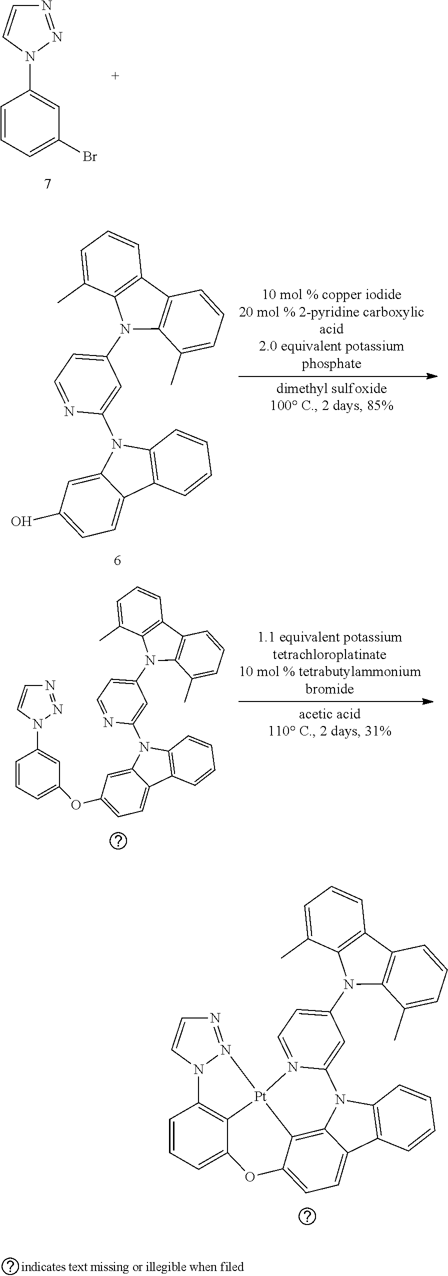

Synthesis of a ligand DMCz-1-ptz: a compound 6 (454 mg, 1.00 mmol, 1.0 equivalent), a compound 7 (246 mg, 1.10 mmol, 1.1 equivalent), copper iodide (19 mg, 0.10 mmol, 10 mol %), 2-pyridine carboxylic acid (25 mg, 0.20 mmol, 20 mol %), and potassium phosphate (425 mg, 2.00 mmol, 2.0 equivalent) were sequentially added into a dry three-necked flask with a magnetic stirring rotor and a condenser tube, then vacuumizing nitrogen-replacement was carried out three times, and dimethyl sulfoxide (20 mL) was added under the protection of nitrogen. A mixture was stirred in a 100° C. oil bath to react for 2 days, and was cooled to the room temperature when the completion of the raw material reaction was monitored through thin-layer chromatography. Ethyl acetate was added, washing with water was carried out twice, a water layer was extracted twice with ethyl acetate, an organic phase was combined, and drying was carried out with anhydrous sodium sulfate. A solvent was removed through reduced pressure distillation, an obtained crude product was subjected to separation and purification through a silica gel chromatographic column, an eluent: petroleum ether/dichloromethane=10:1-3:1, the ligand DMCz-1-ptz was obtained, foamy solid was 509 mg, and a yield was 85%. ¹H NMR (500 MHz, CDCl₃): δ 2.03 (s, 6H), 7.08-7.10 (m, 4H), 7.19 (t, J=2.5 Hz, 2H), 7.34 (t, J=2.5 Hz, 1H), 7.39-7.45 (m, 5H), 7.64 (d, J=2.0 Hz, 1H), 7.76 (d, J=1.0 Hz, 1H), 7.80-7.84 (m, 3H), 7.98 (d, J=7.5 Hz, 2H), 8.08 (t, J=7.5 Hz, 2H), 8.79 (d, J=5.0 Hz, 1H). ¹³C NMR (125 MHz, CDCl₃): δ 19.67, 102.73, 110.60, 111.03, 113.76, 114.82, 118.23, 118.26, 120.04, 120.83, 120.99, 121.12, 121.22, 121.43, 121.59, 121.82, 124.04, 124.27, 124.64, 126.17, 129.39, 130.83, 134.36, 138.11, 139.72, 140.32, 140.41, 149.81, 152.31, 153.17, 155.21, 159.04.

Synthesis of PtDMCz-1-ptz: a ligand DMCz-1-ptz (100 mg, 0.17 mmol, 1.0 equivalent), potassium tetrachloroplatinate (77 mg, 0.18 mmol, 1.1 equivalent), and tetrabutylammonium bromide (6 mg, 0.02 mmol, 10 mol %) were sequentially added into a dry three-necked flask with a magnetic stirring rotor and a condenser tube, then vacuumizing nitrogen-replacement was carried out three times, acetic acid (10 mL) was added under the protection of nitrogen, and nitrogen bubbling was carried out for 25 minutes. A mixture was stirred in a 110° C. oil bath pan to react for 2 days, and was cooled to the room temperature. Afterwards, a solvent was removed through reduced pressure distillation, an obtained crude product was subjected to separation and purification through a silica gel chromatographic column, an eluent: petroleum ether/dichloromethane=10:1-3:1, PtDMCz-1-ptz was obtained, yellow solid was 41 mg, and a yield was 31%. ¹H NMR (500 MHz, DMSO-d₆): δ 2.15 (s, 6H), 7.04-7.08 (m, 5H), 7.29-7.34 (m, 3H), 7.39 (t, J=8.0 Hz, 1H), 7.76 (d, J=7.5 Hz, 1H), 7.80-7.82 (m, 1H), 7.91 (dd, J=6.0, 2.0 Hz, 1H), 7.99 (d, J=8.5 Hz, 1H), 8.11 (dd, J=7.0, 1.0 Hz, 2H), 8.15-8.18 (m, 1H), 8.43 (dd, J=2.0, 1.0 Hz, 1H), 8.46 (d, J=0.5 Hz, 1H), 9.44 (d, J=1.5 Hz, 1H), 10.36 (d, J=6.0 Hz, 1H).

Embodiment 4: a synthetic route of a tetradentate cyclometalated platinum (II) complex phosphorescent luminescent material PtDMCz-piz is as follows:

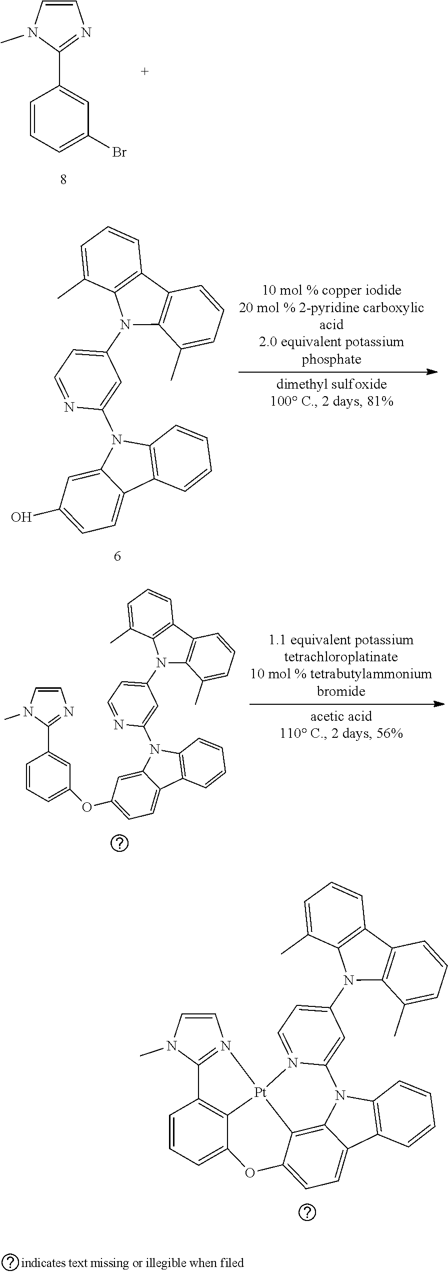

Synthesis of a ligand DMCz-piz: a compound 6 (363 mg, 0.80 mmol, 1.0 equivalent), a compound 8 (228 mg, 0.96 mmol, 1.1 equivalent), copper iodide (15 mg, 0.08 mmol, 10 mol %), 2-pyridine carboxylic acid (20 mg, 0.16 mmol, 20 moe), and potassium phosphate (340 mg, 1.60 mmol, 2.0 equivalent) were sequentially added into a dry three-necked flask with a magnetic stirring rotor and a condenser tube, then vacuumizing nitrogen-replacement was carried out three times, and dimethyl sulfoxide (16 mL) was added under the protection of nitrogen. A mixture was stirred in a 100° C. oil bath to react for 2 days, and was cooled to the room temperature when the completion of the raw material reaction was monitored through thin-layer chromatography. Ethyl acetate was added, washing with water was carried out twice, a water layer was extracted twice with ethyl acetate, an organic phase was combined, and drying was carried out with anhydrous sodium sulfate. A solvent was removed through reduced pressure distillation, an obtained crude product was subjected to separation and purification through a silica gel chromatographic column, an eluent: petroleum ether/dichloromethane=10:1-3:1, the ligand DMCz-piz was obtained, foamy solid was 268 mg, and a yield was 81%. ¹H NMR (500 MHz, CDCl₃): δ 1.97 (s, 6H), 3.58 (s, 3H), 6.87 (s, 1H), 7.00 (dd, J=8.5, 2.0 Hz, 1H), 7.04 (d, J=7.0 Hz, 2H), 7.06-7.08 (m, 1H), 7.10-7.13 (m, 3H), 7.22 (s, 1H), 7.24-7.27 (m, 1H), 7.32 (dd, J=8.5, 1.5 Hz, 1H), 7.35 (d, J=5.0 Hz, 2H), 7.37 (dd, J=5.0, 1.5 Hz, 1H), 7.57 (d, J=2.0 Hz, 1H), 7.71 (d, J=8.5 Hz, 1H), 7.75 (d, J=1.5 Hz, 1H), 7.91 (d, J=7.5 Hz, 2H), 7.99 (dd, J=7.5, 1.5 Hz, 2H), 8.72 (d, J=5.0 Hz, 1H). ¹³C NMR (125 MHz, CDCl₃): δ 19.64, 34.40, 102.37, 110.88, 113.53, 118.14, 118.50, 118.72, 119.89, 120.65, 120.74, 120.98, 121.13, 121.18, 121.65, 122.46, 123.36, 123.94, 124.35, 124.58, 125.89, 128.18, 129.36, 129.87, 131.97, 139.63, 140.36, 140.37, 149.75, 152.31, 153.07, 156.02, 157.77.

Synthesis of PtDMCz-piz: a ligand DMCz-piz (94 mg, 0.15 mmol, 1.0 equivalent), potassium tetrachloroplatinate (70 mg, 0.17 mmol, 1.1 equivalent), and tetrabutylammonium bromide (6 mg, 0.02 mmol, 10 mol %) were sequentially added into a dry three-necked flask with a magnetic stirring rotor and a condenser tube, then vacuumizing nitrogen-replacement was carried out three times, acetic acid (10 mL) was added under the protection of nitrogen, and nitrogen bubbling was carried out for 25 minutes. A mixture was stirred in a 110° C. oil bath pan to react for 2 days, and was cooled to the room temperature. Afterwards, a solvent was removed through reduced pressure distillation, an obtained crude product was subjected to separation and purification through a silica gel chromatographic column, an eluent: petroleum ether/dichloromethane=10:1-3:1, PtDMCz-piz was obtained, yellow solid was 69 mg, and a yield was 56%. ¹H NMR (500 MHz, DMSO-d₆): δ 2.14 (s, 6H), 4.13 (s, 3H), 7.08 (dd, J=8.0 Hz, 1H), 7.17-7.23 (m, 4H), 7.24 (d, J=8.5 Hz, 1H), 7.27 (t, J=7.5 Hz, 1H), 7.32-7.34 (m, 2H), 7.59 (d, J=1.0 Hz, 1H), 7.61 (dd, J=6.5, 2.0 Hz, 1H), 7.63-7.65 (m, 2H), 7.86 (d, J=8.0 Hz, 1H), 8.09-8.12 (m, 4H), 8.46 (d, J=2.0 Hz, 1H), 9.42 (d, J=6.0 Hz, 1H).

Embodiment 5: a synthetic route of a tetradentate cyclometalated platinum (II) complex phosphorescent luminescent material PtDMCz-ppy is as follows:

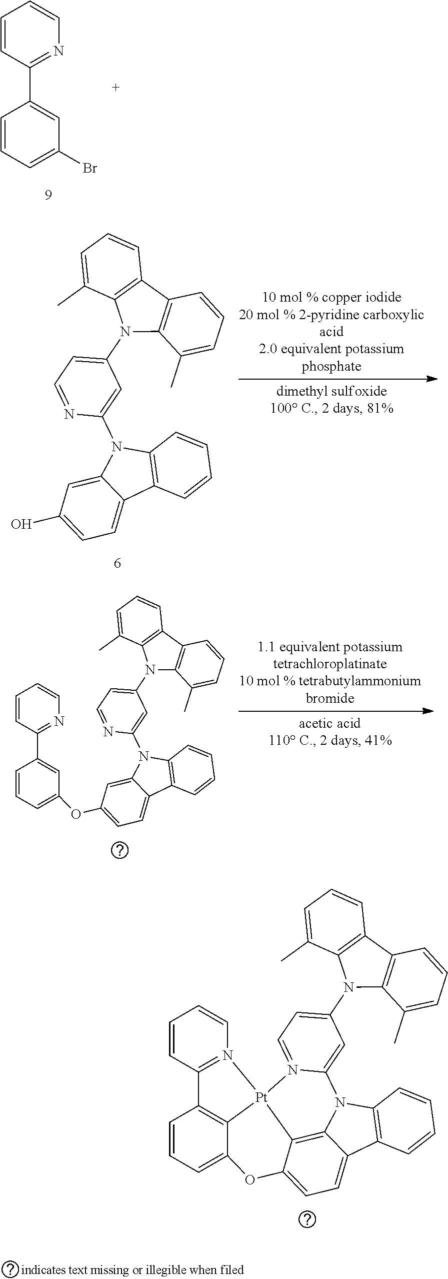

Synthesis of a ligand DMCz-ppy: a compound 6 (454 mg, 1.00 mmol, 1.0 equivalent), a compound 9 (258 mg, 1.10 mmol, 1.1 equivalent), copper iodide (19 mg, 0.10 mmol, 10 mol %), 2-pyridine carboxylic acid (25 mg, 0.20 mmol, 20 mol %), and potassium phosphate (425 mg, 2.00 mmol, 2.0 equivalent) were sequentially added into a dry three-necked flask with a magnetic stirring rotor and a condenser tube, then vacuumizing nitrogen-replacement was carried out three times, and dimethyl sulfoxide (20 mL) was added under the protection of nitrogen. A mixture was stirred in a 100° C. oil bath to react for 2 days, and was cooled to the room temperature when the completion of the raw material reaction was monitored through thin-layer chromatography. Ethyl acetate was added, washing with water was carried out twice, a water layer was extracted twice with ethyl acetate, an organic phase was combined, and drying was carried out with anhydrous sodium sulfate. A solvent was removed through reduced pressure distillation, an obtained crude product was subjected to separation and purification through a silica gel chromatographic column, an eluent: petroleum ether/dichloromethane=10:1-3:1, the ligand DMCz-ppy was obtained, foamy solid was 490 mg, and a yield was 81%. ¹H NMR (500 MHz, CDCl₃): δ 1.91 (s, 6H), 6.99 (d, J=7.0 Hz, 2H), 7.03 (d, J=2.5 Hz, 1H), 7.05 (d, J=1.5 Hz, 1H), 7.07-7.14 (m, 3H), 7.24-7.27 (m, 1H), 7.28 (dd, J=5.0, 1.5 Hz, 1H), 7.30-7.34 (m, 2H), 7.46 (d, J=7.5 Hz, 1H), 7.52 (d, J=2.0 Hz, 1H), 7.57 (t, J=6.5 Hz, 2H), 7.65 (t, J=2.0 Hz, 1H), 7.75-7.78 (m, 2H), 7.87 (d, J=7.5 Hz, 2H), 7.98 (d, J=8.0 Hz, 2H), 8.48 (d, J=4.0 Hz, 1H), 8.68 (d, J=5.0 Hz, 1H).

Synthesis of PtDMCz-ppy: a ligand DMCz-ppy (100 mg, 0.16 mmol, 1.0 equivalent), potassium tetrachloroplatinate (75 mg, 0.18 mmol, 1.1 equivalent), and tetrabutylammonium bromide (6 mg, 0.02 mmol, 10 mol %) were sequentially added into a dry three-necked flask with a magnetic stirring rotor and a condenser tube, then vacuumizing nitrogen-replacement was carried out three times, acetic acid (10 mL) was added under the protection of nitrogen, and nitrogen bubbling was carried out for 25 minutes. A mixture was stirred in a 110° C. oil bath pan to react for 2 days, and was cooled to the room temperature. Afterwards, a solvent was removed through reduced pressure distillation, an obtained crude product was subjected to separation and purification through a silica gel chromatographic column, an eluent: petroleum ether/dichloromethane=10:1-3:1, PtDMCz-ppy was obtained, yellow solid was 54 mg, and a yield was 41%. ¹H NMR (500 MHz, CDCl₃): δ 2.10 (s, 6H), 7.08 (d, J=7.0 Hz, 2H), 7.15 (d, J=7.5 Hz, 2H), 7.18 (d, J=2.0 Hz, 1H), 7.20-7.26 (m, 4H), 7.32-7.36 (m, 2H), 7.55 (dd, J=5.0, 3.0 Hz, 1H), 7.68 (d, J=8.0 Hz, 1H), 7.73 (d, J=8.0 Hz, 1H), 7.87-7.90 (m, 1H), 7.93 (d, J=7.5 Hz, 4H), 8.36 (d, J=1.5 Hz, 1H), 8.64 (d, J=5.5 Hz, 1H), 9.11 (d, J=6.0 Hz, 1H).

Embodiment 6: a synthetic route of a tetradentate cyclometalated platinum (II) complex phosphorescent luminescent material PtDMCz-NHC is as follows:

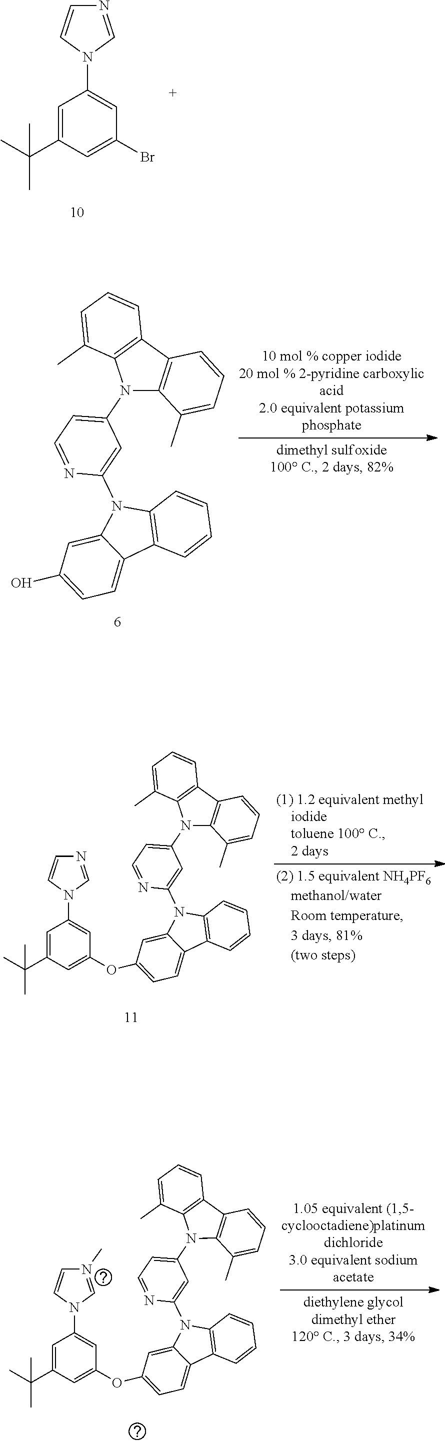

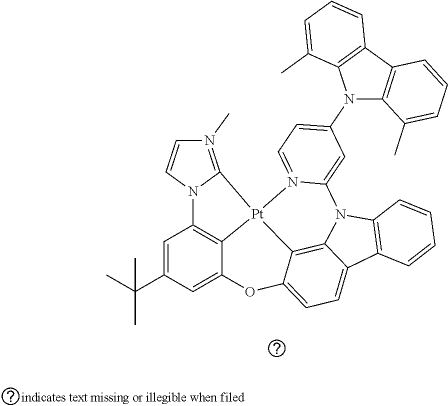

Synthesis of an intermediate 11: a compound 6 (676 mg, 1.49 mmol, 1.0 equivalent), a compound 10 (500 mg, 1.79 mmol, 1.2 equivalent), copper iodide (29 mg, 0.15 mmol, 10 mol %), 2-pyridine carboxylic acid (37 mg, 0.30 mmol, 20 mol %), and potassium phosphate (633 mg, 2.98 mmol, 2.0 equivalent) were sequentially added into a dry three-necked flask with a magnetic stirring rotor and a condenser tube, then vacuumizing nitrogen-replacement was carried out three times, and dimethyl sulfoxide (20 mL) was added under the protection of nitrogen. A mixture was stirred in a 100° C. oil bath to react for 2 days, and was cooled to the room temperature when the completion of the raw material reaction was monitored through thin-layer chromatography. Ethyl acetate was added, washing with water was carried out twice, a water layer was extracted twice with ethyl acetate, an organic phase was combined, and drying was carried out with anhydrous sodium sulfate. A solvent was removed through reduced pressure distillation, an obtained crude product was subjected to separation and purification through a silica gel chromatographic column, an eluent: petroleum ether/dichloromethane=10:1-3:1, the intermediate 11 was obtained, foamy solid was 801 mg, and a yield was 82%. ¹H NMR (500 MHz, CDCl₃): δ 1.28 (s, 9H), 2.05 (s, 6H), 6.39 (t, J=7.5 Hz, 1H), 6.87 (s, 1H), 7.07 (d, J=2.0 Hz, 1H), 7.09 (d, J=1.5 Hz, 1H), 7.10-7.12 (m, 2H), 7.14 (s, 1H), 7.20 (t, J=7.5 Hz, 2H), 7.23-7.27 (m, 1H), 7.32-7.35 (m, 1H), 7.40 (dd, J=8.5, 2.0 Hz, 1H), 7.42-7.44 (m, 2H), 7.69 (d, J=2.0 Hz, 1H), 7.79 (d, J=8.5 Hz, 1H), 7.83 (d, J=2.0 Hz, 1H), 7.99 (d, J=2.5 Hz, 2H), 8.08 (t, J=6.5 Hz, 2H), 8.78 (d, J=5.0 Hz, 1H).

Synthesis of a ligand DMCz-NHC: an intermediate 11 (800 mg, 1.23 mmol, 1.0 equivalent) was added into a dry sealed tube with a magnetic stirring rotor, then vacuumizing nitrogen-replacement was carried out three times, and toluene (40 mL) and methyl iodide (210 mg, 1.48 mmol, 1.2 equivalent) were added under the protection of nitrogen. A mixture was stirred in a 100° C. oil bath pan to react for 2 days and cooled to the room temperature, filtering was carried out, a filtrate was eluted with petroleum ether, drying was carried out, obtained grey solid was added into methanol/water (40 mL/4 mL), after stirring to be dissolved, ammonium hexafluorophosphate (302 mg, 1.85 mmol, 1.5 equivalent) was added, and stirring was carried out at the room temperature to react for 3 days. Water was added, most methanol was removed through reduced pressure distillation, filtering was carried out, washing was carried out with water followed by petroleum ether, drying was carried out, a ligand DMCz-NHC was obtained, grey solid was 810 mg, and a yield was 81%. ¹H NMR (500 MHz, DMSO-d₆): δ 1.23 (s, 9H), 2.15 (s, 6H), 3.32 (s, 3H), 6.93 (t, J=2.5 Hz, 1H), 7.01 (dd, J=8.0, 0.5 Hz, 1H), 7.18-7.27 (m, 6H), 7.33-7.37 (m, 2H), 7.54 (dd, J=7.5, 0.5 Hz, 1H), 7.60 (dd, J=6.0, 2.0 Hz, 1H), 7.88-7.91 (m, 2H), 8.09-8.11 (m, 2H), 8.13-8.14 (m, 1H), 8.31 (d, J=2.0 Hz, 1H), 8.50 (d, J=2.0 Hz, 1H), 8.93 (d, J=2.5 Hz, 1H), 9.42 (d, J=6.5 Hz, 1H), 11.94 (s, 1H).

Synthesis of PtDMCz-NHC: a ligand DMCz-NHC (200 mg, 0.25 mmol, 1.0 equivalent), (1,5-cyclooctadiene)platinum dichloride (97 mg, 0.26 mmol, 1.05 equivalent) and sodium acetate (61 mg, 0.74 mmol, 3.0 equivalent) were sequentially added into a sealed tube with a magnetic stirring rotor, then vacuumizing nitrogen-replacement was carried out three times, diethylene glycol dimethyl ether (20 mL) was added under the protection of nitrogen, and nitrogen was blown for 30 minutes. A mixture was stirred in a 120° C. oil bath pan under a dark condition to react for 3 days, and was cooled to the room temperature, distilled water was added for quenching reaction, and a solvent was removed through reduced pressure distillation. An obtained crude product was subjected to separation and purification through a silica gel chromatographic column, an eluent: petroleum ether/dichloromethane=10:1-3:1, PtDMCz-NHC was obtained, yellow solid was 71 mg, and a yield was 34%. ¹H NMR (500 MHz, DMSO-d₆): δ 1.43 (s, 9H), 2.15 (s, 6H), 4.11 (s, 3H), 6.99 (d, J=2.5 Hz, 1H), 7.25-7.30 (m, 4H), 7.37-7.40 (m, 3H), 7.42 (d, J=2.0 Hz, 1H), 7.54 (d, J=2.5 Hz, 1H), 7.58 (dd, J=6.0, 1.5 Hz, 1H), 7.93-7.96 (m, 2H), 8.15-8.18 (m, 3H), 8.30 (d, J=2.0 Hz, 1H), 8.43 (d, J=2.5 Hz, 1H), 9.75 (d, J=6.0 Hz, 1H).

Embodiment 7: a synthetic route of a tetradentate cyclometalated platinum (II) complex phosphorescent luminescent material PtDMCz-Ph-NHC is as follows:

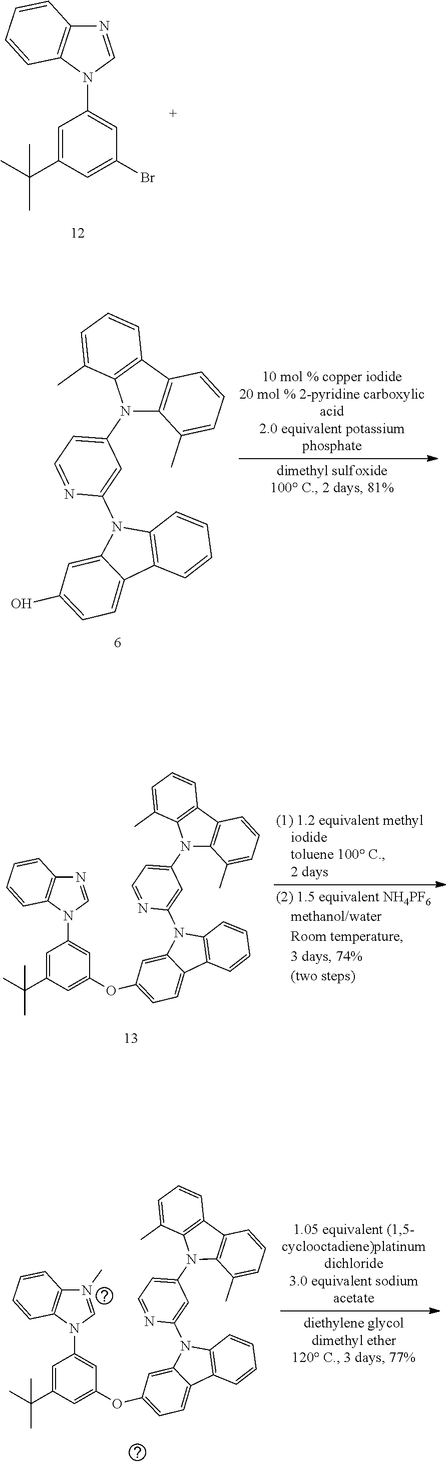

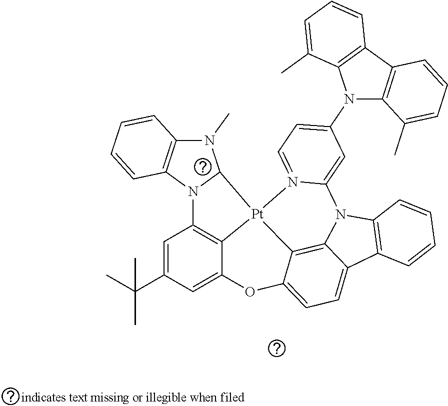

Synthesis of an intermediate 13: a compound 6 (1.80 g, 3.97 mmol, 1.0 equivalent), a compound 12 (1.44 g, 4.37 mmol, 1.1 equivalent), copper iodide (76 mg, 0.40 mmol, 10 mol %), 2-pyridine carboxylic acid (97 mg, 0.79 mmol, 20 mol %), and potassium phosphate (1.69 g, 7.94 mmol, 2.0 equivalent) were sequentially added into a dry three-necked flask with a magnetic stirring rotor and a condenser tube, then vacuumizing nitrogen-replacement was carried out three times, and dimethyl sulfoxide (60 mL) was added under the protection of nitrogen. A mixture was stirred in a 100° ° C. oil bath to react for 2 days, and was cooled to the room temperature when the completion of the raw material reaction was monitored through thin-layer chromatography. Ethyl acetate was added, washing with water was carried out twice, a water layer was extracted twice with ethyl acetate, an organic phase was combined, and drying was carried out with anhydrous sodium sulfate. A solvent was removed through reduced pressure distillation, an obtained crude product was subjected to separation and purification through a silica gel chromatographic column, an eluent: petroleum ether/dichloromethane=10:1-3:1, the intermediate 13 was obtained, foamy solid was 2.25 g, and a yield was 81%. ¹H NMR (500 MHz, CDCl₃): δ 1.32 (s, 9H), 2.06 (s, 6H), 7.00 (s, 1H), 7.09-7.12 (m, 3H), 7.17-7.21 (m, 4H), 7.26-7.36 (m, 6H), 7.40 (td, J=8.5, 1.5 Hz, 1H), 7.43 (dd, J=5.0, 1.5 Hz, 1H), 7.75-7.77 (m, 2H), 7.85 (d, J=1.0 Hz, 1H), 7.98 (d, J=7.5 Hz, 2H), 8.07 (d, J=7.0 Hz, 1H), 8.09 (d, J=8.5 Hz, 1H), 8.79 (d, J=5.0 Hz, 1H).

Synthesis of a ligand DMCz-Ph-NHC: an intermediate 13 (400 mg, 0.57 mmol, 1.0 equivalent) was added into a dry sealed tube with a magnetic stirring rotor, then vacuumizing nitrogen-replacement was carried out three times, and toluene (40 mL) and methyl iodide (97 mg, 0.68 mmol, 1.2 equivalent) were added under the protection of nitrogen. A mixture was stirred in a 100° C. oil bath pan to react for 2 days and cooled to the room temperature, filtering was carried out, a filtrate was eluted with petroleum ether, drying was carried out, obtained grey solid was added into methanol/water (40 mL/4 mL), after stirring to be dissolved, ammonium hexafluorophosphate (140 mg, 0.86 mmol, 1.5 equivalent) was added, and stirring was carried out at the room temperature to react for 3 days. Water was added, most methanol was removed through reduced pressure distillation, filtering was carried out, washing was carried out with water followed by petroleum ether, drying was carried out, a ligand DMCz-Ph-NHC was obtained, grey solid was 364 mg, and a yield was 74%. ¹H NMR (500 MHz, CDCl₃): δ 1.36 (s, 9H), 2.07 (s, 6H), 4.20 (s, 3H), 7.03 (t, J=2.5 Hz, 1H), 7.11-7.14 (m, 3H), 7.19 (t, J=2.5 Hz, 2H), 7.30-7.33 (m, 1H), 7.37-7.40 (m, 2H), 7.45-7.47 (m, 2H), 7.54-7.58 (m, 1H), 7.63-7.66 (m, 2H), 7.70-7.75 (m, 3H), 7.83 (d, J=1.5 Hz, 1H), 7.97 (d, J=7.5 Hz, 2H), 8.05 (d, J=7.5 Hz, 1H), 8.11 (d, J=8.5 Hz, 1H), 8.81 (d, J=5.0 Hz, 1H), 9.34 (s, 1H). ¹³C NMR (125 MHz, CDCl₃): δ 19.71, 30.95, 33.77, 35.49, 102.95, 110.73, 110.84, 113.22, 113.30, 113.75, 116.76, 117.77, 118.26, 120.15, 120.90, 120.99, 121.13, 121.35, 121.64, 121.82, 124.17, 124.23, 124.66, 126.19, 127.70, 127.88, 129.42, 131.17, 132.03, 133.33, 139.60, 140.43, 140.45, 140.86, 149.98, 152.22, 153.21, 154.70, 157.05, 159.15.

Synthesis of PtDMCz-Ph-NHC: a ligand DMCz-Ph-NHC (100 mg, 0.12 mmol, 1.0 equivalent), (1,5-cyclooctadiene)platinum dichloride (49 mg, 0.13 mmol, 1.05 equivalent) and sodium acetate (48 mg, 0.35 mmol, 3.0 equivalent) were sequentially added into a sealed tube with a magnetic stirring rotor, then vacuumizing nitrogen-replacement was carried out three times, diethylene glycol dimethyl ether (10 mL) was added under the protection of nitrogen, and nitrogen was blown for 30 minutes. A mixture was stirred in a 120° C. oil bath pan under a dark condition to react for 3 days, and was cooled to the room temperature, distilled water was added for quenching reaction, and a solvent was removed through reduced pressure distillation. An obtained crude product was subjected to separation and purification through a silica gel chromatographic column, an eluent: petroleum ether/dichloromethane=10:1-3:1, PtDMCz-Ph-NHC was obtained, yellow solid was 82 mg, and a yield was 77%. ¹H NMR (500 MHz, DMSO-d₆): δ 1.47 (s, 9H), 2.11 (s, 6H), 4.14 (s, 3H), 7.03 (d, J=1.5 Hz, 1H), 7.18-7.22 (m, 4H), 7.32-7.35 (m, 3H), 7.51-7.52 (m, 1H), 7.54 (t, J=7.5 Hz, 2H), 7.64 (d, J=1.5 Hz, 1H), 7.82 (d, J=8.0 Hz, 1H), 7.92 (d, J=8.0 Hz, 2H), 8.10-8.14 (m, 3H), 8.30 (d, J=8.0 Hz, 1H), 8.48 (d, J=2.0 Hz, 1H), 9.77 (d, J=6.0 Hz, 1H).

Embodiment 8: a synthetic route of a tetradentate cyclometalated platinum (II) complex phosphorescent luminescent material PtDMCz-ppz is as follows:

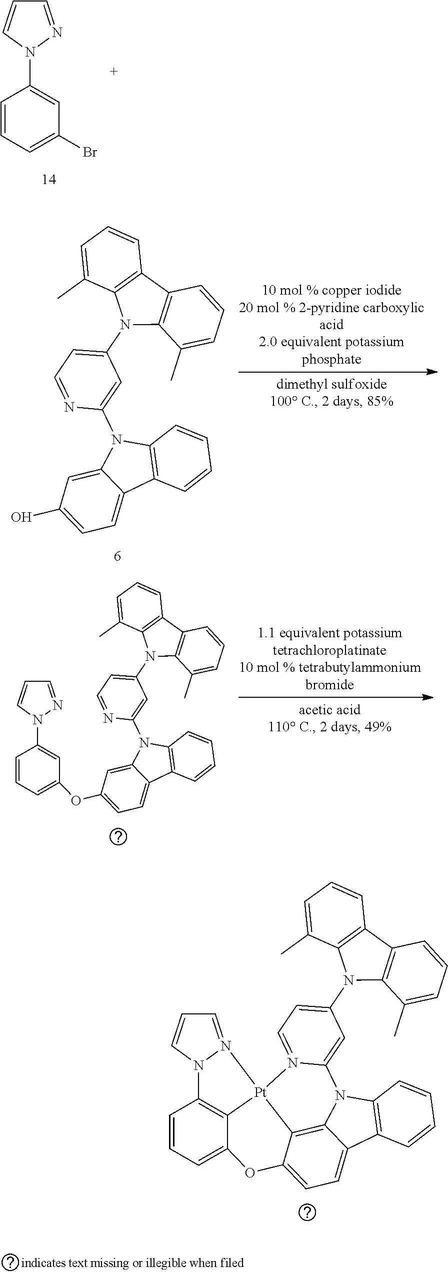

Synthesis of a ligand DMCz-ppz: a compound 6 (454 mg, 1.00 mmol, 1.0 equivalent), a compound 14 (245 mg, 1.10 mmol, 1.1 equivalent), copper iodide (19 mg, 0.10 mmol, 10 mol %), 2-pyridine carboxylic acid (25 mg, 0.20 mmol, 20 mol %), and potassium phosphate (425 mg, 2.00 mmol, 2.0 equivalent) were sequentially added into a dry three-necked flask with a magnetic stirring rotor and a condenser tube, then vacuumizing nitrogen-replacement was carried out three times, and dimethyl sulfoxide (20 mL) was added under the protection of nitrogen. A mixture was stirred in a 100° C. oil bath to react for 2 days, and was cooled to the room temperature when the completion of the raw material reaction was monitored through thin-layer chromatography. Ethyl acetate was added, washing with water was carried out twice, a water layer was extracted twice with ethyl acetate, an organic phase was combined, and drying was carried out with anhydrous sodium sulfate. A solvent was removed through reduced pressure distillation, an obtained crude product was subjected to separation and purification through a silica gel chromatographic column, an eluent: petroleum ether/dichloromethane=10:1-3:1, the ligand DMCz-ppz was obtained, foamy solid was 506 mg, and a yield was 85%. ¹H NMR (500 MHz, CDCl₃): δ 2.02 (s, 6H), 6.37 (dd, J=2.5, 2.0 Hz, 1H), 6.93-6.95 (m, 1H), 7.07-7.09 (m, 3H), 7.18 (d, J=7.5 Hz, 2H), 7.30-7.35 (m, 4H), 7.38-7.40 (m, 1H), 7.41-7.43 (m, 2H), 7.62 (t, J=1.5 Hz, 1H), 7.78-7.82 (m, 3H), 7.97 (d, J=8.0 Hz, 2H), 8.06 (d, J=8.0 Hz, 2H), 8.78 (dd, J=5.5, 0.5 Hz, 1H). ¹³C NMR (125 MHz, CDCl₃): δ 19.65, 102.38, 107.65, 109.49, 110.99, 113.51, 113.65, 116.22, 118.20, 119.95, 120.76, 120.82, 121.06, 121.14, 121.29, 121.72, 123.98, 124.36, 124.65, 125.98, 126.66, 129.36, 130.43, 139.71, 140.33, 140.42, 141.09, 141.40, 149.77, 152.35, 153.15, 155.81, 158.68.

Synthesis of PtDMCz-ppz: a ligand DMCz-ppz (100 mg, 0.17 mmol, 1.0 equivalent), potassium tetrachloroplatinate (77 mg, 0.18 mmol, 1.1 equivalent), and tetrabutylammonium bromide (6 mg, 0.02 mmol, 10 mol %) were sequentially added into a dry three-necked flask with a magnetic stirring rotor and a condenser tube, then vacuumizing nitrogen-replacement was carried out three times, acetic acid (15 mL) was added under the protection of nitrogen, and nitrogen bubbling was carried out for 25 minutes. A mixture was stirred in a 110° C. oil bath pan to react for 2 days, and was cooled to the room temperature. Afterwards, a solvent was removed through reduced pressure distillation, an obtained crude product was subjected to separation and purification through a silica gel chromatographic column, an eluent: petroleum ether/dichloromethane=10:1-3:1, PtDMCz-ppz was obtained, yellow solid was 65 mg, and a yield was 49%. ¹H NMR (500 MHz, DMSO-d₆): δ 2.10 (s, 6H), 6.63 (t, J=2.5 Hz, 1H), 7.05-7.11 (m, 4H), 7.15-7.18 (m, 4H), 7.22-7.26 (m, 2H), 7.33 (d, J=8.5 Hz, 1H), 7.66 (d, J=8.5 Hz, 1H), 7.73 (d, J=8.5 Hz, 1H), 7.81 (d, J=2.0 Hz, 1H), 7.90-7.94 (m, 3H), 8.05 (d, J=2.5 Hz, 1H), 8.36 (d, J=2.0 Hz, 1H), 9.33 (d, J=6.5 Hz, 1H).

### Description of Electrochemical and Photophysical Testing and Theoretical Calculation:

An absorption spectrum is measured on an Agilent 8453 ultraviolet-visible light spectrometer, and steady-state emission experiments and lifetime measurement are conducted using a Horiba Jobin Yvon FluoroLog-3 spectrometer. A low temperature (77 K) emission spectrum and lifetime are measured in a 2-methyltetrahydrofuran solution cooled with liquid nitrogen. A Pd (II) complex is theoretically calculated using a Gaussian 09 software package, the geometric structure of ground state (S₀) molecules is optimized using the density functional theory (DFT), B3LYP functional is used for DFT calculation, with C, H, O, and N atoms using a 6-31G(d) basis set and Pd atoms using an LANL2DZ basis set. A photostability test condition is luminescence intensity attenuation of 5% luminescent material: polystyrene thin film under excitation of 375 nm ultraviolet (light intensity: 500 W/m2).

Experiment Data and Analysis: In order to prove the necessity of introducing substituents at 1-, 8-position of carbazole, we made further comparison of Pt-DMCz with Pt1 (J. Pgys. Chem. Lett, 2018, 9, 2285), PtON1 (Inorg. Chem., 2017, 56, 8244), PtON1-Ph (Inorg. Chem., 2017, 56, 8244) and PtON1-Cz (Inorg. Chem., 2017, 56, 8244) that had been reported in literatures, their structural formulas are as shown below, and their photophysical property data are as shown in Table 1 below.

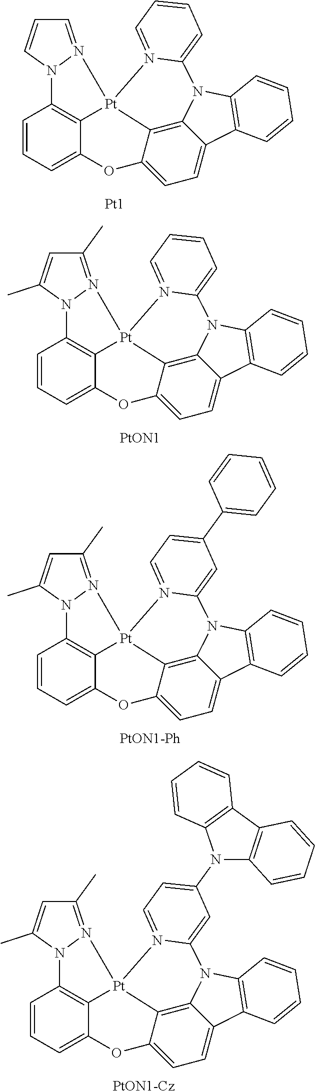

TABLE 1
List of photophysical property data of tetradentate cyclometalated
platinum (II) complex luminescent material

| | | Emission spectrum at | | | | |
|---|---|---|---|---|---|---|
| | | room temperature | | | | |
| | | (Dichloromethane | | | | |
| | calc. | solution) | | | | |
| Com- | ΔE_{ST} | λ | τ^{obs} | Φ_{PL} | kᵣ^{obs} | |
| plexes | [eV]^{a} | [nm] | [μs] | [%] | [10⁵ s⁻¹] | References |
| Pt1 | 0.26 | 449 | 2.4 | 39 | 1.63 | J. Pgys. Chem. |
| | | | | | | Lett, 2018, 9, |
| | | | | | | 2285 |
| PtON1 | 0.171 | 454, 478 | 3.3 | 71 | 2.15 | Inorg. Chem., |
| | | | | | | 2017, 56, 8244 |
| PtON1-Ph | — | 546 | 0.8 | 19 | 2.38 | Inorg. Chem., |
| | | | | | | 2017, 56, 8244 |
| PtON1-Cz | 0.135 | 496 | 1.8 | 53 | 2.94 | Inorg. Chem., |
| | | | | | | 2017, 56, 8244 |
| Pt-DMCz | 0.137 | 507 | 1.1 | 88 | 8.00 | The present |
| | | | | | | invention |

Note:
^{a}In order to facilitate comparison, the theoretical calculation values based on the optimized S₀ state at the B3LYP/6-31G(d)/LANL2DZ level are taken.
λ is an emission wavelength; τ^{obs} is an excited-state lifetime of the material; Φ_{PL} is phosphorescent quantum efficiency; and kᵣ^{obs} is a radiation rate, wherein kᵣ^{obs} = Φ_{PL}/τ^{obs}.

TABLE 2
Theoretical calculation experiment data of tetradentate cyclometalated platinum (II)
complex luminescent material

| | | | LUMO | HOMO | Gap | Dihedral |
|---|---|---|---|---|---|---|
| Complexes | Front view | Side view | eV | eV | eV | angle (°) |
| 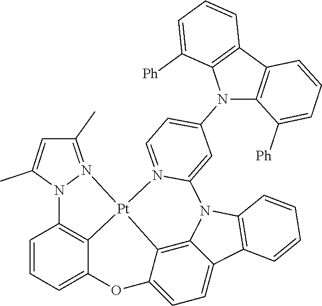 | 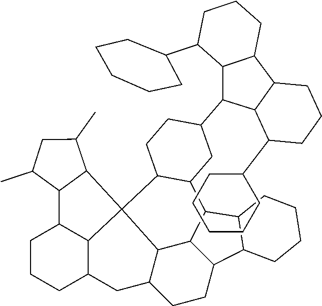 [SMILES: CC1CC(C)C2C1C1CCCC3CC4CCC5C6CCCCC6C6C7CC(C8C9C(C%10CCCCC%10)CCCC9C9CCCC(C%10CCCCC%10)C98)CCC7C2(C31)C4C56] | 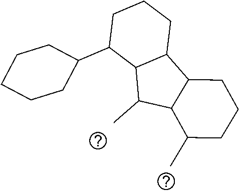 [SMILES: CC1CCCC2C3CCCC(C4CCCCC4)C3C(C)C12] | −1.44 | −4.77 | 3.33 | 67.5 |
| 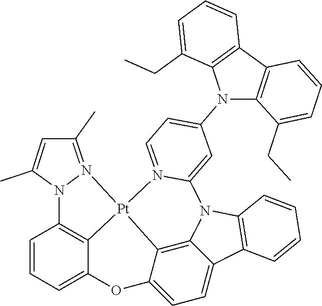 | 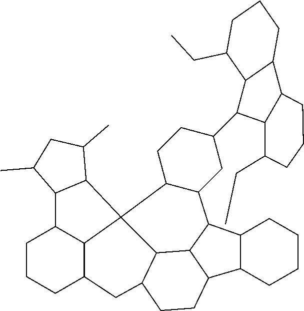 [SMILES: CCC1CCCC2C3CCCC(CC)C3C(C3CCC4C(C3)C3C5CCCCC5C5CCC6CC7CCCC8C9C(C)CC(C)C9C4(C78)C6C53)C12] | 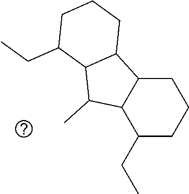 [SMILES: CCC1CCCC2C3CCCC(CC)C3C(C)C12] | −1.68 | −4.86 | 3.18 | 85.3 |
| 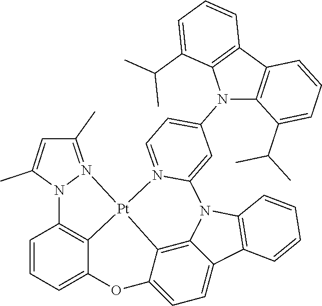 | 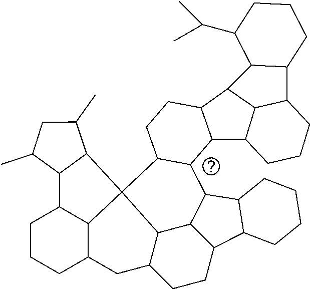 [SMILES: CC(C)C1CCCC2C3CCCC4C3C(C3CCC5C(C43)C3C4CCCCC4C4CCC6CC7CCCC8C9C(C)CC(C)C9C5(C78)C6C43)C12] | 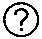 | −1.55 | −4.78 | 3.23 | 86.4 |
| 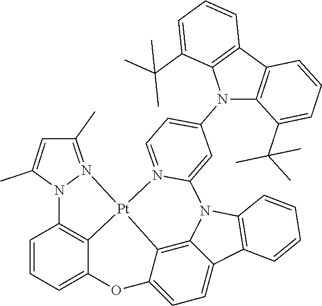 | 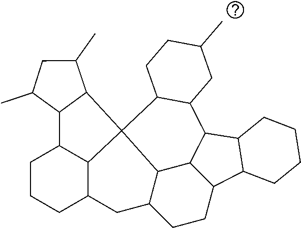 [SMILES: CC1CCC2C(C1)C1C3CCCCC3C3CCC4CC5CCCC6C7C(C)CC(C)C7C2(C56)C4C31] | 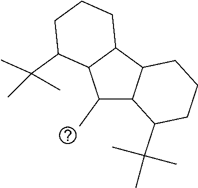 [SMILES: CC1C2C(CCCC2C(C)(C)C)C2CCCC(C(C)(C)C)C12] | −1.49 | −4.76 | 3.27 | 87.1 |
| 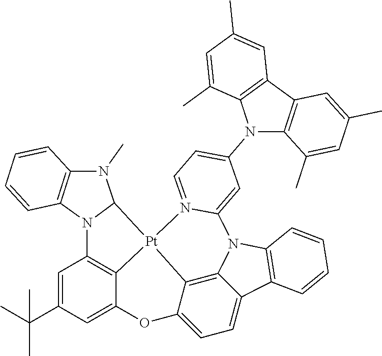 | 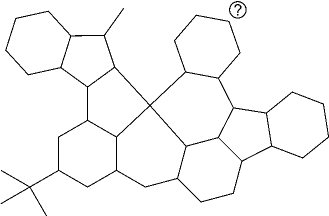 [SMILES: CC1C2CCCCC2C2C3CC(C(C)(C)C)CC4CC5CCC6C7CCCCC7C7C8CCCCC8C(C43)(C5C67)C12] | 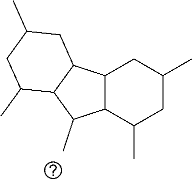 | −1.65 | −4.78 | 3.13 | 87.2 |
| 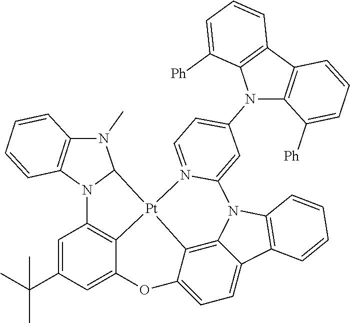 | 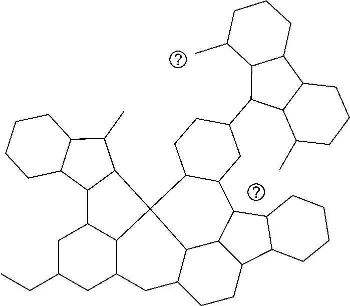 [SMILES: CCC1CC2CC3CCC4C5CCCCC5C5C6CC(C7C8C(C)CCCC8C8CCCC(C)C87)CCC6C6(C2C(C1)C1C2CCCCC2C(C)C16)C3C45] | 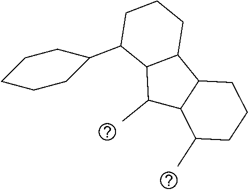 [SMILES: CC1CCCC2C3CCCC(C4CCCCC4)C3C(C)C12] | −1.48 | −4.73 | 3.25 | 66.5 |
| 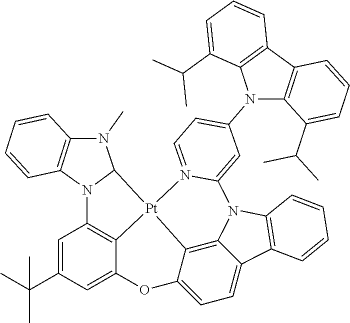 | 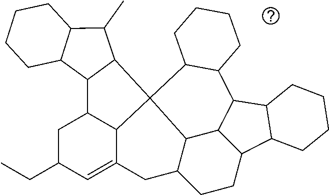 [SMILES: CCC1C=C2CC3CCC4C5CCCCC5C5C6CCCCC6C6(C2C(C1)C1C2CCCCC2C(C)C16)C3C45] | 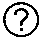 | −1.59 | −4.75 | 3.16 | 84.8 |
| 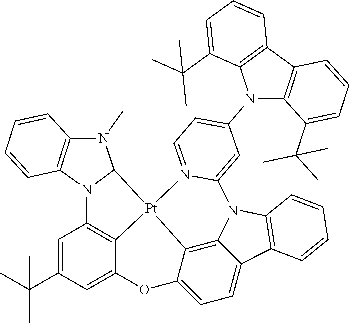 | 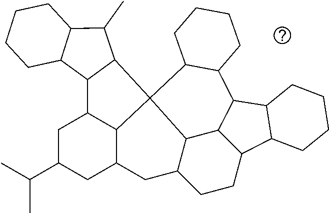 [SMILES: CC(C)C1CC2CC3CCC4C5CCCCC5C5C6CCCCC6C6(C2C(C1)C1C2CCCCC2C(C)C16)C3C45] | 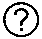 | −1.55 | -4.71 | 3.16 | 89.0 |
| 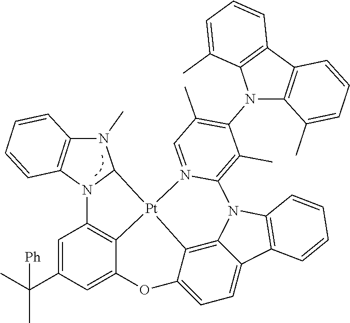 | 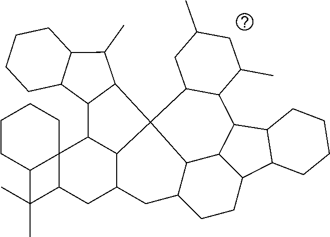 [SMILES: CC1CC(C)C2C3C4CCCCC4C4CCC5CC6CC7C(C)(C)C8CCCCC87C7C8C9CCCCC9C(C)C8C(C2C1)(C5C43)C67] | 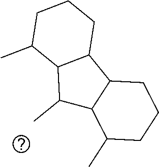 [SMILES: CC1CCCC2C3CCCC(C)C3C(C)C12] | −1.66 | −4.78 | 3.12 | 84.2 |
| 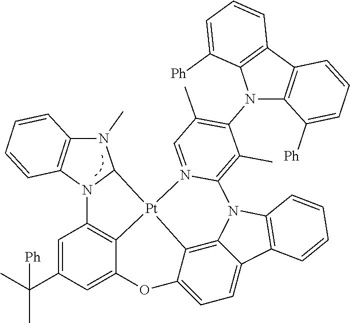 | 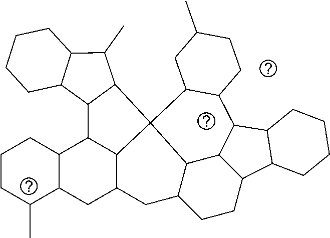 [SMILES: CC1CCC2C3C4CCCCC4C4CCC5CC6CC7C(C)CCCC7C7C8C9CCCCC9C(C)C8C(C2C1)(C5C43)C67] | 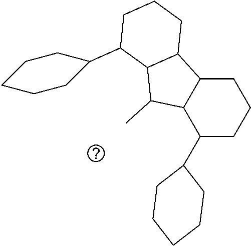 [SMILES: CC1C2C(C3CCCCC3)CCCC2C2CCCC(C3CCCCC3)C12] | -1.49 | -4.70 | 3.21 | 79.6 |
| 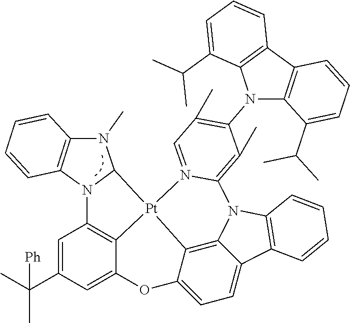 | 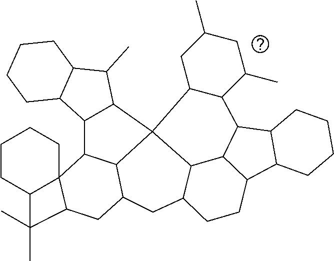 [SMILES: CC1CC(C)C2C3C4CCCCC4C4CCC5CC6CC7C(C)(C)C8CCCCC87C7C8C9CCCCC9C(C)C8C(C2C1)(C5C43)C67] | 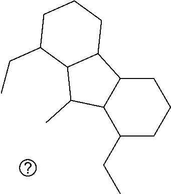 [SMILES: CCC1CCCC2C3CCCC(CC)C3C(C)C12] | −1.65 | −4.77 | 3.12 | 89.5 |
| 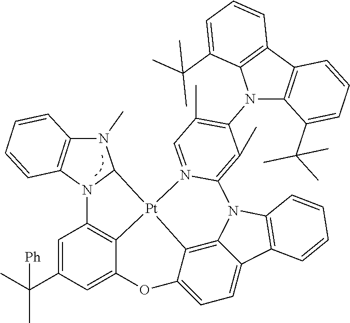 | 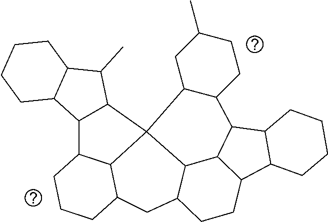 [SMILES: CC1CCC2C3C4CCCCC4C4CCC5CC6CCCC7C8C9CCCCC9C(C)C8C(C2C1)(C67)C5C43] | 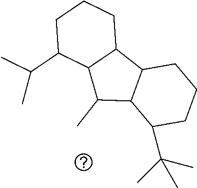 [SMILES: CC(C)C1CCCC2C3CCCC(C(C)(C)C)C3C(C)C12] | −1.62 | −4.74 | 3.12 | 77.5 |
| 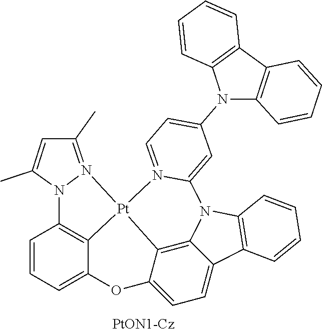 | 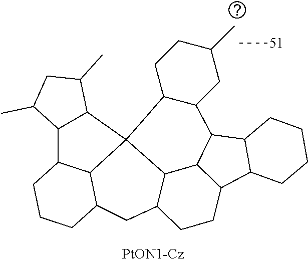 | | | | | 51 |

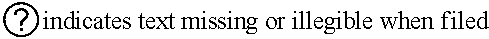

Note: The dihedral angle is an angle between a pyridine ring and the other four carbazole rings.

It can be seen from FIG. 1 that, through theoretical calculation, a dihedral angle between (substituted) carbazole/pyridine in PtON1-Cz and PtDMCz after structure optimization is 51° and 88° respectively, indicating that the dihedral angle between the substituted carbazole/pyridine may be greatly increased by introducing methyl at the 1-, 8-position of carbazole in PtDMCz. The increase of the dihedral angle may improve the rigidity of molecules, effectively reduce the energy consumed by vibration and rotation of a carbazole ring in the molecules, reduce non-radiative attenuation and improve the radiative transition rate of the material molecules.

In addition, a large amount of theoretical calculation experimental data in Table 2 also indicates that introducing substituents at the 1-, 8-position of carbazole may greatly increase the dihedral angle between carbazole/pyridine, which is greater than the dihedral angle of the control substance PtON1-Cz. At the same time, it also indicates the importance of 1-, 8-position group hindrance, which is the key to this application. At the same time, the numerous synthetic experimental embodiments mentioned above, as well as the characterization of their photophysical properties (Table 1) and subsequent device testing, also indicate that the molecular design method of the luminescent material in this application is completely successful.

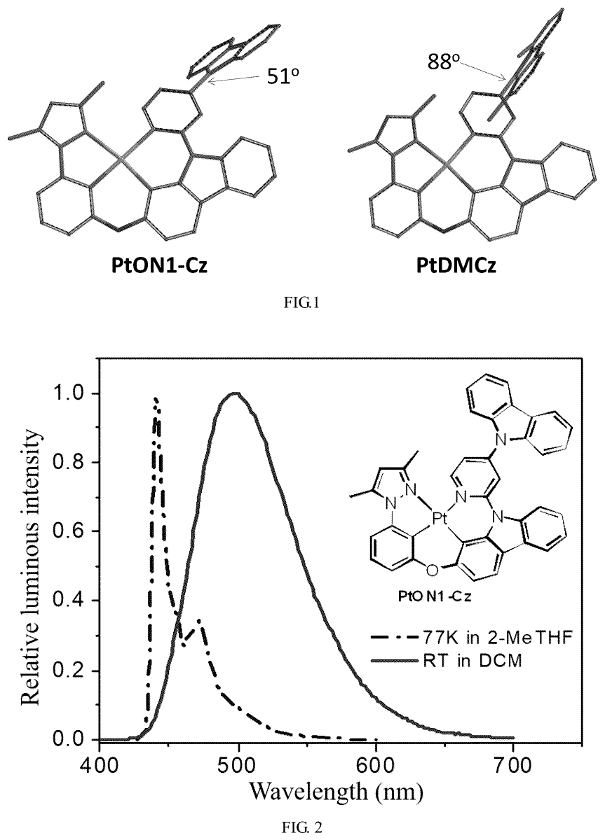

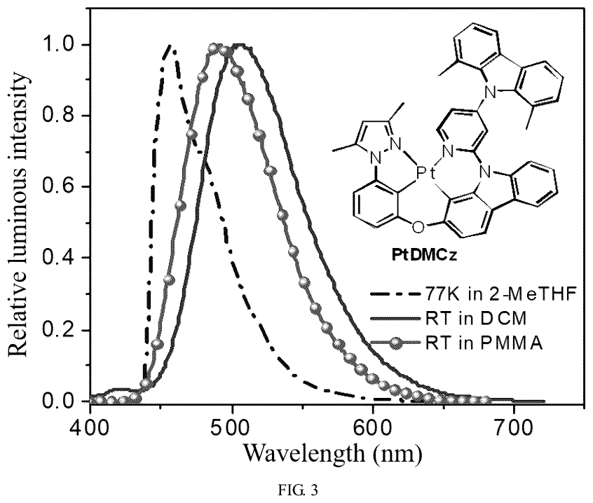

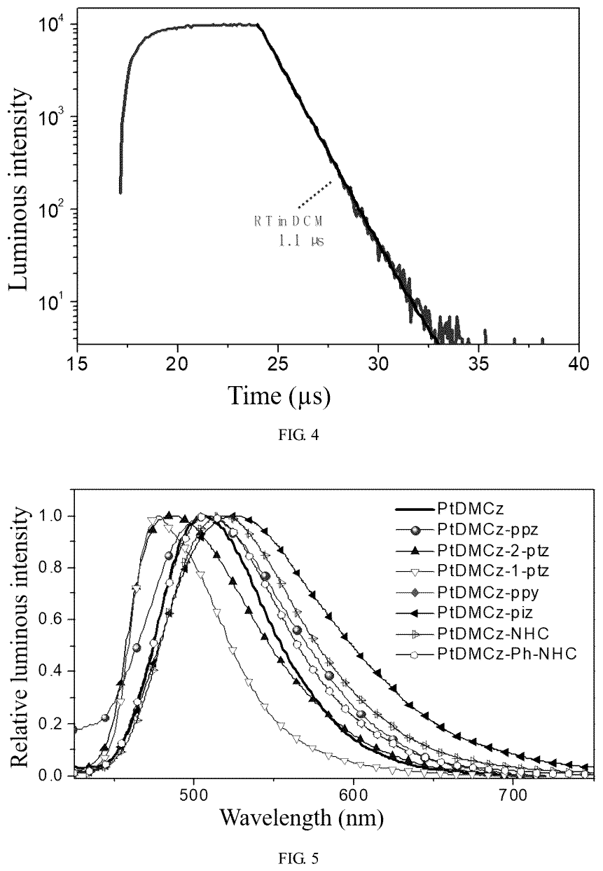

From the low-temperature emission spectra of PtON1-Cz and PtDMCz in FIGS. 2 and 3, it can be seen that PtON1-Cz is a spectrum with a fine vibrational structure, representing typical charge transfer state (CT) luminescence; while PtDMCz is a smooth spectrum lack of vibrational peaks, indicating significant increase in a metal-to-ligand charge transfer state (MLCT) in its luminescence, resulting in a shortened excited-state lifetime. From the experimental data in Table 1 and FIG. 4, it can be seen that the excited-state lifetime of PtDMCz in a dichloromethane solution at the room temperature is shortened to 1.1 microseconds (μs); at the same time, due to the increased dihedral angle between a substituted carbazole ring and a pyridine ring, the rigidity of molecules may be improved, effectively reducing the energy consumed by the vibration and rotation of the carbazole ring in the molecules, reducing non-radiative attenuation, and improving the phosphorescent quantum efficiency to 88%. The above two factors make the radiative transition rate (kᵣ^{obs}=Φ_{PL}/τ^{obs}) of PtDMCz greatly improved. From the experimental data in Table 1, it can be seen that the radiative transition rate kᵣ^{obs} of PtDMCz is 2.72-4.91 times that of its homolog luminescent materials Pt1, PtON1, PtON1-Ph and PtON1-Cz.

From comparison of the emission spectrogram of PtDMCz, PtDMCz-ppz, PtDMCz-2-ptz, PtDMCz-1-ptz, PtDMCz-piz, PtDMCz-ppy, PtDMCz-NHC and PtDMCz-Ph-NHC in the dichloromethane solution under the room temperature in FIG. 5, it can be seen that, by regulating the heterocyclic structure, its photophysical properties, such as the half peak width and emission wavelength of the emission spectrogram, can be effectively regulated. The absolute quantum efficiency of PtDMCz-1-ptz under this condition may reach up to 98%. The radiative transition rates (kᵣ^{obs}=Φ_{PL}/τ^{obs}) of the above material molecules are each at the order of about 8×10⁵ s⁻¹, which are far higher than the radiative transition rate of the material molecules for comparison.

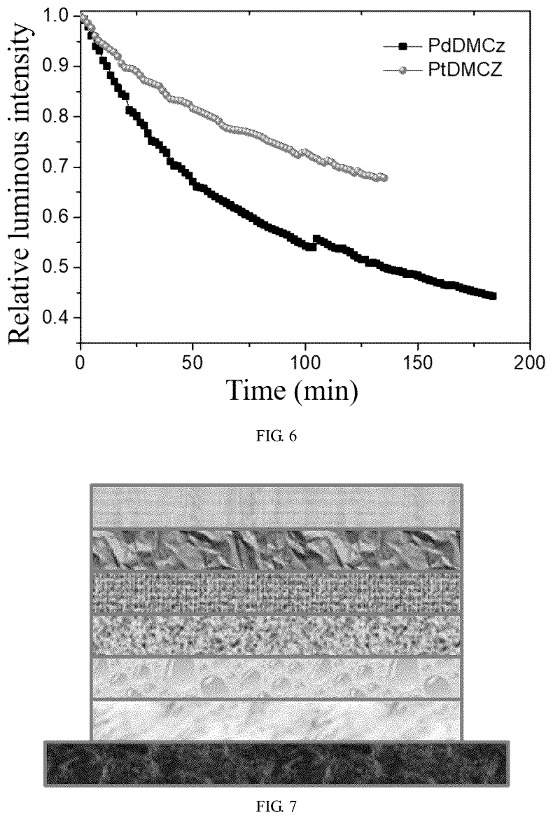

From the comparison of photostability tests between PtDMCz and PdDMCz in FIG. 6, it can be seen that PtDMCz has significant improvement in stability compared to its corresponding palladium (II) complex PdDMCz.

The above experimental data and theoretical calculation results fully indicate that the tetradentate cyclometalated platinum (II) complex luminescent material based on 1,8-substituted carbazole developed in the present invention has the characteristics of short excited-state lifetime, high radiative transition rate, and high phosphorescent quantum efficiency, making it have huge application prospects in the OLED field.

In an organic light emitting element, carriers are injected into the luminescent material from both positive and negative electrodes, generating an excited-state luminescent material and causing it to emit light. The complex of the present invention represented by general formula (1) may be applied as a phosphorescent luminescent material to excellent organic light emitting elements such as an organic photoluminescent element or an organic electroluminescent element. The organic photoluminescent element has a structure at least with a light emitting layer formed on a substrate. In addition, the organic electroluminescent element has a structure at least with an anode, a cathode, and an organic layer between the anode and cathode formed. The organic layer at least includes a light emitting layer, and may be composed of only a light emitting layer or may have more than one organic layer in addition to the light emitting layer. As such other organic layers, a hole transport layer, a hole injection layer, an electron blocking layer, a hole blocking layer, an electron injection layer, an electron transport layer, an exciton blocking layer, etc. may be listed. The hole transport layer may also be a hole injection transport layer with a hole injection function, and the electron transport layer may also be an electron injection transport layer with an electron injection function. The specific structural diagram of the organic light emitting element is as shown in FIG. 7. In FIG. 7, there are a total of 7 layers from bottom to top, representing a substrate, an anode, a hole injection layer, a hole transport layer, a light emitting layer, an electron transport layer, and a cathode in sequence. The light emitting layer is a mixed layer where a guest material is doped into a host material.

The light emitting layer made by doping the phosphorescent luminescent material, as the guest material, into the host material in the present invention may be applied to an OLED device, with the structure represented as:
ITO/HATCN (10 nm)/TAPC (65 nm)/mCBP: the compound represented in the embodiments (4-20 wt. %, 20 nm)/PPT(2 nm)/Li₂CO₃: Bepp₂ (5%, 30 nm)/Li₂CO₃ (1 nm)/Al(100 nm)

ITO is a transparent anode; HATCN is a hole injection layer, TAPC is a hole transport layer, mCBP is a host material, the represented compound (4-20 wt. % is a doping concentration, and 20 nm is a thickness of the light emitting layer) is a guest material, PPT is a hole blocking layer, Li₂CO₃: Bepp₂ is an electron transport layer, Li₂CO₃ is an electron injection layer, and Al is a cathode. The number with the unit being nanometer (nm) in the brackets is a thickness of a thin film.

Without optimizing the device structure mentioned above, the external quantum efficiency (EQE) of an OLED device using PtDMCz as the doped luminescent material may reach over 20%, and has a small efficiency drop, which is significantly better than the device performance of the same device structure where the luminescent material PtON1-Cz is doped for comparison. It is believed that through the optimization of the device structure and the improvement of the host materials, the device performance will be further improved.

It should be noted that the structure is an example of an application of the luminescent material of the present invention, and does not limit the specific OLED device structure of the luminescent material shown in the present invention. The phosphorescent luminescent material is also not limited to the compounds represented in the embodiments.

Molecular formulas of the materials applied to the devices are as follows:

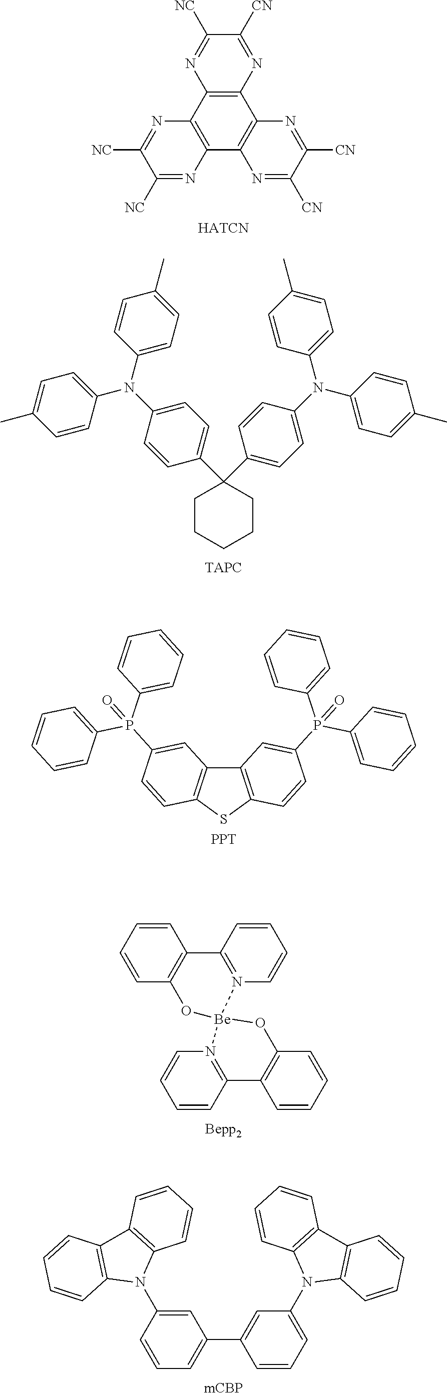

The layers of the organic light emitting device of the present invention may be formed by adopting the methods such as vacuum evaporation, sputtering and ion plating, or wet film forming such as spin coating and printing, and there is no special limitation on adopted solvents.

In another preferred implementation of the present invention, the OLED device of the present invention includes a hole transport layer, and a hole transport material may be preferably selected from known or unknown materials, particularly preferably from the following structures, but it does not mean that the present invention is limited to the following structures:

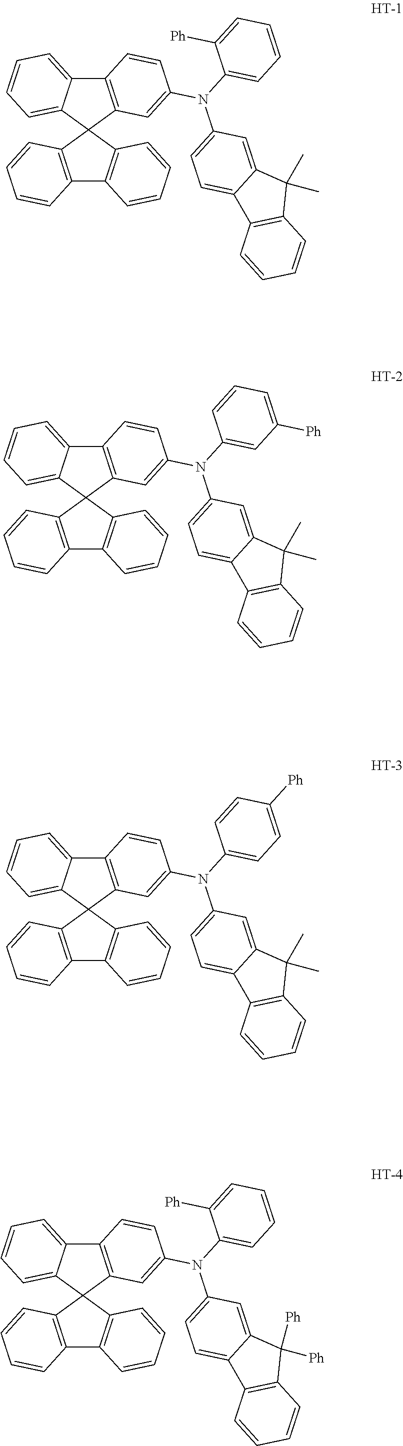 [SMILES: CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3cccc(-c4ccccc4)c3)c3ccc4c(c3)C3(c5ccccc5-c5ccccc53)c3ccccc3-4)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2ccccc2N(c2ccc3c(c2)C(c2ccccc2)(c2ccccc2)c2ccccc2-3)c2ccc3c(c2)C2(c4ccccc4-c4ccccc42)c2ccccc2-3)cc1]

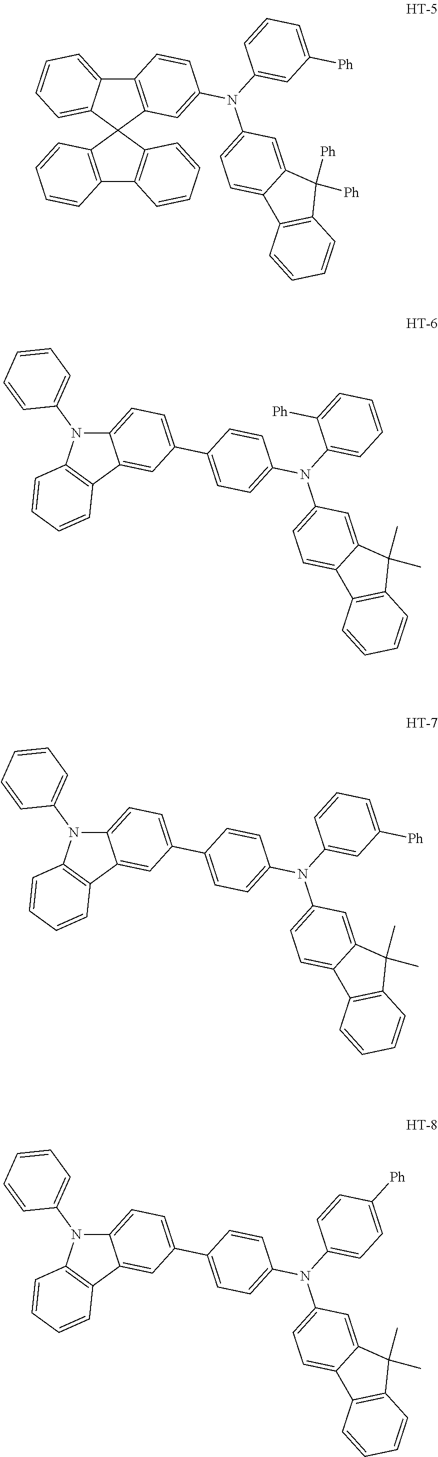 [SMILES: c1ccc(-c2cccc(N(c3ccc4c(c3)C(c3ccccc3)(c3ccccc3)c3ccccc3-4)c3ccc4c(c3)C3(c5ccccc5-c5ccccc53)c3ccccc3-4)c2)cc1 ; CC1(C)c2ccccc2-c2ccc(N(c3ccc(-c4ccc5c(c4)c4ccccc4n5-c4ccccc4)cc3)c3ccccc3-c3ccccc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

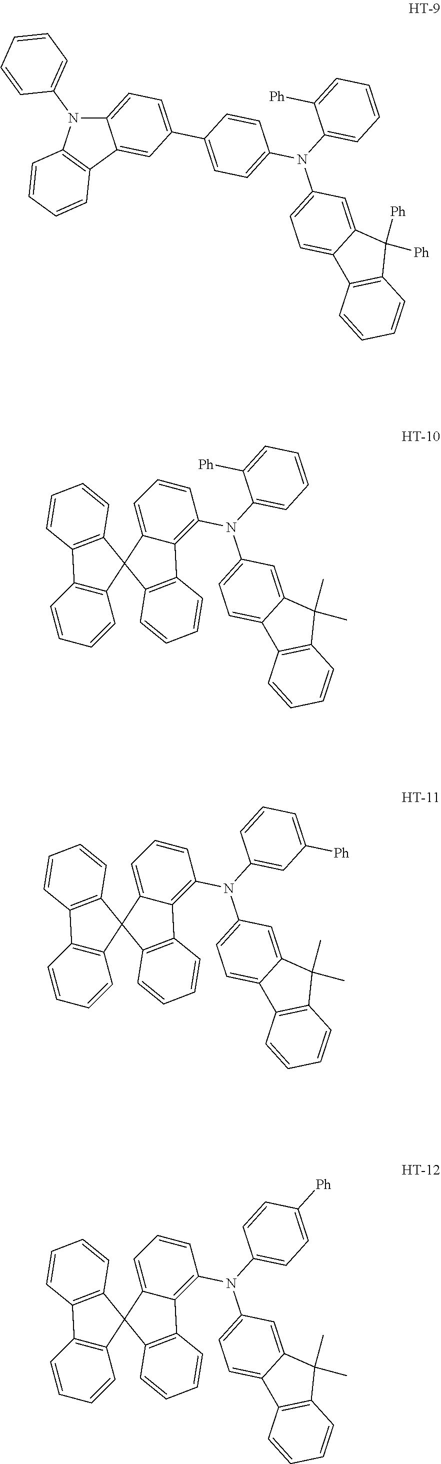 [SMILES: c1ccc(-c2ccccc2N(c2ccc(-c3ccc4c(c3)c3ccccc3n4-c3ccccc3)cc2)c2ccc3c(c2)C(c2ccccc2)(c2ccccc2)c2ccccc2-3)cc1 ; CC1(C)c2ccccc2-c2ccc(N(c3ccccc3-c3ccccc3)c3cccc4c3-c3ccccc3C43c4ccccc4-c4ccccc43)cc21 ; CC1(C)c2ccccc2-c2ccc(N(c3cccc(-c4ccccc4)c3)c3cccc4c3-c3ccccc3C43c4ccccc4-c4ccccc43)cc21 ; CC1(C)c2ccccc2-c2ccc(N(c3ccc(-c4ccccc4)cc3)c3cccc4c3-c3ccccc3C43c4ccccc4-c4ccccc43)cc21]

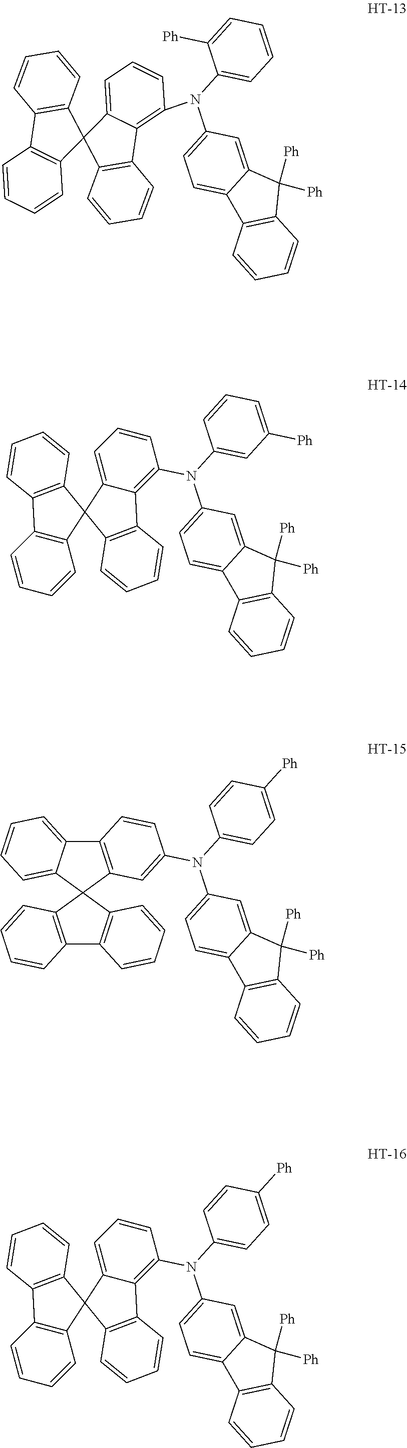 [SMILES: c1ccc(-c2ccccc2N(c2ccc3c(c2)C(c2ccccc2)(c2ccccc2)c2ccccc2-3)c2cccc3c2-c2ccccc2C32c3ccccc3-c3ccccc32)cc1 ; c1ccc(-c2cccc(N(c3ccc4c(c3)C(c3ccccc3)(c3ccccc3)c3ccccc3-4)c3cccc4c3-c3ccccc3C43c4ccccc4-c4ccccc43)c2)cc1 ; c1ccc(-c2ccc(N(c3ccc4c(c3)C(c3ccccc3)(c3ccccc3)c3ccccc3-4)c3ccc4c(c3)C3(c5ccccc5-c5ccccc53)c3ccccc3-4)cc2)cc1 ; c1ccc(-c2ccc(N(c3ccc4c(c3)C(c3ccccc3)(c3ccccc3)c3ccccc3-4)c3cccc4c3-c3ccccc3C43c4ccccc4-c4ccccc43)cc2)cc1]

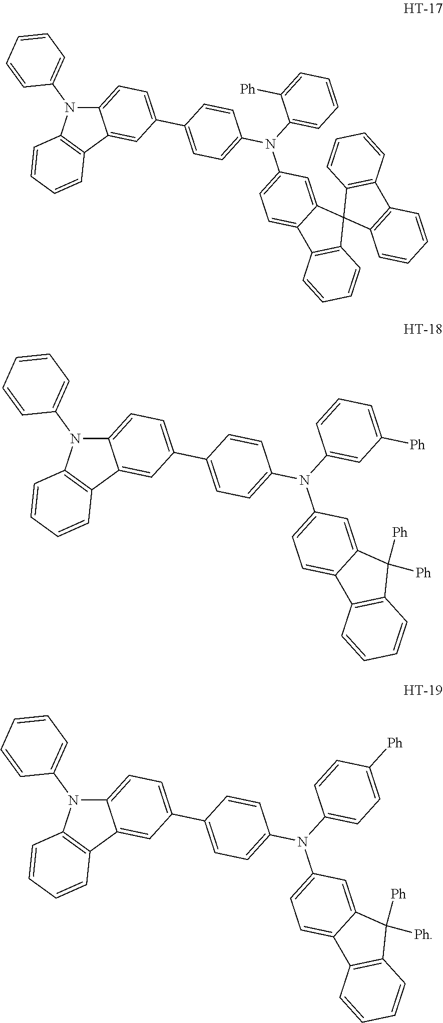 [SMILES: c1ccc(-c2ccccc2N(c2ccc(-c3ccc4c(c3)c3ccccc3n4-c3ccccc3)cc2)c2ccc3c(c2)C2(c4ccccc4-c4ccccc42)c2ccccc2-3)cc1 ; c1ccc(-c2cccc(N(c3ccc(-c4ccc5c(c4)c4ccccc4n5-c4ccccc4)cc3)c3ccc4c(c3)C(c3ccccc3)(c3ccccc3)c3ccccc3-4)c2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In a preferred implementation of the present invention, the hole transport layer included in the OLED device of the present invention contains one or more p-type doping agents. Preferred p-type doping agents of the present invention are the following structures, but it does not mean that the present invention is limited to the following structures:

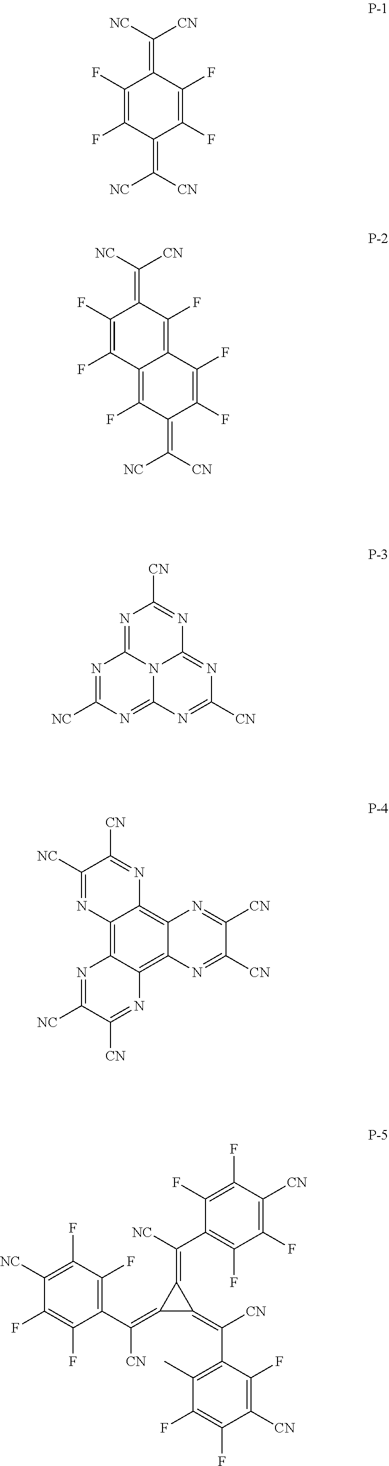 [SMILES: N#CC(C#N)=c1c(F)c(F)c(=C(C#N)C#N)c(F)c1F ; N#CC(C#N)=c1c(F)c(F)c2c(F)c(=C(C#N)C#N)c(F)c(F)c2c1F ; N#CC1=NC2=NC(C#N)=NC3=NC(C#N)=NC(=N1)N23 ; N#Cc1nc2c3nc(C#N)c(C#N)nc3c3nc(C#N)c(C#N)nc3c2nc1C#N ; Cc1c(F)c(F)c(C#N)c(F)c1/C(C#N)=C1/C(=C(/C#N)c2c(F)c(F)c(C#N)c(F)c2F)/C1=C(/C#N)c1c(F)c(F)c(C#N)c(F)c1F]

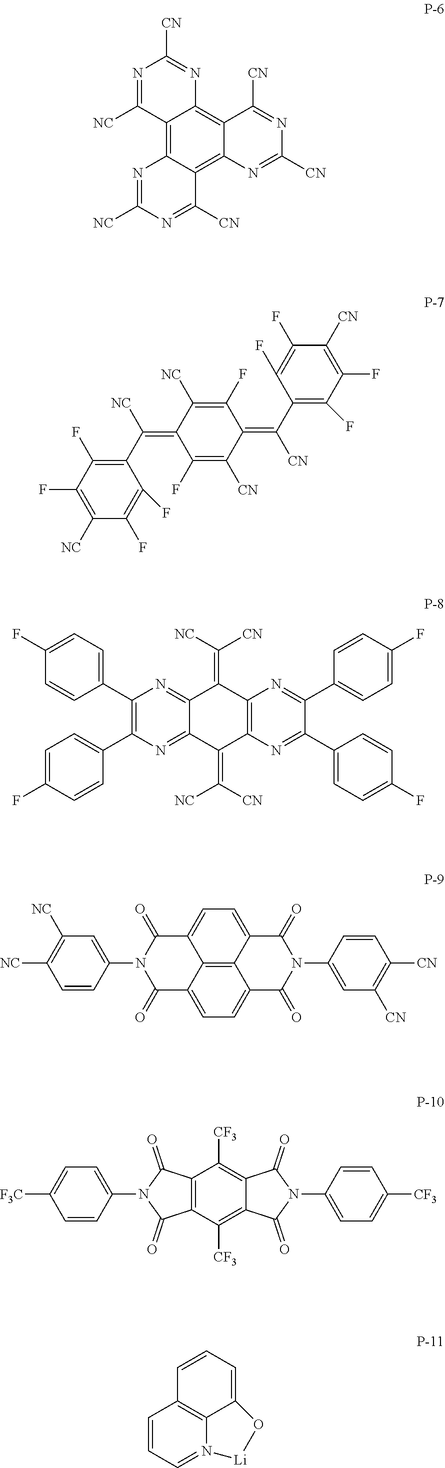

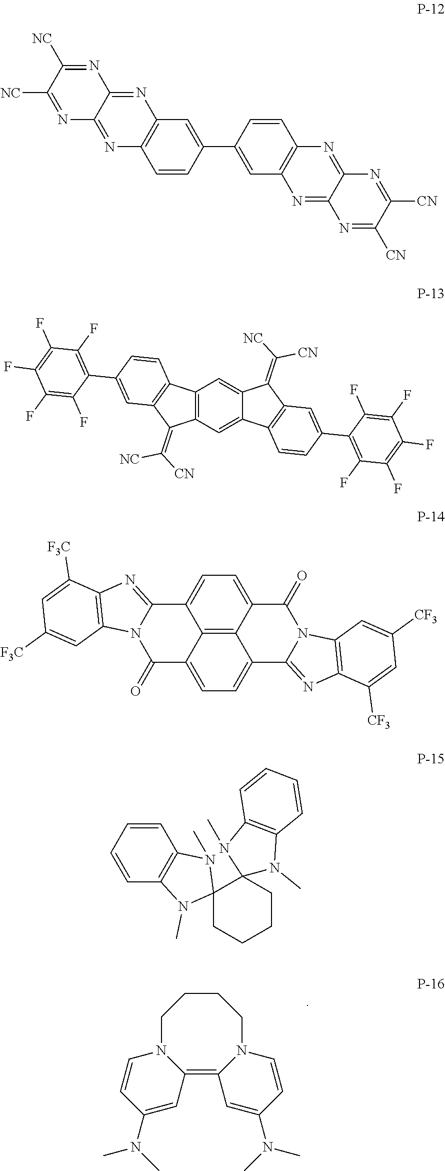

In a preferred implementation of the present invention, the electron transport layer may be selected from at least one of compounds ET-1 to ET-13, but it does not mean that the present invention is limited to the following structures:

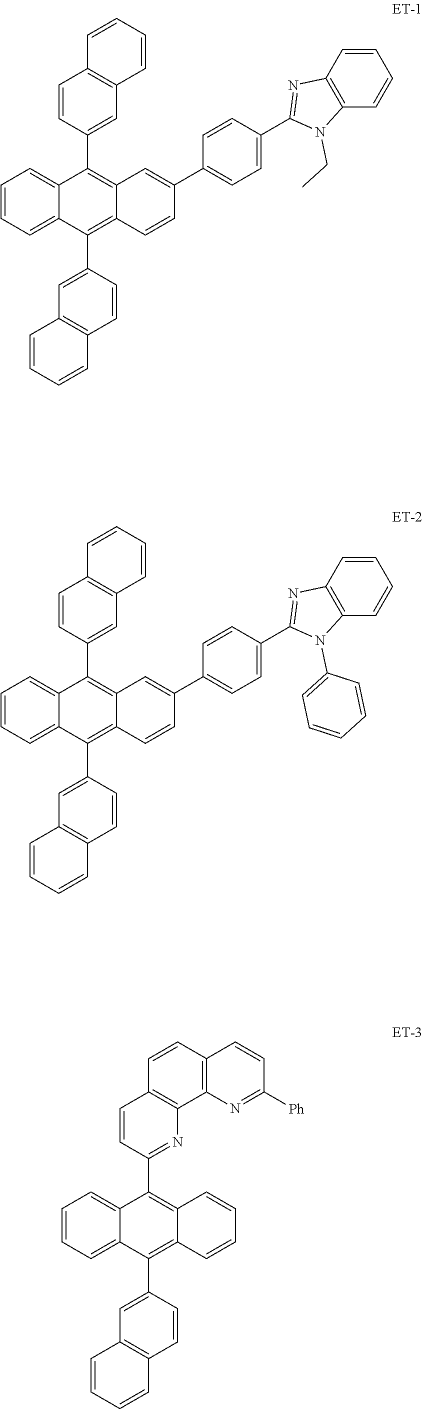 [SMILES: CCn1c(-c2ccc(-c3ccc4c(-c5ccc6ccccc6c5)c5ccccc5c(-c5ccc6ccccc6c5)c4c3)cc2)nc2ccccc21 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3ccc4ccc(-c5c6ccccc6c(-c6ccc7ccccc7c6)c6ccccc56)nc4c3n2)cc1]

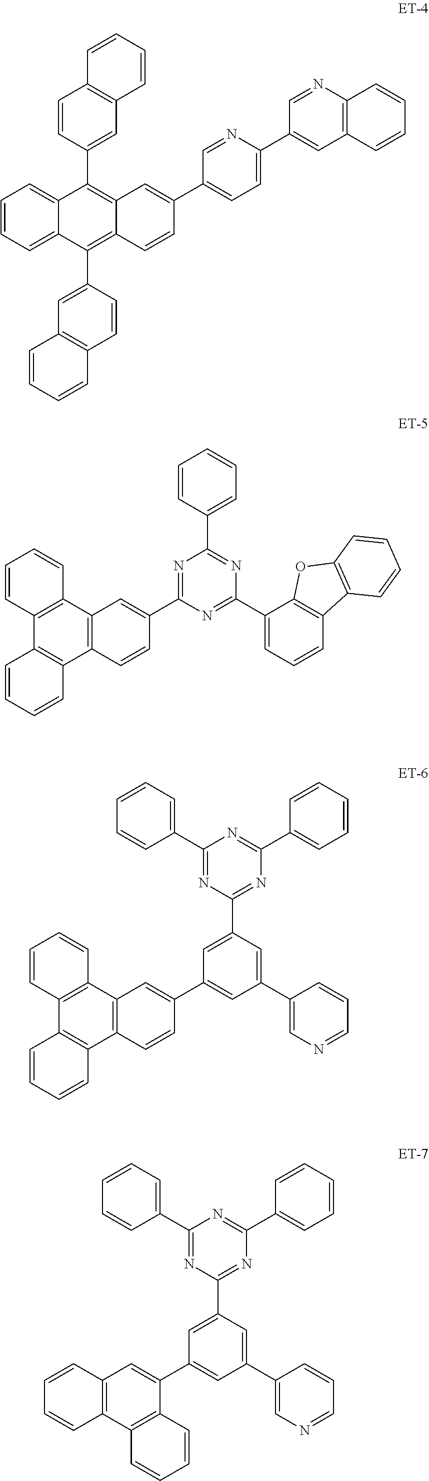 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-c2nc(-c3ccc4c5ccccc5c5ccccc5c4c3)nc(-c3cccc4c3oc3ccccc34)n2)cc1 ; c1ccc(-c2nc(-c3ccccc3)nc(-c3cc(-c4cccnc4)cc(-c4ccc5c6ccccc6c6ccccc6c5c4)c3)n2)cc1 ; c1ccc(-c2nc(-c3ccccc3)nc(-c3cc(-c4cccnc4)cc(-c4cc5ccccc5c5ccccc45)c3)n2)cc1]

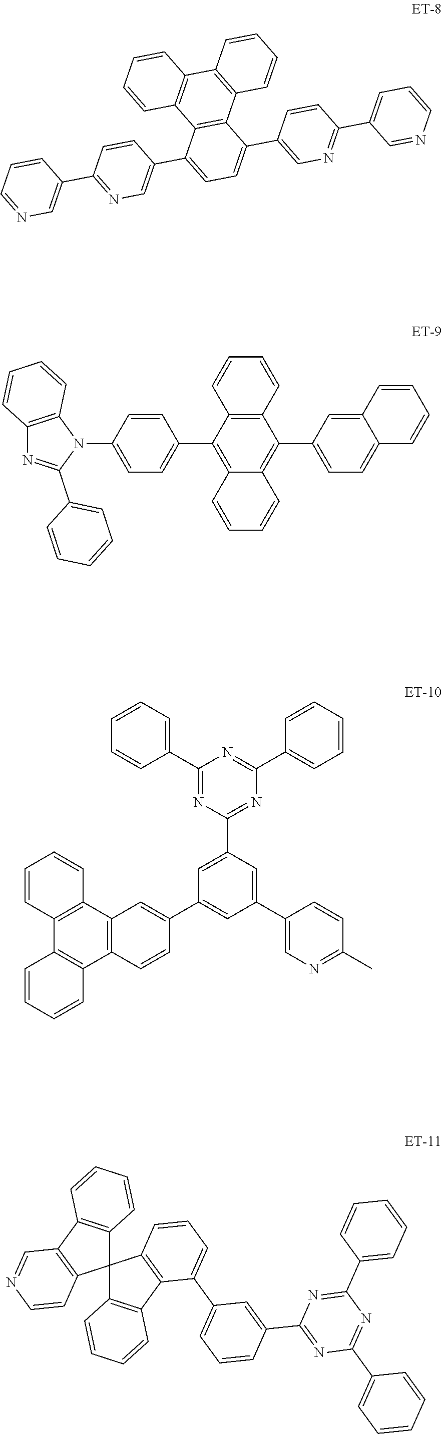 [SMILES: c1cncc(-c2ccc(-c3ccc(-c4ccc(-c5cccnc5)nc4)c4c5ccccc5c5ccccc5c34)cn2)c1 ; c1ccc(-c2nc3ccccc3n2-c2ccc(-c3c4ccccc4c(-c4ccc5ccccc5c4)c4ccccc34)cc2)cc1 ; Cc1ccc(-c2cc(-c3ccc4c5ccccc5c5ccccc5c4c3)cc(-c3nc(-c4ccccc4)nc(-c4ccccc4)n3)c2)cn1 ; c1ccc(-c2nc(-c3ccccc3)nc(-c3cccc(-c4cccc5c4-c4ccccc4C54c5ccccc5-c5cnccc54)c3)n2)cc1]

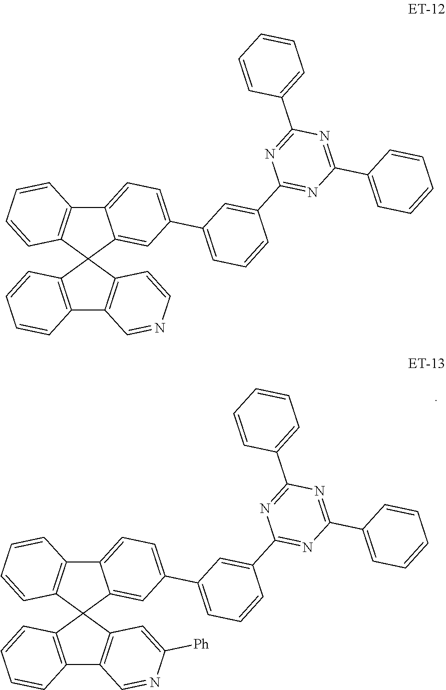 [SMILES: c1ccc(-c2nc(-c3ccccc3)nc(-c3cccc(-c4ccc5c(c4)C4(c6ccccc6-c6cnccc64)c4ccccc4-5)c3)n2)cc1 ; c1ccc(-c2cc3c(cn2)-c2ccccc2C32c3ccccc3-c3ccc(-c4cccc(-c5nc(-c6ccccc6)nc(-c6ccccc6)n5)c4)cc32)cc1]

The electron transport layer may be formed by an organic material and one or more n-type doping agents (such as LiQ) together.

The compound represented in embodiment 1 is applied to the OLED device as a circularly polarized light emitting material, and the structure is represented as: on glass containing ITO, a hole injection layer (HIL) is HT-1:P-3 (95:5 v/v %), with a thickness of 10 nm; a hole transport layer (HTL) is HT-1, with a thickness of 90 nm; an electron blocking layer (EBL) is HT-10, with a thickness of 10 nm, a light emitting layer (EML) is a host material (H-1 or H-2 or H-3 or H-4 or H-5 or H-6):the platinum metal complex of the present invention (95:5 v/v %), with a thickness of 35 nm, an electron transport layer (ETL) is ET-13:LiQ (50:50 v/v %), with a thickness of 35 nm, and then an evaporated cathode Al is 70 nm.

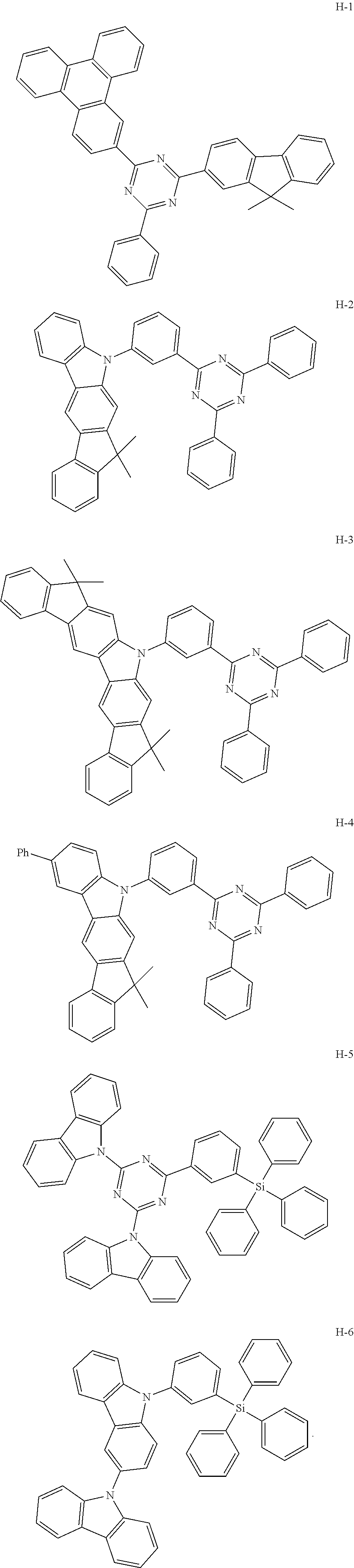

TABLE 3

| | Doped | Maximum | External quantum |
|---|---|---|---|
| | platinum | emission | efficiency EQE |
| | (II) | wavelength | (@1000 cd/m²) |
| | complexes | (nm) | (relative value) |
| Comparison devices | PtON1-Cz | 497 | 100 |
| Device 1 | Pt-DMCz | 509 | 155 |
| Device 2 | PtDMCz-ppz | 501 | 158 |
| Device 3 | PtDMCz-2-ptz | 486 | 176 |
| Device 4 | PtDMCz-1-ptz | 480 | 183 |
| Device 5 | PtDMCz-piz | 530 | 167 |
| Device 6 | PtDMCz-ppy | 510 | 169 |
| Device 7 | PtDMCz-NHC | 519 | 162 |
| Device 8 | PtDMCz-Ph-NHC | 508 | 159 |

From the above device data, it can be seen that the devices with high radiation rate doping in this application have significant performance improvement in external quantum efficiency EQE. In addition, compared with the comparison devices, the efficiency drop of the devices 1 to 8 is also significantly reduced.

Those of ordinary skill in the art can understand that the above implementations are specific embodiments of the present invention, and in practical applications, various changes can be made in form and details without deviating from the spirit and scope of the present invention. For example, without departing from the spirit of the present invention, many substituent structures described here can be replaced by other structures.

1. A high radiation rate platinum complex luminescent material based on 1,8-substituted carbazole, wherein the high radiation rate platinum complex luminescent material based on 1,8-substituted carbazole is a tetradentate cyclometalated platinum (II) complex containing 1,8-di(substituted) carbazole having a chemical formula as shown in General Formula (1): 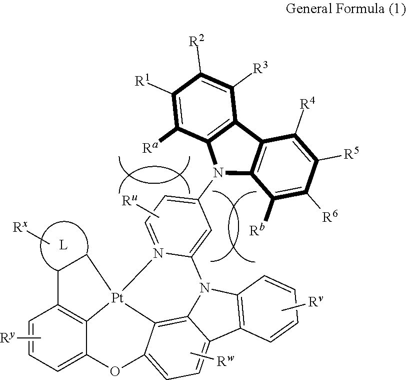
wherein L is a five-membered or six-membered heteroaromatic ring,
R^{a} and R^{b} are not hydrogen atoms, and each independently represent alkyl, alkoxy, cycloalkyl, heterocyclyl, alkenyl, substituted or unsubstituted aryl, substituted or unsubstituted aryloxy, substituted or unsubstituted heteroaryl, halogen, hydroxyl, sulfhydryl, nitryl, cyano, amino, carboxyl, sulfo, hydrazino, carbamido, alkynyloxy, ester group, acylamino, sulfonyl, sulfinyl, sulfonylamino, phosphorylamino, alkoxycarbonylamino, aryloxycarbonylamino, silyl, alkylamino, dialkylamino, monoarylamino, biarylamino, ureylene, imino, or a combination thereof;
R¹, R², R³, R⁴, R⁵ and R⁶ each independently represent hydrogen, deuterium, alkyl, alkoxy, cycloalkyl, heterocyclyl, alkenyl, substituted or unsubstituted aryl, substituted or unsubstituted aryloxy, substituted or unsubstituted heteroaryl, halogen, hydroxyl, sulfhydryl, nitryl, cyano, amino, carboxyl, sulfo, hydrazino, carbamido, alkynyloxy, ester group, acylamino, sulfonyl, sulfinyl, sulfonylamino, phosphorylamino, alkoxycarbonylamino, aryloxycarbonylamino, silyl, alkylamino, dialkylamino, monoarylamino, biarylamino, ureylene, imino, or a combination thereof;
two or more of R¹, R², R³, R⁴, R⁵ and R⁶ are able to be connected to form a fused ring, and the fused ring is further able to be fused with other rings;
R^{u}, R^{v}, R^{w}, R^{x} and R^{y} each independently represent mono-substituted, bis-substituted, tri-substituted, tetra-substituted or unsubstituted, and R^{u}, R^{v}, R^{w}, R^{x} and R^{y} each independently are hydrogen, deuterium, alkyl, alkoxy, cycloalkyl, heterocyclyl, alkenyl, substituted or unsubstituted aryl, substituted or unsubstituted aryloxy, substituted or unsubstituted heteroaryl, halogen, hydroxyl, sulfhydryl, nitryl, cyano, amino, carboxyl, sulfo, hydrazino, carbamido, alkynyloxy, ester group, acylamino, sulfonyl, sulfinyl, sulfonylamino, phosphorylamino, alkoxycarbonylamino, aryloxycarbonylamino, silyl, alkylamino, dialkylamino, monoarylamino, biarylamino, ureylene, imino, or a combination thereof; and two or more adjacent ones of R^{u}, R^{v}, R^{w}, R^{x} and R^{y} are each independently or selectively connected to form a fused ring.

2. The high radiation rate platinum complex luminescent material based on 1,8-substituted carbazole according to claim 1, wherein the high radiation rate platinum complex luminescent material based on 1,8-substituted carbazole is selected from, but not limited to, the following chemical structures: 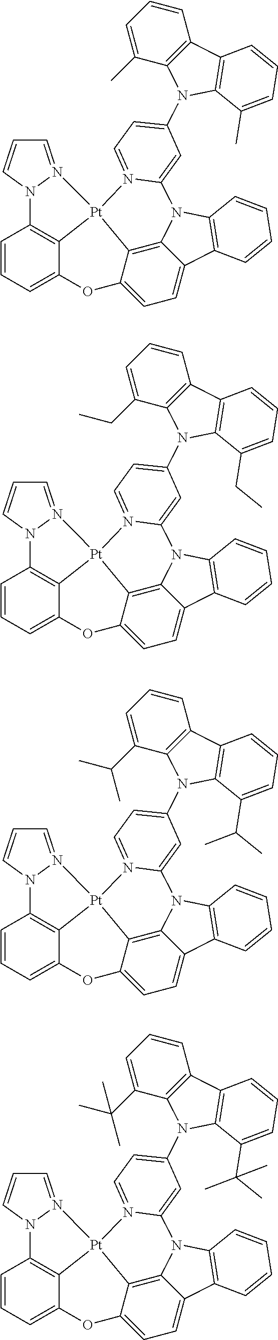 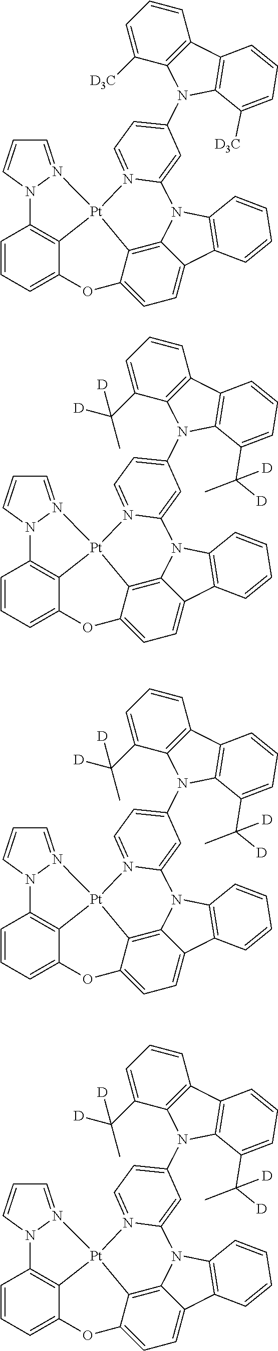 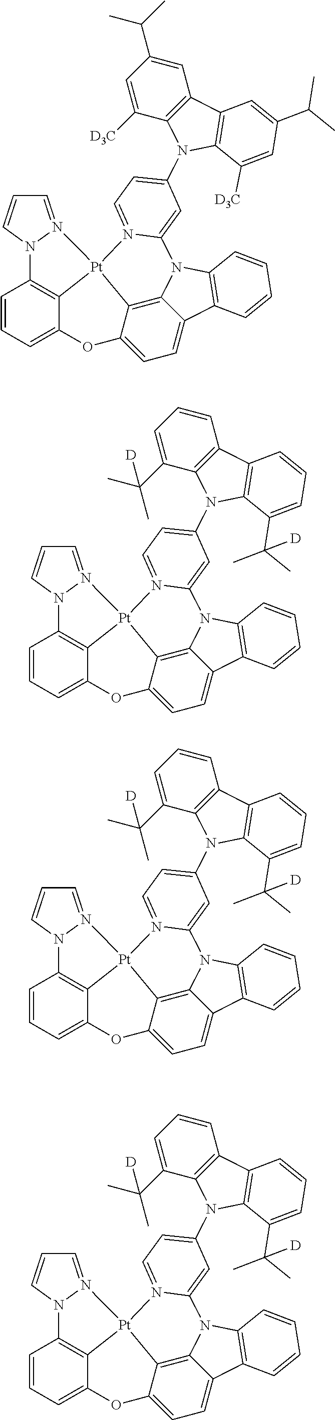 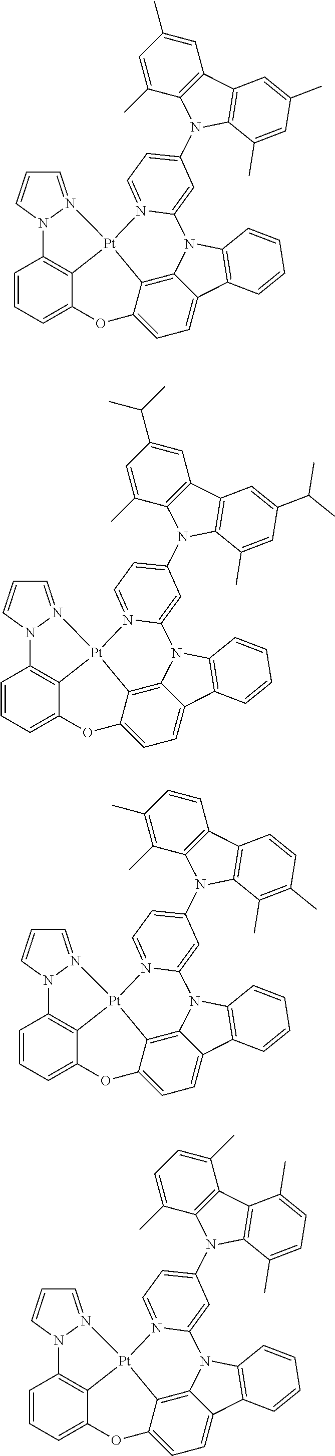 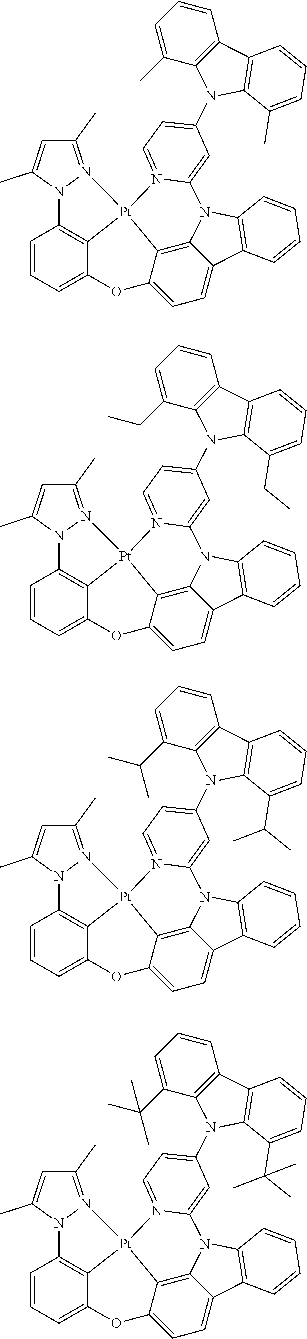 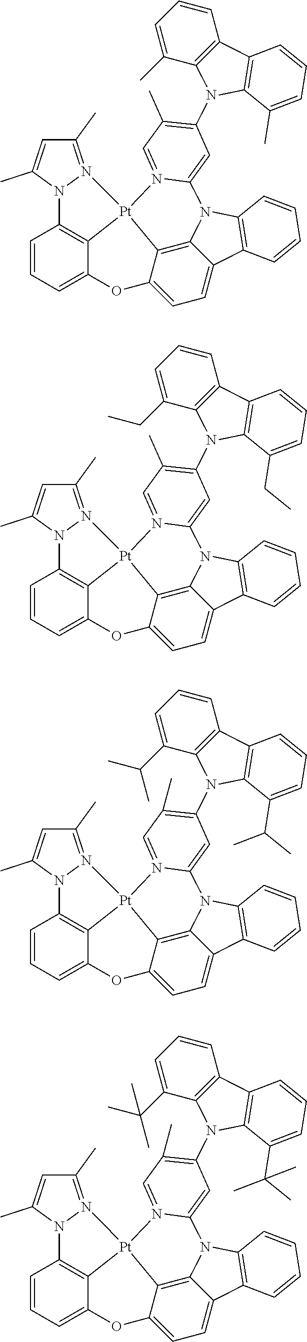 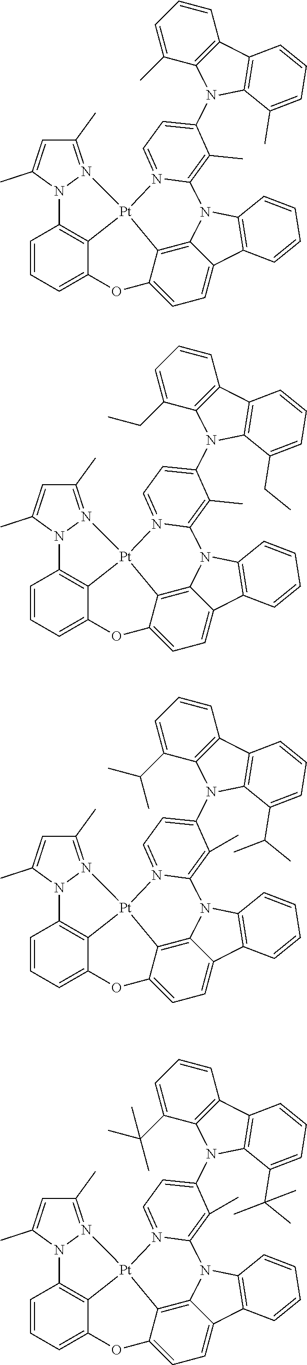 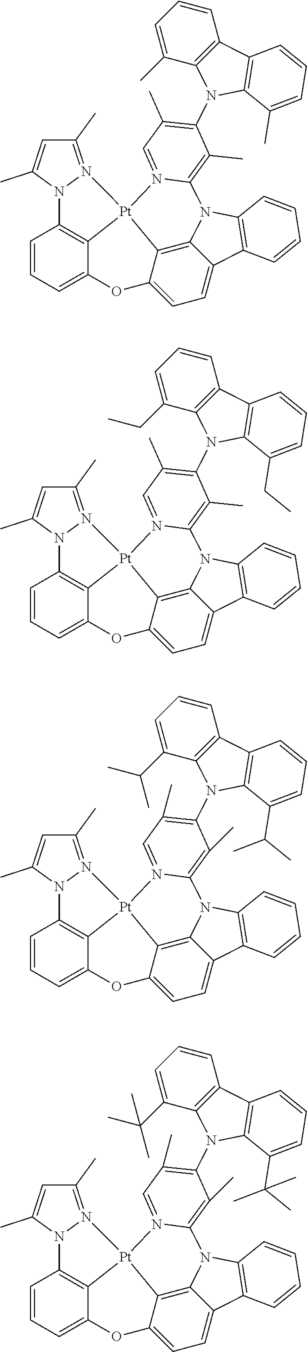 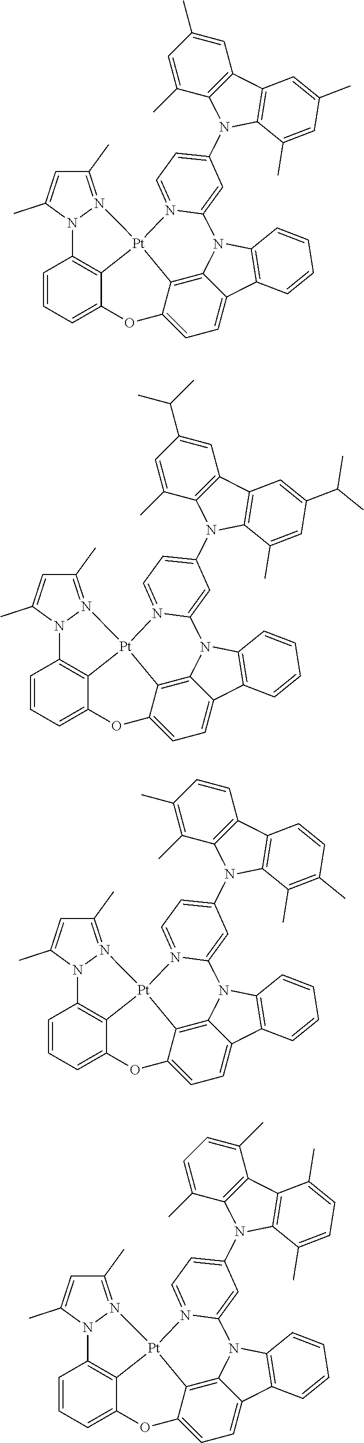 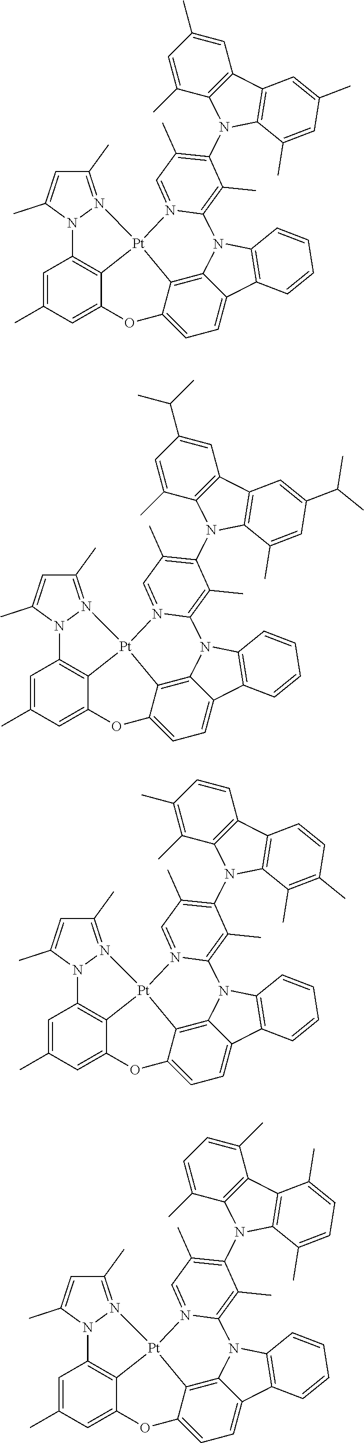 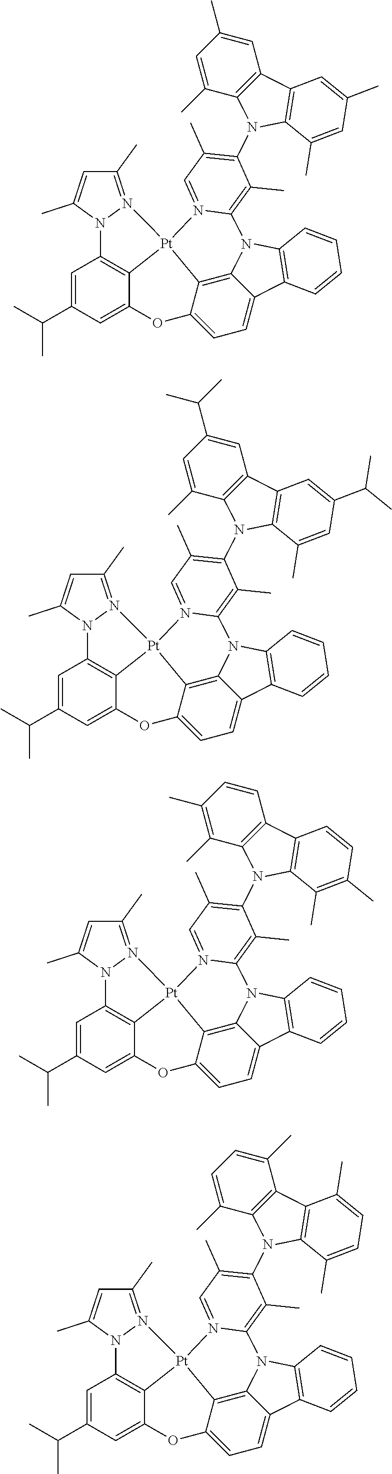 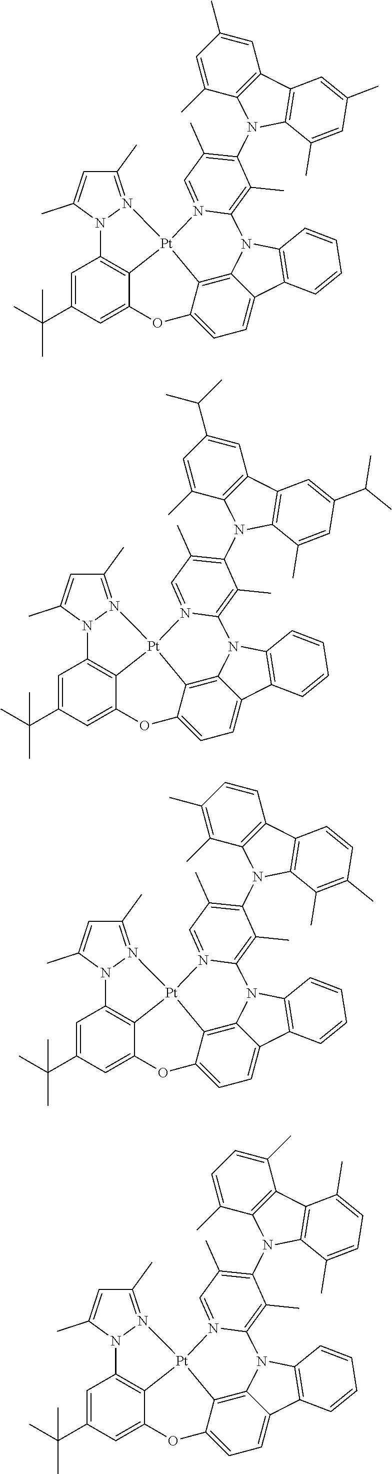 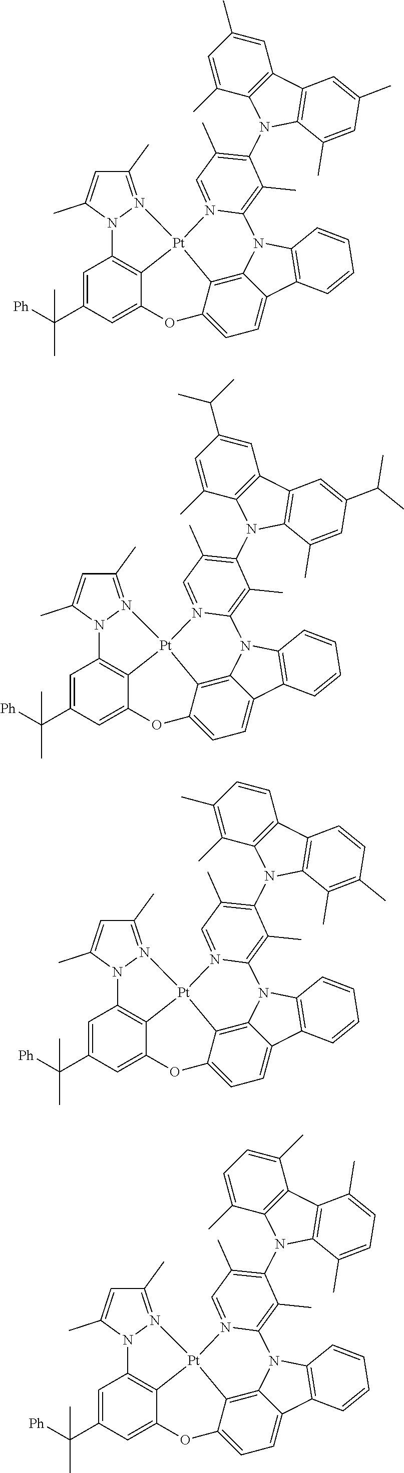 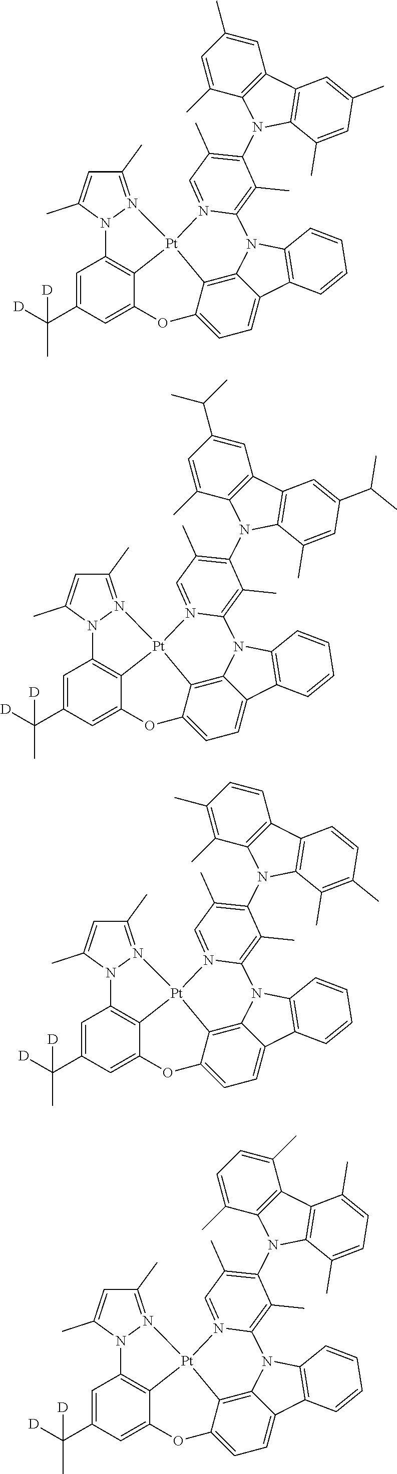 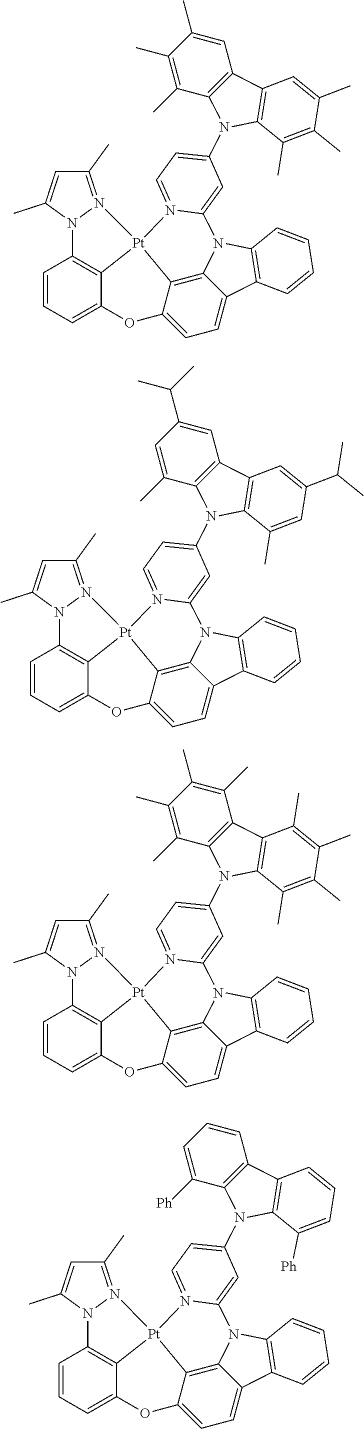 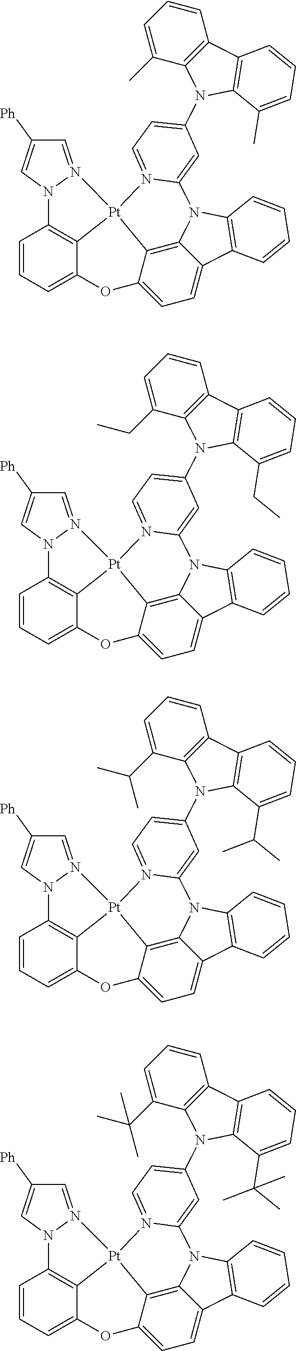 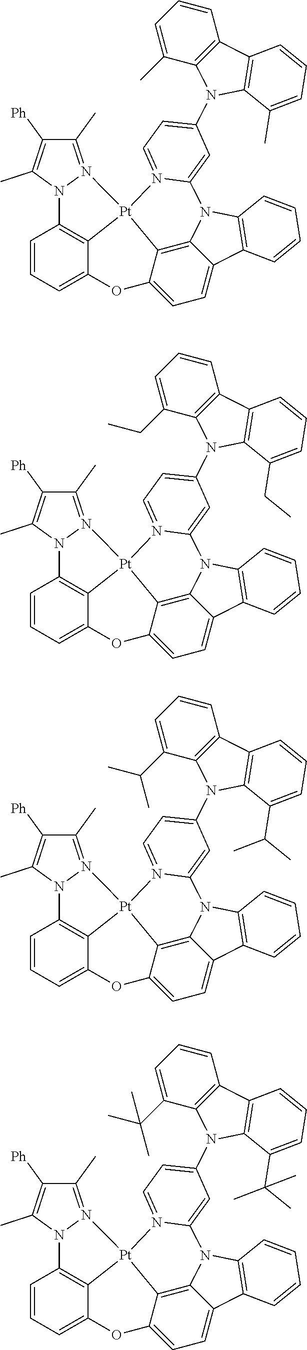 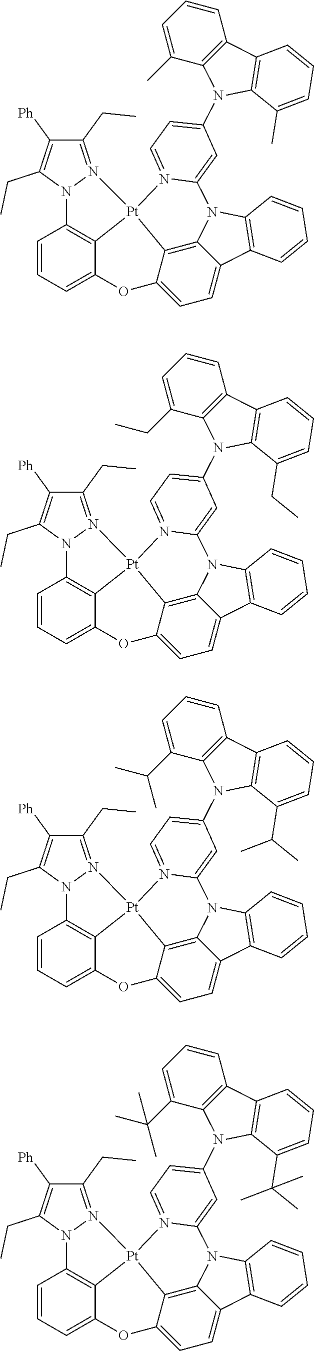 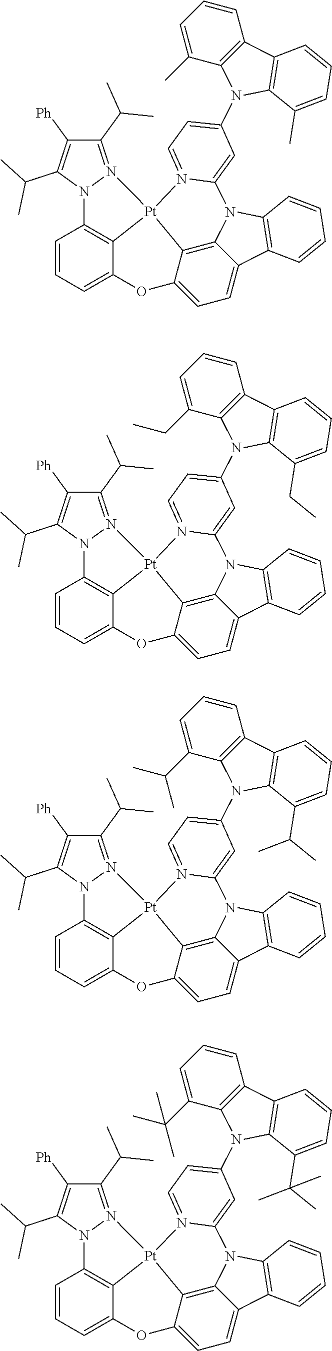 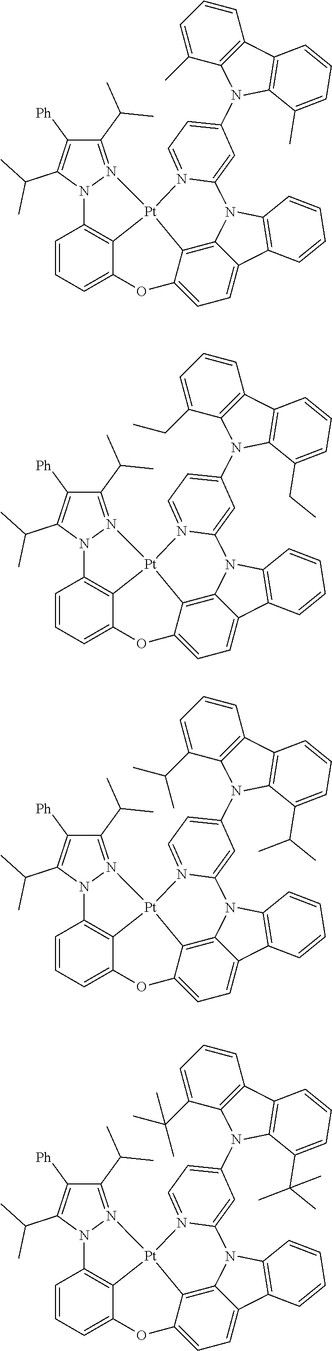 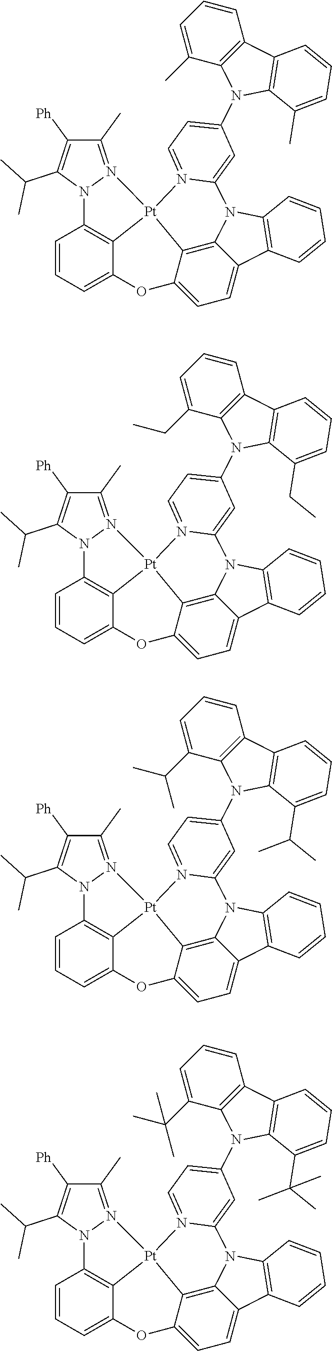 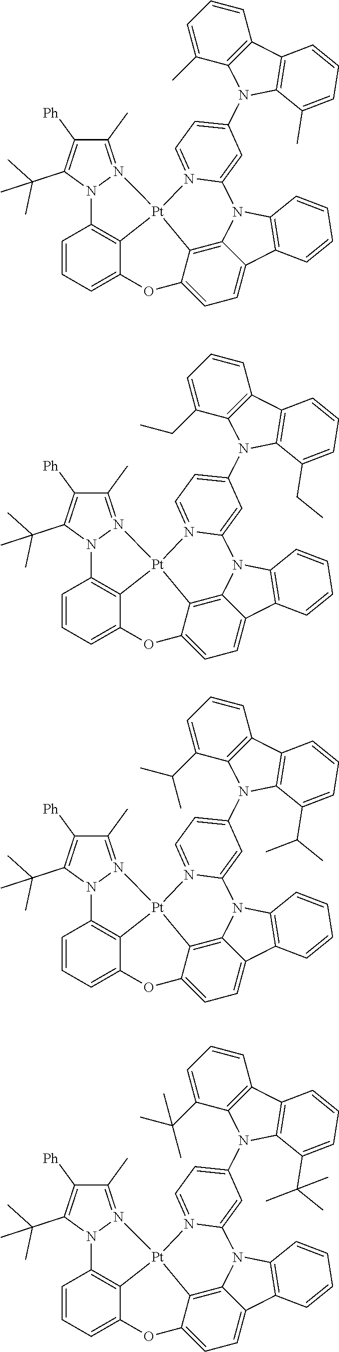 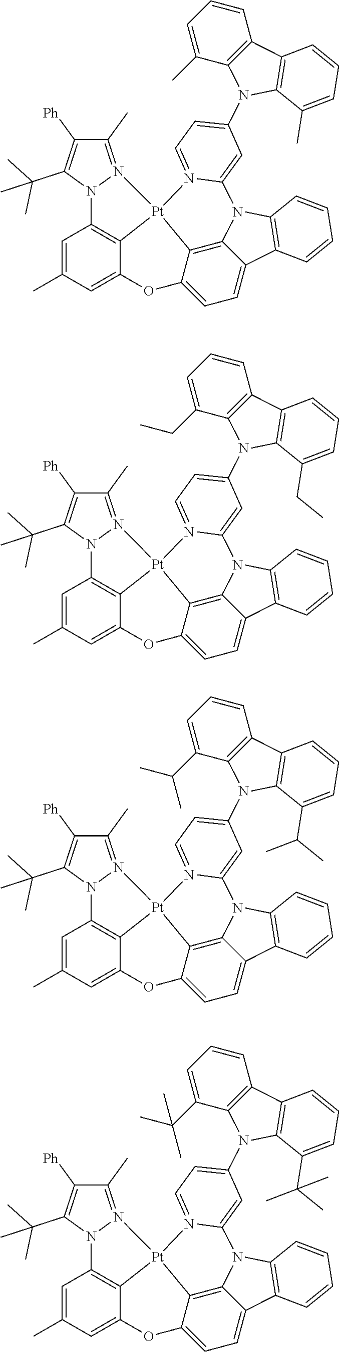 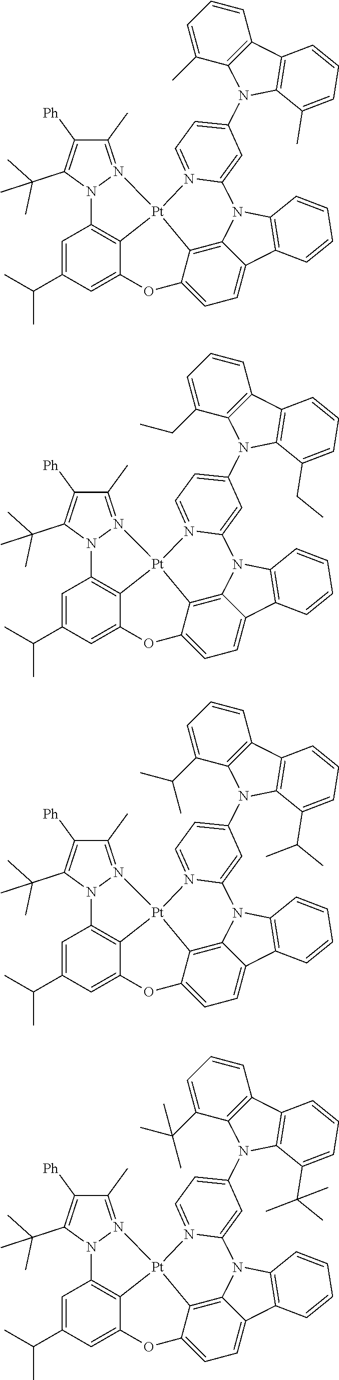 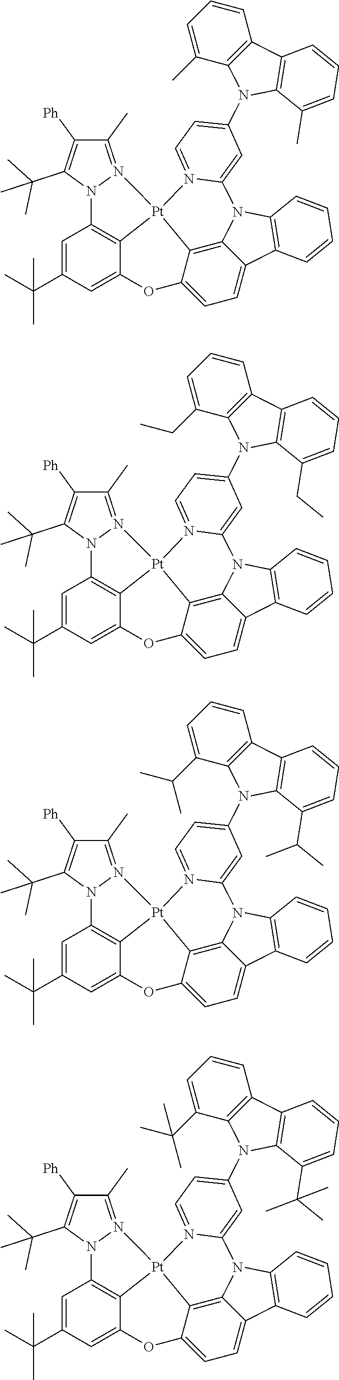 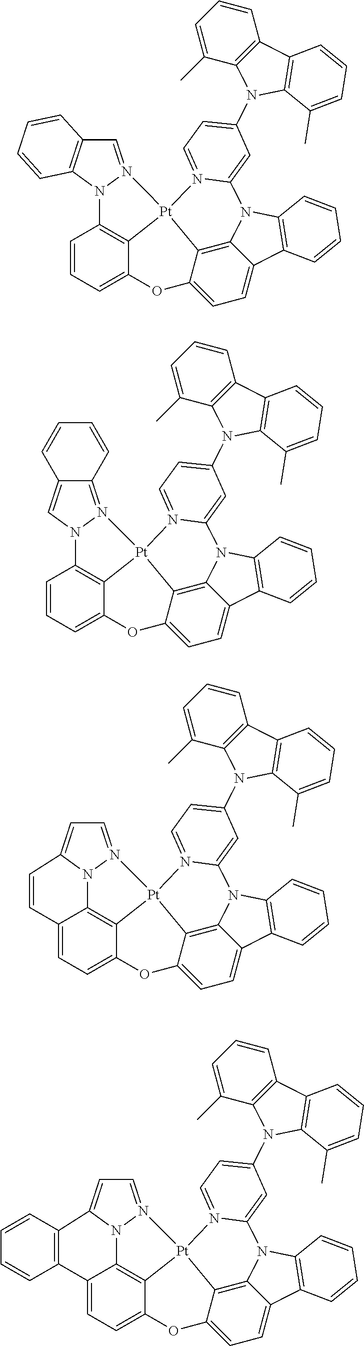 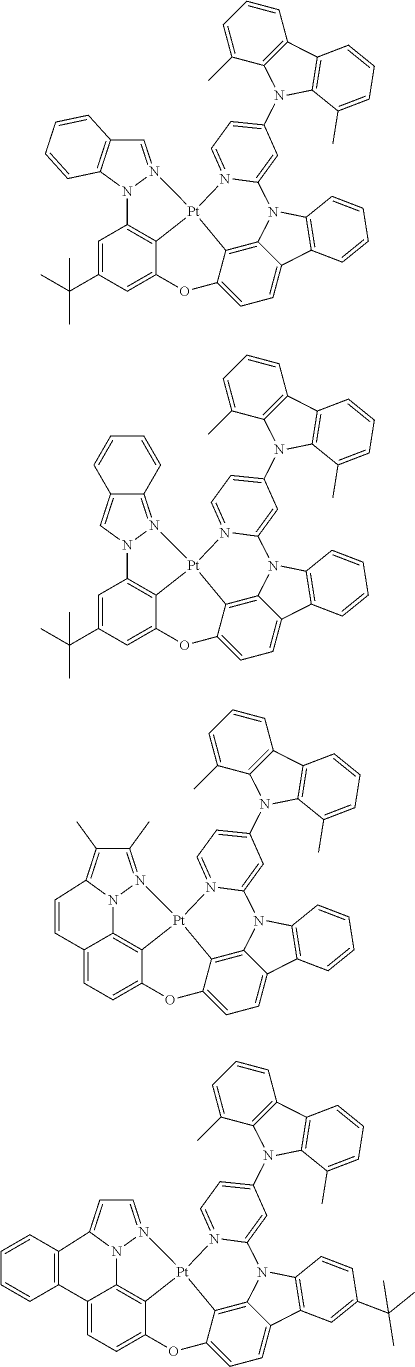 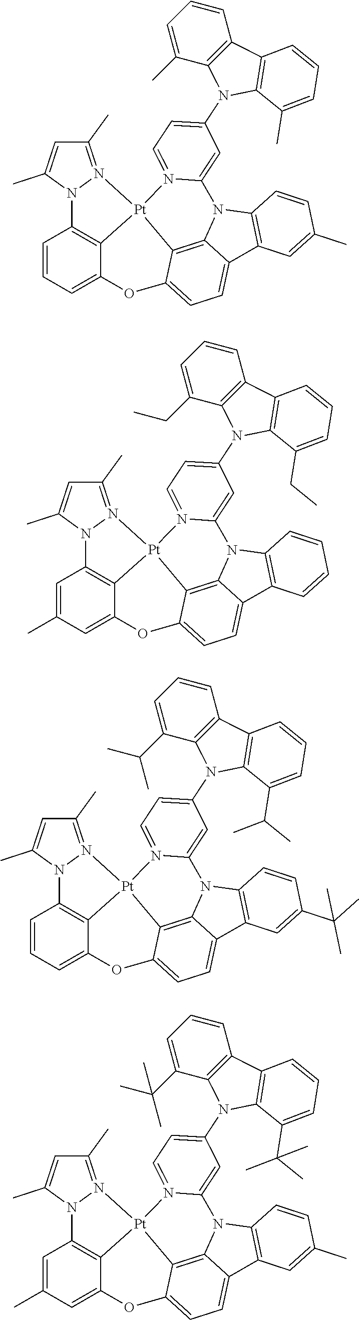 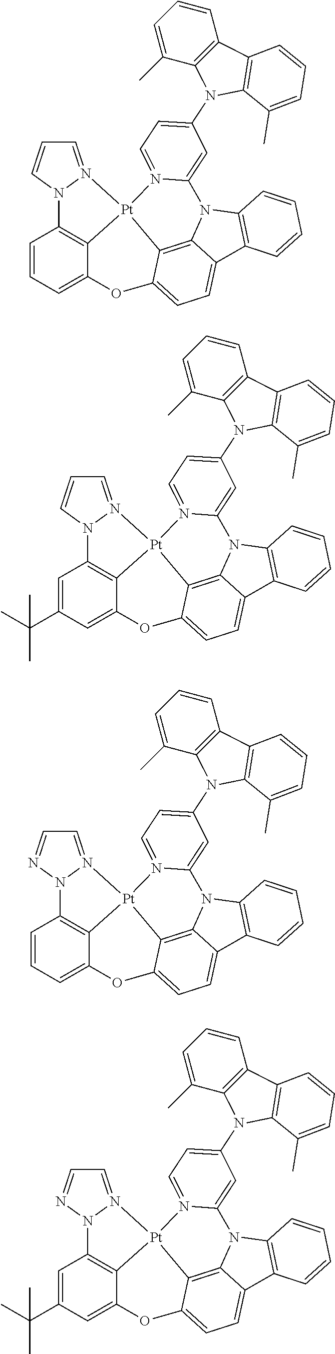 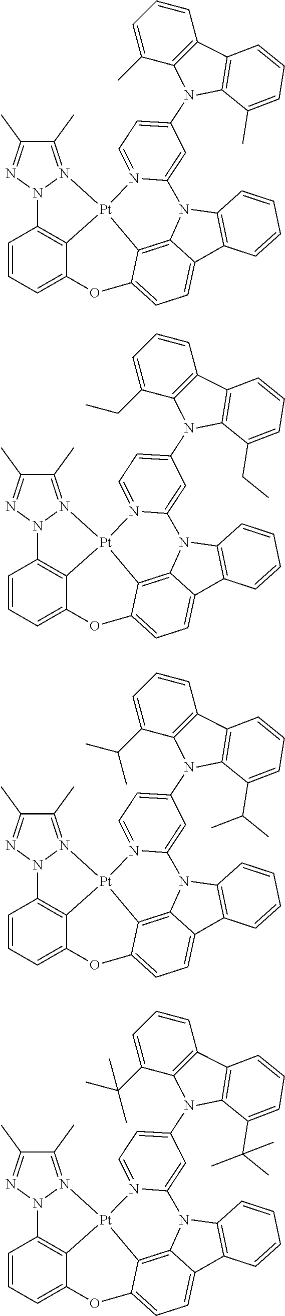 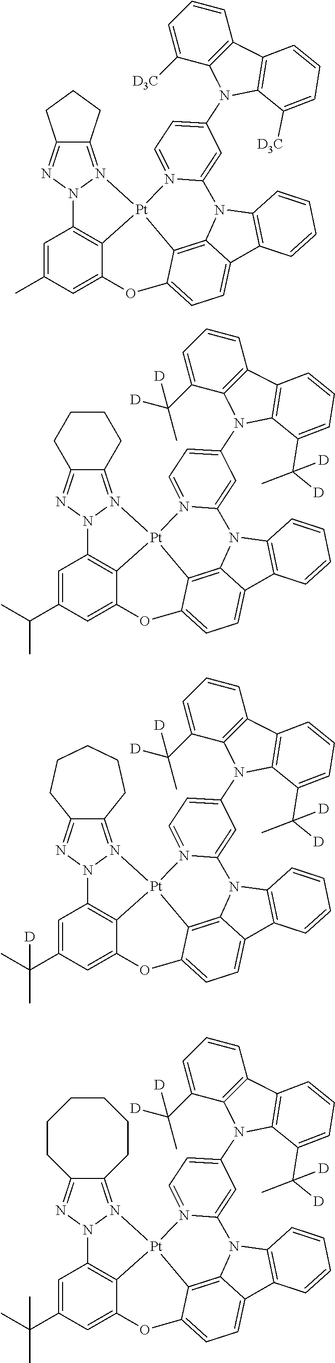 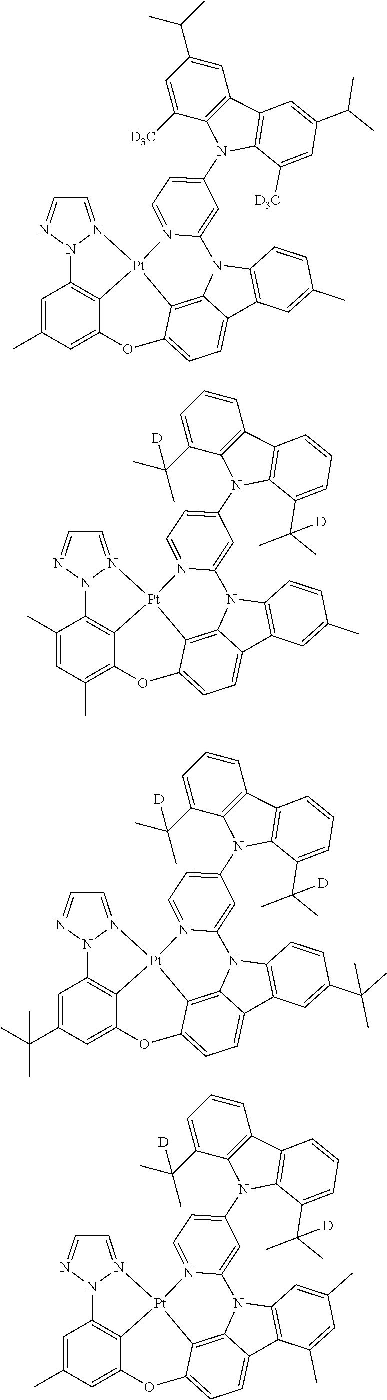 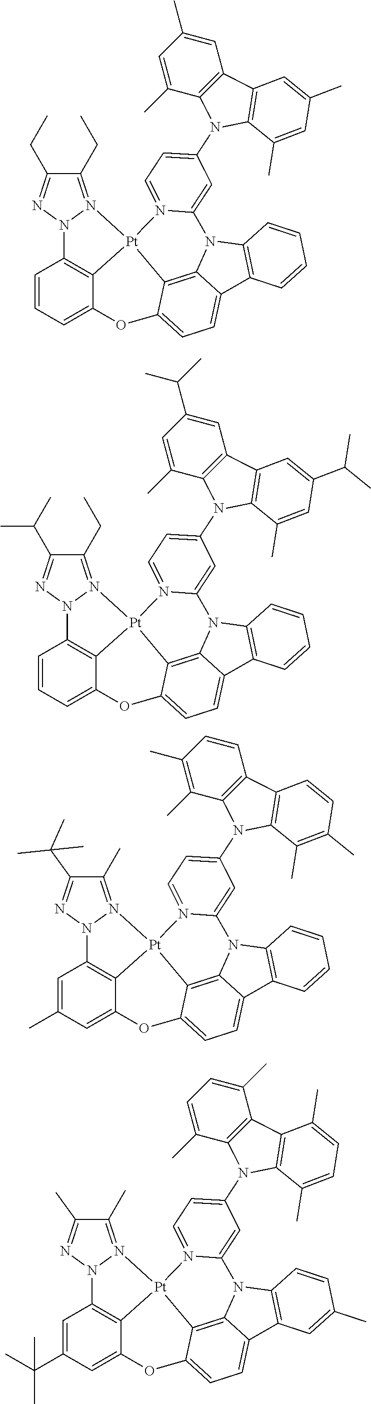 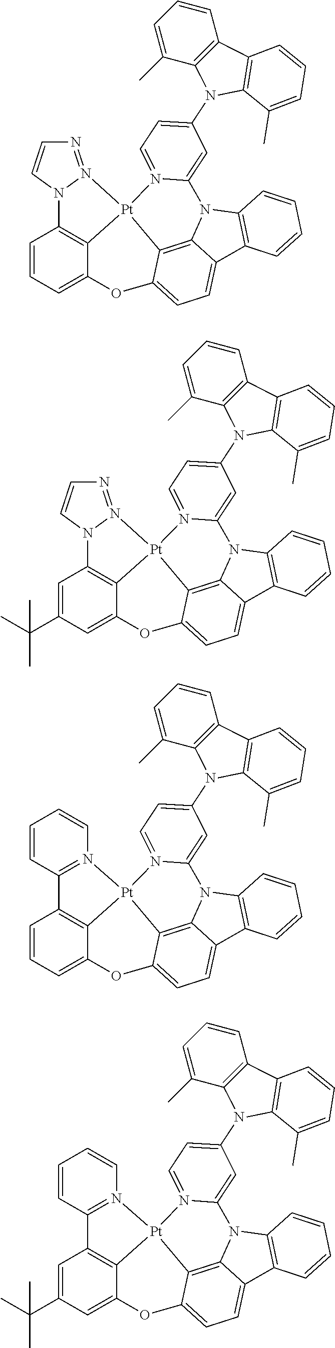 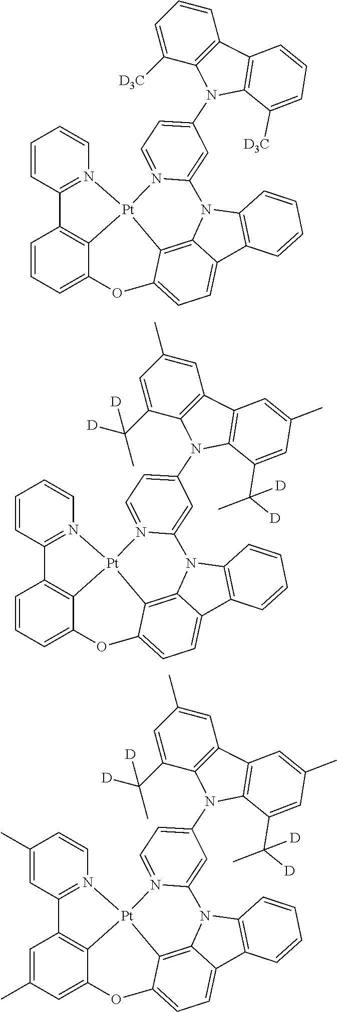 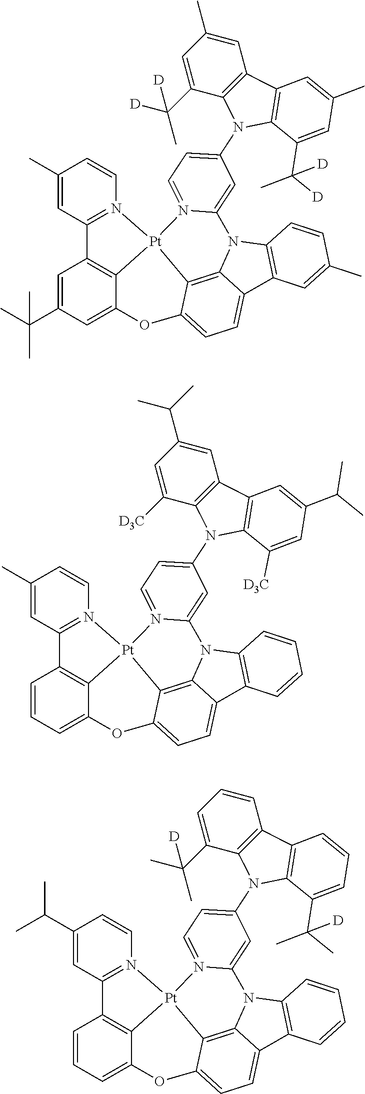 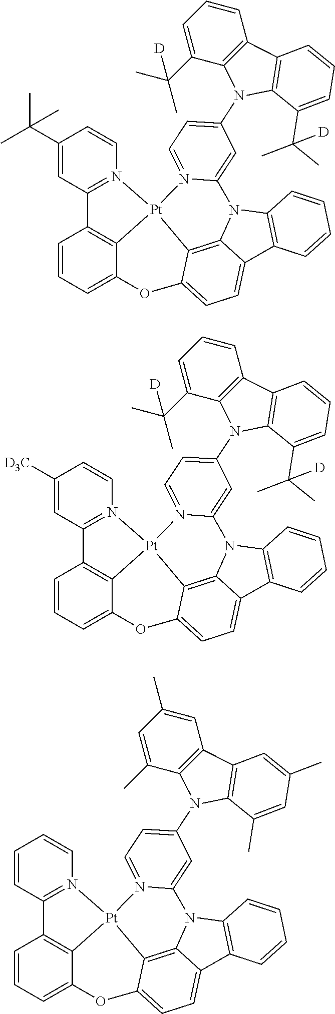 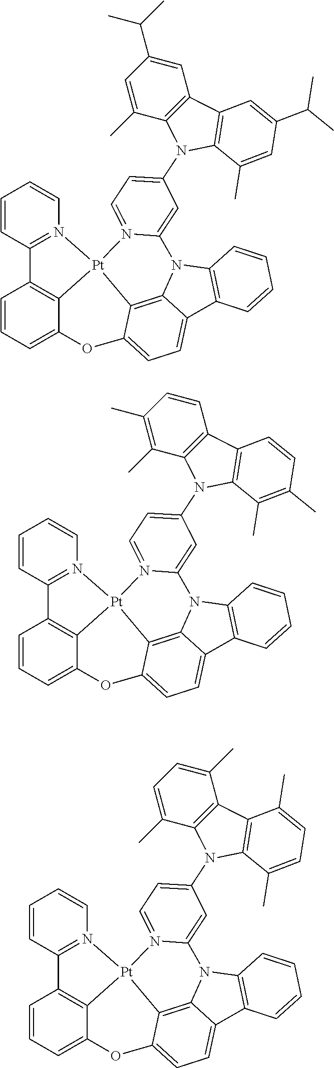 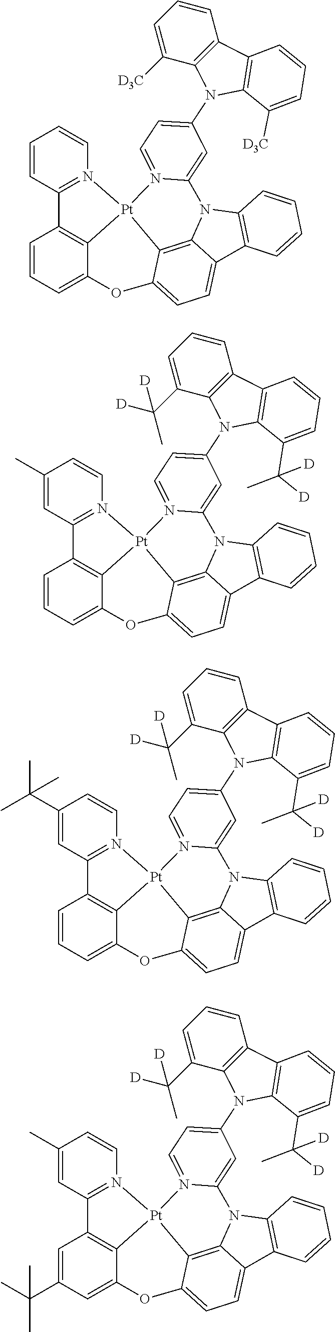 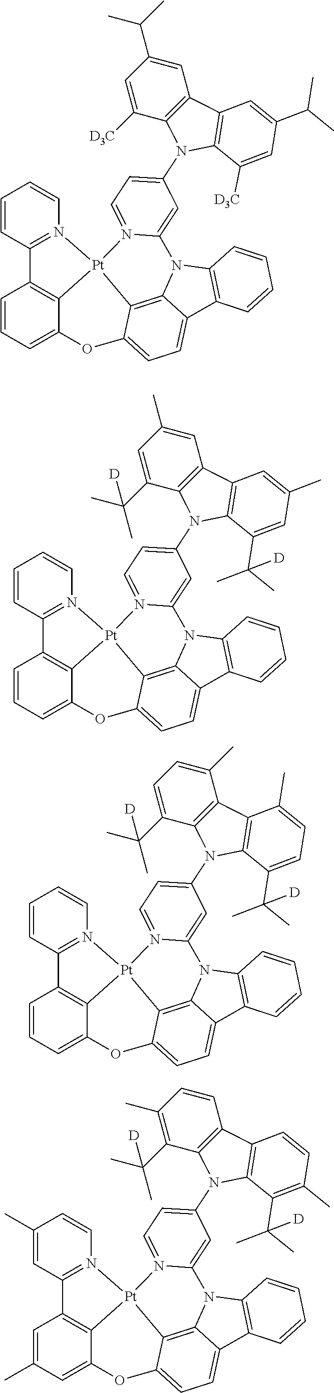 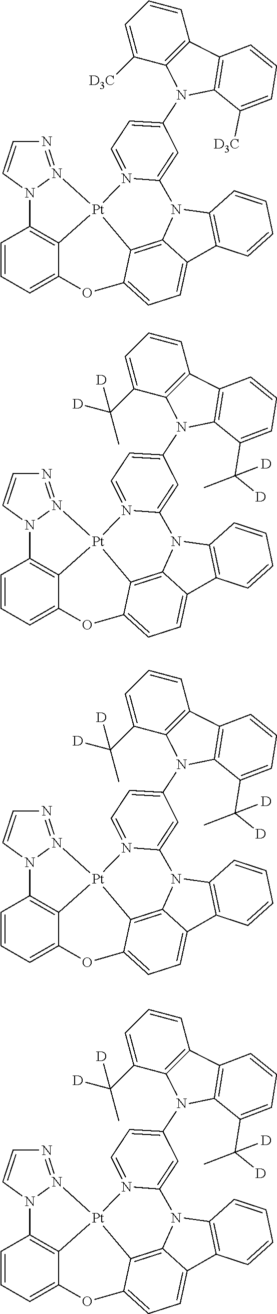 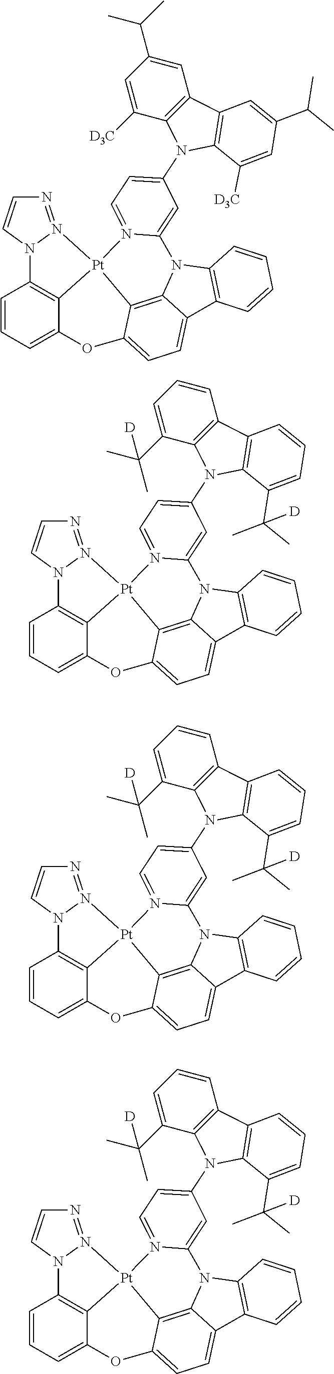 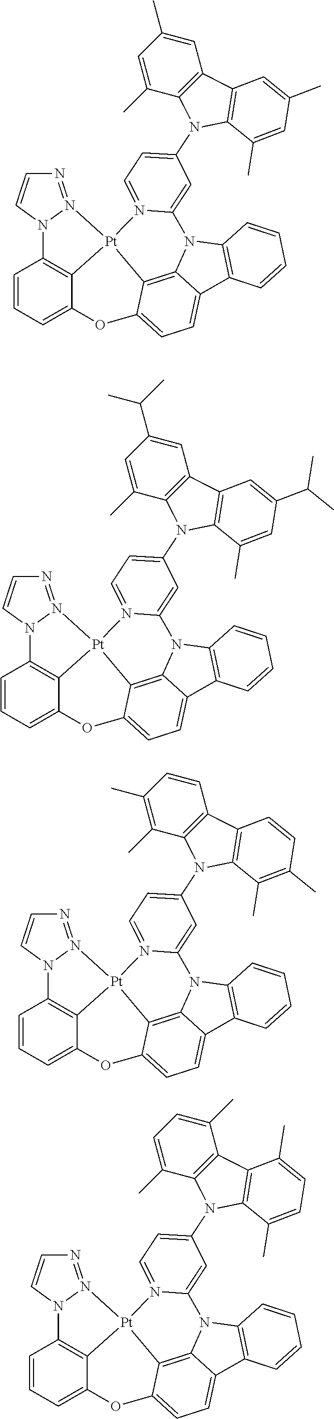 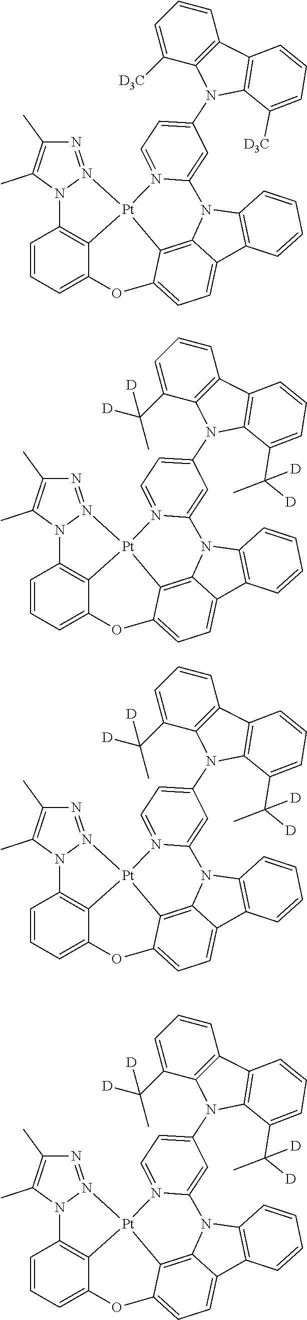 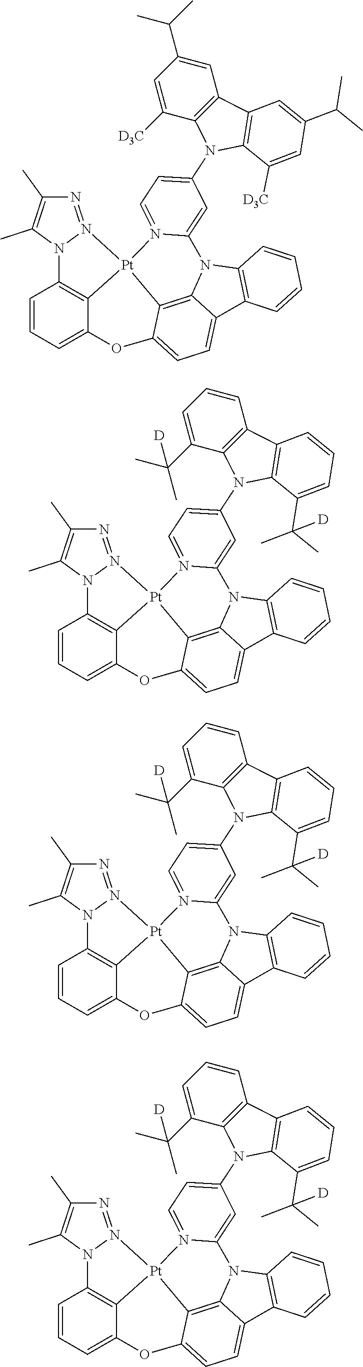 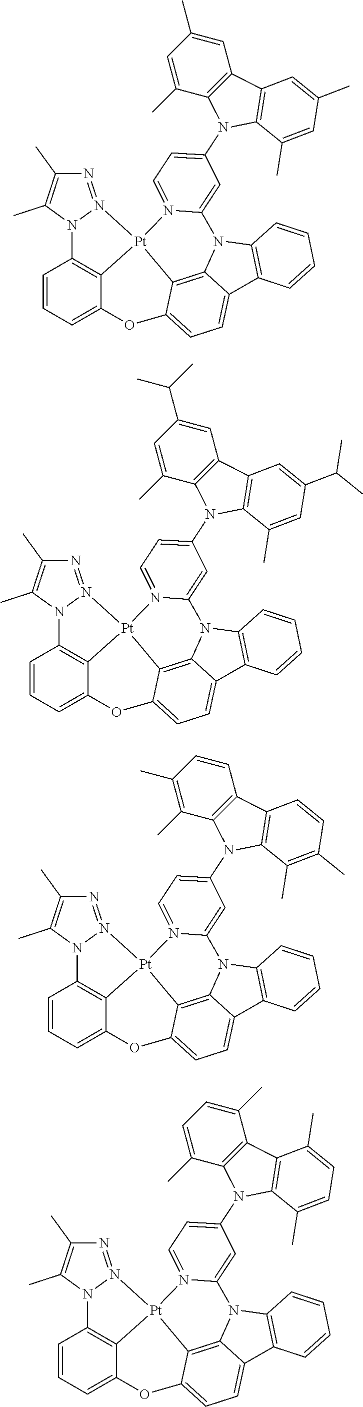 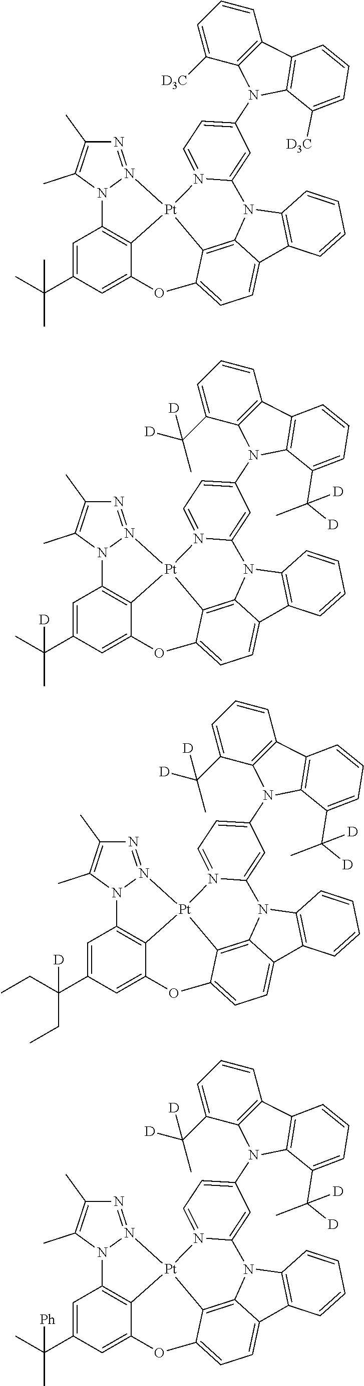 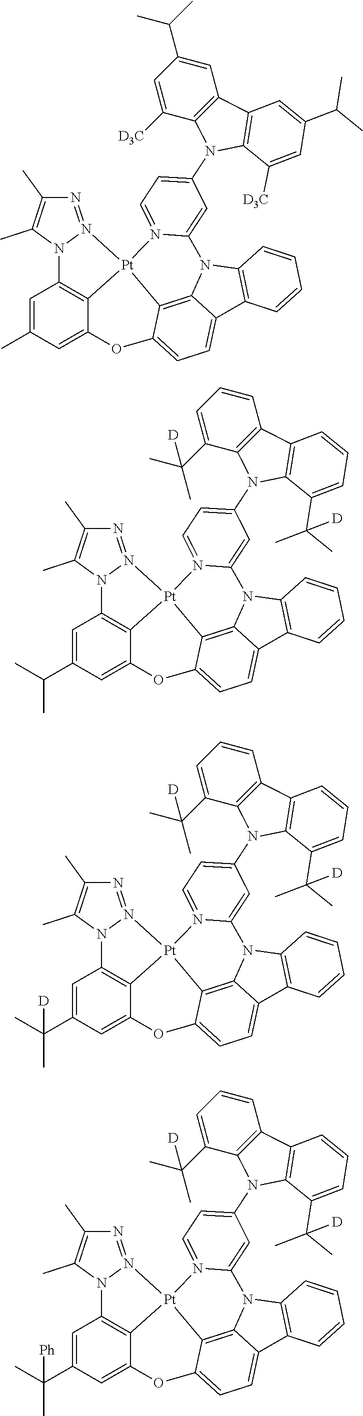 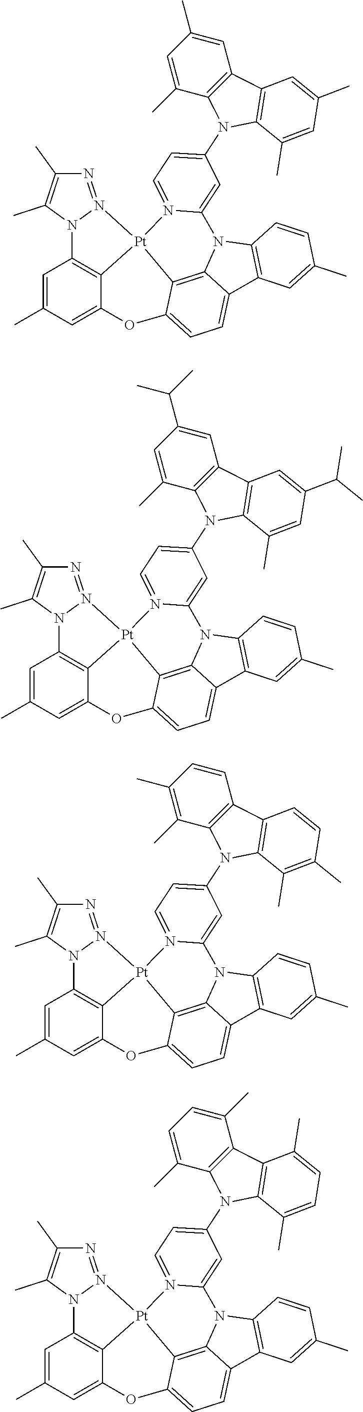 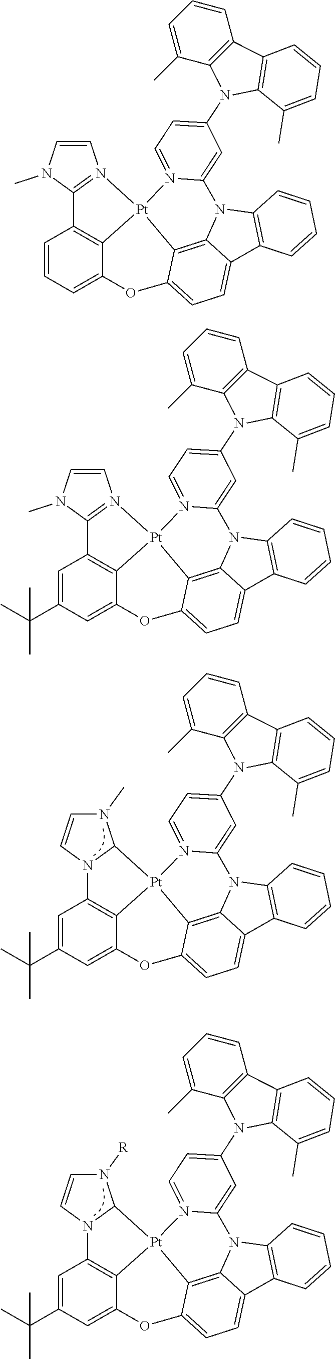 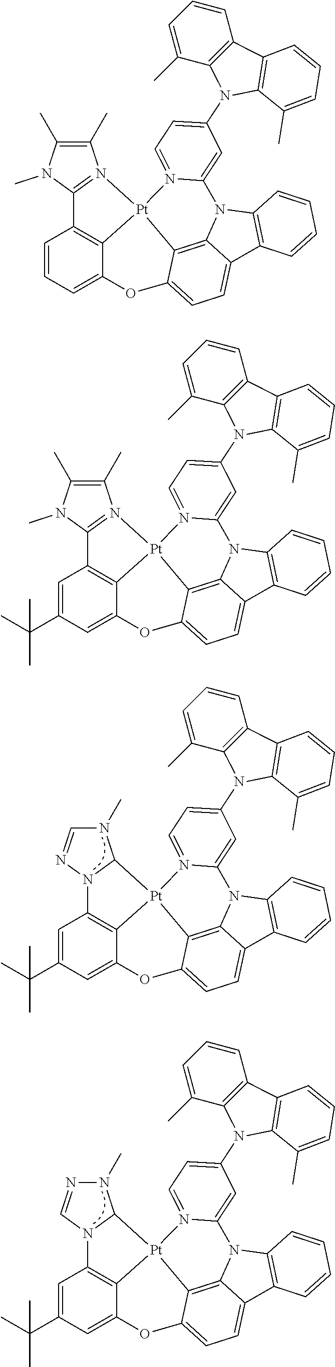 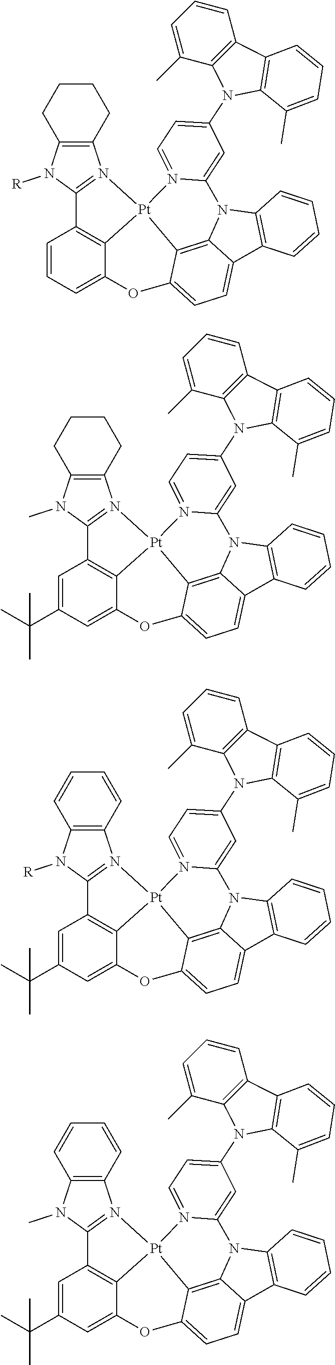 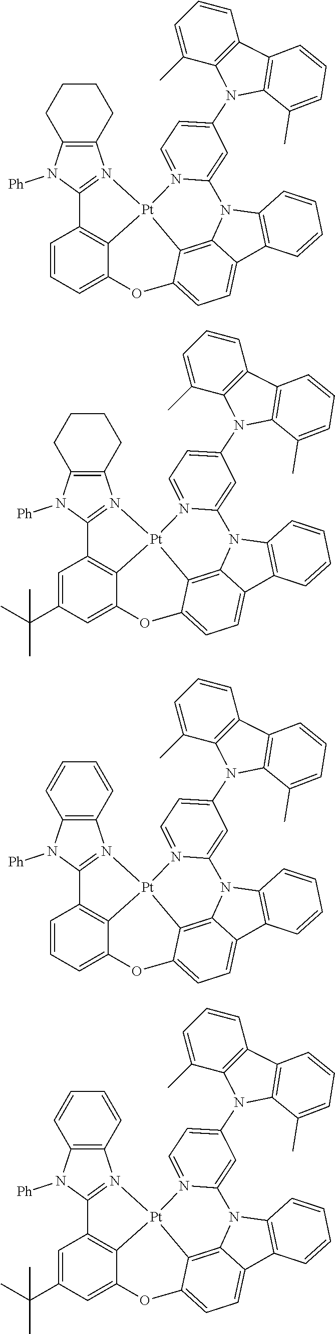 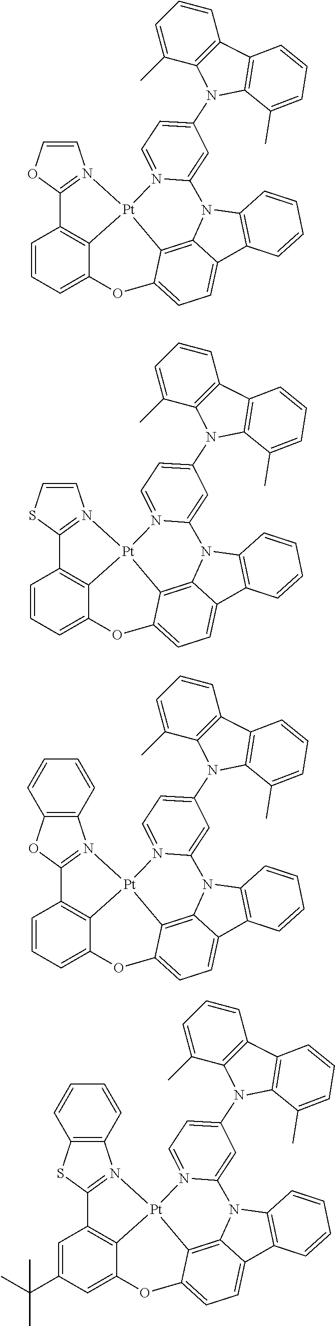 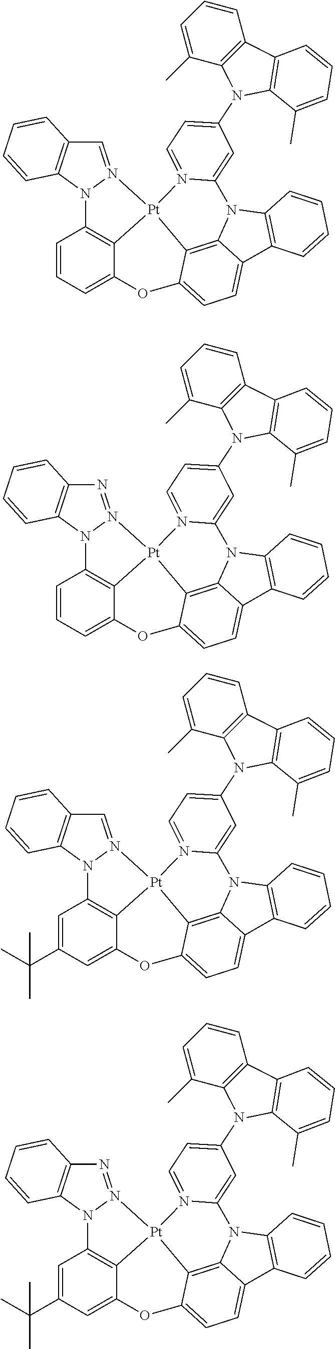 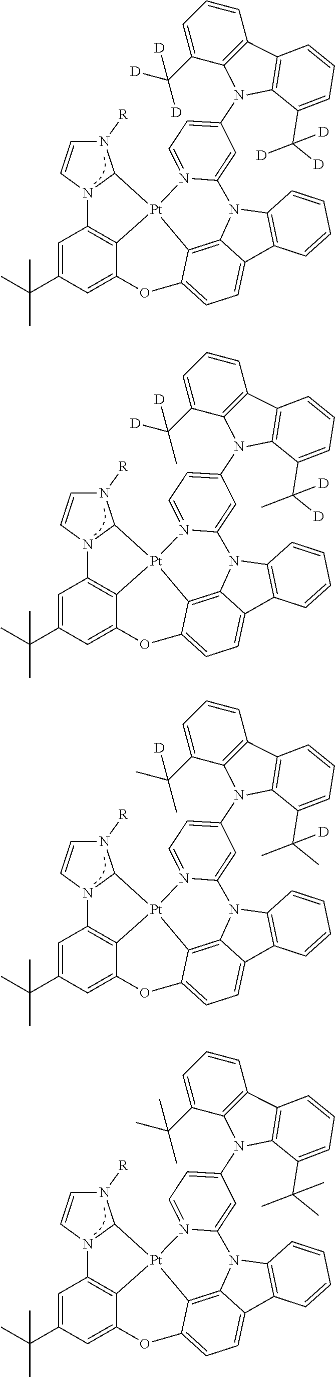 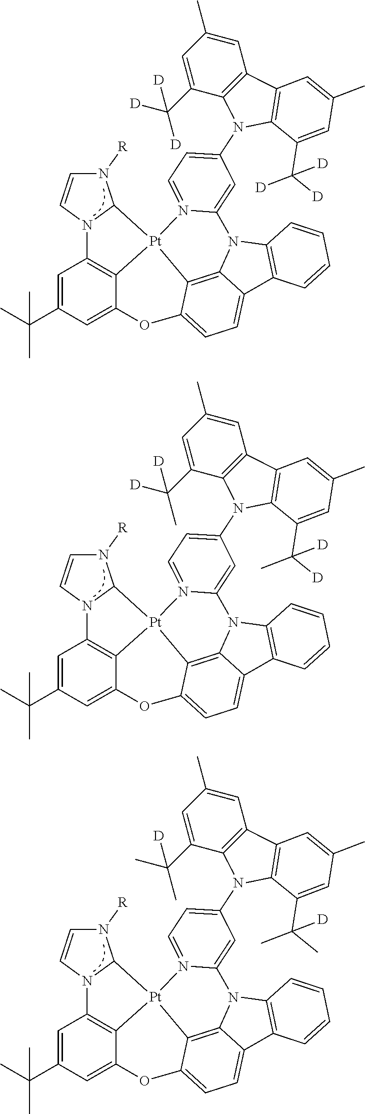 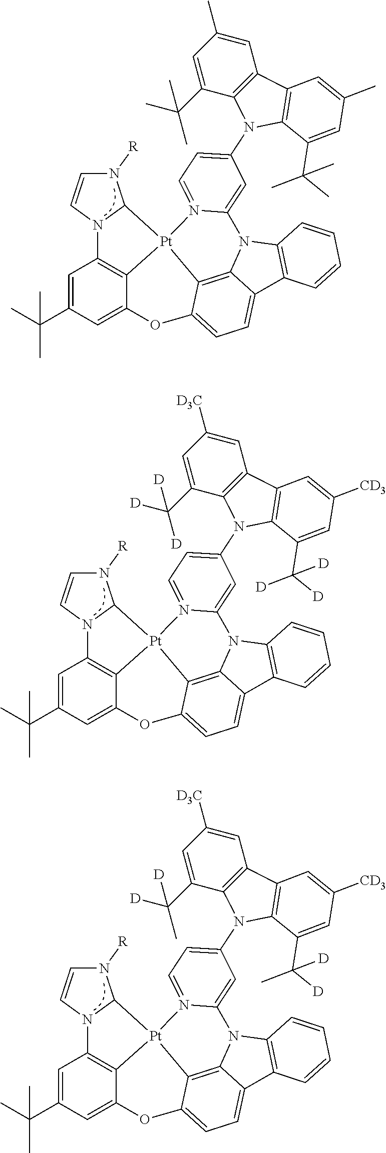 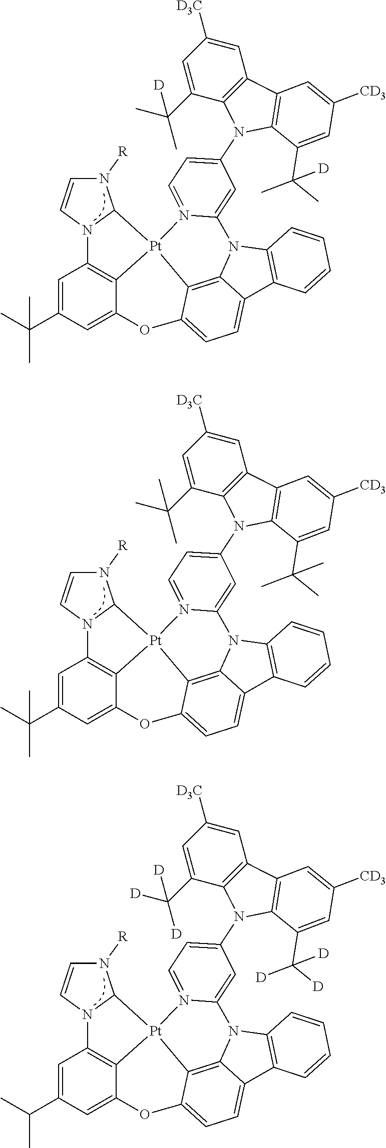 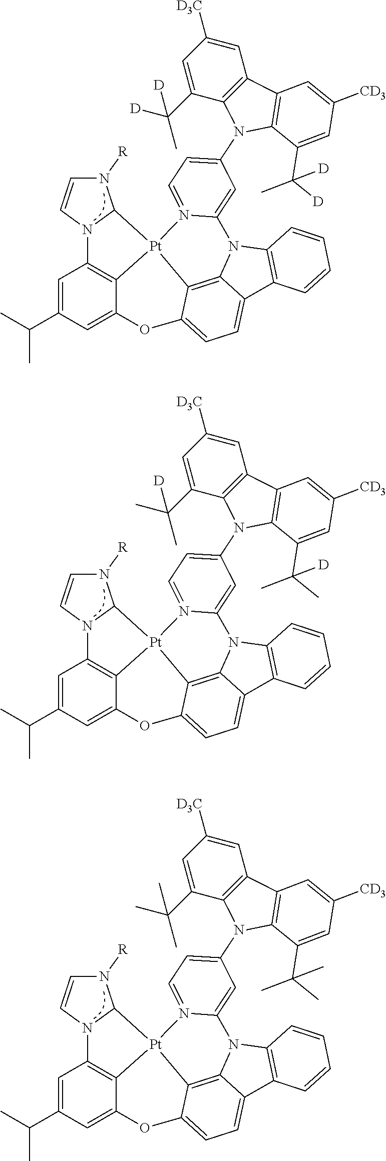 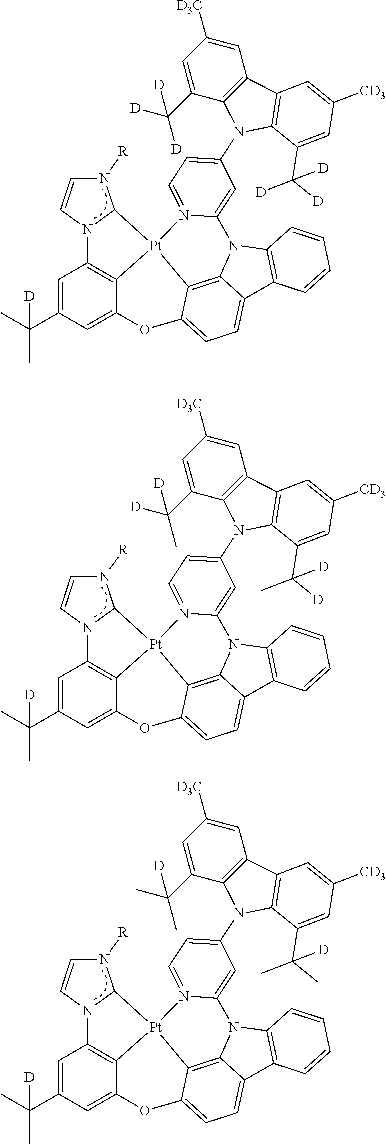 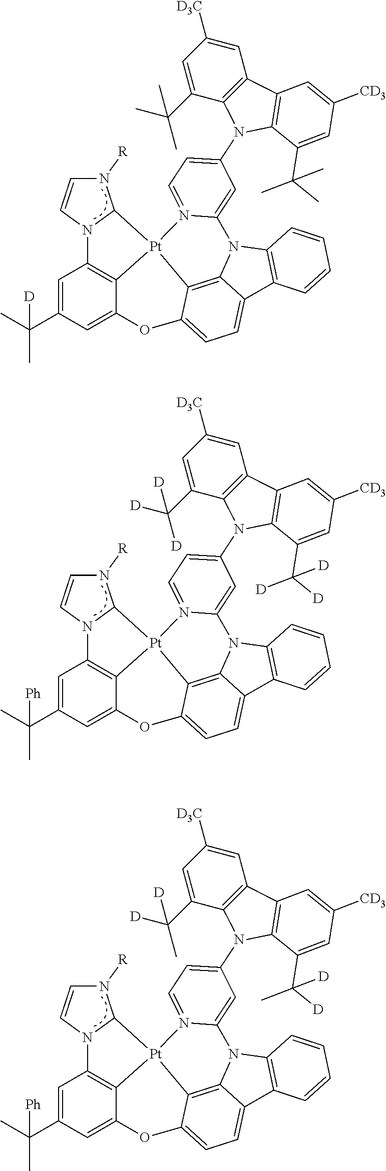 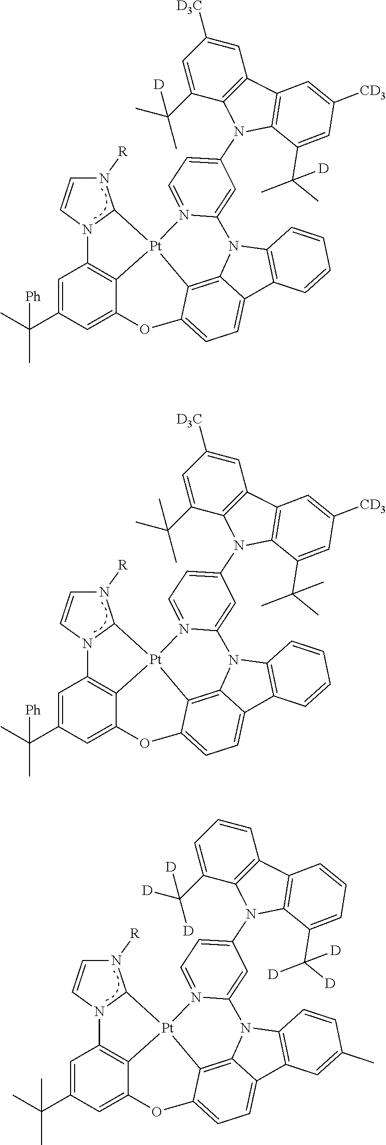 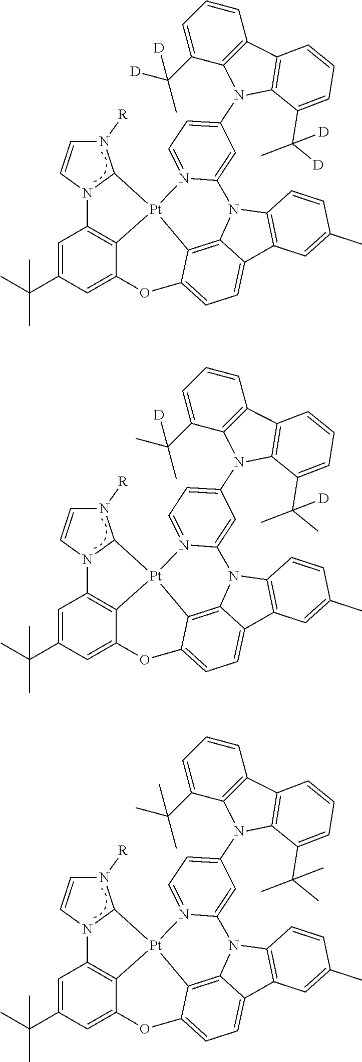 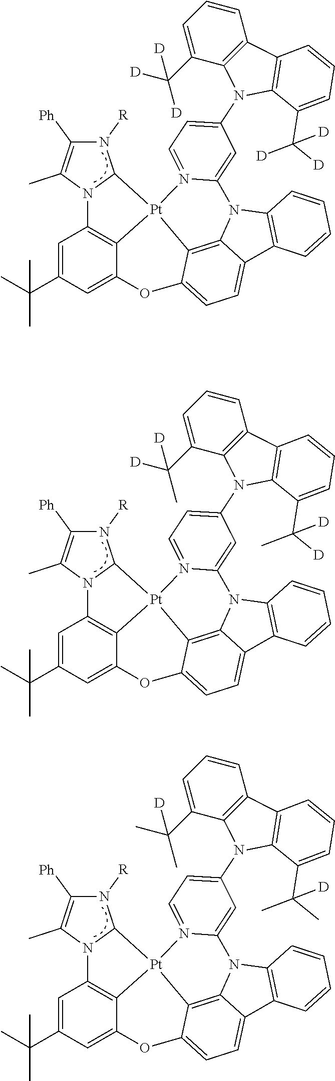 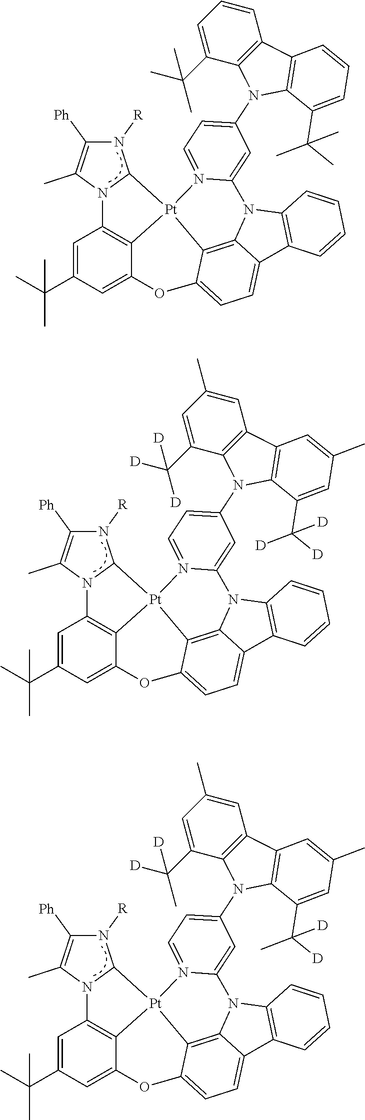 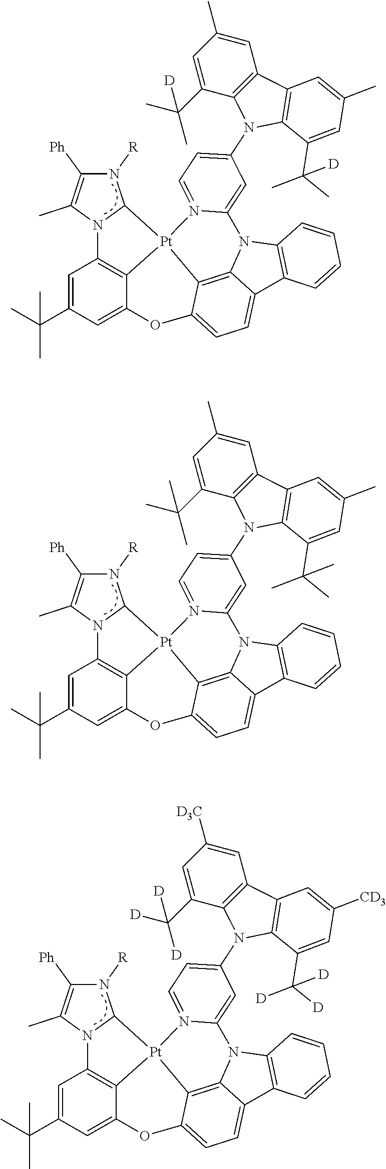 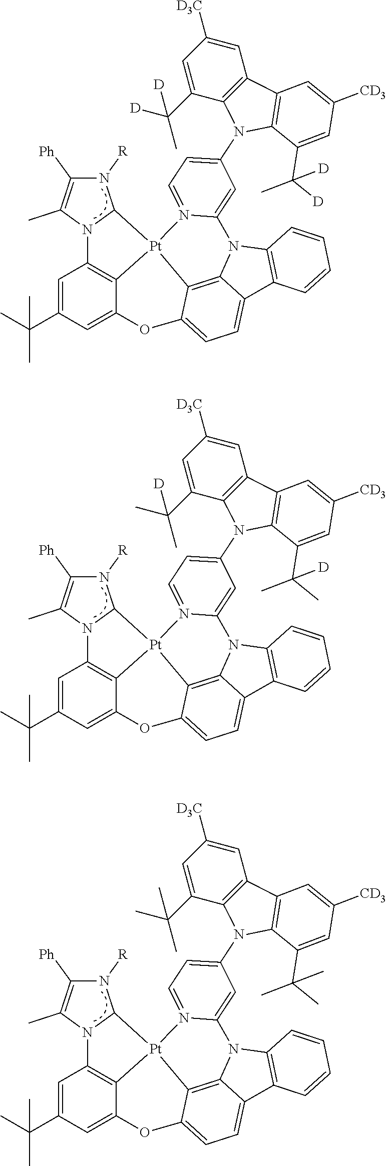 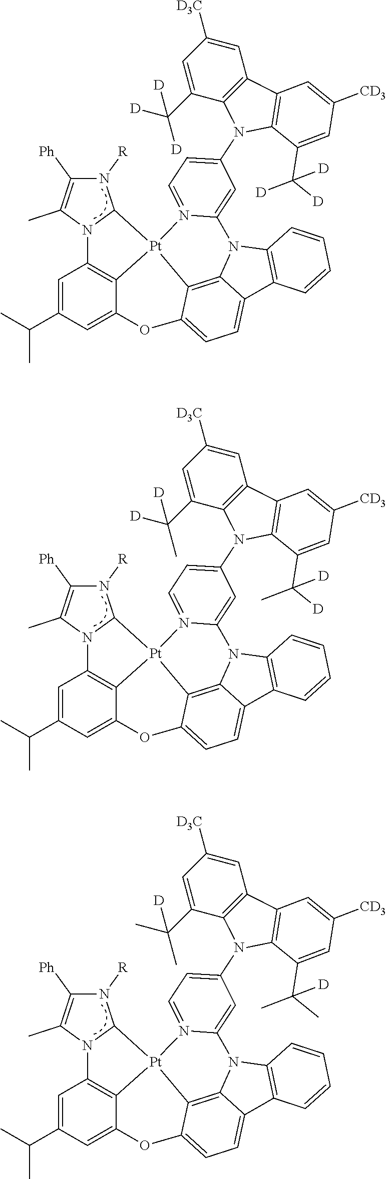 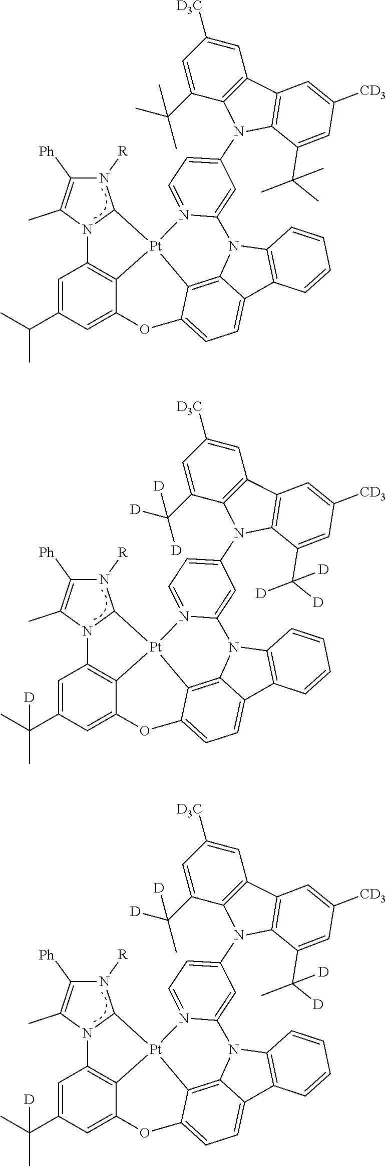 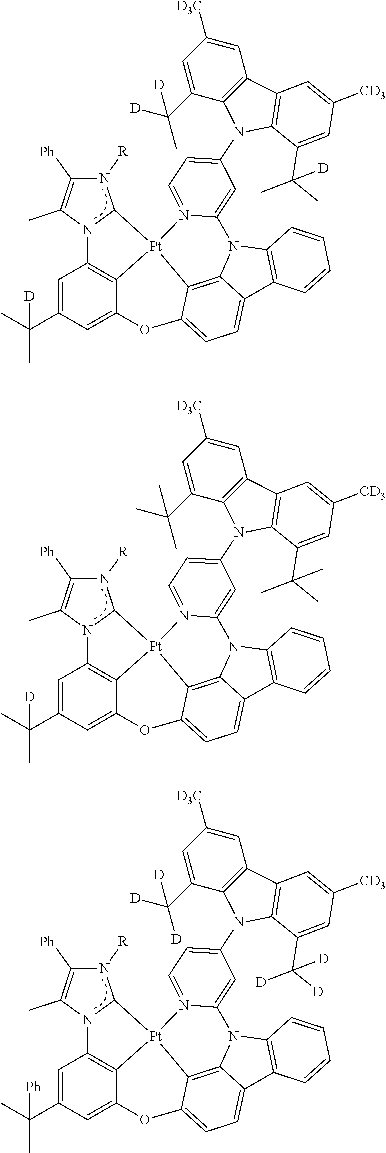 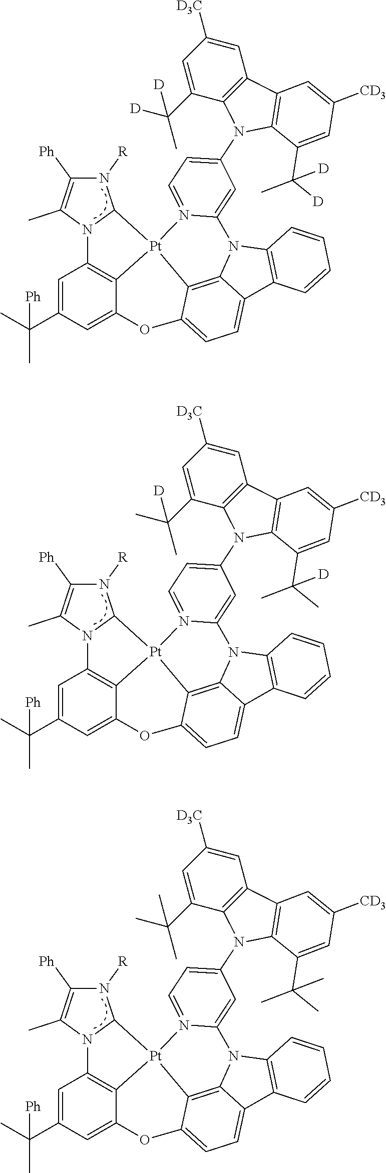 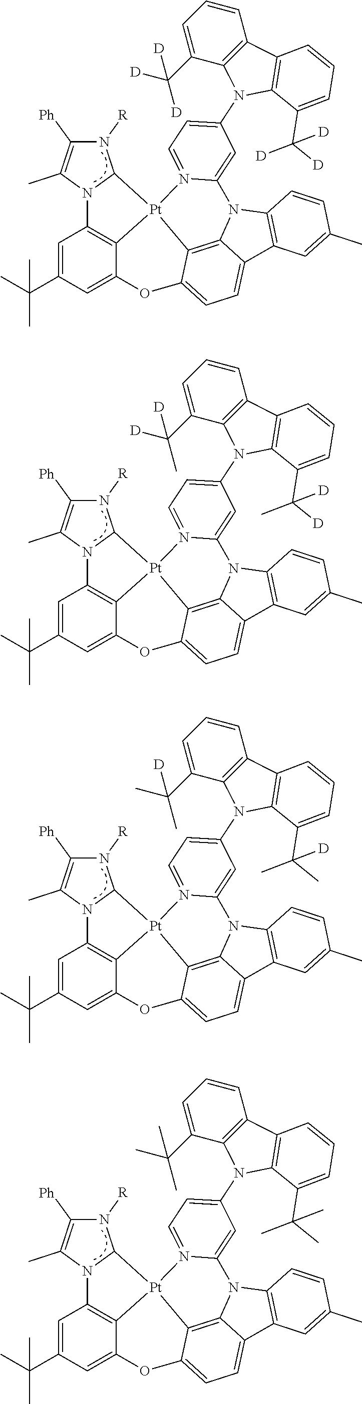 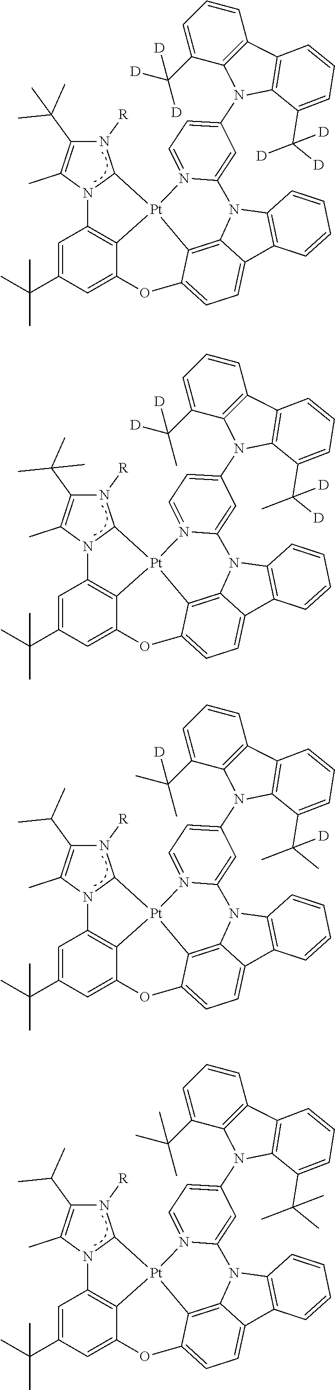 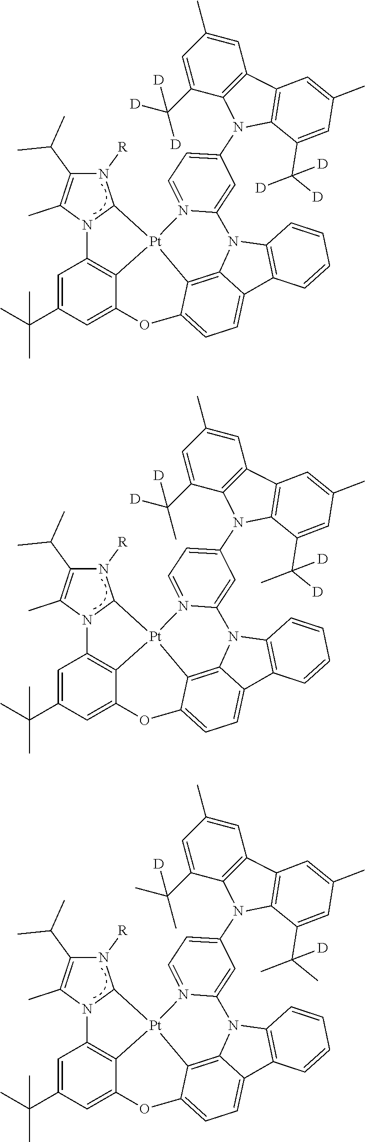 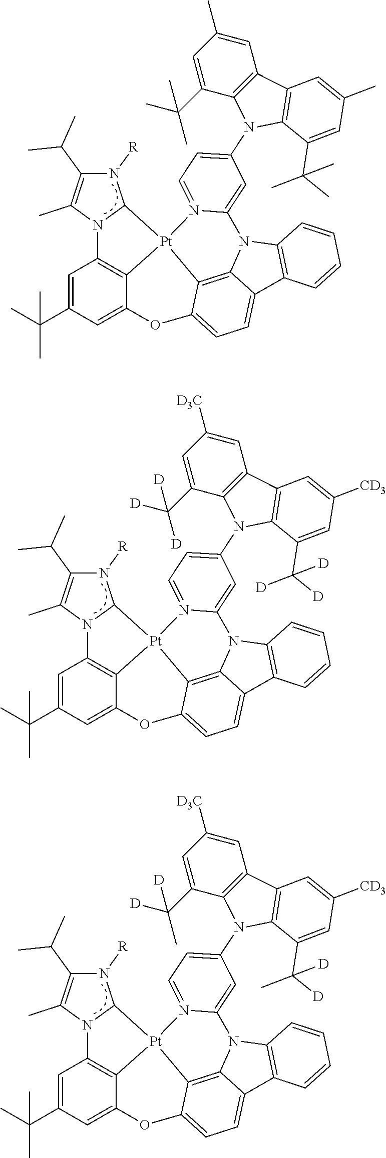 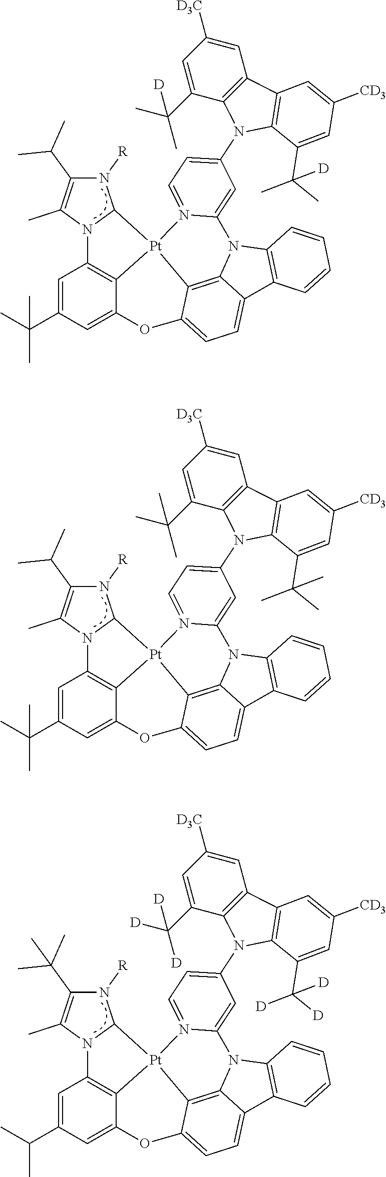 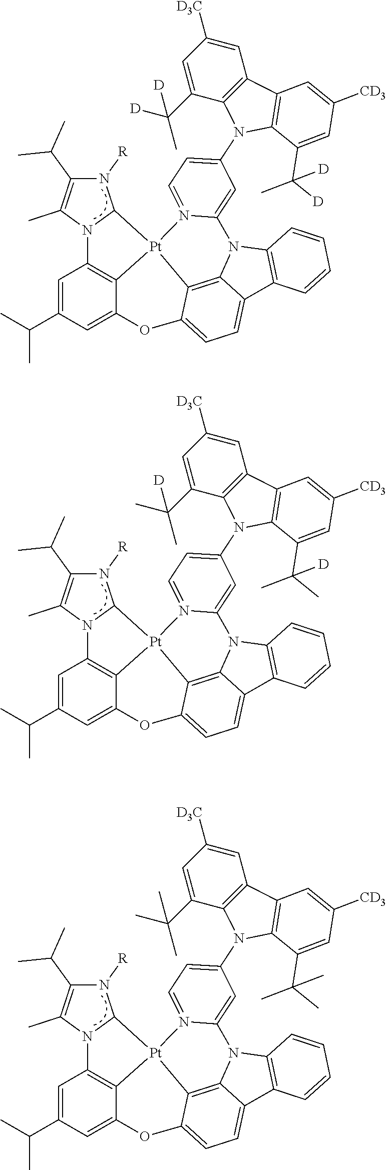 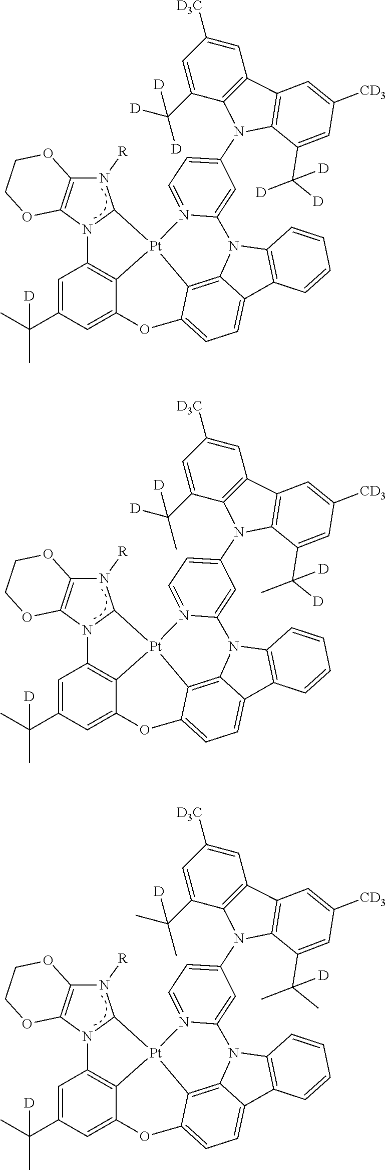 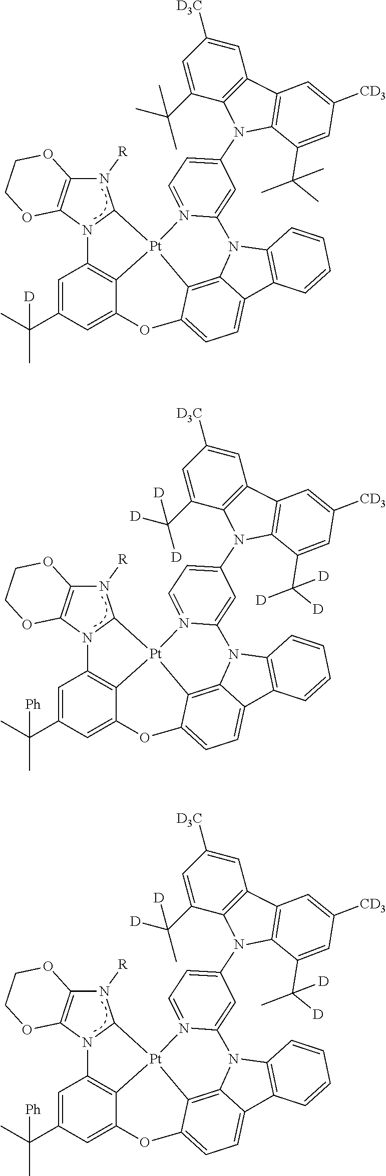 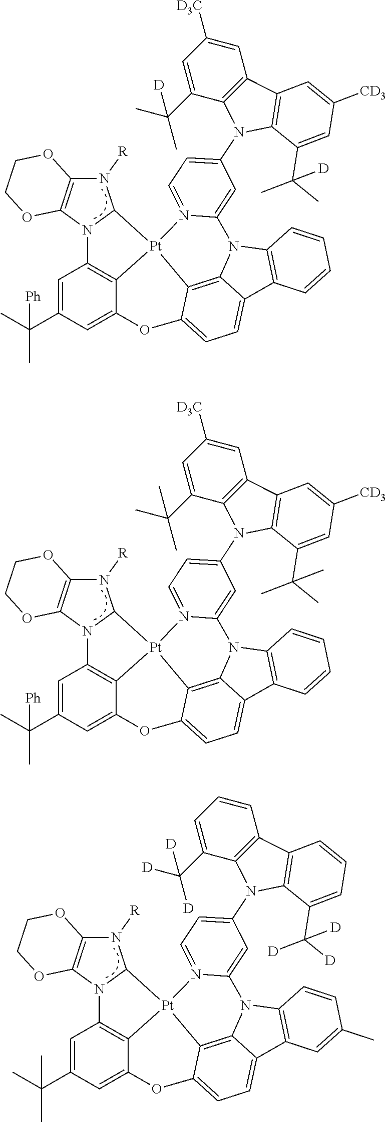 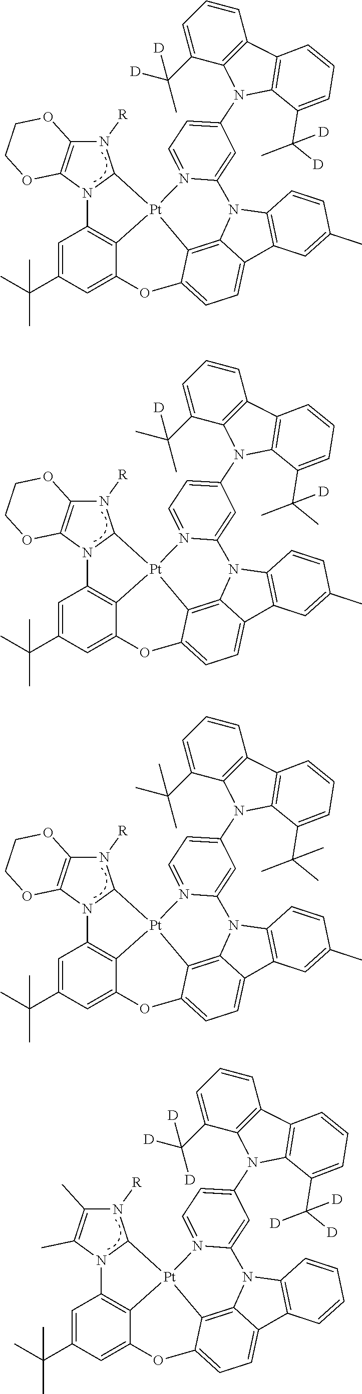 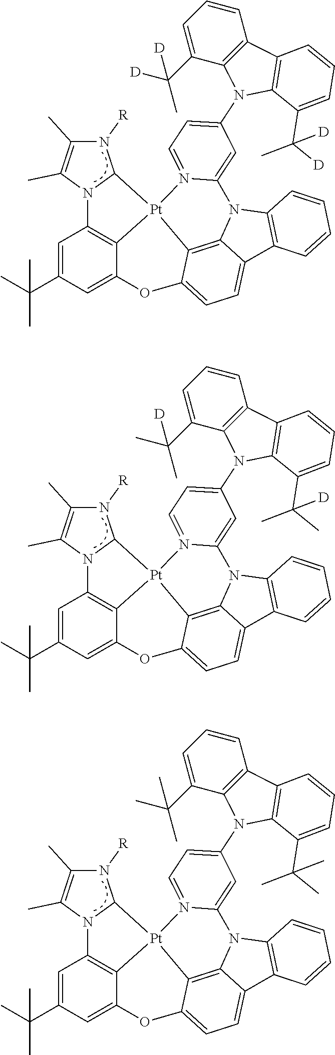 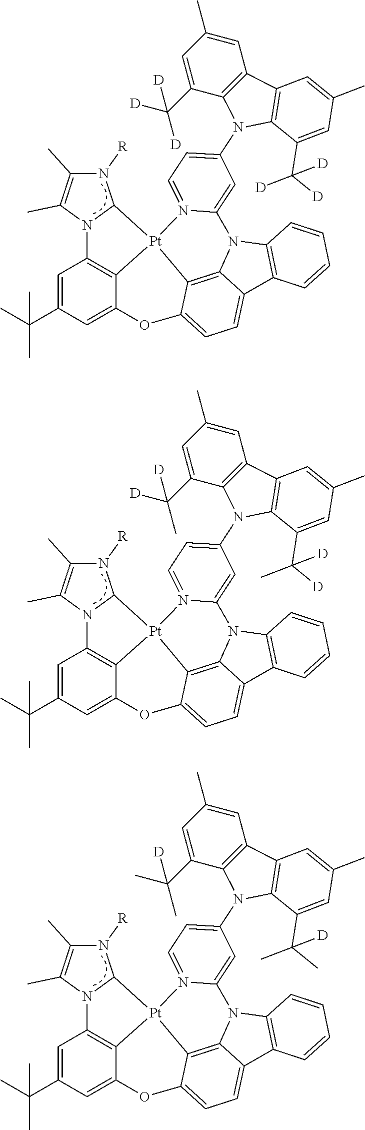 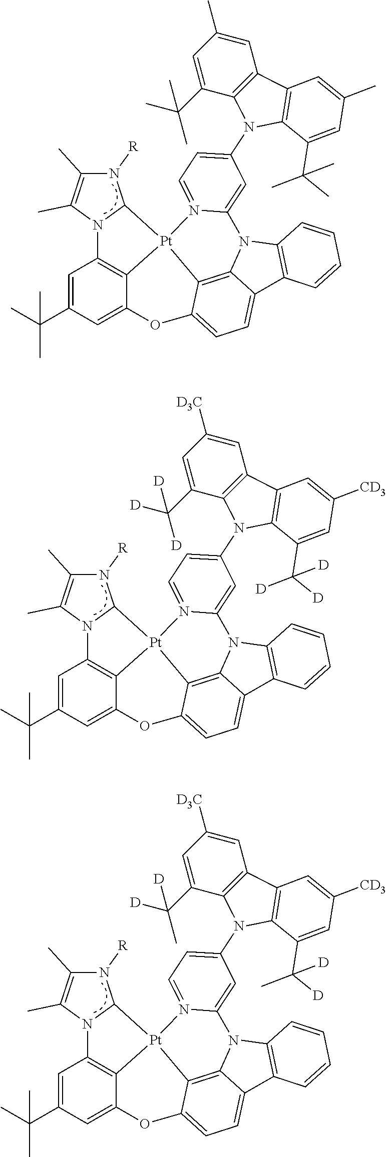 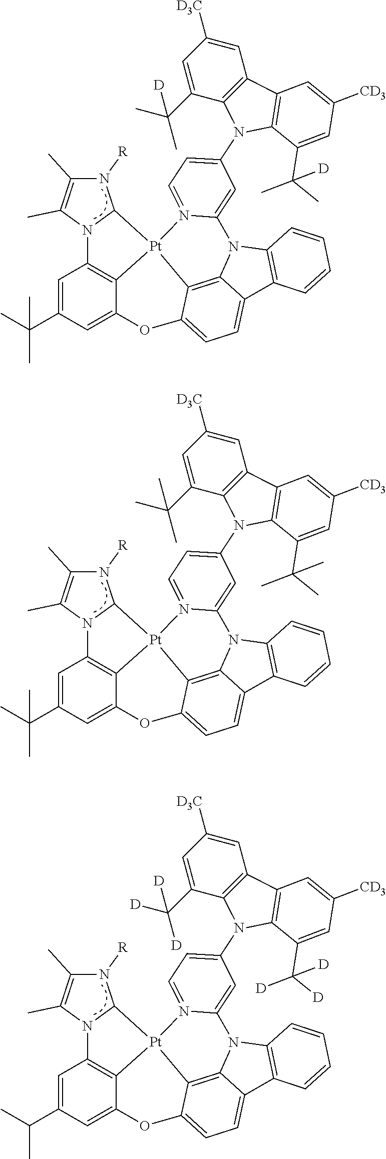 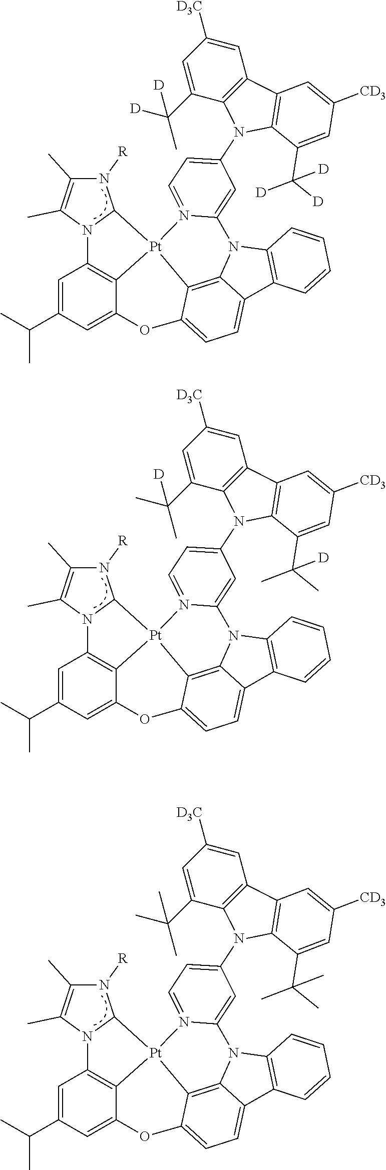 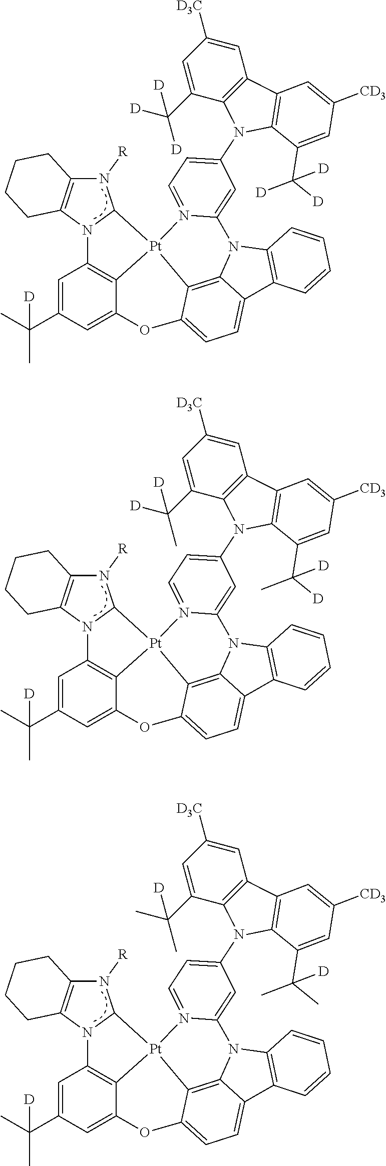 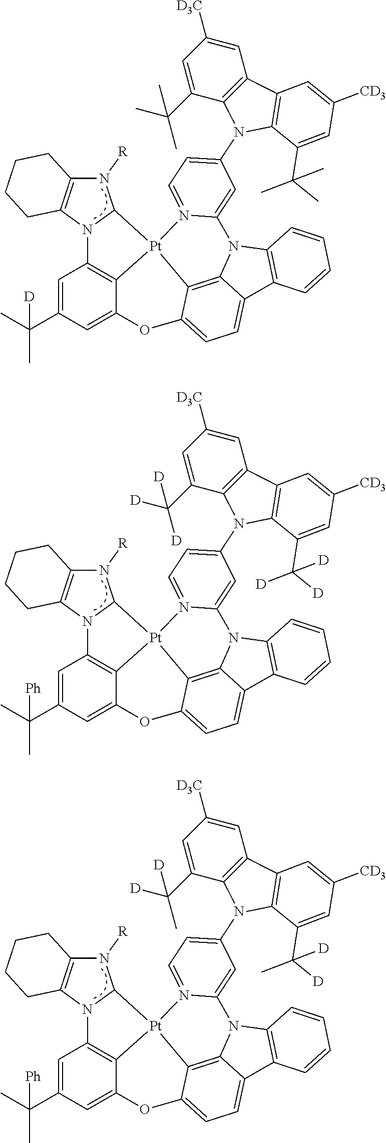 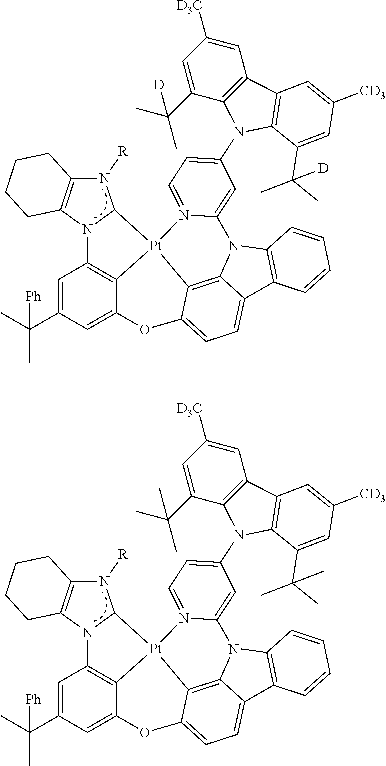 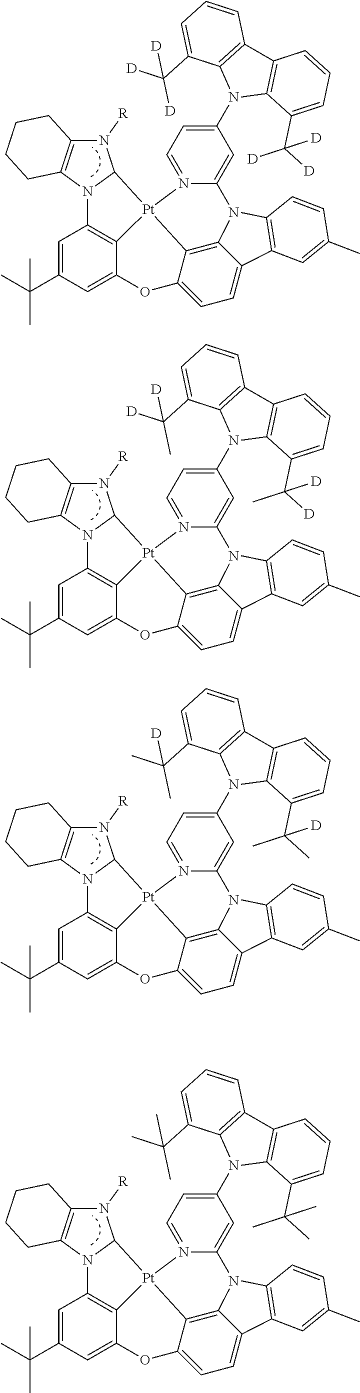 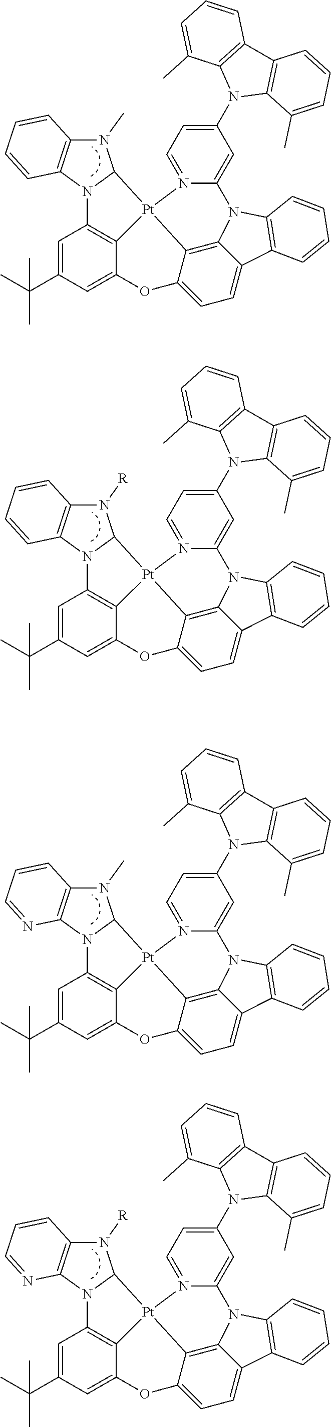 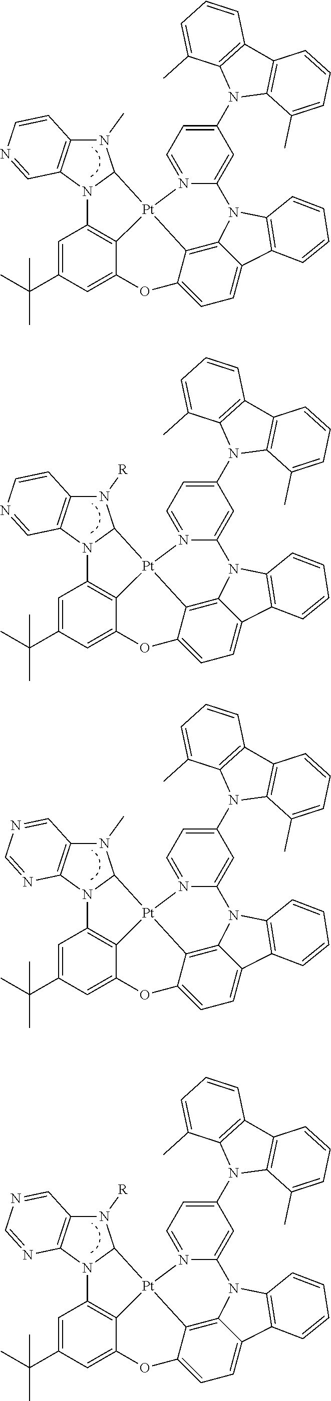 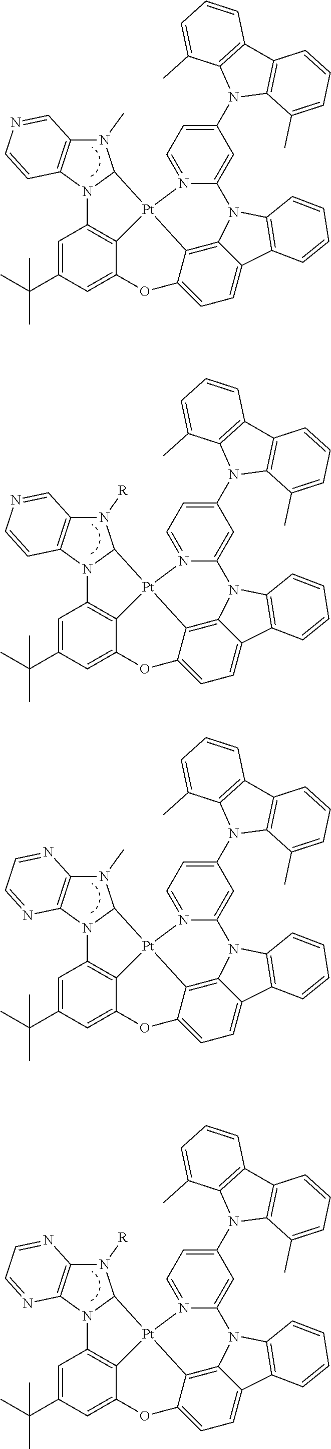 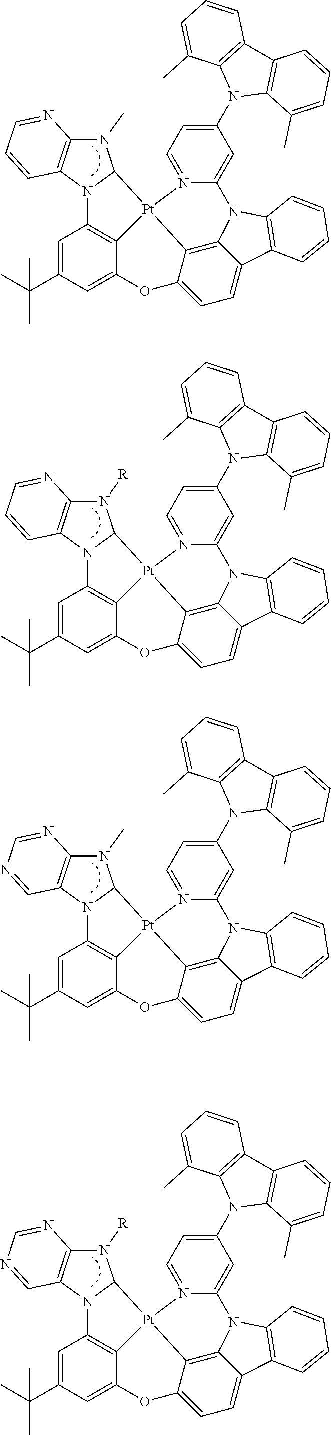 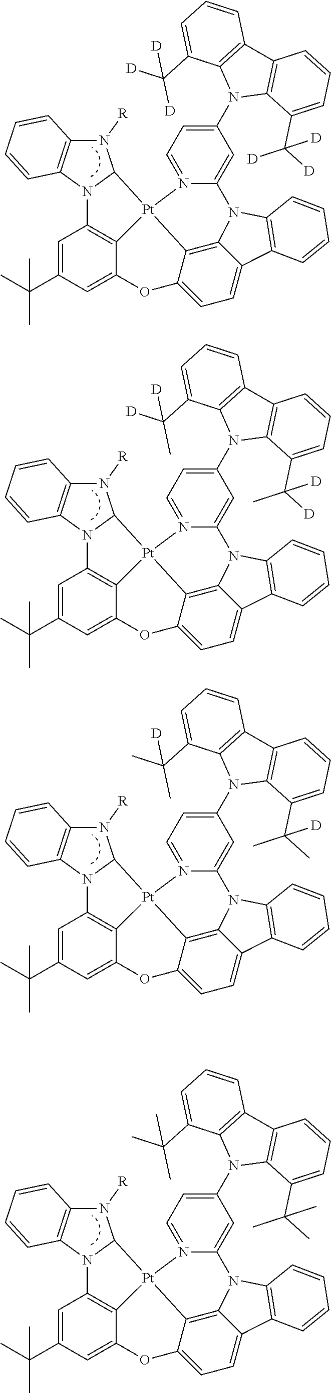 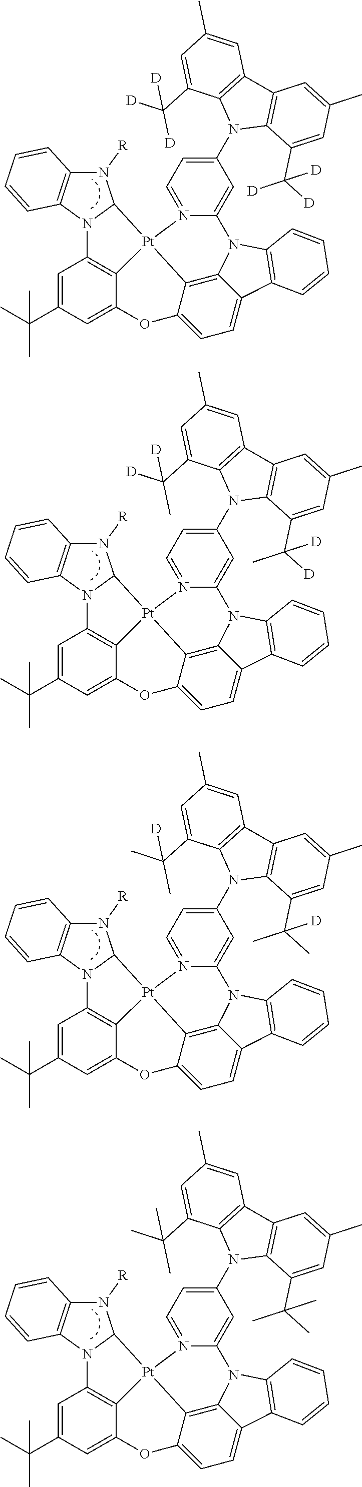 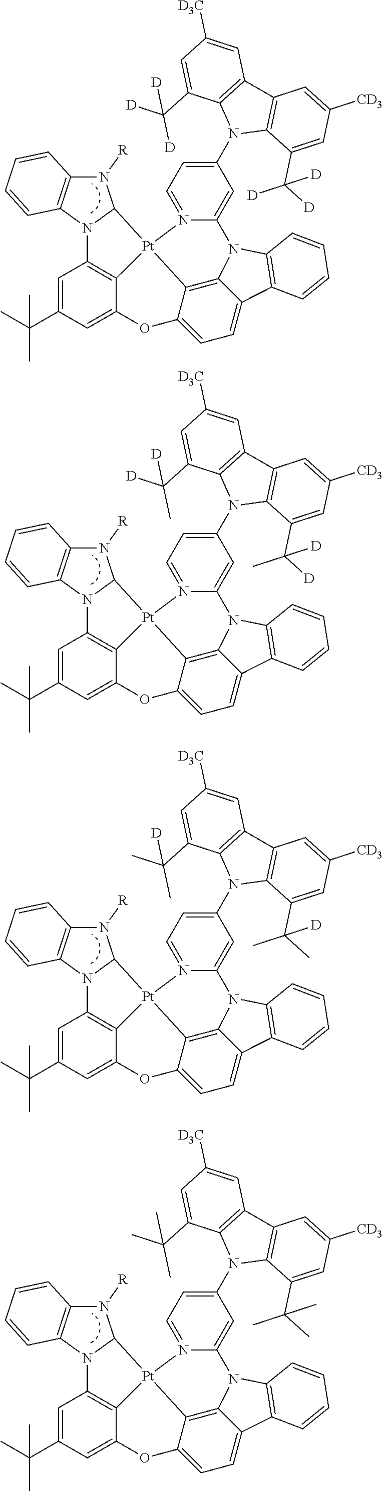 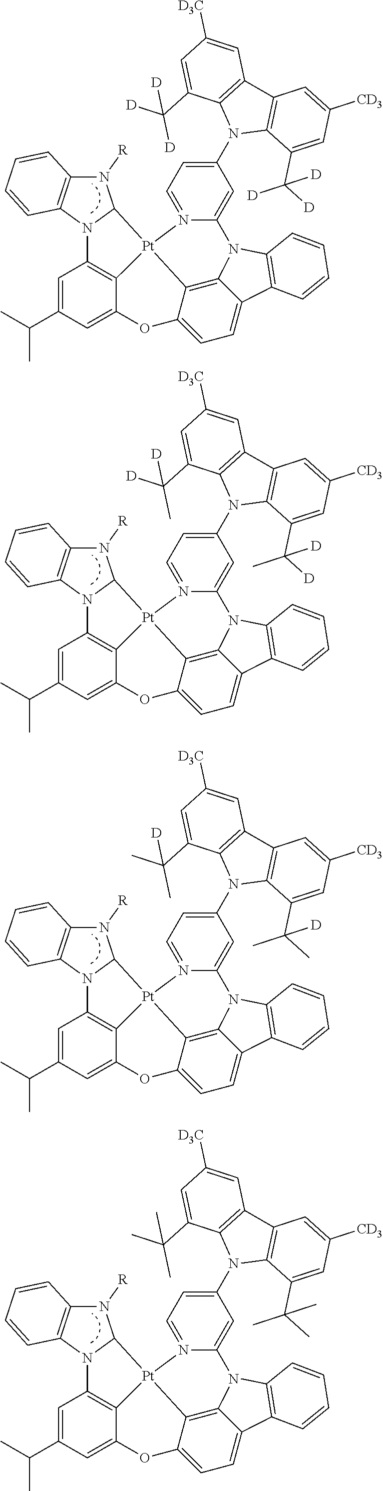 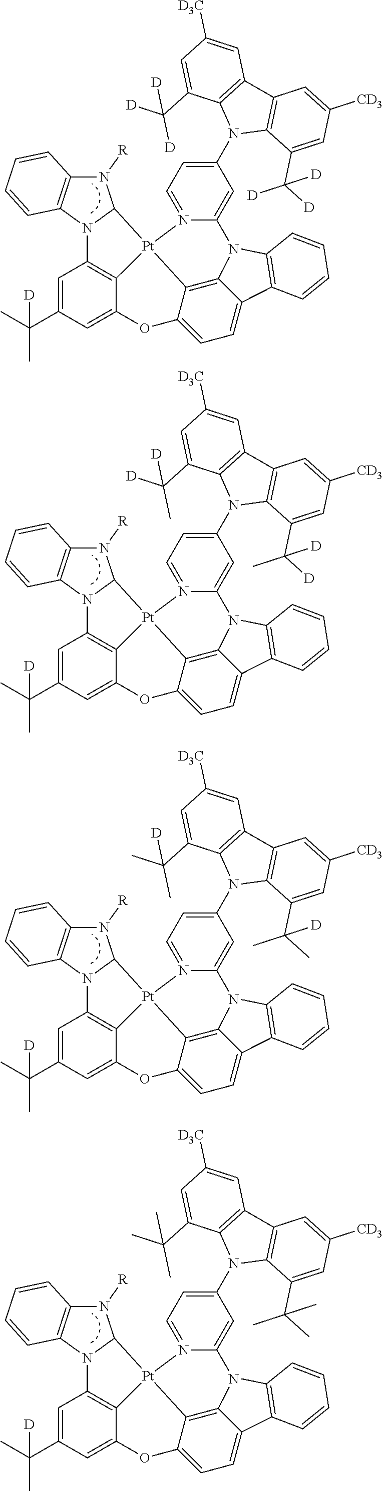 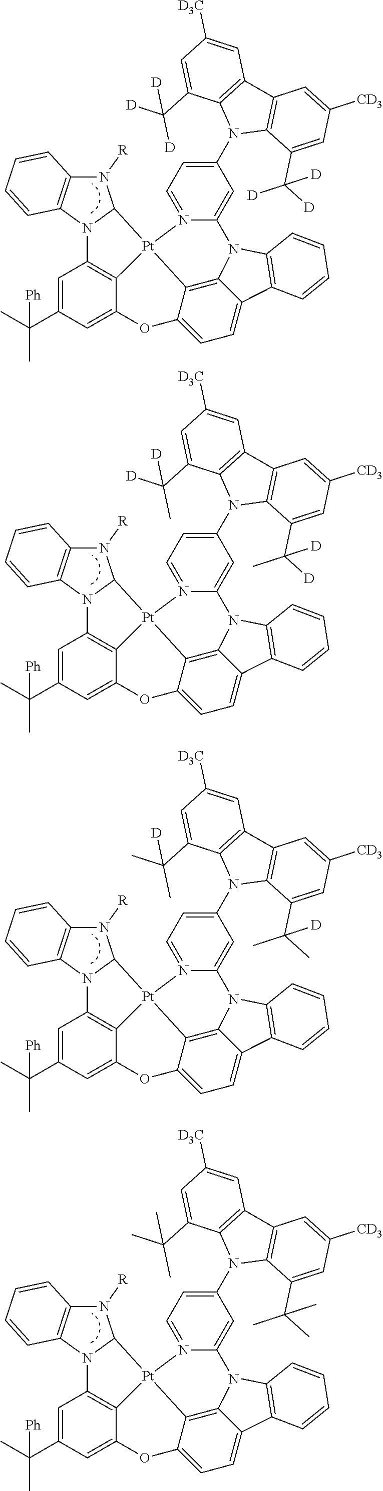 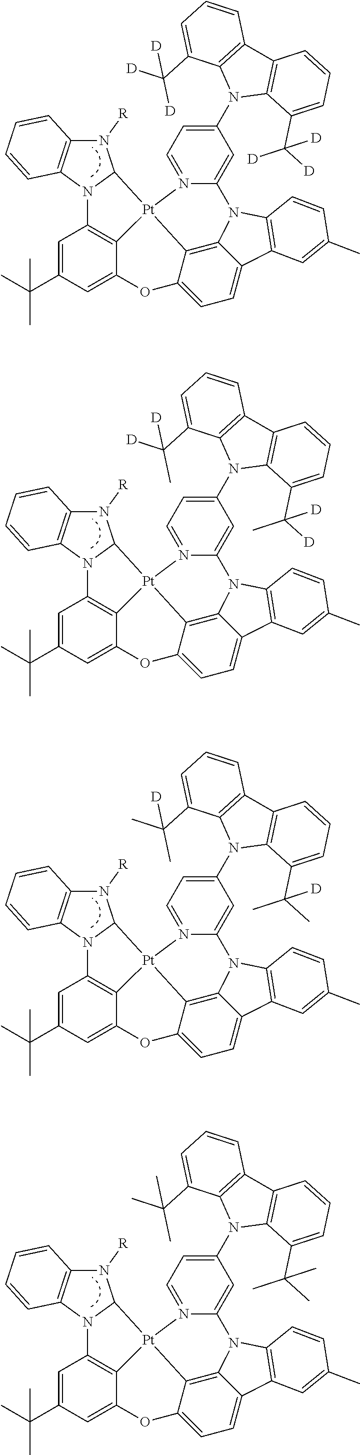 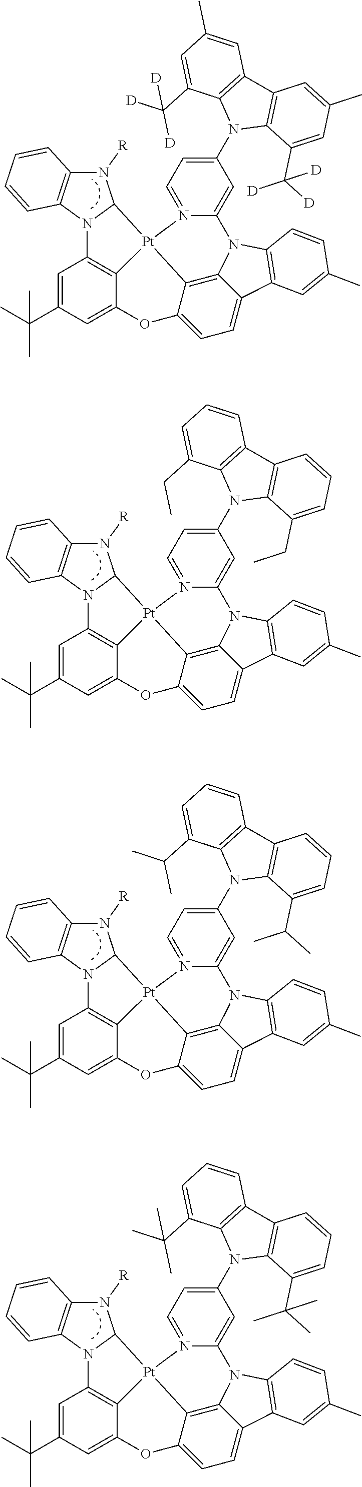 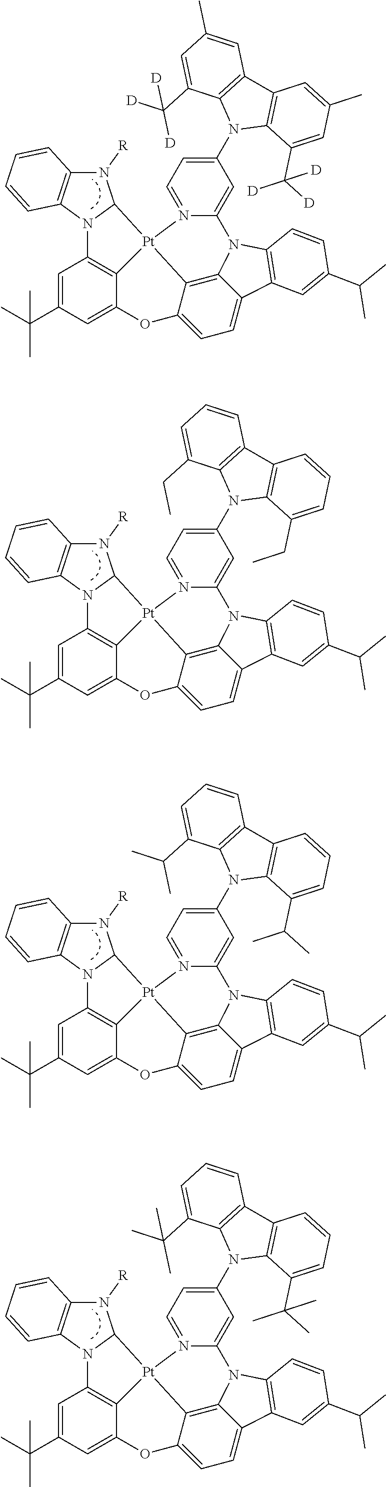 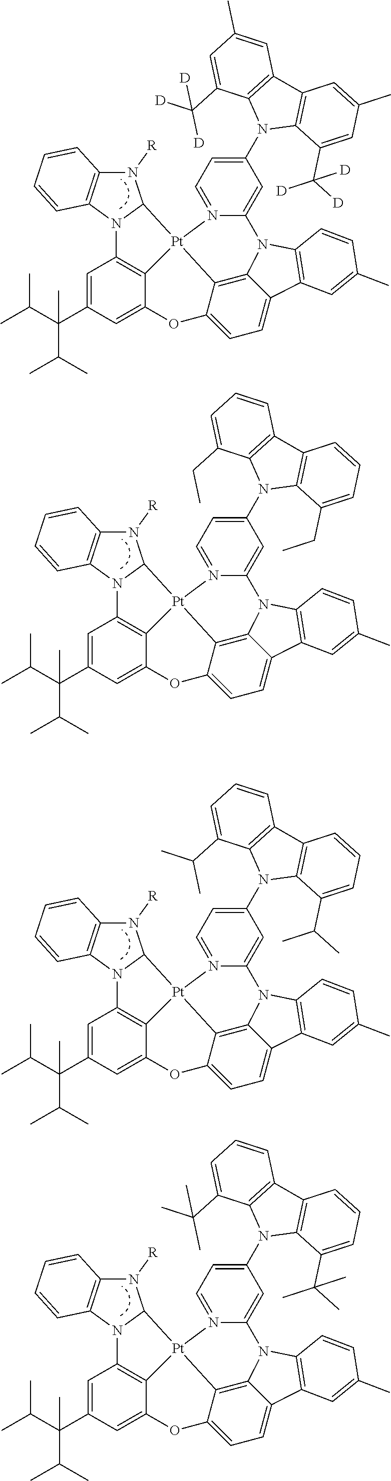 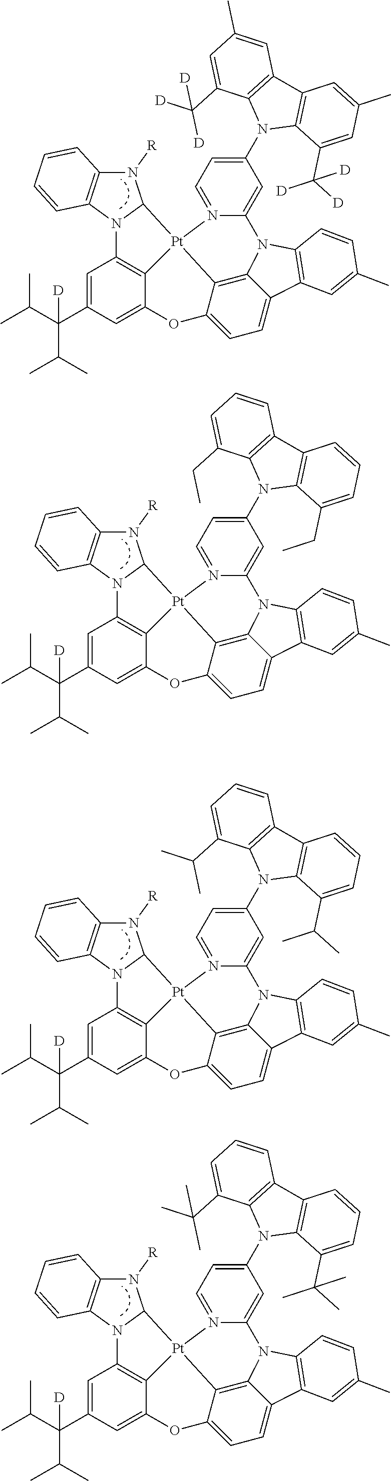 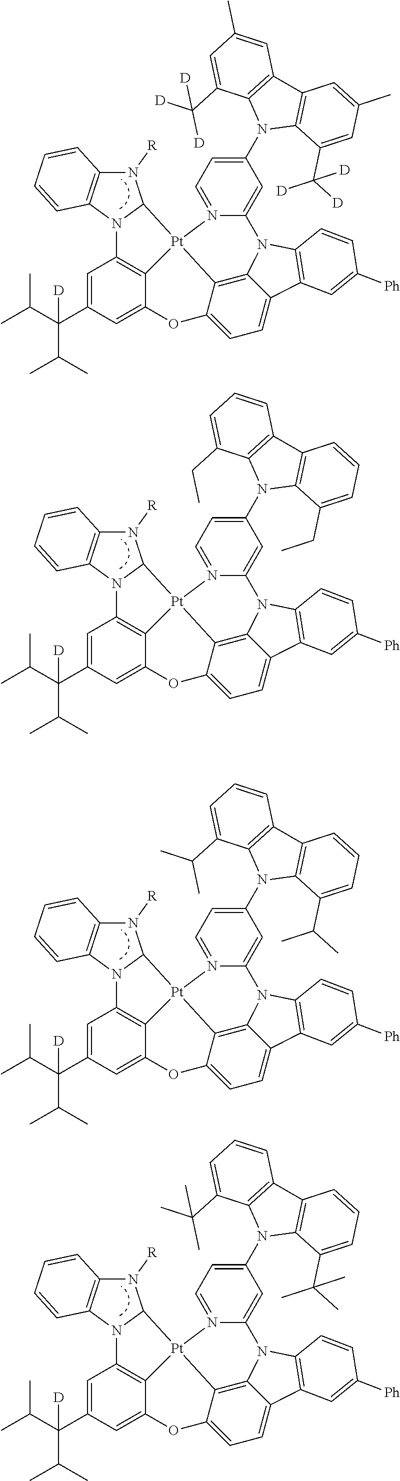 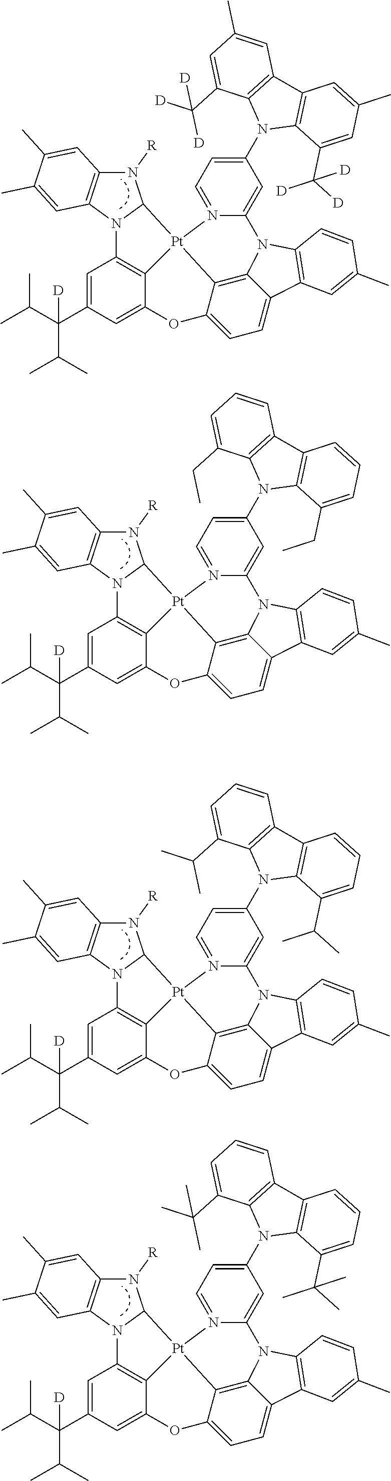 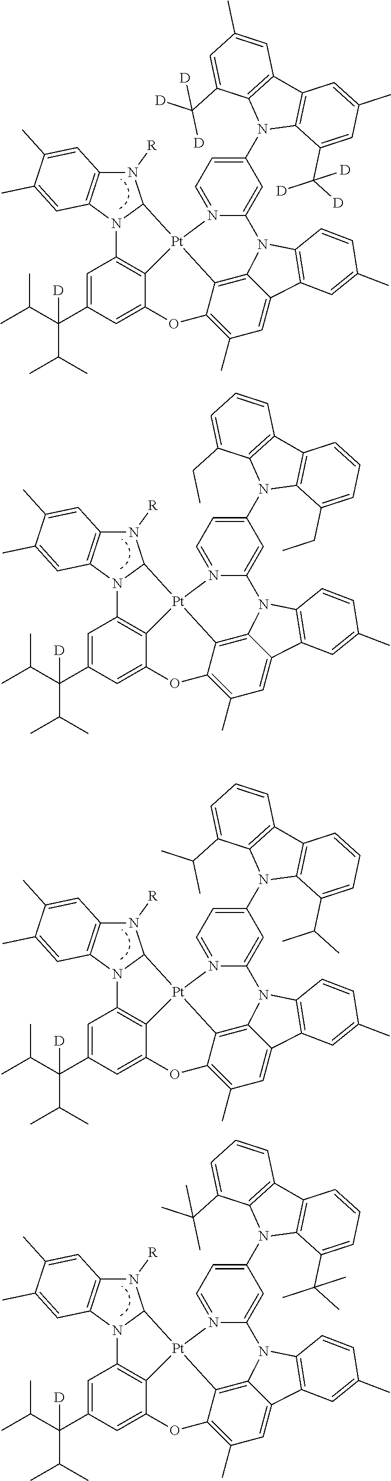 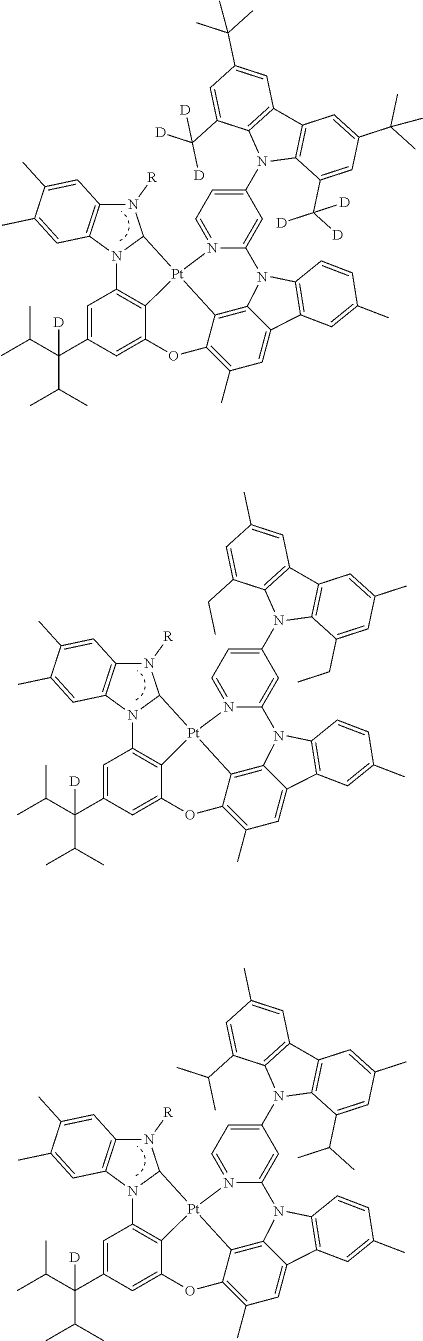 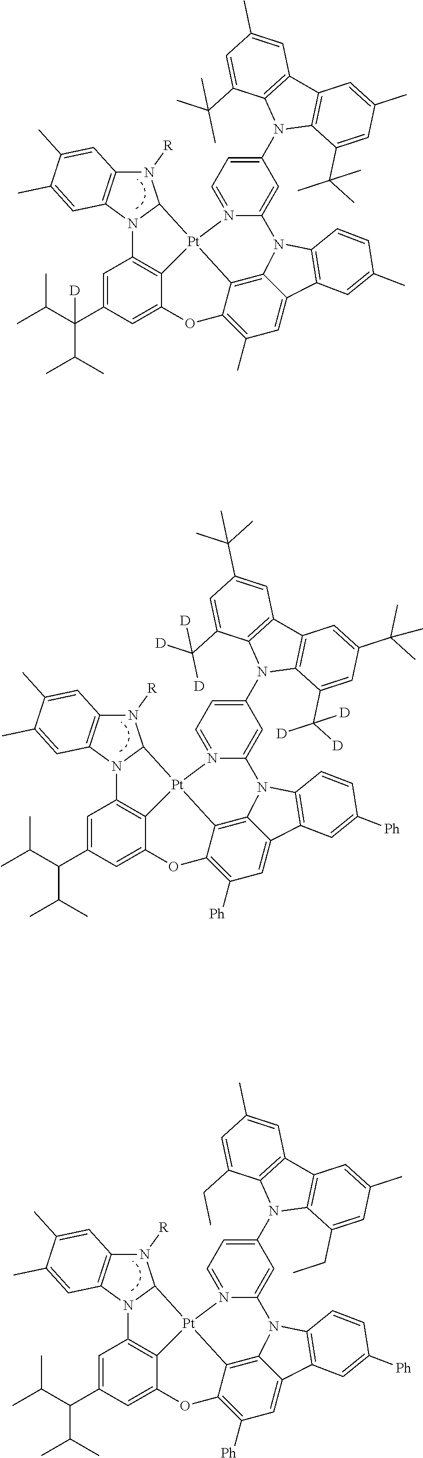 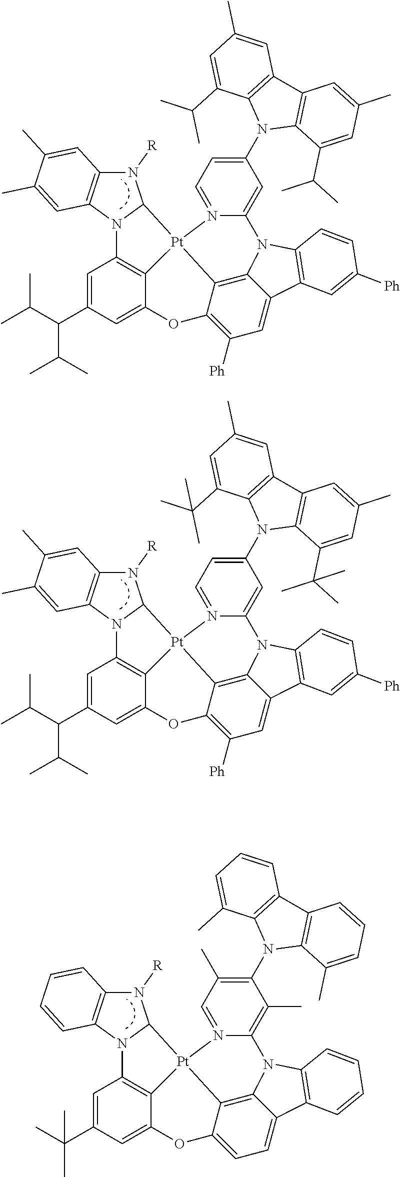 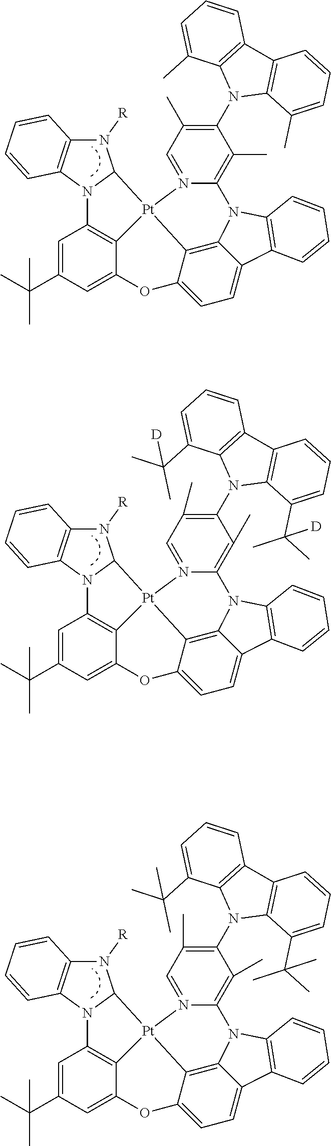 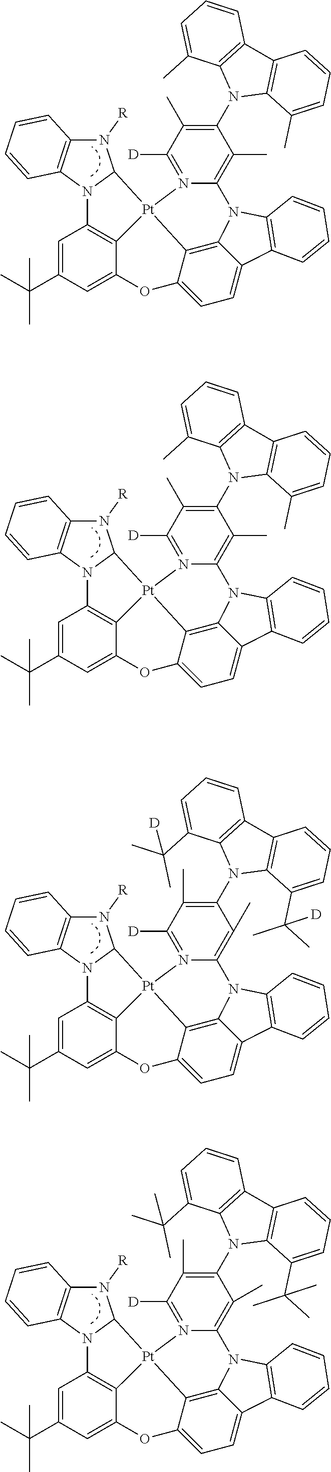 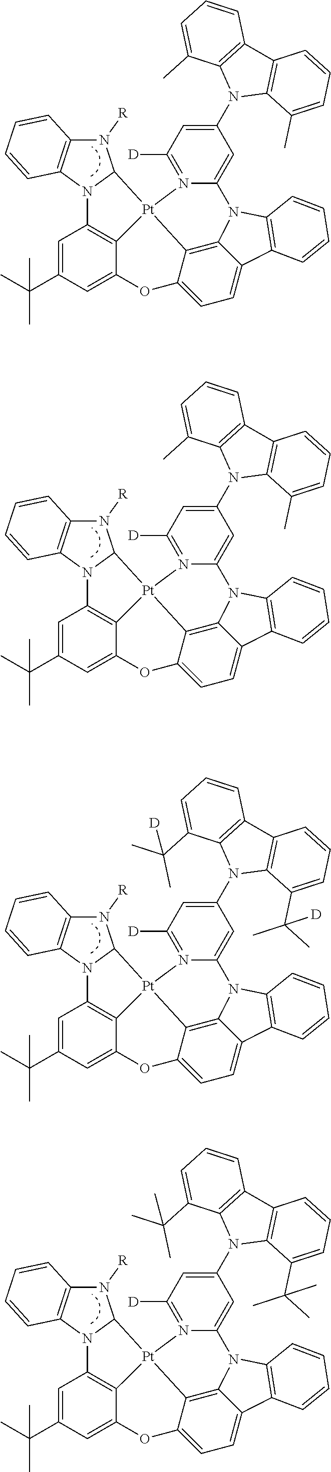 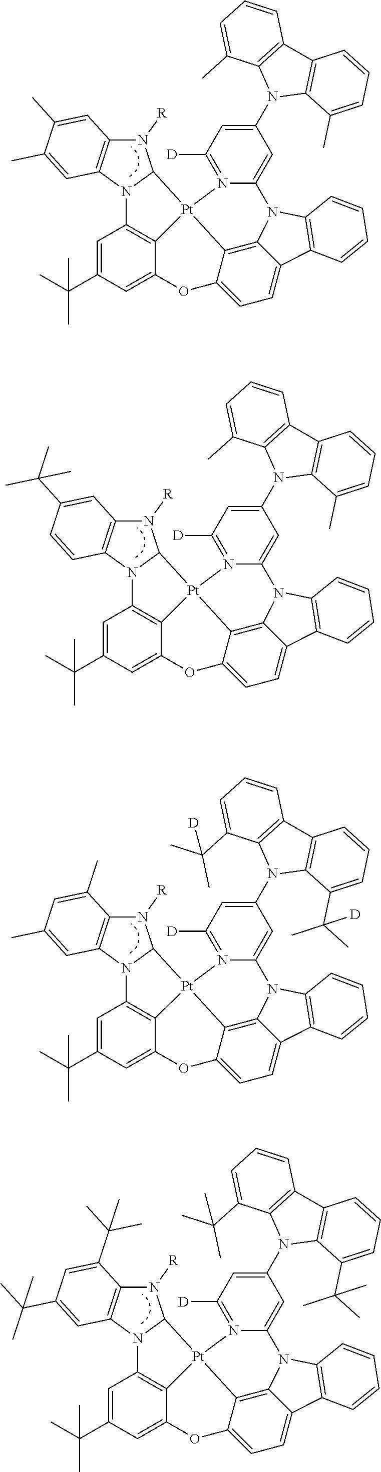 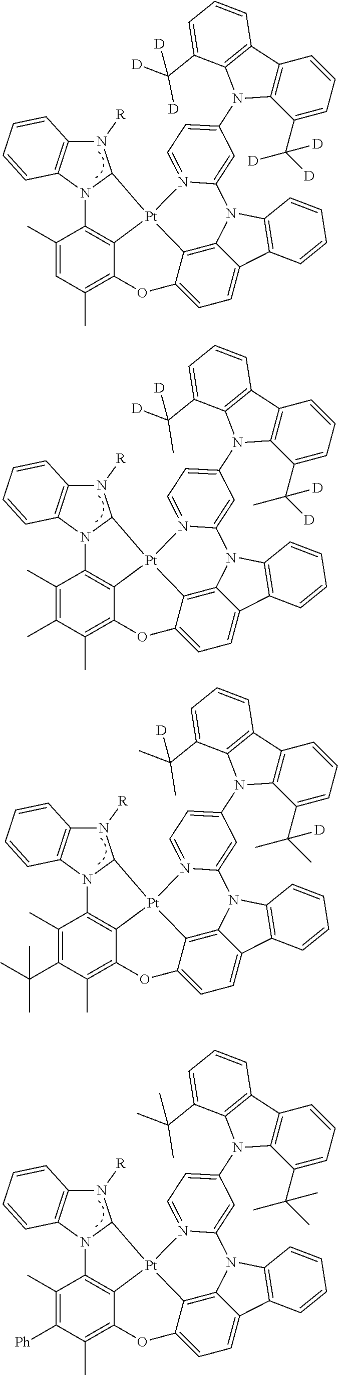 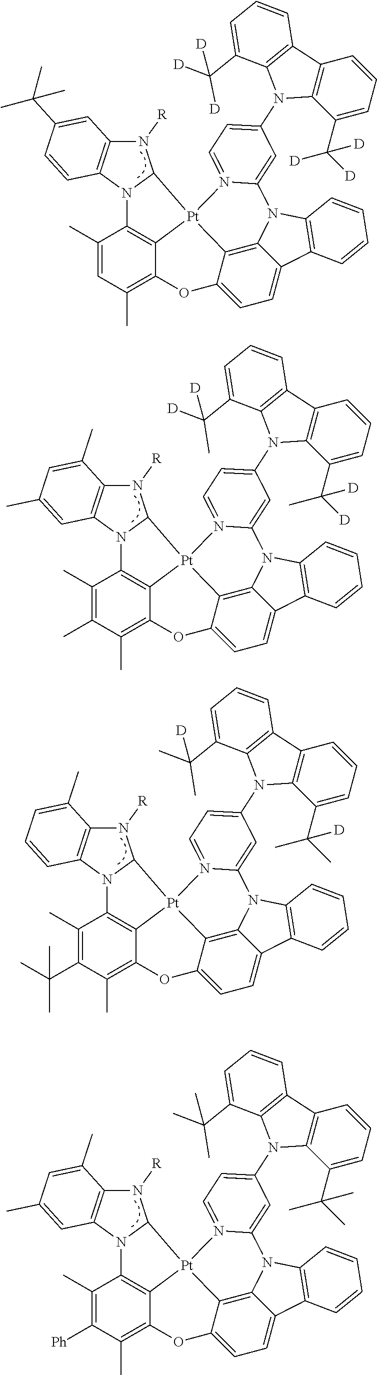 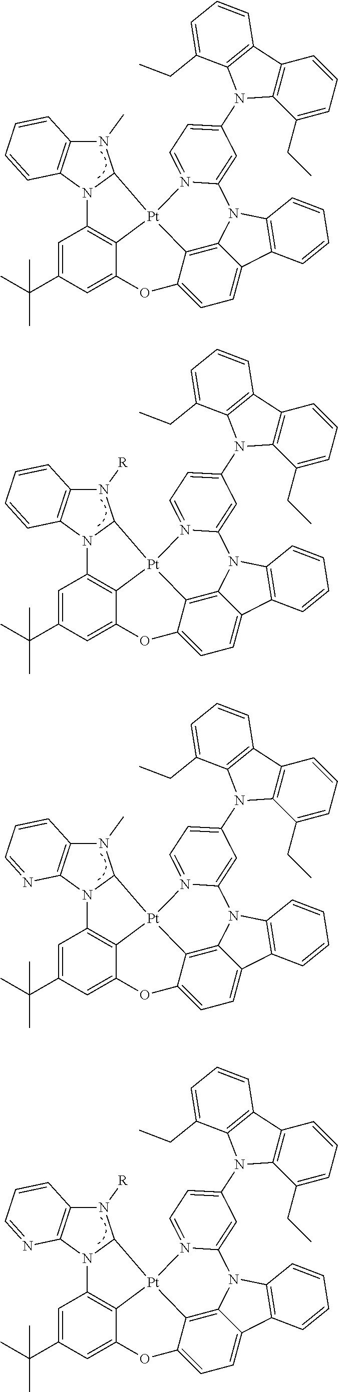 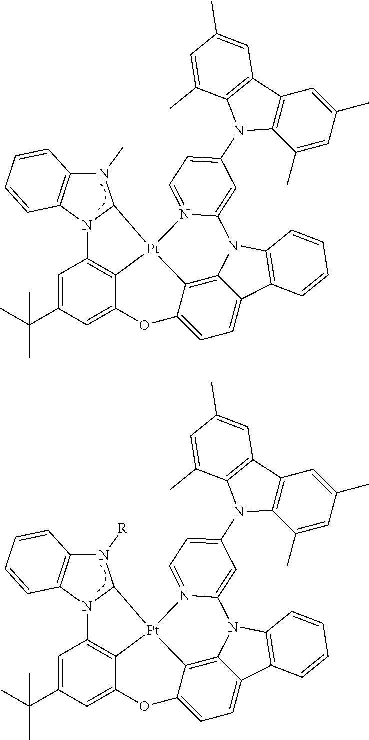 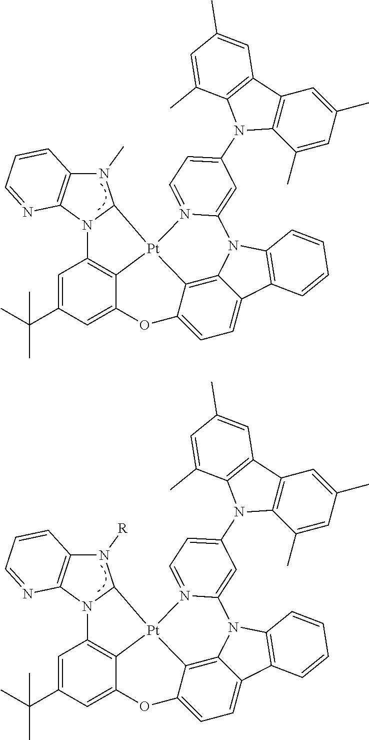 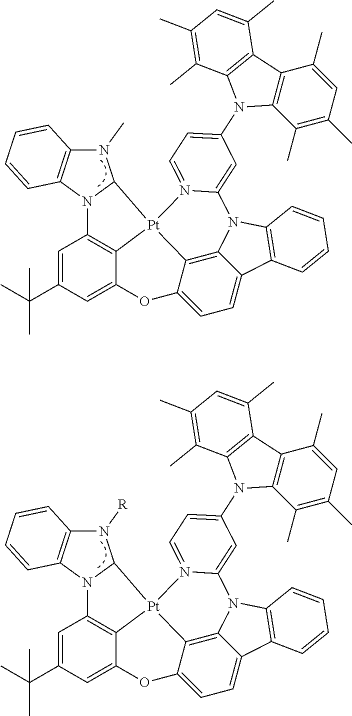 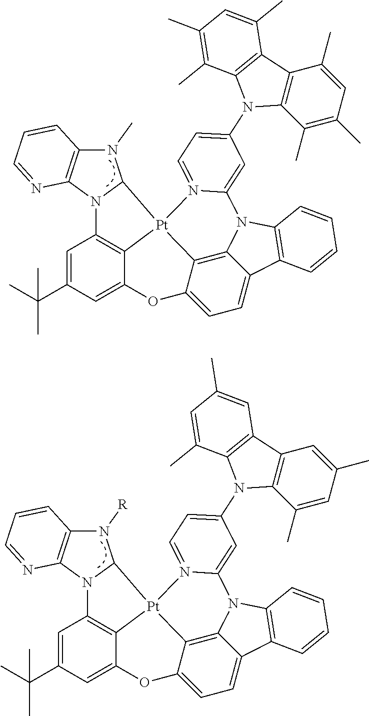 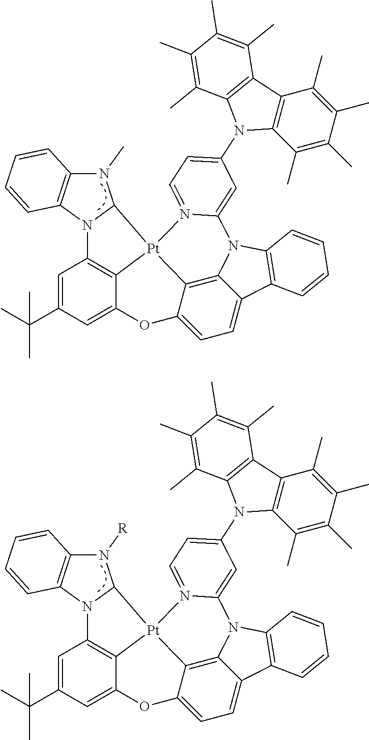 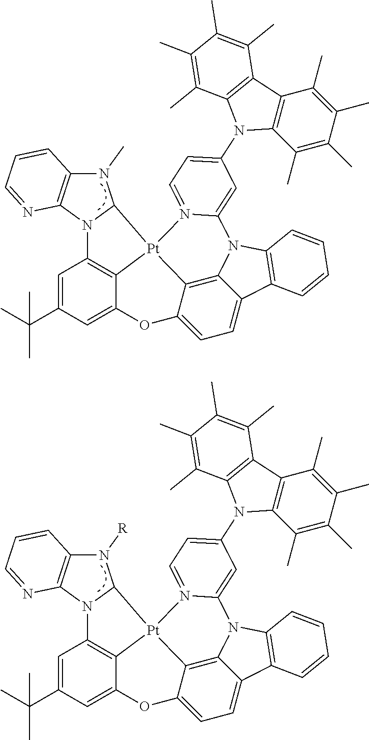 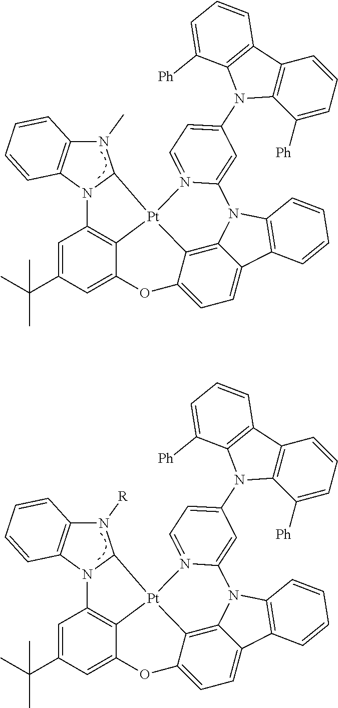 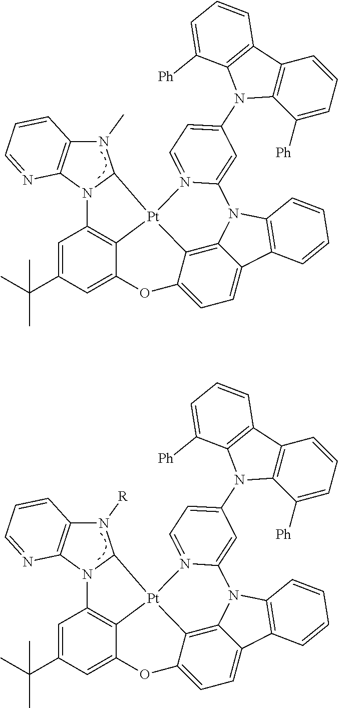 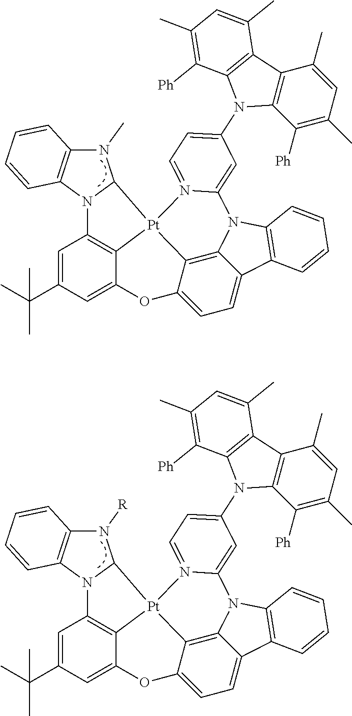 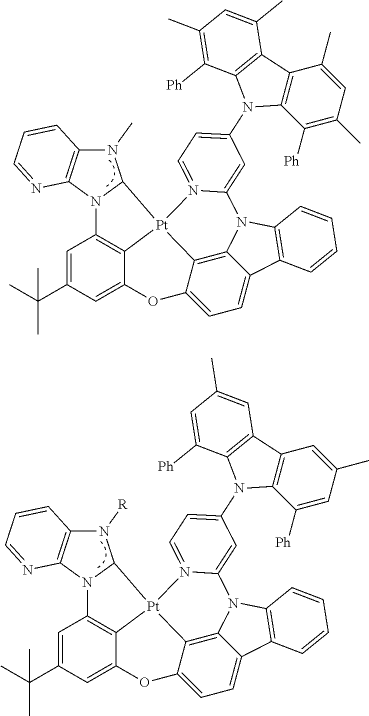 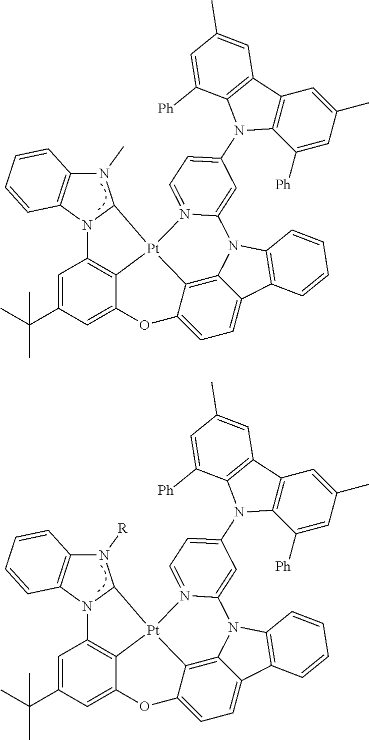 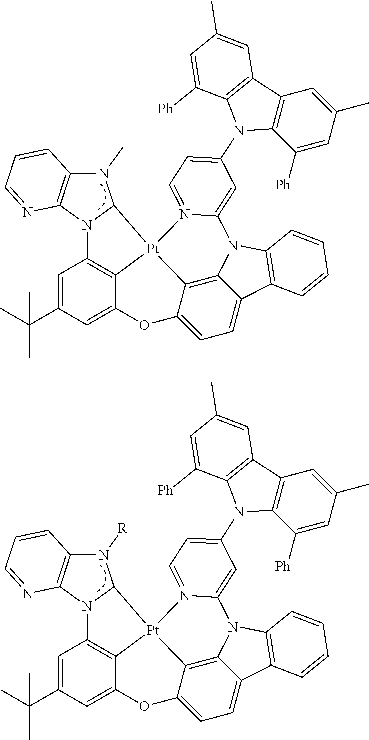 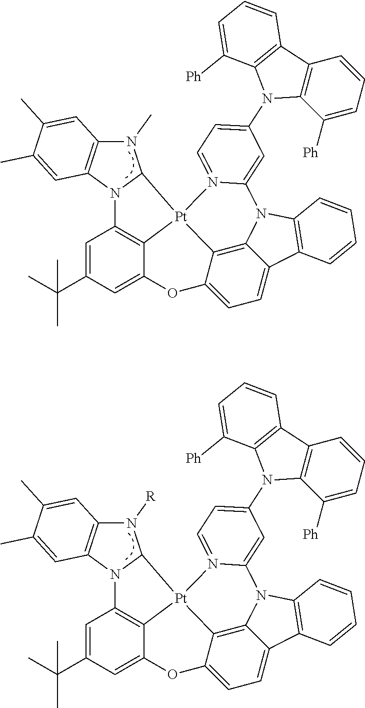 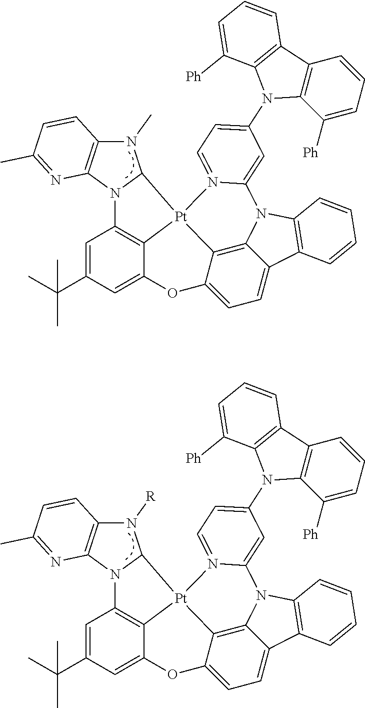 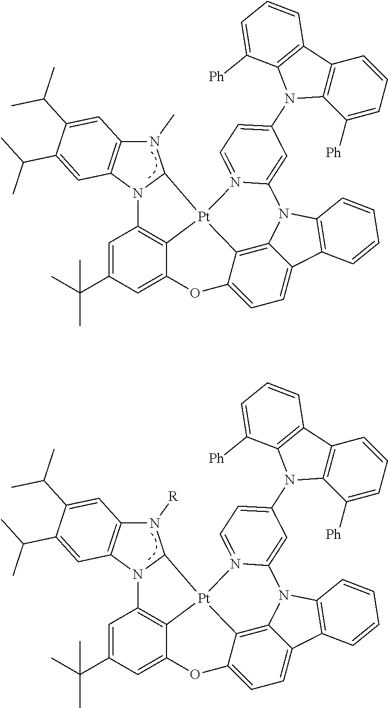 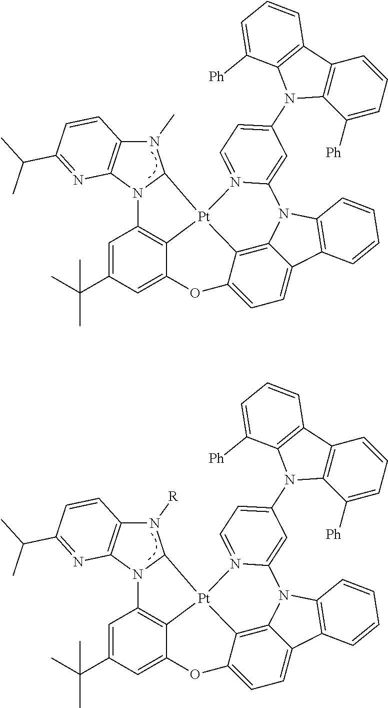 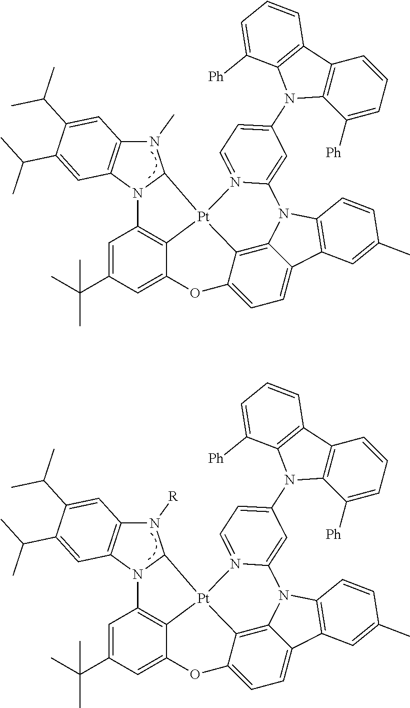 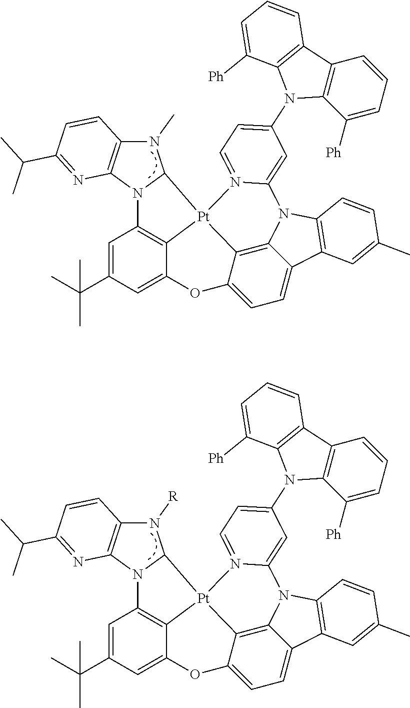 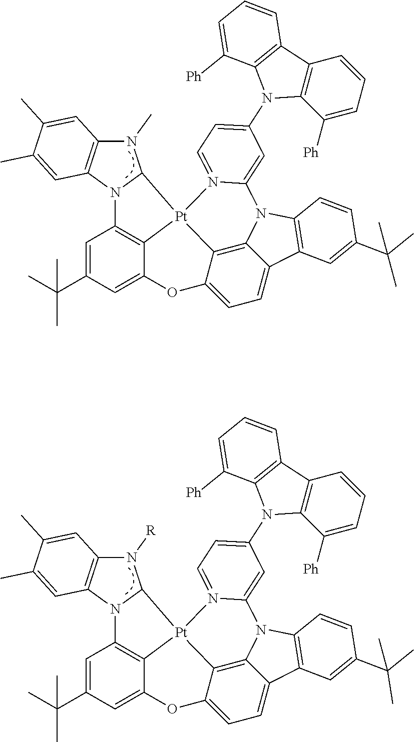 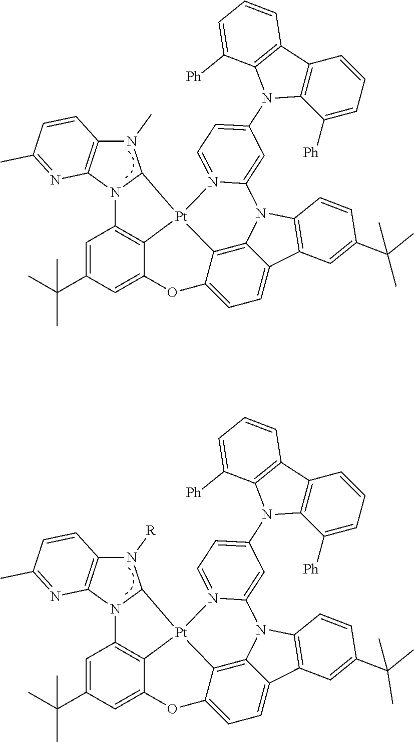
wherein R is not alkyl except for methyl, alkoxy, cycloalkyl, heterocyclyl, alkenyl, substituted or unsubstituted aryl, substituted or unsubstituted aryloxy, substituted or unsubstituted heteroaryl, or deuterated substituents thereof.

3. An organic light emitting device, comprising: the high radiation rate platinum complex luminescent material based on 1,8-substituted carbazole according to claim 1.

4. The organic light emitting device according to claim 3, wherein the organic light emitting device is an organic light emitting diode, a light emitting diode, a light emitting electrochemical cell or the like.

5. A light emitting device, comprising the high radiation rate platinum complex luminescent material based on 1,8-substituted carbazole according to claim 1 as a phosphorescence luminescent material or a delayed fluorescent material in an organic light emitting device.

6. A light emitting device, comprising a first electrode, a second electrode and an organic layer, wherein at least one of the organic layer is disposed between the first electrode and the second electrode; and the organic layer comprises the high radiation rate platinum complex luminescent material based on 1,8-substituted carbazole according to claim 1.

7. The light emitting device according to claim 6, wherein the organic layer is at least one of a hole injection layer, a hole transport layer, a light emitting layer or active layer, an electron blocking layer or an electron transport layer.

8. A display apparatus, comprising the light emitting device according to claim 6.

9. An organic light emitting device, comprising: the high radiation rate platinum complex luminescent material based on 1,8-substituted carbazole according to claim 2.

10. A light emitting device, comprising the high radiation rate platinum complex luminescent material based on 1,8-substituted carbazole according to claim 2 as a phosphorescence luminescent material or a delayed fluorescent material in an organic light emitting device.

11. A light emitting device, comprising a first electrode, a second electrode and an organic layer, wherein at least one of the organic layer is disposed between the first electrode and the second electrode; and the organic layer comprises the high radiation rate platinum complex luminescent material based on 1,8-substituted carbazole according to claim 2.
